(19) United States
(12) Patent Application Publication
(10) Pub. No.: US 2024/0423089 A1
(43) Pub. Date: Dec. 19, 2024

(54) LIGHT EMITTING ELEMENT, FUSED POLYCYCLIC COMPOUND FOR THE SAME, AND DISPLAY DEVICE INCLUDING THE LIGHT EMITTING ELEMENT

(71) Applicant: Samsung Display Co., Ltd., Yongin-si (KR)

(72) Inventors: TAEIL KIM, Yongin-si (KR); SUN YOUNG PAK, Yongin-si (KR); JUNHA PARK, Yongin-si (KR); MinJae SUNG, Yongin-si (KR); MUN-KI SIM, Yongin-si (KR); CHANSEOK OH, Yongin-si (KR); MINJUNG JUNG, Yongin-si (KR); Giwoong HAN, Yongin-si (KR); Seonhyoung HUR, Yongin-si (KR)

(73) Assignee: Samsung Display Co., Ltd., Yongin-si (KR)

(21) Appl. No.: 18/660,530

(22) Filed: May 10, 2024

(30) Foreign Application Priority Data
Jun. 8, 2023 (KR) 10-2023-0073832

(51) Int. Cl. H10K 85/60; C07F 5/02; C09K 11/06; H10K 50/11; H10K 101/00

(52) U.S. Cl. CPC H10K 85/658; C07F 5/027; C09K 11/06; C07B 2200/05; C09K 2211/1018; H10K 50/11; H10K 2101/90

(57) ABSTRACT

Embodiments provide a fused polycyclic compound, a light emitting element including the fused polycyclic compound, and a display device including the light emitting element. The light emitting element includes a first electrode, a second electrode facing the first electrode, and at least one functional layer disposed between the first electrode and the second electrode, wherein the at least one functional layer includes a first compound represented by Formula 1. Formula 1 is explained in the specification:

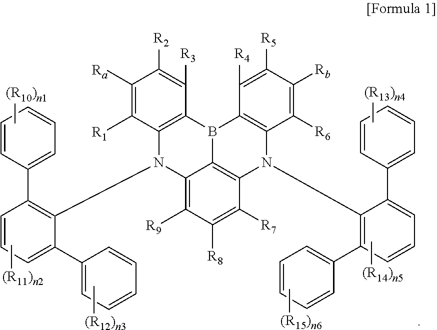

### CROSS-REFERENCE TO RELATED APPLICATION(S)

This application claims priority to and benefits of Korean Patent Application No. 10-2023-0073832 under 35 U.S.C. § 119, filed on Jun. 8, 2023, in the Korean Intellectual Property Office, the entire contents of which are incorporated herein by reference.

### BACKGROUND

### 1. Technical Field

The disclosure relates to a light emitting element, a fused polycyclic compound used therein, and a display device including the light emitting element.

### 2. Description of the Related Art

Active development continues for an organic electroluminescence display device as an image display device. In contrast to liquid crystal display devices and the like, an organic electroluminescence display device is a so-called self-luminescent display device in which holes and electrons respectively injected from a first electrode and a second electrode recombine in an emission layer, so that a luminescent material including an organic compound in the emission layer emits light to achieve display.

In the application of an organic electroluminescence device to a display device, there is a demand for an organic electroluminescence device having a low driving voltage, high luminous efficiency, and a long service life, and continuous development is required on materials for an organic electroluminescence device that are capable of stably achieving such characteristics.

In order to implement a highly efficient organic electroluminescence device, technologies pertaining to phosphorescence emission, which uses triplet state energy, or to fluorescence, which uses triplet-triplet annihilation (TTA) in which singlet excitons are generated by collision of triplet excitons, are being developed. Development is presently directed to thermally activated delayed fluorescence (TADF) materials which use delayed fluorescence phenomenon.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting element in which luminescence characteristics and an element service life are improved.

The disclosure also provides a fused polycyclic compound capable of improving luminescence characteristics and an element service life of a light emitting element.

The disclosure also provides a display device including the light emitting element in which the luminous efficiency and service life are improved, thereby having excellent display quality.

Embodiments provide a light emitting element which may include a first electrode, a second electrode disposed on the first electrode, and at least one functional layer disposed between the first electrode and the second electrode and including a first compound represented by Formula 1:

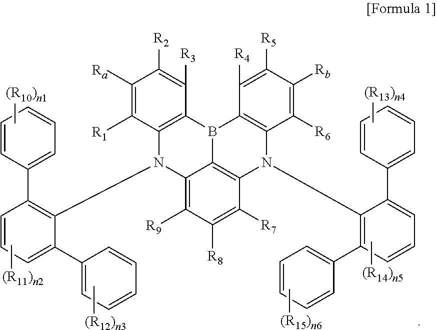

In Formula 1, R₁ to R₁₅ may each independently be a hydrogen atom, a deuterium atom, a halogen atom, a cyano group, a hydroxy group, a substituted or unsubstituted oxy group, a substituted or unsubstituted thio group, a substituted or unsubstituted boron group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms; Rₐ and R_{b} may each independently be a substituted or unsubstituted heteroaryl group having 2 to 30 ring-forming carbon atoms and a nitrogen atom (N) as a ring-forming atom, or a group represented by Formula 2; at least one of Rₐ and R_{b} may be a group represented by Formula 2; n1, n3, n4, and n6 may each independently be an integer from 0 to 5; and n2 and n5 may each independently be an integer from 0 to 3.

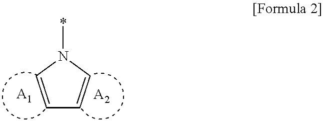

In Formula 2, A₁ and A₂ may each independently be a substituted or unsubstituted hydrocarbon ring having 6 to 30 carbon atoms or a substituted or unsubstituted heterocycle having 2 to 30 ring-forming carbon atoms; at least one of A₁ and A₂ may be a heterocycle including, as a ring-forming atom, at least one of a sulfur atom (S), a selenium atom (Se), and a tellurium atom (Te); and [symbol] is a position linked to Formula 1.

In an embodiment, the at least one functional layer may include an emission layer, a hole transport region disposed between the first electrode and the emission layer, and an electron transport region disposed between the emission layer and the second electrode; and the emission layer may include the first compound.

In an embodiment, the emission layer may emit delayed fluorescence having a central wavelength in a range of about 430 nm to about 490 nm.

In an embodiment, R₁ to R₇ and R₉ may each independently be a hydrogen atom or a deuterium atom; and R₈ may be a substituted or unsubstituted alkyl group having 1 to 4 carbon atoms, a substituted or unsubstituted aryl group having 6 to 30 ring-forming carbon atoms, or a substituted or unsubstituted heteroaryl group having 2 to 30 ring-forming carbon atoms.

In an embodiment, R₁₀ to R₁₅ may each independently be a hydrogen atom, a deuterium atom, a halogen atom, a cyano group, a substituted or unsubstituted alkyl group having 1 to 4 carbon atoms, or a substituted or unsubstituted aryl group having 6 to 12 ring-forming carbon atoms.

In an embodiment, wherein the first compound may be represented by Formula 1-1:

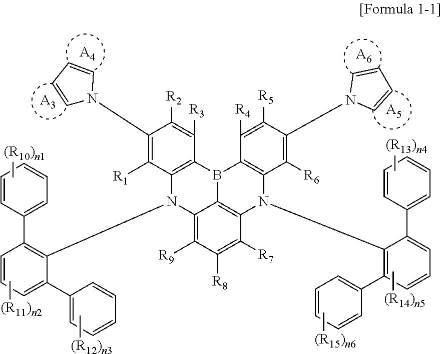

In Formula 1-1, A₃, A₄, A₅, and A₆ may each independently be a substituted or unsubstituted hydrocarbon ring having 6 to 30 carbon atoms or a substituted or unsubstituted heterocycle having 2 to 30 ring-forming carbon atoms; at least one of A₃, A₄, A₅, and A₆ may be a heterocycle including, as a ring-forming atom, at least one of a sulfur atom (S), a selenium atom (Se), and a tellurium atom (Te); and R₁ to R₁₅ and n1 to n6 are the same as defined in Formula 1.

In an embodiment, the group represented by Formula 2 may be a group represented by any one of Formula 2-1 to Formula 2-4:

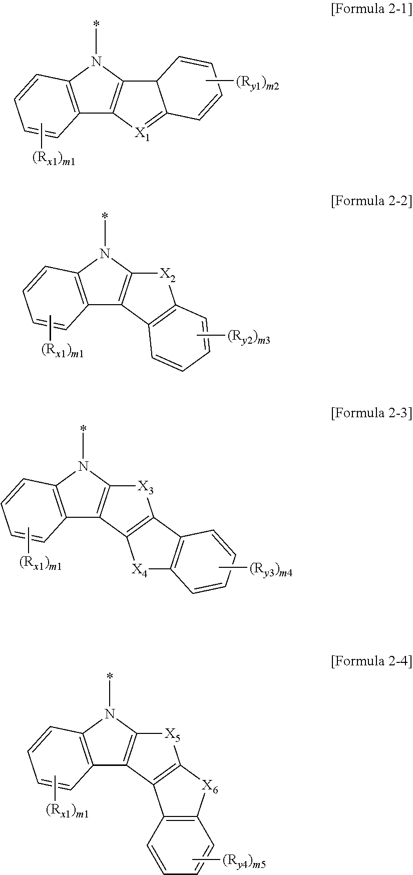

In Formula 2-1 to Formula 2-4, Rₓ₁ and R_{y1} to R_{y4} may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms; X₁ to X₆ may each independently be a sulfur atom (S), a selenium atom (Se), or a tellurium atom (Te); m1 to m5 may each independently be an integer from 0 to 4; and [symbol] is a position linked to Formula 1.

In an embodiment, Rₓ₁ and R_{y1} to R_{y4} may each independently be a hydrogen atom, a deuterium atom, a halogen atom, a cyano group, a substituted or unsubstituted alkyl group having 1 to 4 carbon atoms, or a substituted or unsubstituted aryl group having 6 to 12 ring-forming carbon atoms.

In an embodiment, the group represented by Formula 2 may be a group represented by Formula 3:

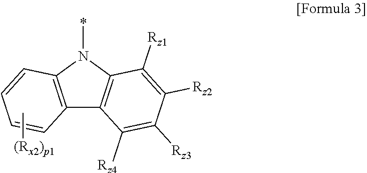

In Formula 3, Rₓ₂ may be a hydrogen atom, a deuterium atom, a halogen atom, a cyano group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms; R_{z1} to R_{z4} may each independently be a hydrogen atom, a deuterium atom, a thio group, a selenyl group, a tellanyl group, a substituted or unsubstituted aryl group having 6 to 30 ring-forming carbon atoms, or a substituted or unsubstituted heteroaryl group having 2 to 30 ring-forming carbon atoms; one of R_{z1} to R_{z4} may be a thio group, a selenyl group, or a tellanyl group, and may be bonded to an adjacent group among the remainder of R_{z1} to R_{z4} to form a ring; p1 may be an integer from 0 to 4; and [symbol] is a position linked to Formula 1.

In an embodiment, the group represented by Formula 3 may be a group represented by one of Formula 3-1 to Formula 3-6:

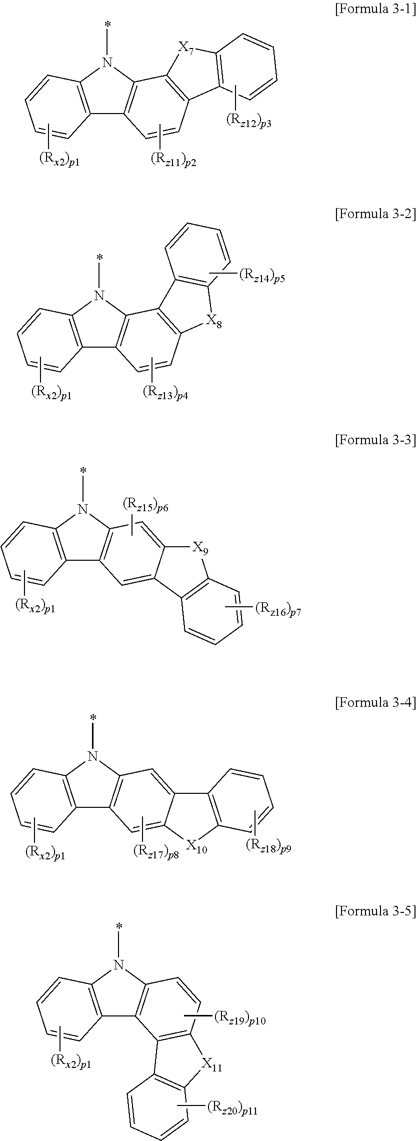

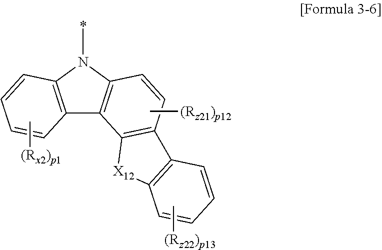

In Formula 3-1 to Formula 3-6, R_{z11} to R_{z22} may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms; X₇ to X₁₂ may each independently be a sulfur atom (S), a selenium atom (Se), or a tellurium atom (Te); p2, p4, p6, p8, p10, and p12 may each independently be an integer from 0 to 2; p3, p5, p7, p9, p11, and p13 may each independently be an integer from 0 to 4; and Rₓ₂, p1, and [symbol] are the same as defined in Formula 3.

In an embodiment, R_{z11} to R_{z22} may each independently be a hydrogen atom, a deuterium atom, a halogen atom, a cyano group, a substituted or unsubstituted alkyl group having 1 to 4 carbon atoms, or a substituted or unsubstituted aryl group having 6 to 12 ring-forming carbon atoms.

In an embodiment, the first compound may include at least one compound selected from Compound Group 1, which is described below.

Embodiments provide a fused polycyclic compound which may be represented by Formula 1, which is described herein.

In an embodiment, R₁ to R₇ and R₉ may each independently be a hydrogen atom or a deuterium atom; and R₈ may be a substituted or unsubstituted alkyl group having 1 to 4 carbon atoms, a substituted or unsubstituted aryl group having 6 to 30 ring-forming carbon atoms, or a substituted or unsubstituted heteroaryl group having 2 to 30 ring-forming carbon atoms.

In an embodiment, R₁₀ to R₁₅ may each independently be a hydrogen atom, a deuterium atom, a halogen atom, a cyano group, a substituted or unsubstituted alkyl group having 1 to 4 carbon atoms, or a substituted or unsubstituted aryl group having 6 to 12 ring-forming carbon atoms.

In an embodiment, the fused polycyclic compound represented by Formula 1 may be represented by Formula 1-1, which is described herein.

In an embodiment, the group represented by Formula 2 may be a group represented by one of Formula 2-1 to Formula 2-4, which are described herein

In an embodiment, the group represented by Formula 2 may be a group represented by one of Formula 3-1 to Formula 3-6, which are described herein.

In an embodiment, the fused polycyclic compound represented by Formula 1 may be selected from Compound Group 1, which is described below.

Embodiments provide a display device which may include a circuit layer disposed on a base layer, and a display element layer disposed on the circuit layer and including a light emitting element. The light emitting element may include a first electrode, a second electrode disposed on the first electrode, and an emission layer disposed between the first electrode and the second electrode and including a first compound represented by Formula 1, which is described herein.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the principles thereof. The above and other aspects and features of the disclosure will become more apparent by describing in detail embodiments thereof with reference to the accompanying drawings in which:

FIG. 1 is a schematic plan view of a display device according to an embodiment;

FIG. 2 is a schematic cross-sectional view of a display device according to an embodiment;

FIG. 3 is a schematic cross-sectional view of a light emitting element according to an embodiment;

FIG. 4 is a schematic cross-sectional view of a light emitting element according to an embodiment;

FIG. 5 is a schematic cross-sectional view of a light emitting element according to an embodiment;

FIG. 6 is a schematic cross-sectional view of a light emitting element according to an embodiment;

FIG. 7 is a schematic cross-sectional view of a display device according to an embodiment;

FIG. 8 is a schematic cross-sectional view of a display device according to an embodiment;

FIG. 9 is a schematic cross-sectional view of a display device according to an embodiment;

FIG. 10 is a schematic cross-sectional view of a display device according to an embodiment; and

FIG. 11 is a schematic perspective view of an interior of a vehicle in which display devices are disposed according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and/or like reference characters refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amino group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the phrase “bonded to an adjacent group to form a ring” may be interpreted as a group that is bonded to an adjacent group to form a substituted or unsubstituted hydrocarbon ring or a substituted or unsubstituted heterocycle. The hydrocarbon ring may be aliphatic or aromatic. The heterocycle may be aliphatic or aromatic. The hydrocarbon ring and the heterocycle may each independently be monocyclic or polycyclic. A ring that is formed by adjacent groups being bonded to each other may itself be connected to another ring to form a spiro structure.

In the specification, the term “adjacent group” may be interpreted as a substituent that is substituted for an atom which is directly linked to an atom substituted with a corresponding substituent, as another substituent substituted for an atom which is substituted with a corresponding substituent, or as a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, or an iodine atom.

In the specification, an alkyl group may be linear or branched. The number of carbons in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, a cycloalkyl group may be a cyclic alkyl group. The number of carbons in a cycloalkyl group may be 3 to 50, 3 to 30, 3 to 20, or 3 to 10. Examples of a cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but embodiments are not limited thereto.

In the specification, an alkenyl group may be a hydrocarbon group including at least one carbon-carbon double bond in the middle or at a terminus of an alkyl group having 2 or more carbon atoms. The alkenyl group may be linear or branched. The number of carbon atoms in an alkenyl group is not specifically limited, but may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, etc., but embodiments are not limited thereto.

In the specification, an alkynyl group may be a hydrocarbon group including at least one carbon-carbon triple bond in the middle or at a terminus of an alkyl group having 2 or more carbon atoms. The alkynyl group may be linear or branched. Although the number of carbon atoms is not specifically limited, it may be 2 to 30, 2 to 20, or 2 to 10. Examples of an alkynyl group may include an ethynyl group, a propynyl group, etc., but are not limited thereto.

In the specification, the hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the specification, an aryl group may be any functional group or substituent derived from an aromatic hydrocarbon ring. The aryl group may be monocyclic or polycyclic. The number of ring-forming carbon atoms in the aryl group may be 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorenyl group may be substituted, and two substituents may be bonded to each other to form a spiro structure. Examples of a substituted fluorenyl group are as follows, but embodiments are not limited thereto.

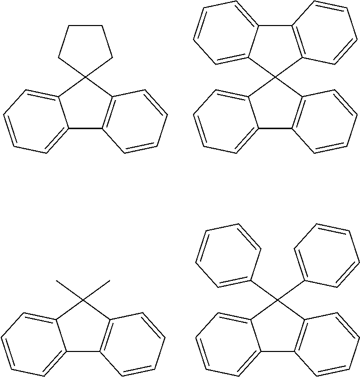

In the specification, a heterocyclic group may be any functional group or substituent derived from a ring containing at least one of B, O, N, P, Si, S, Se, or Te as a heteroatom. The heterocyclic group may be aliphatic or aromatic. An aromatic heterocyclic group may be a heteroaryl group. The aliphatic heterocycle and the aromatic heterocycle may each independently be monocyclic or polycyclic.

In the specification, a heterocyclic group may contain at least one of B, O, N, P, Si, S, Se, or Te as a heteroatom. If the heterocyclic group contains two or more heteroatoms, the two or more heteroatoms may be the same as or different from each other. The heterocyclic group may be monocyclic or polycyclic, and a heterocyclic group may be a heteroaryl group. The number of ring-forming carbon atoms in a heterocyclic group may be 2 to 30, 2 to 20, or 2 to 10.

In the specification, an aliphatic heterocyclic group may contain at least one of B, O, N, P, Si, S, Se, or Te as a heteroatom. The number of ring-forming carbon atoms in an aliphatic heterocyclic group may be 2 to 30, 2 to 20, or 2 to 10. Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

In the specification, a heteroaryl group may contain at least one of B, O, N, P, Si, S, Se, or Te as a heteroatom. If a heteroaryl group contains two or more heteroatoms, the two or more heteroatoms may be the same as or different from each other. A heteroaryl group may be monocyclic or polycyclic. The number of ring-forming carbon atoms in a heteroaryl group may be 2 to 30, 2 to 20, or 2 to 10. Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a benzothienocarbazole group, a benzothienoindole group, a benzodibenzothiophene group, a thienothiophene group, an indolodibenzothiophene group, a benzoselenophene group, a dibenzoselenophene group, a benzoselenophenocarbazole group, a benzoselenophenoindole group, a benzotellurophene group, a dibenzotellurophene group, a benzotellurophenocarbazole group, a benzotellurophenoindole group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of an aryl group may be applied to an arylene group, except that an arylene group may be a divalent group. The above description of a heteroaryl group may be applied to a heteroarylene group, except that a heteroarylene group may be a divalent group.

In the specification, a silyl group may be an alkylsilyl group or an arylsilyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, the number of carbon atoms in a carbonyl group is not specifically limited, but may be 1 to 40, 1 to 30, or 1 to 20. For example, a carbonyl group may have one of the following structures, but embodiments are not limited thereto.

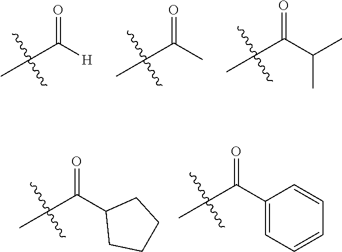

In the specification, the number of carbon atoms in a sulfinyl group and a sulfonyl group is not particularly limited, but may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkylthio group or an arylthio group. A thio group may be a sulfur atom that is bonded to an alkyl group or to an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments are not limited thereto.

In the specification, an oxy group may be an oxygen atom that is bonded to an alkyl group or an aryl group as defined above. An oxy group may be an alkoxy group or an aryl oxy group. The alkoxy group may be linear, branched, or cyclic. The number of carbon atoms in an alkoxy group is not specifically limited, but may be, for example, 1 to 20 or 1 to 10.

Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a boron group may be a boron atom that is bonded to an alkyl group or an aryl group as defined above. A boron group may be an alkyl boron group or an aryl boron group. Examples of a boron group may include a dimethylboron group, a trimethylboron group, a t-butyldimethylboron group, a diphenylboron group, a phenylboron group, etc., but embodiments are not limited thereto.

In the specification, a selenyl group may be an alkyl selenyl group or an aryl selenyl group. A selenyl group may be a selenium atom that is bonded to an alkyl group or an aryl group as defined above. Examples of a selenyl group may include a methylselenyl group, an ethylselenyl group, a propylselenyl group, a pentylselenyl group, a hexylselenyl group, an octylselenyl group, a dodecylselenyl group, a cyclopentylselenyl group, a cyclohexylselenyl group, a phenylselenyl group, a naphthylselenyl group, or the like, but embodiments are not limited thereto.

In the specification, a tellanyl group may be an alkyl tellanyl group or an aryl tellanyl group. A tellanyl group may be a tellurium atom that is bonded to an alkyl group or an aryl group as defined above. Examples of a tellanyl group may include a methyltellanyl group, an ethyltellanyl group, a propyltellanyl group, a pentyltellanyl group, a hexyltellanyl group, an octyltellanyl group, a dodecyltellanyl group, a cyclopentyltellanyl group, a cyclohexyltellanyl group, a phenyltellanyl group, a naphthyltellanyl group, or the like, but embodiments are not limited thereto.

In the specification, an alkyl group within an alkylthio group, an alkylsulfoxy group, an alkylaryl group, an alkylamino group, an alkyl boron group, an alkyl silyl group, or an alkyl amine group may be the same as an example of an alkyl group as described above.

In the specification, an aryl group within an aryloxy group, an arylthio group, an arylsulfoxy group, an arylamino group, an arylboron group, an arylsilyl group, or an arylamine group may be the same as an example of an aryl group as described above.

In the specification, a direct linkage may be a single bond.

In the specification, the symbols

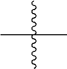

and [symbol] each represent a bonding site to a neighboring atom.

Hereinafter, embodiments will be described with reference to the accompanying drawings.

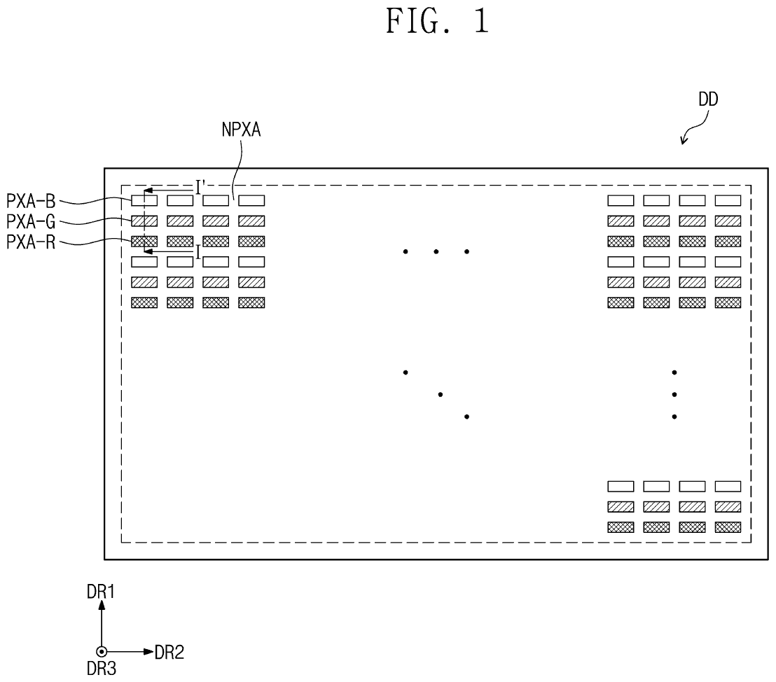

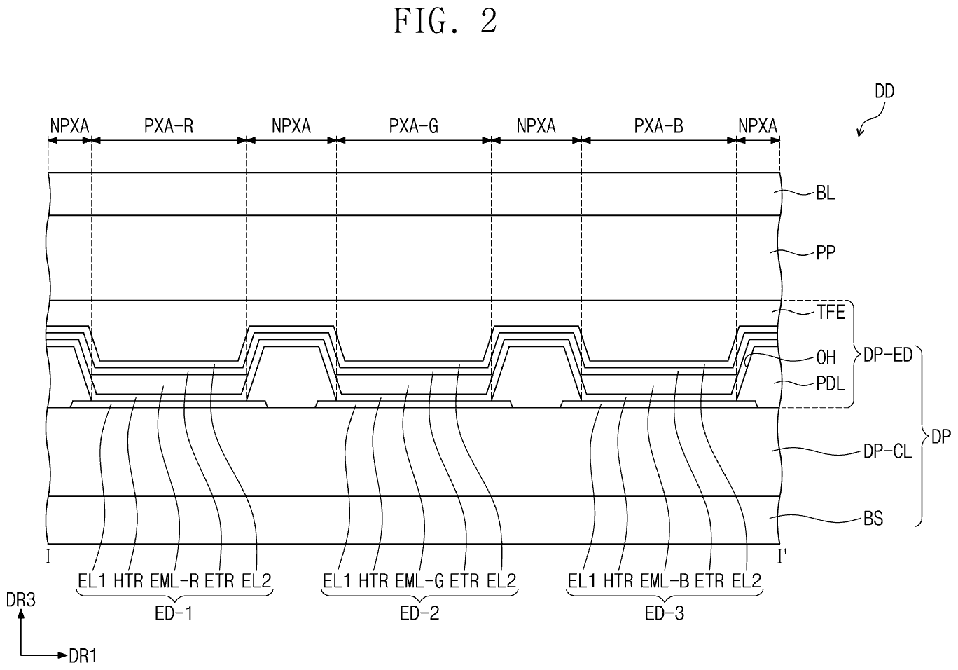

FIG. 1 is a schematic plan view illustrating an embodiment of a display device DD. FIG. 2 is a schematic cross-sectional view of the display device DD according to an embodiment. FIG. 2 is a schematic cross-sectional view illustrating a part taken along line I-I′ of FIG. 1.

The display device DD may include a display panel DP and an optical layer PP disposed on the display panel DP. The display panel DP includes light emitting elements ED-1, ED-2, and ED-3. The display device DD may include multiples of each of the light emitting elements ED-1, ED-2, and ED-3. The optical layer PP may be disposed on the display panel DP to control light that is reflected at the display panel DP from an external light. The optical layer PP may include, for example, a polarization layer or a color filter layer. Although not shown in the drawings, in an embodiment, the optical layer PP may be omitted from the display device DD.

A base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display device DD according to an embodiment may further include a filling layer (not shown). The filling layer (not shown) may be disposed between a display device layer DP-ED and the base substrate BL. The filling layer (not shown) may be an organic material layer.

The filling layer (not shown) may include at least one of an acrylic-based resin, a silicone-based resin, and an epoxy-based resin.

The display panel DP may include a base layer BS, a circuit layer DP-CL provided on the base layer BS, and the display device layer DP-ED. The display device layer DP-ED may include a pixel defining film PDL, the light emitting elements ED-1, ED-2, and ED-3 disposed between portions of the pixel defining film PDL, and an encapsulation layer TFE disposed on the light emitting elements ED-1, ED-2, and ED-3.

The base layer BS may provide a base surface on which the display device layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). Each of the transistors (not shown) may include a control electrode, an input electrode, and an output electrode. For example, the circuit layer DP-CL may include a switching transistor and a driving transistor for driving the light emitting elements ED-1, ED-2, and ED-3 of the display device layer DP-ED.

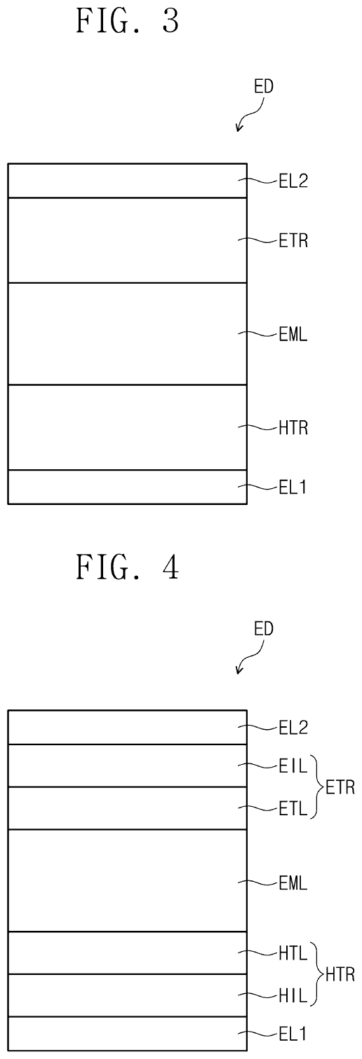

The light emitting elements ED-1, ED-2, and ED-3 may each have a structure of a light emitting element ED of an embodiment according to any of FIGS. 3 to 6, which will be described later. The light emitting elements ED-1, ED-2, and ED-3 may each include a first electrode EL1, a hole transport region HTR, emission layers EML-R, EML-G, and EML-B, an electron transport region ETR, and a second electrode EL2.

FIG. 2 illustrates an embodiment in which the emission layers EML-R, EML-G, and EML-B of the light emitting elements ED-1, ED-2, and ED-3 are disposed in openings OH defined in the pixel defining film PDL, and the hole transport region HTR, the electron transport region ETR, and the second electrode EL2 are each provided as a common layer for all of the light emitting elements ED-1, ED-2, and ED-3. However, embodiments are not limited thereto. Although not shown in FIG. 2, in an embodiment, the hole transport region HTR and the electron transport region ETR may each be provided by being patterned inside the openings OH defined in the pixel defining film PDL. For example, in an embodiment, the hole transport region HTR, the emission layers EML-R, EML-G, and EML-B, and the electron transport region ETR of the light emitting elements ED-1, ED-2, and ED-3 may each be provided by being patterned by an inkjet printing method.

The encapsulation layer TFE may cover the light emitting elements ED-1, ED-2, and ED-3. The encapsulation layer TFE may seal the display device layer DP-ED. The encapsulation layer TFE may be a thin film encapsulation layer. The encapsulation layer TFE may be formed by laminating a single layer or multiple layers. The encapsulation layer TFE may include at least one insulation layer. The encapsulation layer TFE according to an embodiment may include at least one inorganic film (hereinafter, an encapsulation-inorganic film). The encapsulation layer TFE according to an embodiment may also include at least one organic film (hereinafter, an encapsulation-organic film) and at least one encapsulation-inorganic film.

The encapsulation-inorganic film may protect the display device layer DP-ED from moisture and/or oxygen, and the encapsulation-organic film may protect the display device layer DP-ED from foreign substances such as dust particles. The encapsulation-inorganic film may include silicon nitride, silicon oxynitride, silicon oxide, titanium oxide, aluminum oxide, or the like, but the embodiment of the inventive concept is not particularly limited thereto. The encapsulation-organic film may include an acrylic-based compound, an epoxy-based compound, or the like. The encapsulation-organic film may include a photopolymerizable organic material, but embodiments are not particularly limited thereto.

The encapsulation layer TFE may be disposed on the second electrode EL2 and may be disposed to fill the openings OH.

Referring to FIGS. 1 and 2, the display device DD may include a non-light emitting region NPXA and light emitting regions PXA-R, PXA-G, and PXA-B. The light emitting regions PXA-R, PXA-G, and PXA-B may each be a region that emits light respectively generated by the light emitting elements ED-1, ED-2, and ED-3. The light emitting regions PXA-R, PXA-G, and PXA-B may be spaced apart from each other in a plan view.

The light emitting regions PXA-R, PXA-G, and PXA-B may each be a region separated by the pixel defining film PDL. The non-light emitting areas NPXA may be areas between the adjacent light emitting areas PXA-R, PXA-G, and PXA-B, which correspond to the pixel defining film PDL. For example, in an embodiment, the light emitting regions PXA-R, PXA-G, and PXA-B may each correspond to a pixel. The pixel defining film PDL may separate the light emitting elements ED-1, ED-2, and ED-3. The emission layers EML-R, EML-G, and EML-B of the light emitting elements ED-1, ED-2, and ED-3 may be disposed in the openings OH defined in the pixel defining film PDL and separated from each other.

The light emitting regions PXA-R, PXA-G, and PXA-B may be arranged into groups according to the color of light generated from the light emitting elements ED-1, ED-2, and ED-3. In the display device DD according to an embodiment illustrated in FIGS. 1 and 2, three light emitting regions PXA-R, PXA-G, and PXA-B, which respectively emit red light, green light, and blue light, are illustrated as an example. For example, the display device DD may include the red light emitting region PXA-R, the green light emitting region PXA-G, and the blue light emitting region PXA-B that are separated from each other.

In the display device DD according to an embodiment, the light emitting elements ED-1, ED-2, and ED-3 may emit light having wavelengths that are different from each other. For example, in an embodiment, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may respectively correspond to the first light emitting element ED-1, the second light emitting element ED-2, and the third light emitting element ED-3.

However, embodiments are not limited thereto, and the first to third light emitting elements ED-1, ED-2, and ED-3 may emit light in a same wavelength range or at least one light emitting element may emit a light in a wavelength range different from the other light emitting elements. For example, the first to third light emitting elements ED-1, ED-2, and ED-3 may all emit blue light.

The light emitting regions PXA-R, PXA-G, and PXA-B in the display device DD according to an embodiment may be arranged in a stripe configuration. Referring to FIG. 1, the red light emitting regions PXA-R, the green light emitting regions PXA-G, and the blue light emitting regions PXA-B may be arranged along a second directional axis DR2. In another embodiment, the red light emitting region PXA-R, the green light emitting region PXA-G, and the blue light emitting region PXA-B may be arranged in this repeating order along a first directional axis DR1.

FIGS. 1 and 2 illustrate that the light emitting regions PXA-R, PXA-G, and PXA-B have a similar area to each other, but embodiments are not limited thereto. Thus, the light emitting regions PXA-R, PXA-G, and PXA-B may be different in size of shape from each other according to a wavelength range of the emitted light. The areas of the light emitting regions PXA-R, PXA-G, and PXA-B may be areas in a plan view that are defined by the first directional axis DR1 and the second directional axis DR2.

An arrangement of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations according to the display quality characteristics which are required in the display device DD. For example, the light emitting regions PXA-R, PXA-G, and PXA-B may be arranged in a pentile configuration (such as PENTILE®) or in a diamond configuration (such as Diamond Pixel®).

The areas of the light emitting regions PXA-R, PXA-G, and PXA-B may be different in size from each other. For example, in an embodiment, an area of the green light emitting region PXA-G may be smaller than an area of the blue light emitting region PXA-B, but embodiments are not limited thereto.

Hereinafter, FIG. 3 to FIG. 6 each a schematic cross-sectional view showing a light emitting element according to an embodiment. The light emitting element ED according to an embodiment may include a first electrode EL1, a hole transport region HTR, an emission layer EML, an electron transport region ETR, and a second electrode EL2 stacked in that order.

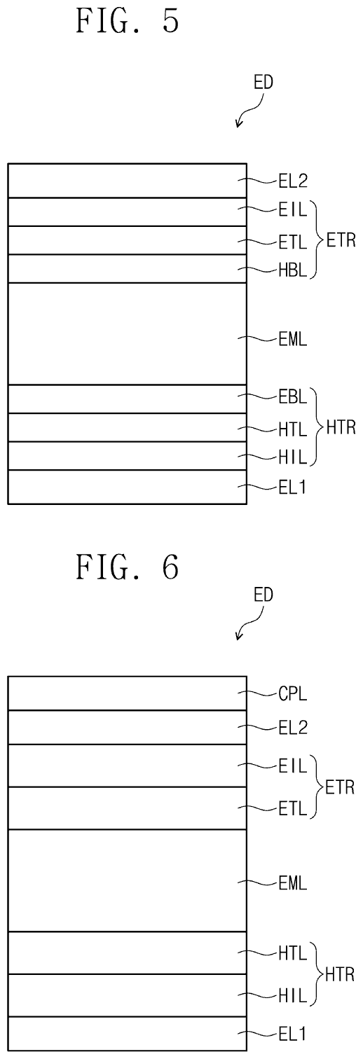

In comparison to FIG. 3, FIG. 4 illustrates a schematic cross-sectional view of a light emitting element ED, in which a hole transport region HTR includes a hole injection layer HIL and a hole transport layer HTL, and an electron transport region ETR includes an electron injection layer EIL and an electron transport layer ETL. In comparison to FIG. 3, FIG. 5 illustrates a schematic cross-sectional view of a light emitting element ED, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison to FIG. 4, FIG. 6 illustrates a schematic cross-sectional view of a light emitting element ED that includes a capping layer CPL disposed on a second electrode EL2.

In the light emitting element ED, the first electrode EL1 may have conductivity. The first electrode EL1 may be formed of a metal material, a metal alloy, or a conductive compound. The first electrode EL1 may be an anode or a cathode. However, the embodiments are not limited thereto. For example, the first electrode EL1 may be a pixel electrode. The first electrode EL1 may be a transmissive electrode, a transflective electrode, or a reflective electrode. The first electrode EL1 may include Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In an embodiment, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but embodiments are not limited thereto. In an embodiment, the first electrode EL1 may include the above-described metal materials, combinations of at least two metal materials of the above-described metal materials, oxides of the above-described metal materials, or the like. A thickness of the first electrode EL1 may be in a range of about 700 Å to about 10,000 Å. For example, the thickness of the first electrode EL1 may be in a range of about 1,000 Å to about 3,000 Å.

The hole transport region HTR is provided on the first electrode EL1. The hole transport region HTR may include at least one of a hole injection layer HIL, a hole transport layer HTL, a buffer layer (not shown), an emission-auxiliary layer (not shown), and an electron blocking layer EBL. A thickness of the hole transport region HTR may be, for example, in a range of about 50 Å to about 15,000 Å.

The hole transport region HTR may be a layer consisting of a single material, a layer including different materials, or a structure including multiple layers including different materials.

For example, the hole transport region HTR may have a single layer structure of a hole injection layer HIL or a hole transport layer HTL, or may have a single layer structure formed of a hole injection material and a hole transport material. In other embodiments, the hole transport region HTR may have a single layer structure formed of different materials, or may have a structure in which a hole injection layer HIL/hole transport layer HTL, a hole injection layer HIL/hole transport layer HTL/buffer layer (not shown), a hole injection layer HIL/buffer layer (not shown), a hole transport layer HTL/buffer layer (not shown), or a hole injection layer HIL/hole transport layer HTL/electron blocking layer EBL are stacked in its respective stated order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

The hole transport region HTR may include a compound represented by Formula H-1:

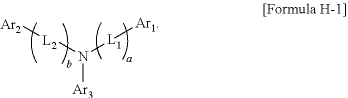

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, a and b may each independently be an integer from 0 to 10. When a or b is 2 or greater, multiple L₁ groups or multiple L₂ groups may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In Formula H-1, Ar₃ may be a substituted or unsubstituted aryl group having 6 to 30 ring-forming carbon atoms or a substituted or unsubstituted heteroaryl group having 2 to 30 ring-forming carbon atoms.

In an embodiment, the compound represented by Formula H-1 may be a monoamine compound. In another embodiment, the compound represented by Formula H-2 may be a diamine compound in which at least one of Ar₁ to Ar₃ includes an amine group as a substituent. In still other embodiments, the compound represented by Formula H-1 may be a carbazole-based compound in which at least one of Ar₁ and Ar₂ includes a substituted or unsubstituted carbazole group, or a fluorene-based compound in which at least one of Ar₁ and Ar₂ includes a substituted or unsubstituted fluorene group.

The compound represented by Formula H-1 may be any compound selected from Compound Group H. However, the compounds listed in Compound Group H are only examples, and the compounds represented by Formula H-1 are not limited to those represented by Compound Group H:

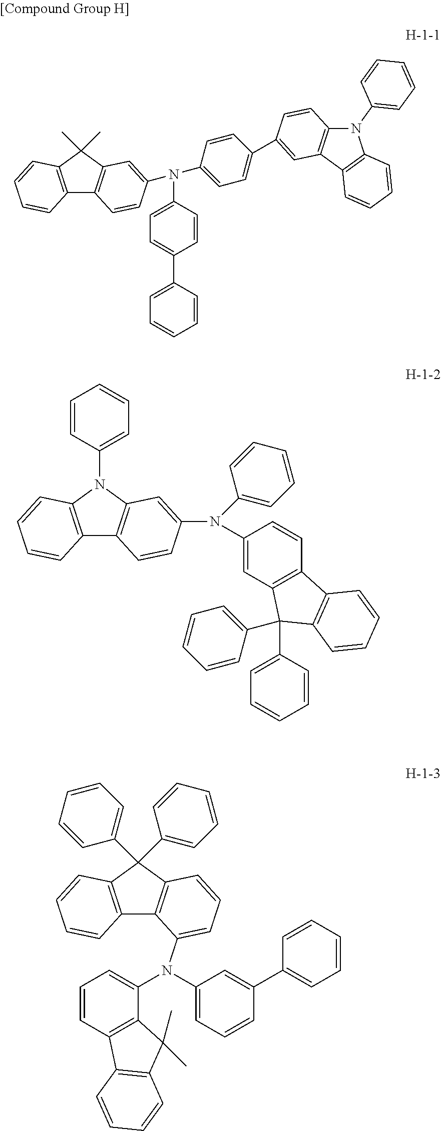 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

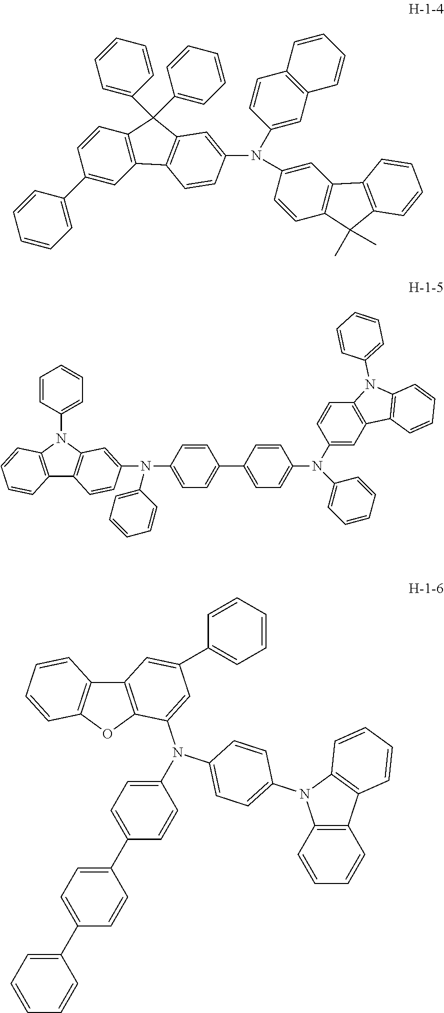 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

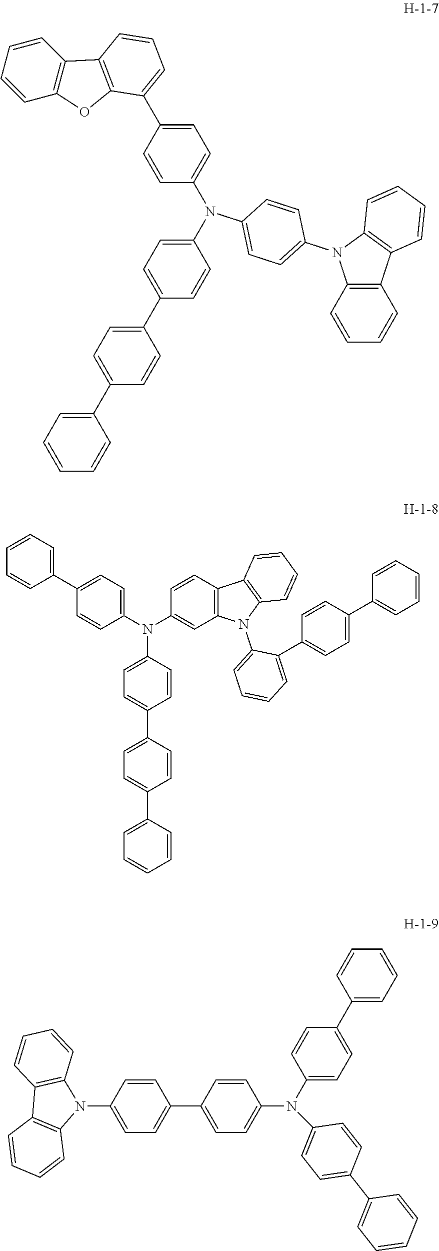 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

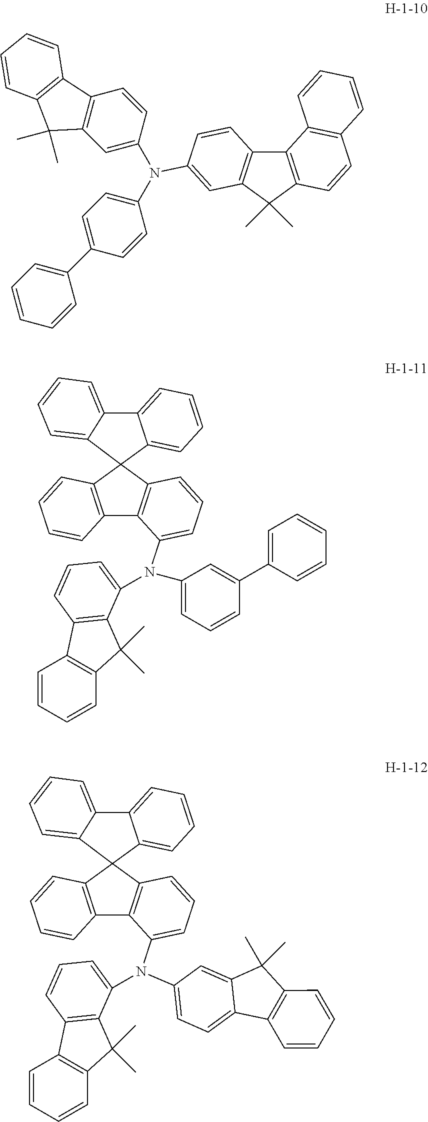 [SMILES: CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21]

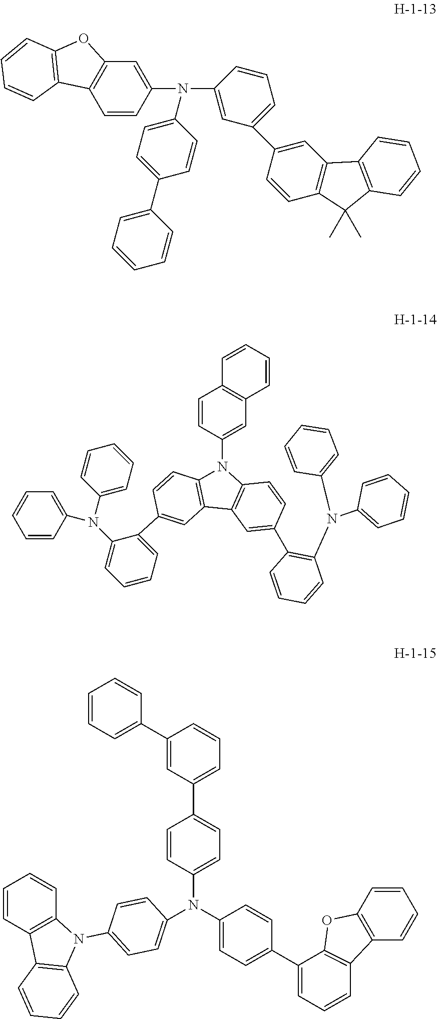 [SMILES: CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

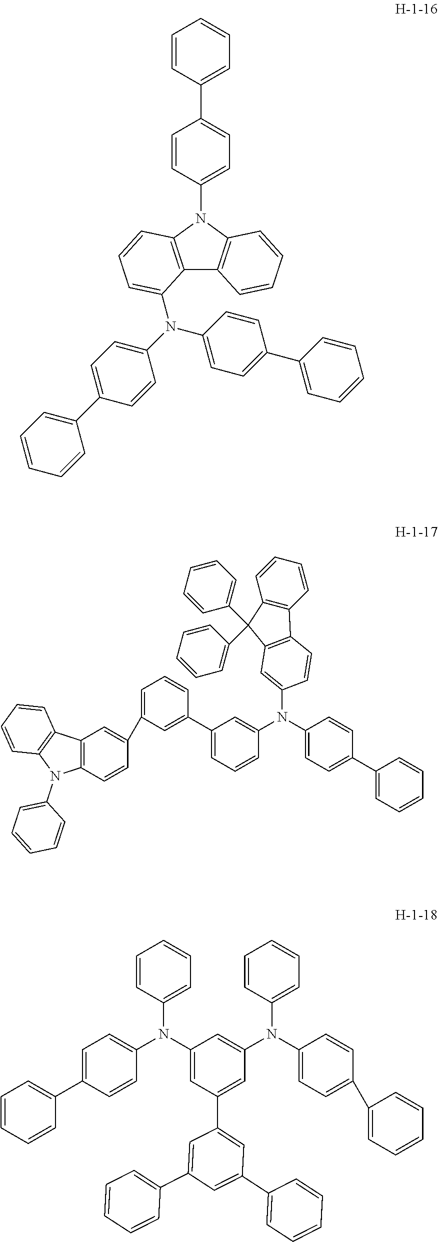 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

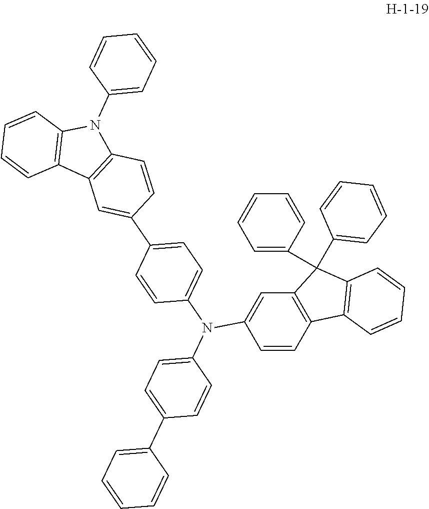 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine; N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), etc.

The hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, and an electron blocking layer EBL.

A thickness of the hole transport region HTR may be in a range of about 100 Å to about 10,000 Å. For example, the thickness of the hole transport region HTR may be in a range of about 100 Å to about 5,000 Å. When the hole transport region HTR includes the hole injection layer HIL, the hole injection layer HIL may have, for example, a thickness in a range of about 30 Å to about 1,000 Å. When the hole transport region HTR includes the hole transport layer HTL, the hole transport layer HTL may have a thickness in a range of about 250 Å to about 1,000 Å. For example, when the hole transport region HTR includes the electron blocking layer EBL, the electron blocking layer EBL may have a thickness in a range of about 10 Å to about 1,000 Å. If the thicknesses of the hole transport region HTR, the hole injection layer HIL, the hole transport layer HTL and the electron blocking layer EBL satisfy the above-described ranges, satisfactory hole transport properties may be achieved without a substantial increase in driving voltage.

The hole transport region HTR may further include a charge generating material to increase conductivity in addition to the above-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but embodiments are not limited thereto. For example, the p-dopant may include a metal halide compound such as CuI or RbI, a quinone derivative such as tetracyanoquinodimethane (TCNQ) or 2,3,5,6-tetrafluoro-7,7′8,8-tetracyanoquinodimethane (F4-TCNQ), a metal oxide such as tungsten oxide or molybdenum oxide, a cyano group-containing compound such as dipyrazino[2,3-f:2′,3′-h] quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the hole transport region HTR may further include at least one of the buffer layer (not shown) or the electron blocking layer EBL in addition to the hole injection layer HIL and the hole transport layer HTL. The buffer layer (not shown) may compensate for a resonance distance according to a wavelength of light emitted from the emission layer EML and may thus increase light emission efficiency. A material that may be included in the hole transport region HTR may be included in the buffer layer (not shown). The electron blocking layer EBL is a layer that may prevent the electron injection from the electron transport region ETR to the hole transport region HTR.

The emission layer EML may be provided on the hole transport region HTR. The emission layer EML may have a thickness in a range of, for example, about 100 Å to about 1,000 Å. For example, the emission layer EML may have a thickness in a range of about 100 Å to about 300 Å. The emission layer EML may be a layer consisting of a single material, a layer including different materials, or a structure including multiple layers including different materials.

The emission layer EML may be formed by using various methods such as a vacuum deposition method, a spin coating method, a casting method, a Langmuir-Blodgett (LB) method, an inject printing method, a laser printing method, and a laser induced thermal imaging (LITI) method.

The light emitting element ED according to an embodiment may include a fused polycyclic compound represented by Formula 1 in at least one functional layer disposed between the first electrode EL1 and the second electrode EL2. An emission layer EML in the light emitting element ED according to an embodiment may include a fused polycyclic compound. In an embodiment, the emission layer EML may include the fused polycyclic compound as a dopant. The fused polycyclic compound according to an embodiment may be a dopant material of the emission layer EML. In the specification, the fused polycyclic compound according to an embodiment, which will be described later, may be referred to as a first compound.

The fused polycyclic compound according to an embodiment may include a structure in which multiple aromatic rings are fused via a boron atom and two heteroatoms. For example, the fused polycyclic compound according to an embodiment may include a structure in which first to third aromatic rings are fused via one boron atom, a first nitrogen atom, and a second nitrogen atom. The first to third aromatic rings may each be linked to the boron atom, the first aromatic ring and the third aromatic ring may be linked to each other via the first nitrogen atom, and the second aromatic ring and the third aromatic ring may be linked to each other via the second nitrogen atom. In an embodiment, the first to third aromatic rings may each be a 6-membered aromatic hydrocarbon ring. For example, the first to third aromatic rings may be benzene rings. In the specification, the boron atom, the first nitrogen atom, and the second nitrogen atom, and the first to third aromatic rings which are fused via the boron atom, the first nitrogen atom, and the second nitrogen atom may be referred to as a “fused ring core.”

The fused polycyclic compound according to an embodiment may include a first substituent linked to the first aromatic ring or the second aromatic ring of the fused ring core. The first substituent may have a structure in which a first heterocycle, a second heterocycle, and a benzene moiety are fused. The first heterocycle and the second heterocycle may each be a pentagonal ring. The first heterocycle may include a third nitrogen atom as a ring-forming atom. A third nitrogen atom may be linked to the first aromatic ring or the second aromatic ring. The third nitrogen atom may be linked at a para-position of the first aromatic ring or second aromatic ring with respect to the boron atom of the fused ring core. The second heterocycle may include a heavy atom as a ring-forming atom. In the specification, the heavy atom may be a sulfur atom (S), a selenium atom (Se), or a tellurium atom (Te). For example, the first substituent may include a benzothienoindole moiety when X is a sulfur atom in Formula S1-1. As another example, the first substituent may include a benzothienocarbazole moiety when X is a sulfur atom in Formula S1-2. However, Formulae S1-1 and S1-2 are described as examples to illustrate the first substituent, and the first substituent is not limited to Formulae 51-1 and S1-2, and may have various structures as necessary, as long as it has a structure in which the above-described first heterocycle, second heterocycle, and benzene moiety are fused.

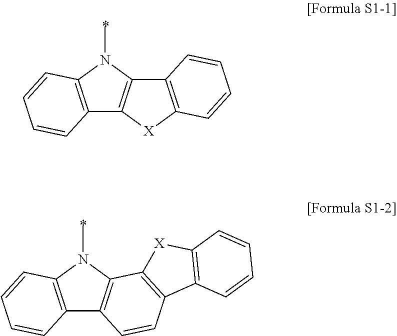

In Formulae S1-1 and S1-2, [symbol] may be a position linked to the first or second aromatic ring of the above-described fused ring core. In Formulae 51-1 and 51-2, X may be a sulfur atom (S), a selenium atom (Se), or a tellurium atom (Te), which may be the above-described heavy atoms.

The fused polycyclic compound according to an embodiment may include second substituents linked to each of the first nitrogen atom and the second nitrogen atom of the fused ring core. The second substituent may include a benzene moiety linked to the first or second nitrogen atom of the fused ring core. The second substituent may have a structure in which substituted or unsubstituted phenyl groups are respectively introduced at both ortho positions with respect to the first nitrogen atom or the second nitrogen atom. The second substituent may include a m-terphenyl moiety represented by Formula S2:

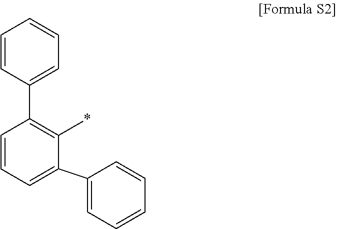

In Formula S2, [symbol] may be a position linked to the first or second nitrogen atom of the above-described fused ring core.

Thus, the fused polycyclic compound according to an embodiment may have an increase in multiple resonance effects since the first substituent and the second substituent are linked to the fused ring core. Therefore, the fused polycyclic compound according to an embodiment may achieve a high efficiency and a long service life when applied to the light emitting element.

The fused polycyclic compound according to an embodiment may be represented by Formula 1:

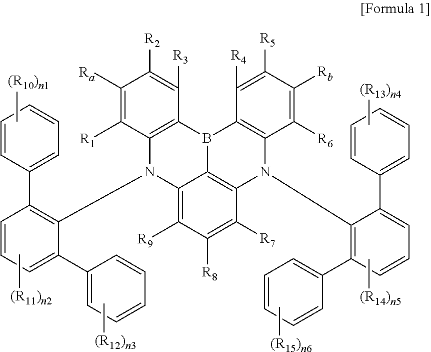

The fused polycyclic compound represented by Formula 1 according to an embodiment may include a structure in which three aromatic rings are fused via one boron atom, the first nitrogen atom, and the second nitrogen atom.

In Formula 1, R₁ to R₁₅ may each independently be a hydrogen atom, a deuterium atom, a halogen atom, a cyano group, a hydroxy group, a substituted or unsubstituted oxy group, a substituted or unsubstituted thio group, a substituted or unsubstituted boron group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. In an embodiment, R₁ to R₇ and R₉ may each independently be a hydrogen atom or a deuterium atom; and R₈ may be a substituted or unsubstituted alkyl group having 1 to 4 carbon atoms, a substituted or unsubstituted aryl group having 6 to 30 ring-forming carbon atoms, or substituted or unsubstituted heteroaryl group having 2 to 30 ring-forming carbon atoms. In an embodiment, R₁₀ to R₁₅ may each independently be a hydrogen atom, a deuterium atom, a halogen atom, a cyano group, a substituted or unsubstituted alkyl group having 1 to 4 carbon atoms, or a substituted or unsubstituted aryl group having 6 to 12 ring-forming carbon atoms.

In Formula 1, Rₐ and R_{b} may each independently be a substituted or unsubstituted heteroaryl group having 2 to 30 ring-forming carbon atoms and including a nitrogen atom (N) as a ring-forming atom, or a group represented by Formula 2. For example, one of Rₐ and R_{b} may be a substituted or unsubstituted carbazole group, and the other one of Rₐ and R_{b} may be a group represented by Formula 2. As another example, Rₐ and R_{b} may each independently be a group represented by Formula 2.

In Formula 1, n1, n3, n4, and n6 may each independently be an integer from 0 to 5. If n1, n3, n4, and n6 are each 0, the fused polycyclic compound may not be substituted with R₁₀, R₁₂, R₁₃, and R₁₅, respectively. A case where n1, n3, n4, and n6 are each 5 and all R₁₀ groups, R₁₂ groups, R₁₃ groups, and R₁₅ groups are hydrogen atoms may be the same as a case where n1, n3, n4, and n6 are each 0. If n1, n3, n4, and n6 are each 2 or greater, multiple groups of each of R₁₀, R₁₂, R₁₃, and R₁₅ may all be the same, or at least one thereof may be different from the others.

In Formula 1, n2 and n5 may each independently be an integer from 0 to 3. If n2 and n5 are each 0, the fused polycyclic compound may not be substituted with R₁₁ and R₁₄, respectively. A case where n2 and n5 are each 3 and all R₁₁ groups and R₁₄ groups are hydrogen atoms may be the same as a case where n2 and n5 are each 0. If n2 and n5 is 2 or greater, multiple R₁₁ groups and multiple R₁₄ groups may all be the same or at least one thereof may be different from the others.

In the specification, in Formula 1, the benzene ring which includes R₁ to R₃ and Rₐ may correspond to the aforementioned first aromatic ring, the benzene ring which includes R₄ to R₆ and R_{b} may correspond to the aforementioned second aromatic ring, and the benzene ring which includes R₇ to R₉ may correspond to the aforementioned third aromatic ring. In Formula 1, the nitrogen atoms shown therein may correspond to the first nitrogen atom and the second nitrogen atom, as described above. In Formula 1, the terphenyl moieties substituted with R₁₀ to R₁₅ may correspond to the aforementioned second substituents.

In Formula 1, at least one of Rₐ and R_{b} is a group represented by Formula 2.

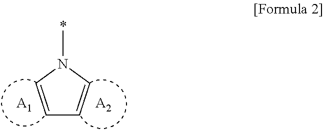

In Formula 2, A₁ and A₂ may each independently be a substituted or unsubstituted hydrocarbon ring having 6 to 30 ring-forming carbon atoms or a substituted or unsubstituted heterocycle having 2 to 30 ring-forming carbon atoms. In Formula 2, at least one of A₁ and A₂ may be a heterocycle including, as a ring-forming atom, at least one of a sulfur atom (S), a selenium atom (Se), and a tellurium atom (Te). For example, one of A₁ and A₂ may be a substituted or unsubstituted benzene ring, and the other one of A₁ and A₂ may be a substituted or unsubstituted benzothiophene, a substituted or unsubstituted benzoselenophene, or a substituted or unsubstituted benzotellurophene. As another example, one of A₁ and A₂ may be a substituted or unsubstituted benzene ring, and the other one of A₁ and A₂ may be a substituted or unsubstituted dibenzothiophene, a substituted or unsubstituted dibenzoselenophene, or a substituted or unsubstituted dibenzotellurophene.

In Formula 2, [symbol] is a position linked to Formula 1.

In the specification, Formula 2 may correspond to the aforementioned first substituent. The nitrogen (N) atom in Formula 2 may correspond to the aforementioned third nitrogen atom.

In an embodiment, the fused polycyclic compound represented by Formula 1 may be represented by Formula 1-1:

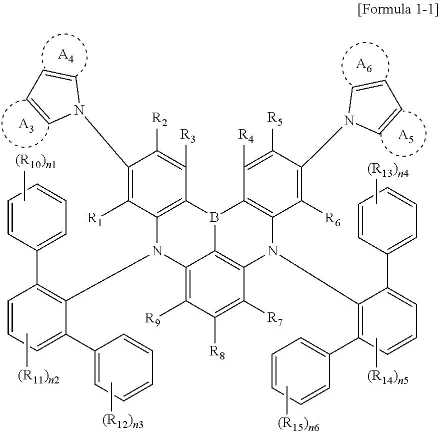

Formula 1-1 represents a case where Rₐ and R_{b} are further defined.

In Formula 1-1, A₃, A₄, A₅, and A₆ may each independently be a substituted or unsubstituted hydrocarbon ring having 6 to 30 ring-forming carbon atoms or a substituted or unsubstituted heterocycle having 2 to 30 ring-forming carbon atoms. In Formula 1-1, at least one of A₃, A₄, A₅, and A₆ may be a heterocycle including, as a ring-forming atom, at least one of a sulfur atom (S), a selenium atom (Se), and a tellurium atom (Te). For example, A₃ and A₅ may each independently be a substituted or unsubstituted benzene ring, and A₄ and A₆ may each independently be a substituted or unsubstituted benzothiophene, a substituted or unsubstituted benzoselenophene, or a substituted or unsubstituted benzotellurophene. As another example, A₃ and A₅ may each independently be a substituted or unsubstituted benzene ring, and A₄ and A₆ may each independently be a substituted or unsubstituted dibenzothiophene, a substituted or unsubstituted dibenzoselenophene, or a substituted or unsubstituted dibenzotellurophene.

In Formula 1-1, R₁ to R₁₅ and n1 to n6 are the same as described in Formula 1.

In an embodiment, the group represented by Formula 2 may be a group represented by one of Formula 2-1 to Formula 2-4:

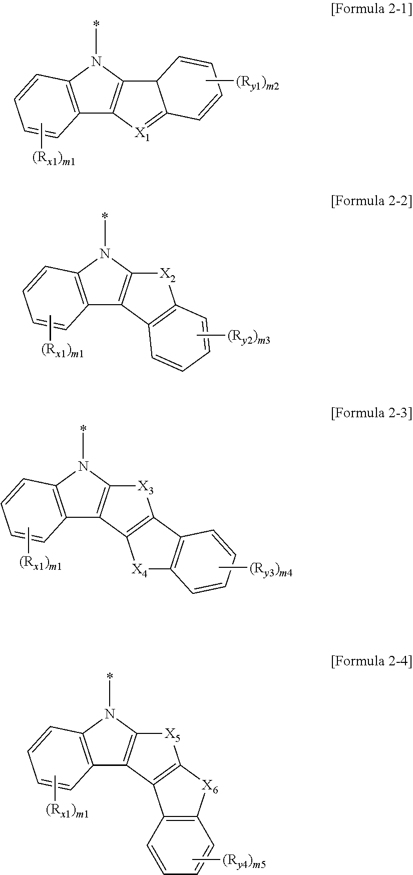

Formula 2-1 to Formula 2-4 each represent a case where A₁ and A₂ are further defined in Formula 2.

In Formula 2-1 to Formula 2-4, Rₓ₁ and R_{y1} to R_{y4} may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. In an embodiment, Rₓ₁ and R_{y1} to R_{y4} may each independently be a hydrogen atom, a deuterium atom, a halogen atom, a cyano group, a substituted or unsubstituted alkyl group having 1 to 4 carbon atoms, or a substituted or unsubstituted aryl group having 6 to 12 ring-forming carbon atoms.

In Formula 2-1 to Formula 2-4, X₁ to X₆ may each independently be a sulfur atom (S), a selenium atom (Se), or a tellurium atom (Te). For example, in Formula 2-3, X₃ and X₄ may each be a sulfur atom. For example, in Formula 2-4, one of X₅ and X₆ may be a sulfur atom, and the other one may be a selenium atom or a tellurium atom.

In Formula 2-1 to Formula 2-4, m1 to m5 may each independently be an integer from 0 to 4. If m1 to m5 are each 0, the fused polycyclic compound may not be substituted with R_{y1} to R_{y4}. A case where m1 to m5 are each 4 and all groups of each of R_{y1} to R_{y4} are hydrogen atoms may be the same as a case where m1 to m5 are each 0. If m1 to m5 are each 2 or greater, multiple groups of each of R_{y1} to R_{y4} may all be the same or at least one thereof may be different from the others.

In Formula 2-1 to Formula 2-4, [symbol] is a position linked to Formula 1.

In an embodiment, the group represented by Formula 2 may be a group represented by Formula 3:

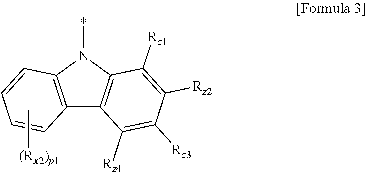

Formula 3 represents a case where A₁ and A₂ are further defined in Formula 2.

In Formula 3, Rₓ₂ may be a hydrogen atom, a deuterium atom, a halogen atom, a cyano group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Rₓ₂ may be a hydrogen atom, a deuterium atom, a halogen atom, a cyano group, a substituted or unsubstituted alkyl group having 1 to 4 carbon atoms, or a substituted or unsubstituted phenyl group.

In Formula 3, R_{z1} to R_{z4} may each independently be a hydrogen atom, a deuterium atom, a thio group, a selenyl group, a tellanyl group, a substituted or unsubstituted aryl group having 6 to 30 ring-forming carbon atoms, or a substituted or unsubstituted heteroaryl group having 2 to 30 ring-forming carbon atoms. In Formula 3, any one of R_{z1} to R_{z4} may be a thio group, a selenyl group, or a tellanyl group, and may be bonded to an adjacent group among the remainder of R_{z1} to R_{z4} to form a ring. For example, R_{z1} may be a thio group, R_{z2} may be a phenyl group, and R_{z1} and R_{z2} may be bonded to each other to further provide a benzothiophene ring containing a sulfur atom in Formula 3. For example, R_{z3} may be a selenyl group, R_{z4} may be a phenyl group, and R_{z3} and R_{z4} may be bonded to each other to further provide a benzoselenophene ring containing a selenium atom in Formula 3.

In Formula 3, p1 may be an integer from 0 to 4. If p1 is 0, the fused polycyclic compound may not be substituted with Rₓ₂. A case where p1 is 4 and all Rₓ₂ groups are hydrogen atoms may be the same as a case where p1 is 0. If p1 is 2 or greater, multiple Rₓ₂ may all be the same, or at least one thereof may be different from the others.

In Formula 3, [symbol] is a position linked to Formula 1.

In an embodiment, the group represented by Formula 3 may be a group represented by one of Formula 3-1 to Formula 3-6:

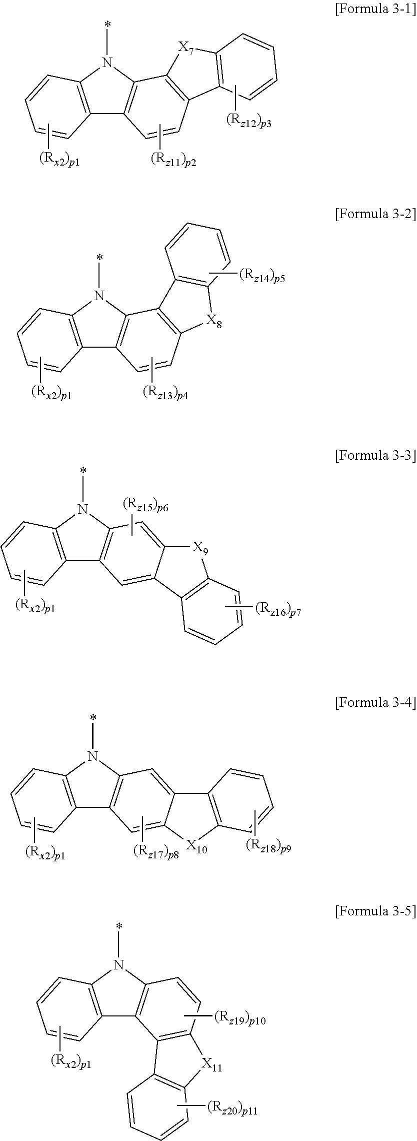

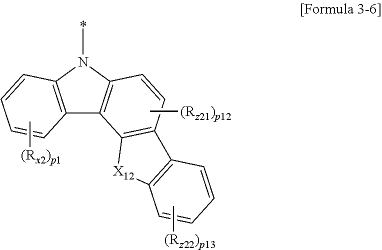

Formula 3-1 to Formula 3-6 each represent a case where R_{z1} to R_{z4} are further defined in Formula 3.

In Formula 3-1 to Formula 3-6, R_{z}ii to R_{z22} may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. In an embodiment, R_{z11} to R_{z22} may each independently be a hydrogen atom, a deuterium atom, a halogen atom, a cyano group, a substituted or unsubstituted alkyl group having 1 to 4 carbon atoms, or a substituted or unsubstituted aryl group having 6 to 12 ring-forming carbon atoms.

In Formula 3-1 to Formula 3-6, X₇ to X₁₂ may each independently be a sulfur atom (S), a selenium atom (Se), or a tellurium atom (Te).

In Formula 3-1 to Formula 3-6, p2, p4, p6, p8, p10, and p12 may each independently be an integer from 0 to 2. If p2, p4, p8, p10, and p12 are each 0, the fused polycyclic compound may not be substituted with R_{z11}, R_{z13}, R_{z15}, R_{z17}, R_{z19}, and R_{z21}, respectively. A case where p2, p4, p6, p8, p10, and p12 are each 2 and all groups of each of R_{z11}, R_{z13}, R_{z15}, R_{z17}, R_{z19}, and R_{z21} are hydrogen atoms may be the same as a case where p2, p4, p6, p8, p10, and p12 are each 0. If p2, p4, p6, p8, p10, and p12 are each 2, multiple groups of each of R_{z11}, R_{z13}, R_{z15}, R_{z17}, R_{z19}, and R_{z21} may all be the same or at least one thereof may be different from the others.

In Formula 3-1 to Formula 3-6, p3, p5, p7, p9, p11, and p13 may each independently be an integer from 0 to 4. If p3, p5, p7, p9, p11, and p13 are each 0, the fused polycyclic compound may not be substituted with R_{z12}, R_{z14}, R_{z16}, R_{z18}, R_{z20}, and R_{z22}, respectively. A case where p3, p5, p7, p9, p11, and p13 are each 4 and all groups of each of R_{z12}, R_{z14}, R_{z16}, R_{z18}, R_{z20}, and R_{z22} are hydrogen atoms may be the same as a case where p3, p5, p7, p9, p11, and p13 are each 0. If p2, p4, p6, p8, p10, and p12 are each 2 or greater, multiple groups of each of R_{z12}, R_{z14}, R_{z16}, R_{z18}, R_{z20}, and R_{z22} may all be the same or at least one thereof may be different from the others.

In Formula 3-1 to Formula 3-6, Rₓ₂, p1, and [symbol] are the same as described in Formula 3.

In an embodiment, the fused polycyclic compound may be any compound selected from Compound Group 1. In an embodiment, in the light emitting element ED, the at least one functional layer (for example, an emission layer EML) may include at least one fused polycyclic compound selected from Compound Group 1:

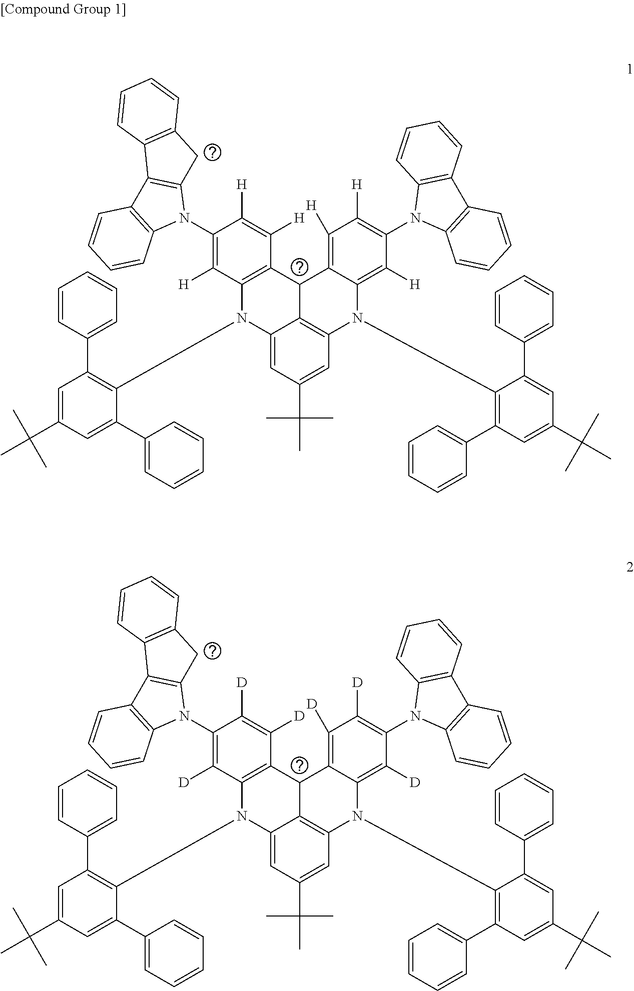

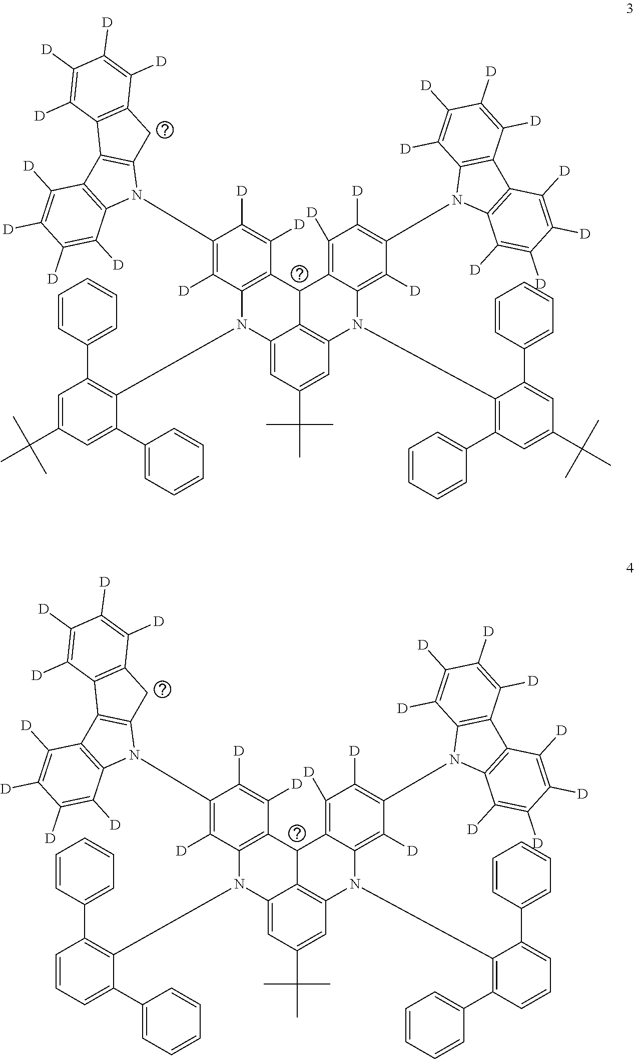

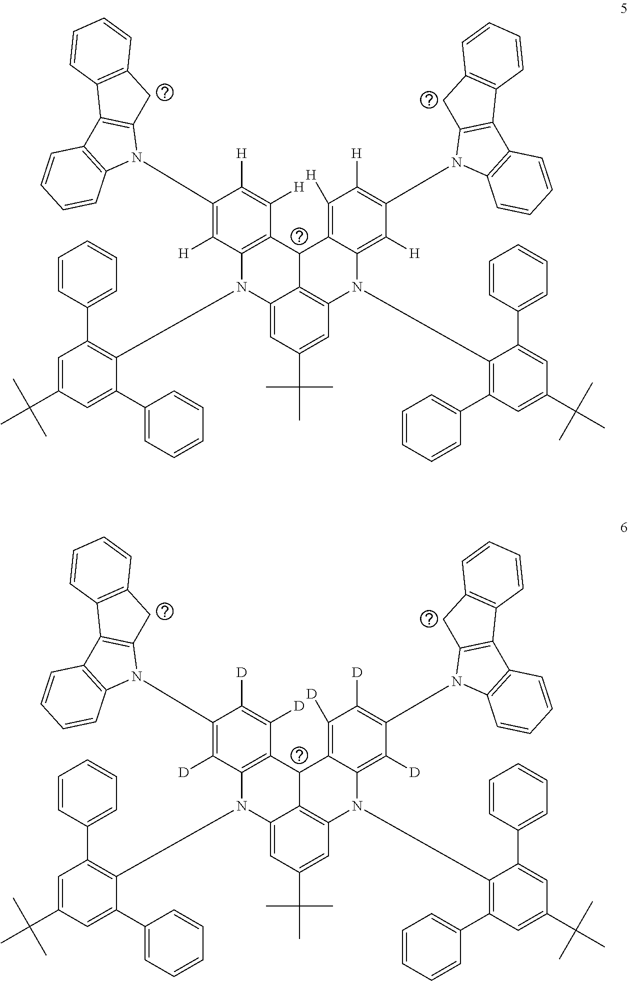

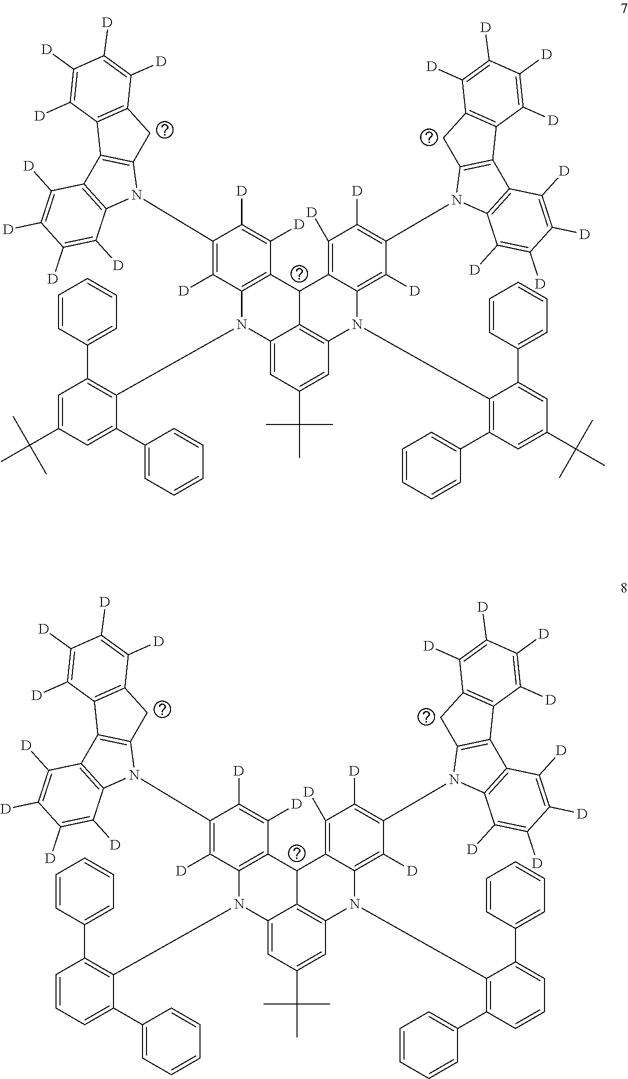

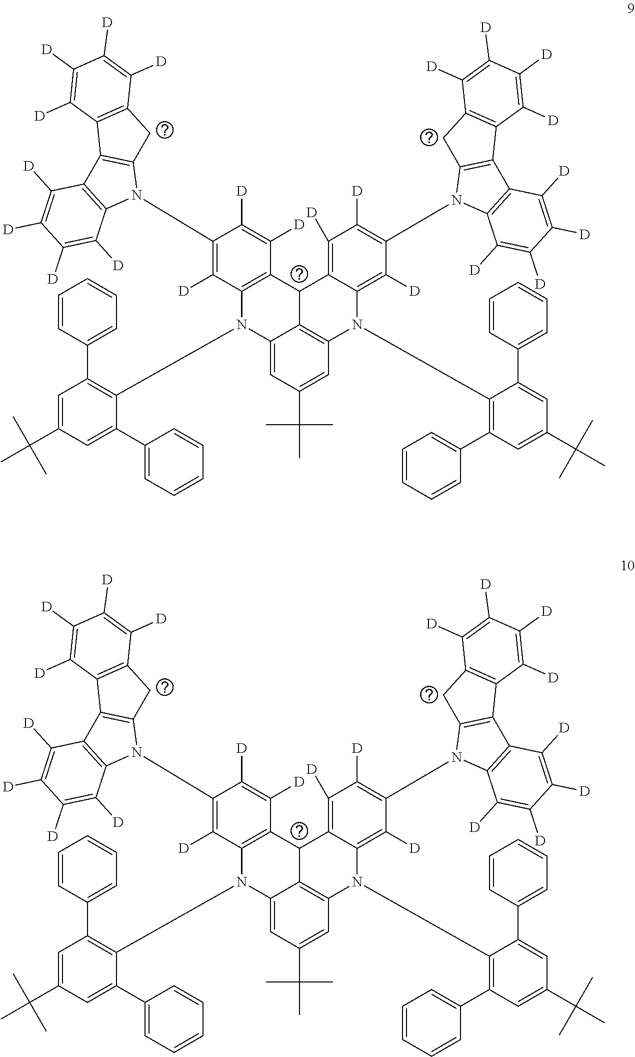

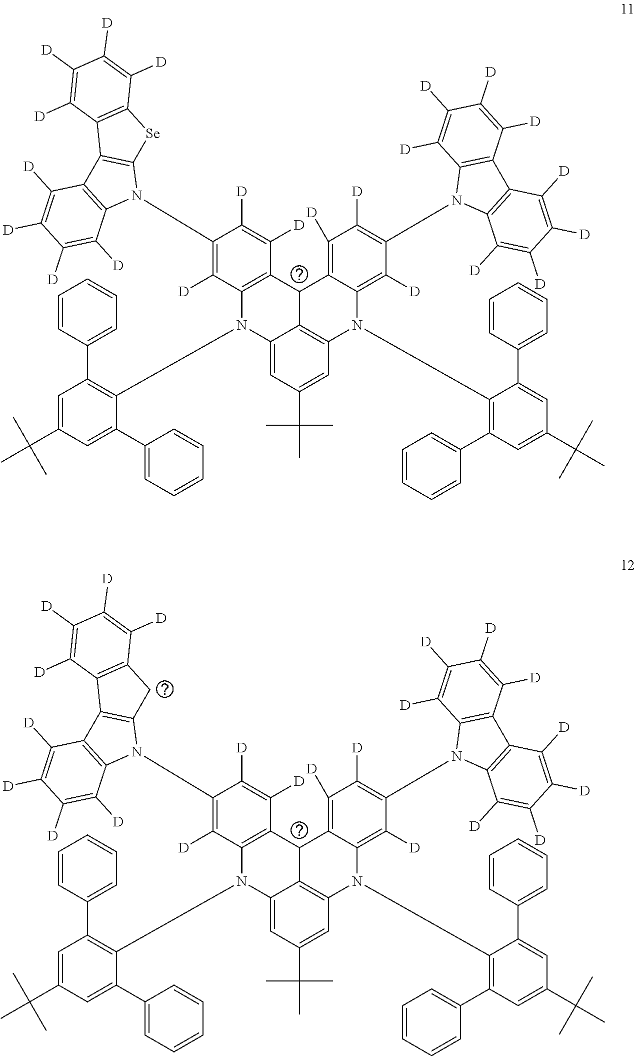

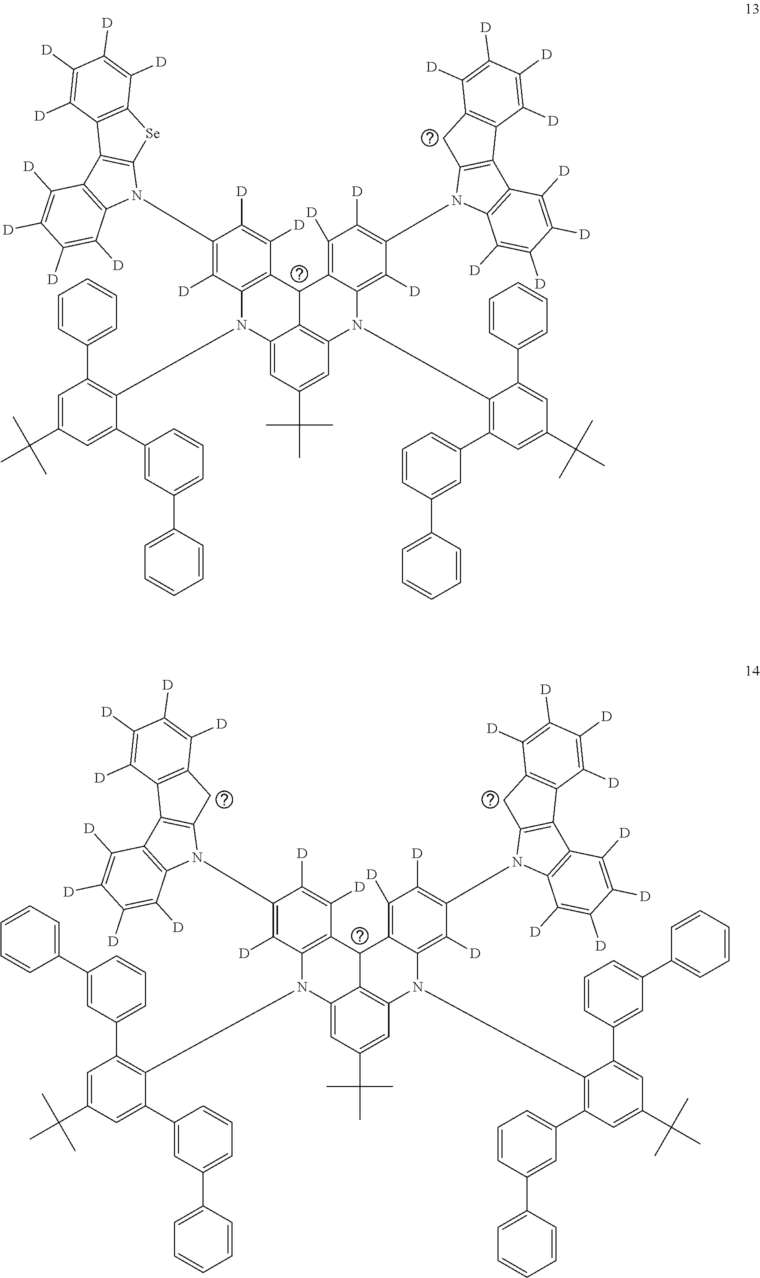

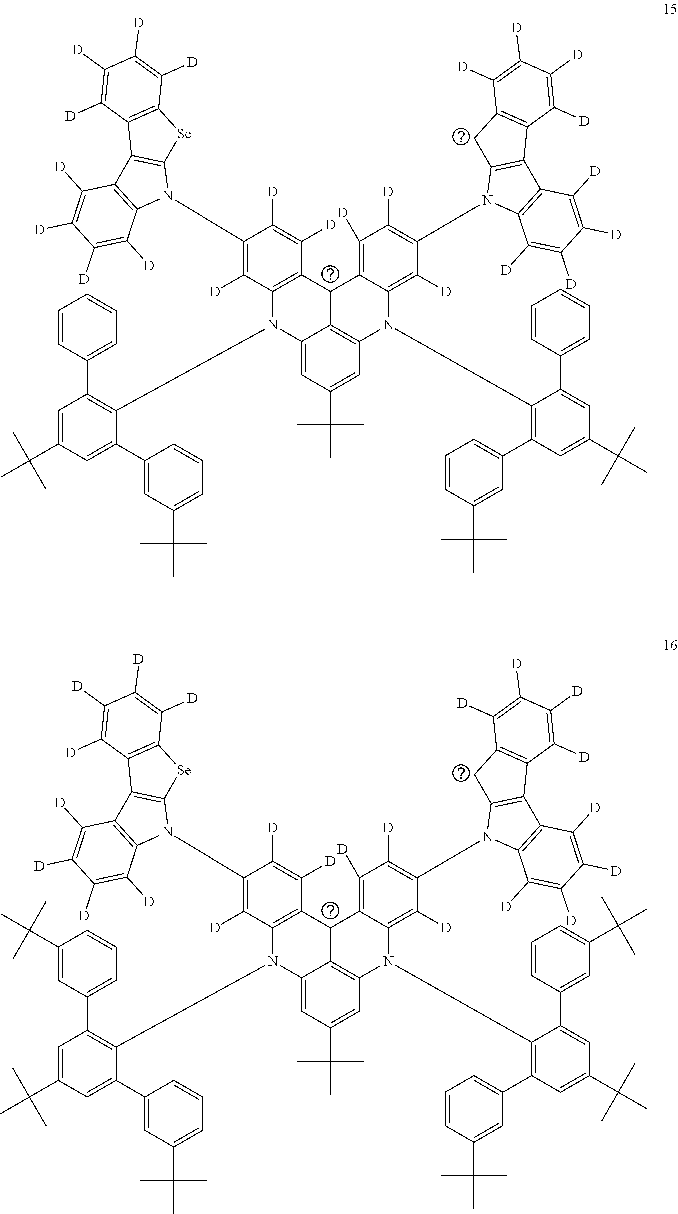

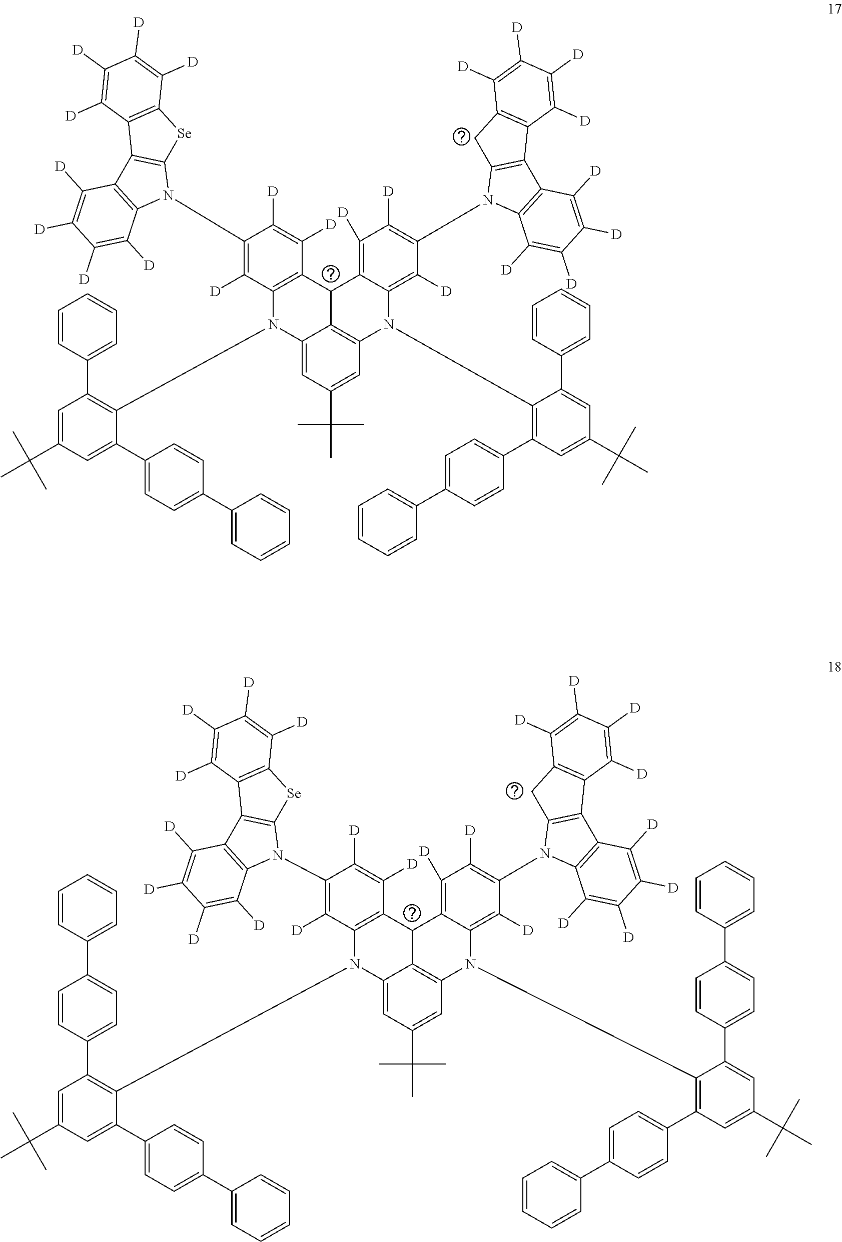

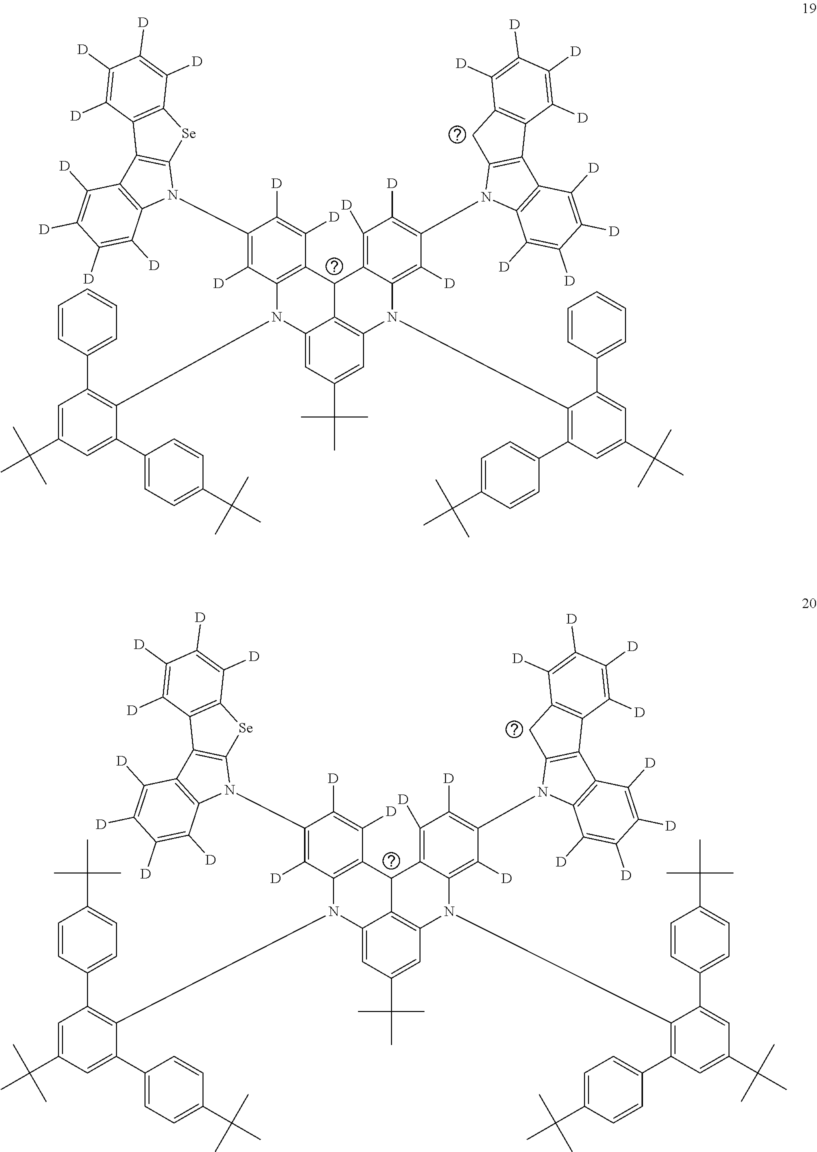

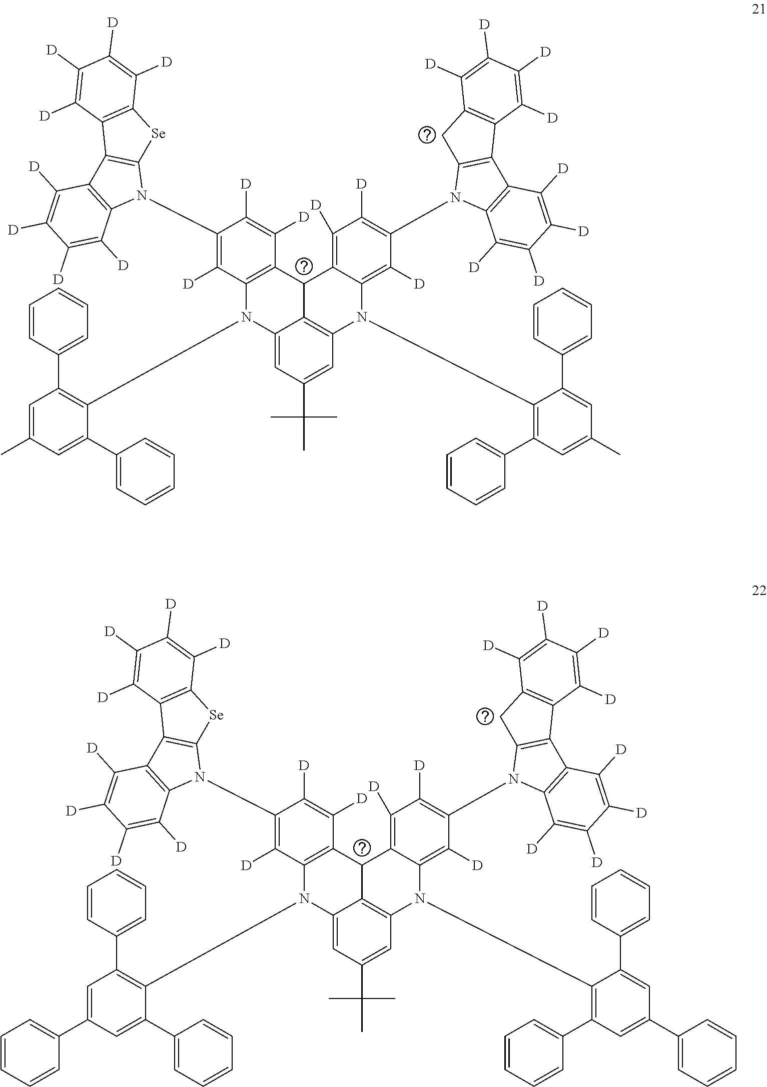

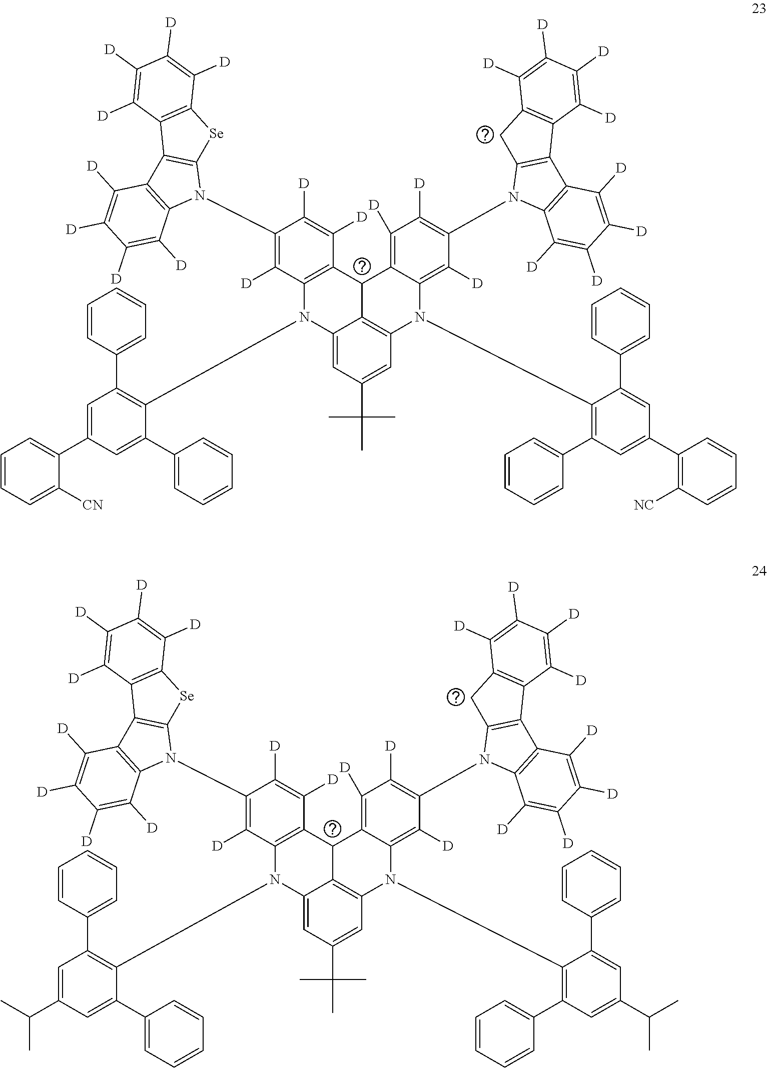

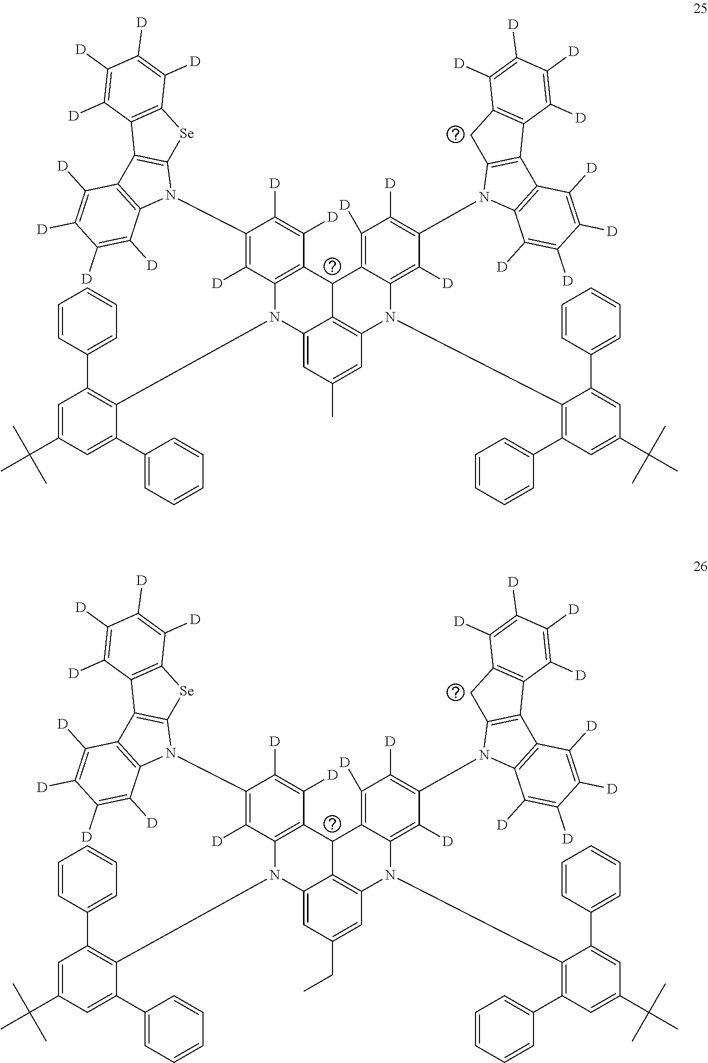

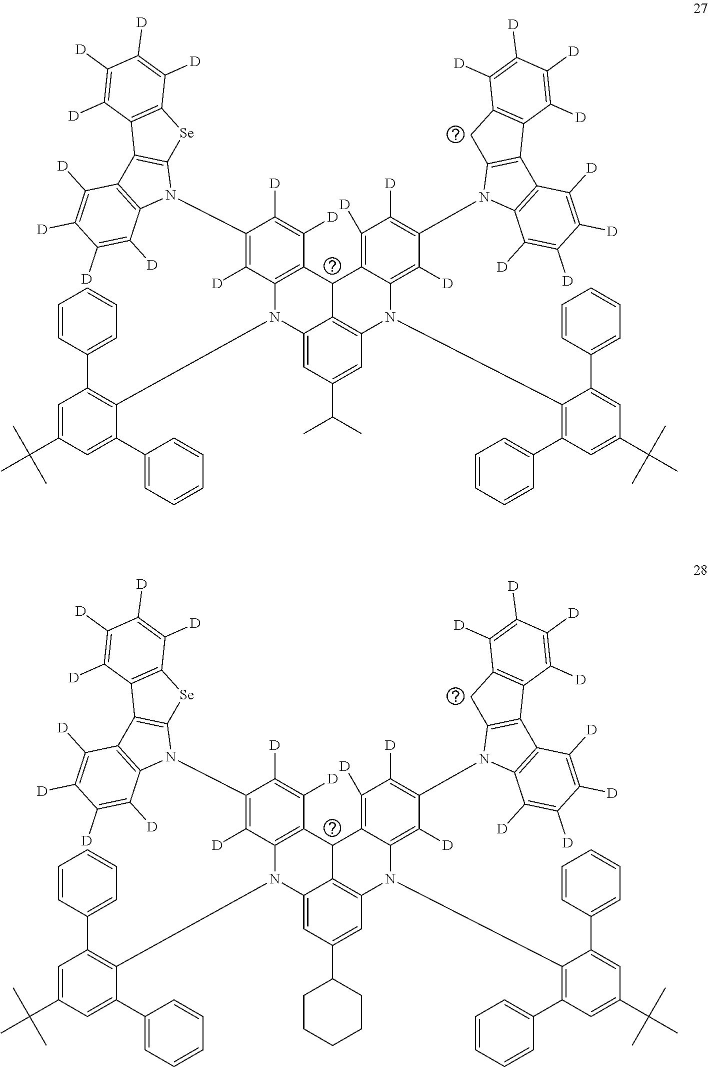

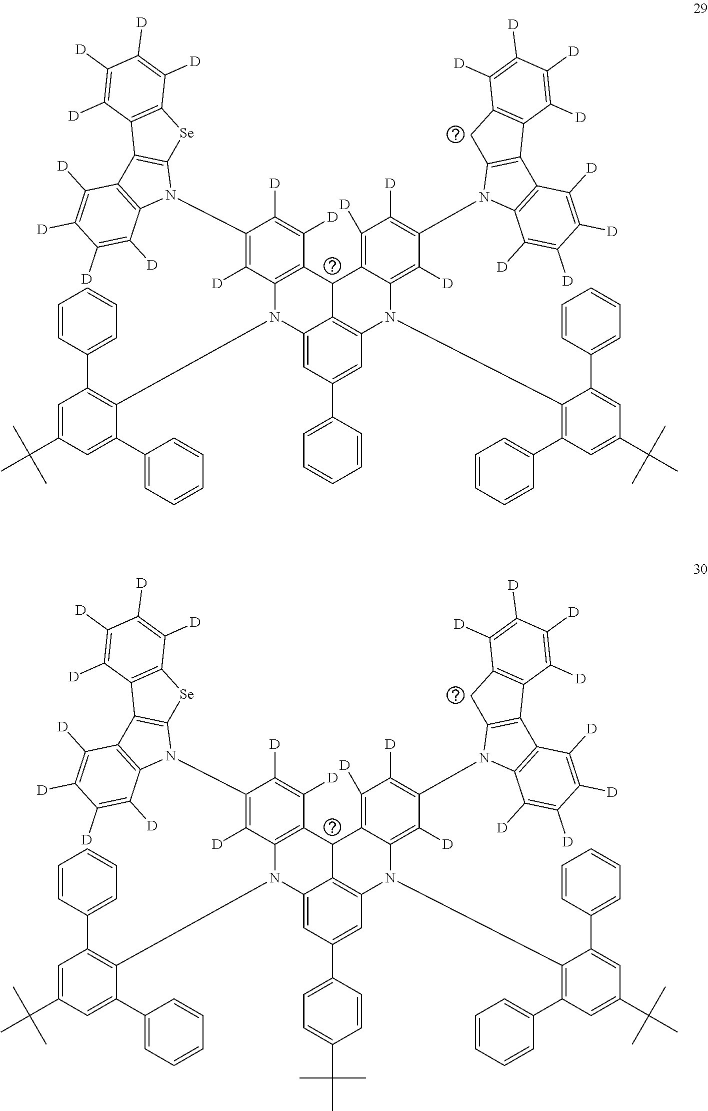

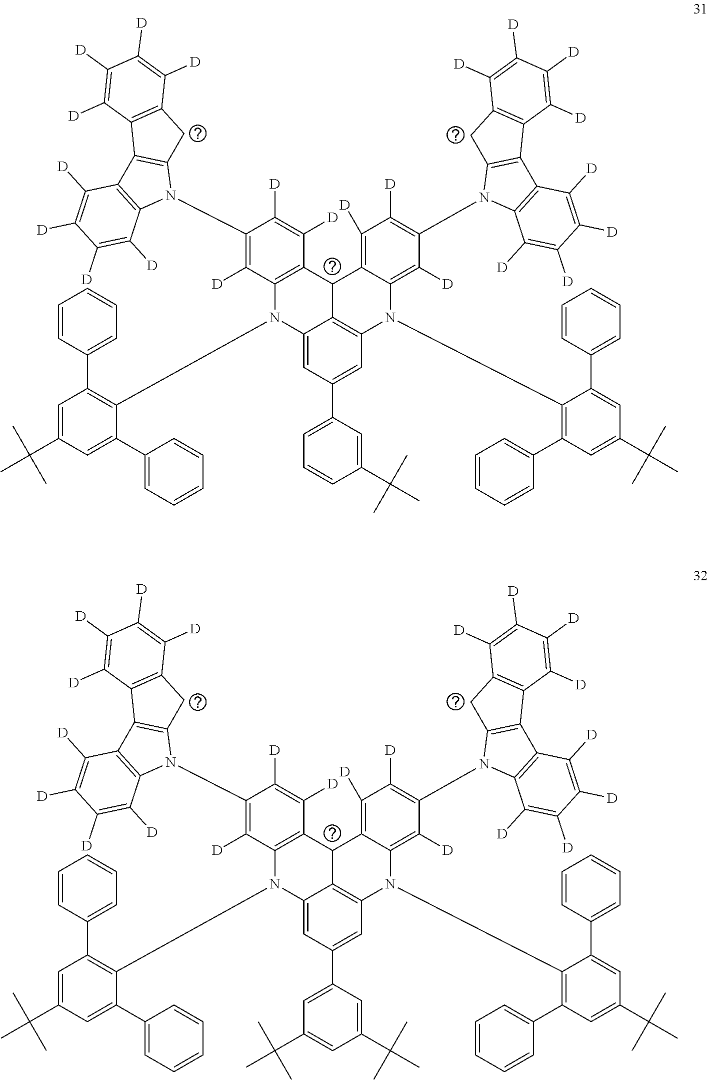

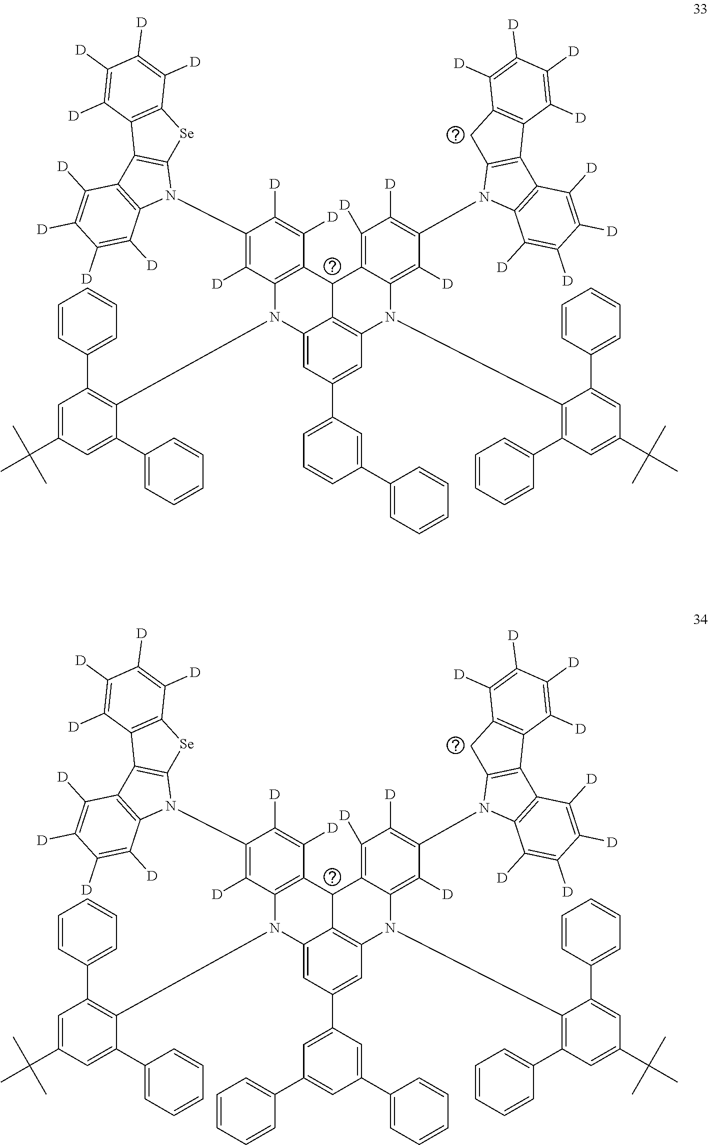

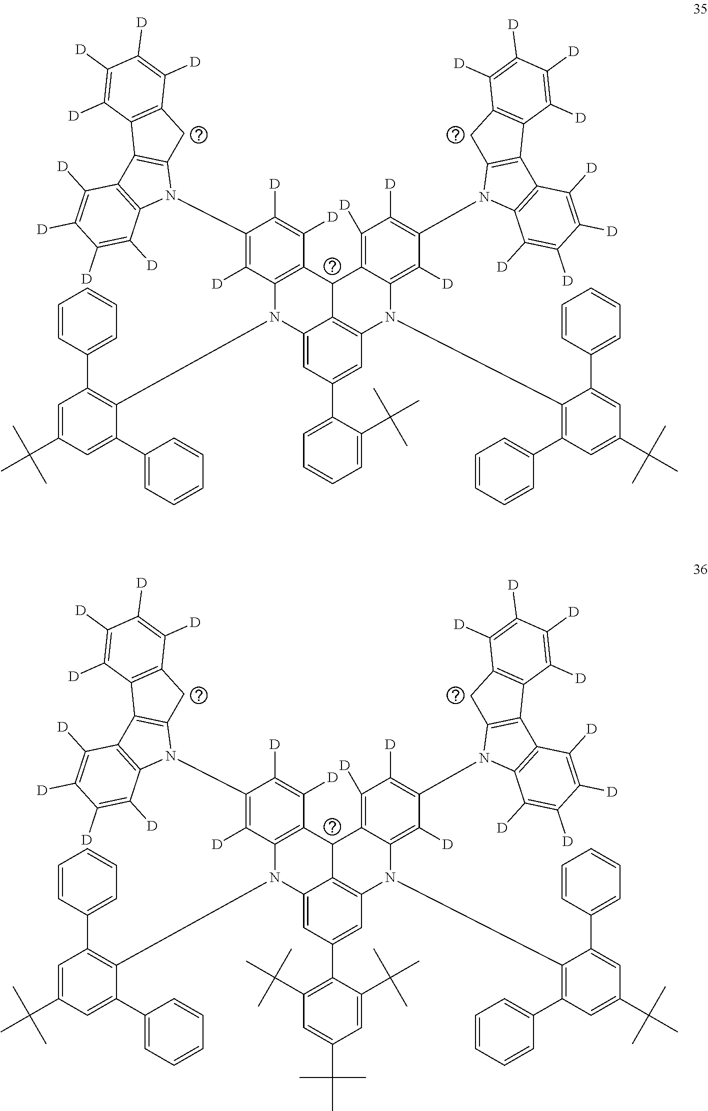

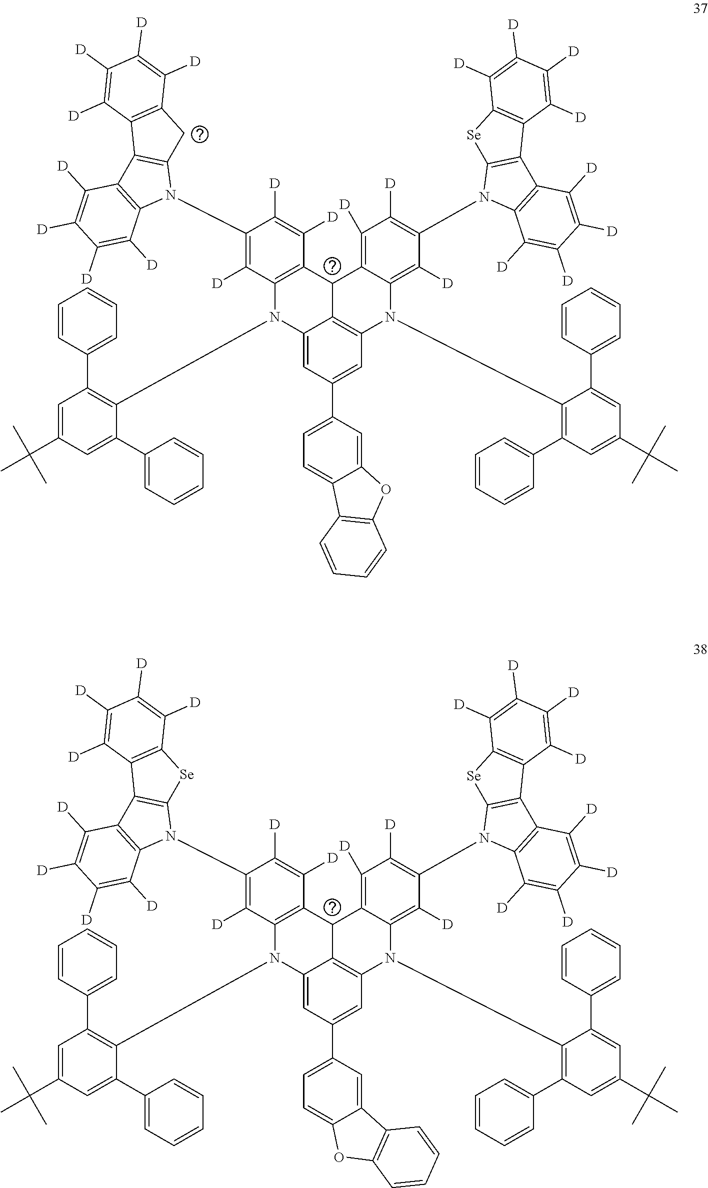

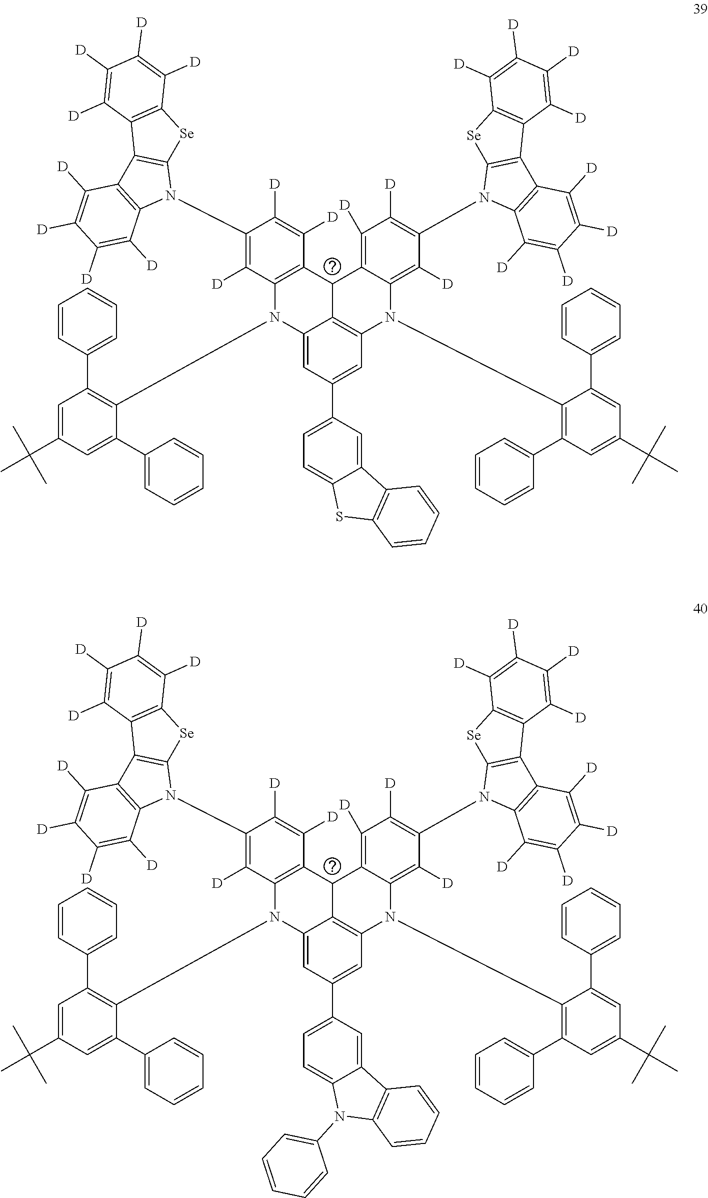

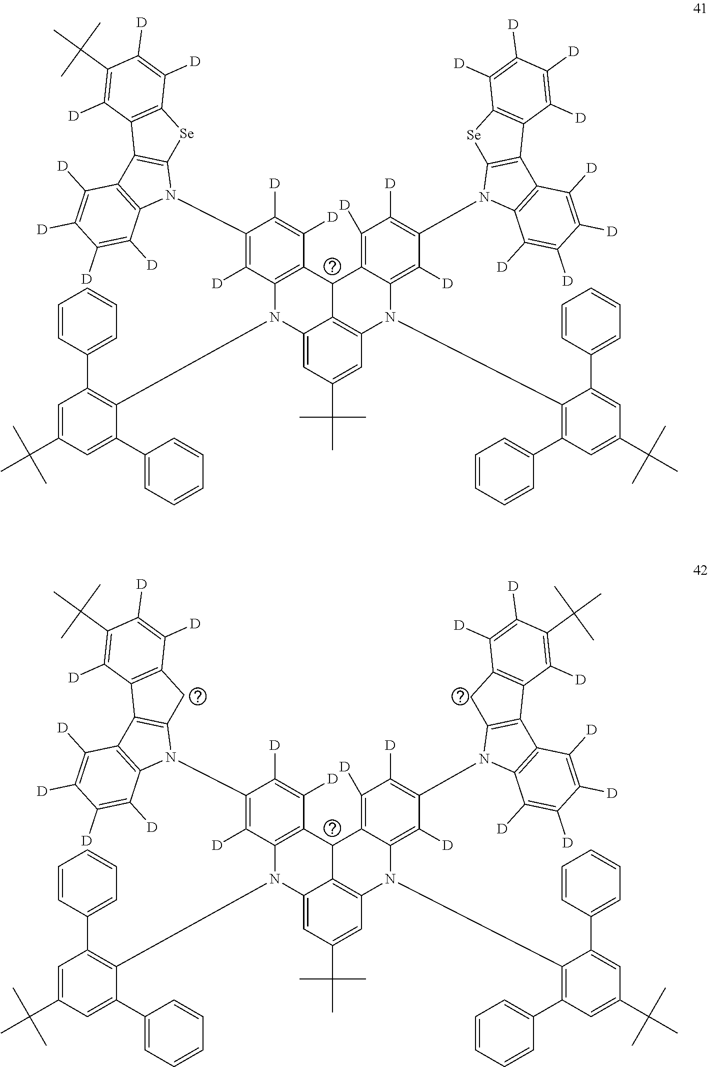

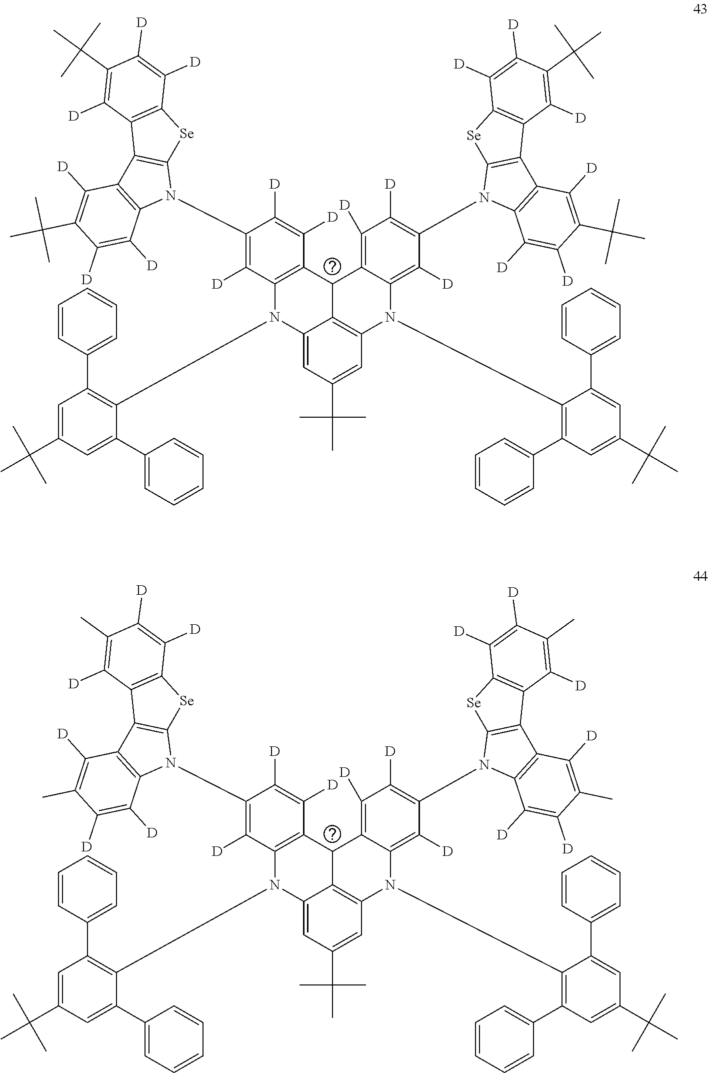

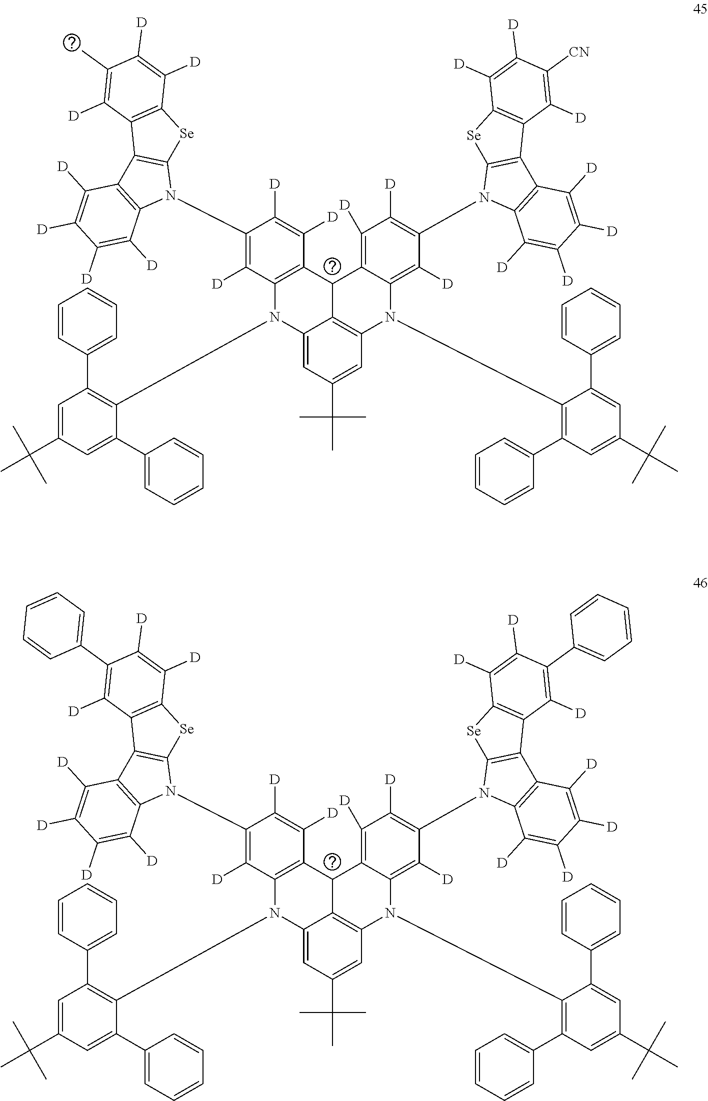

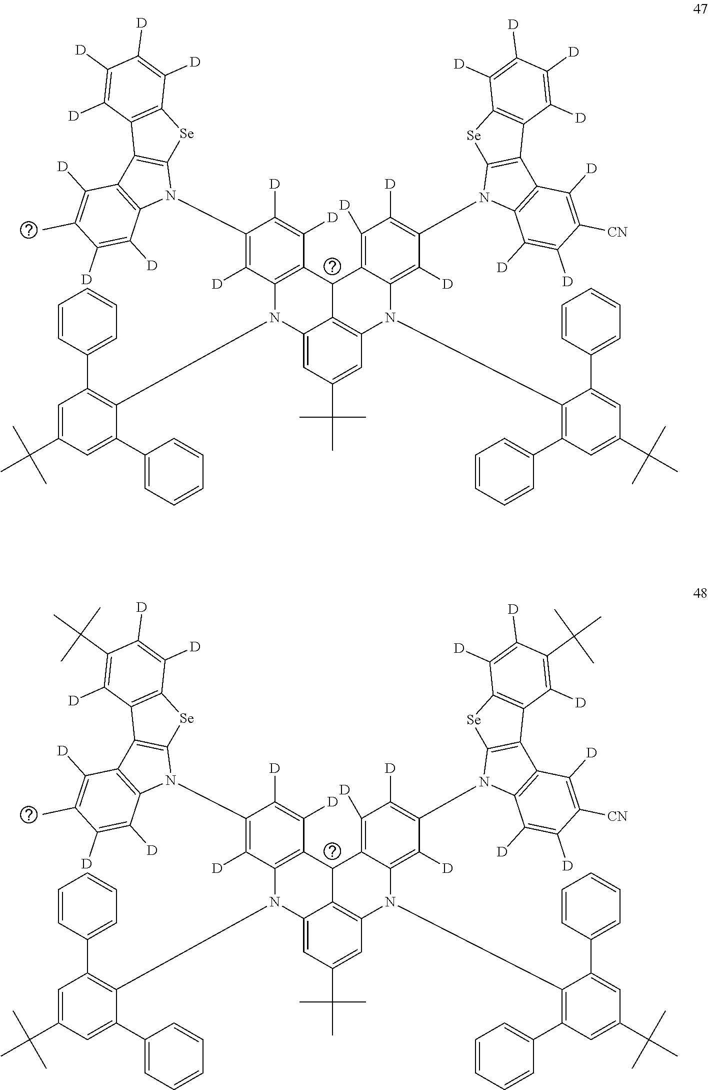

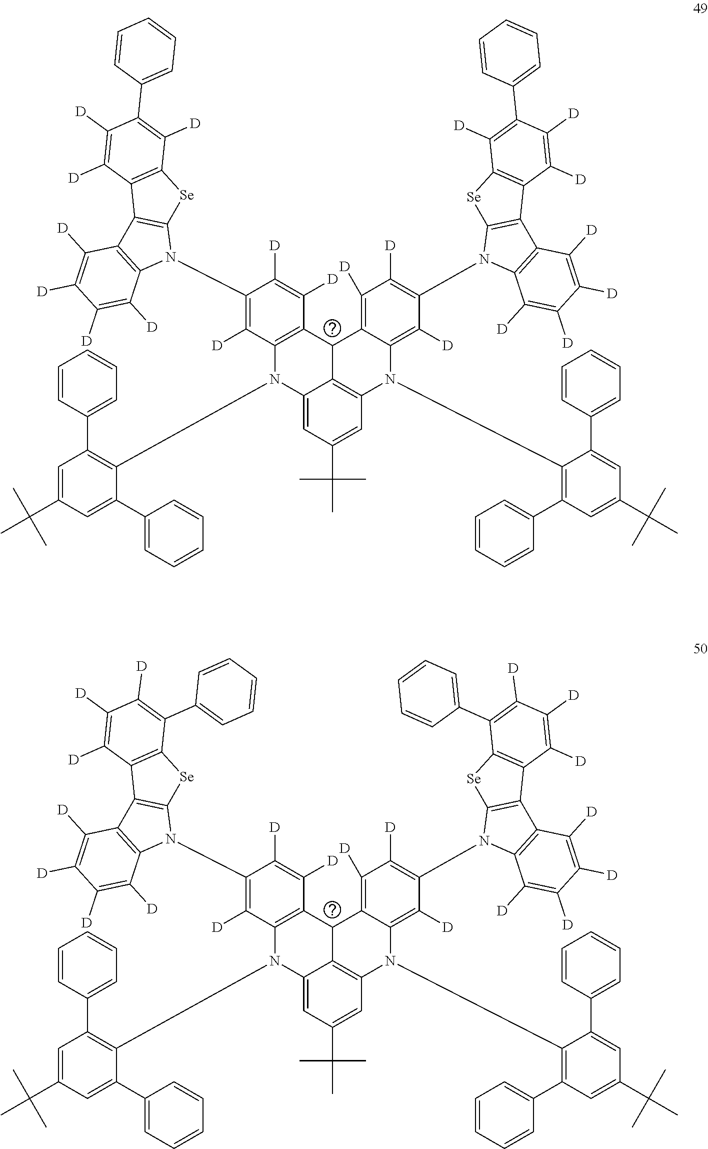

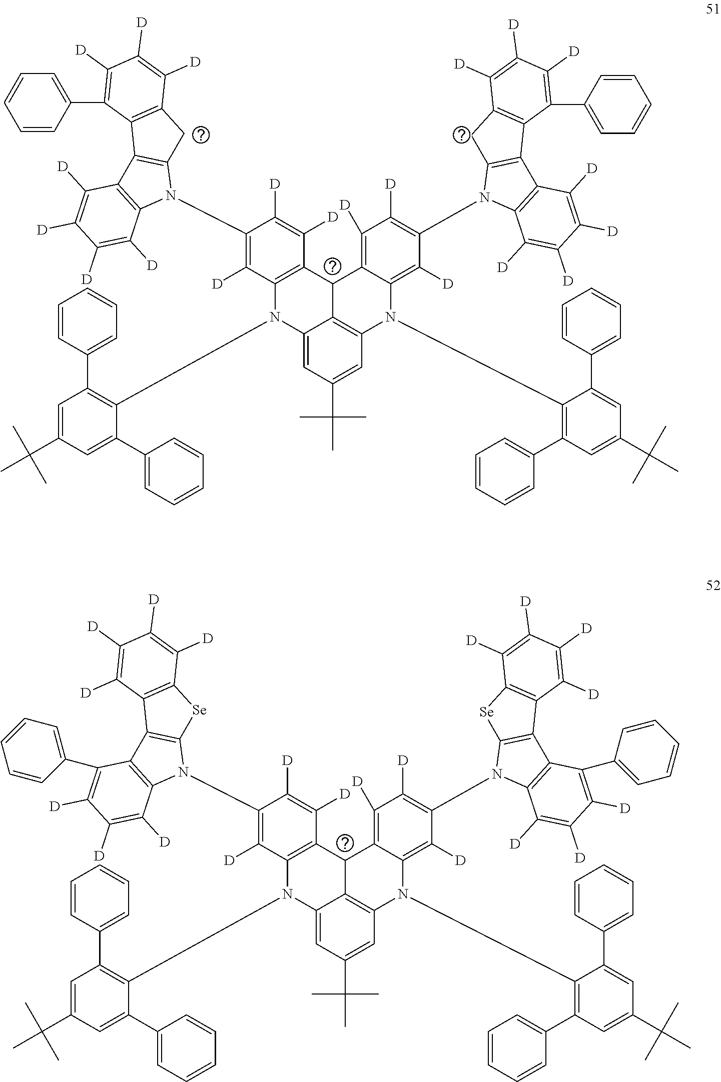

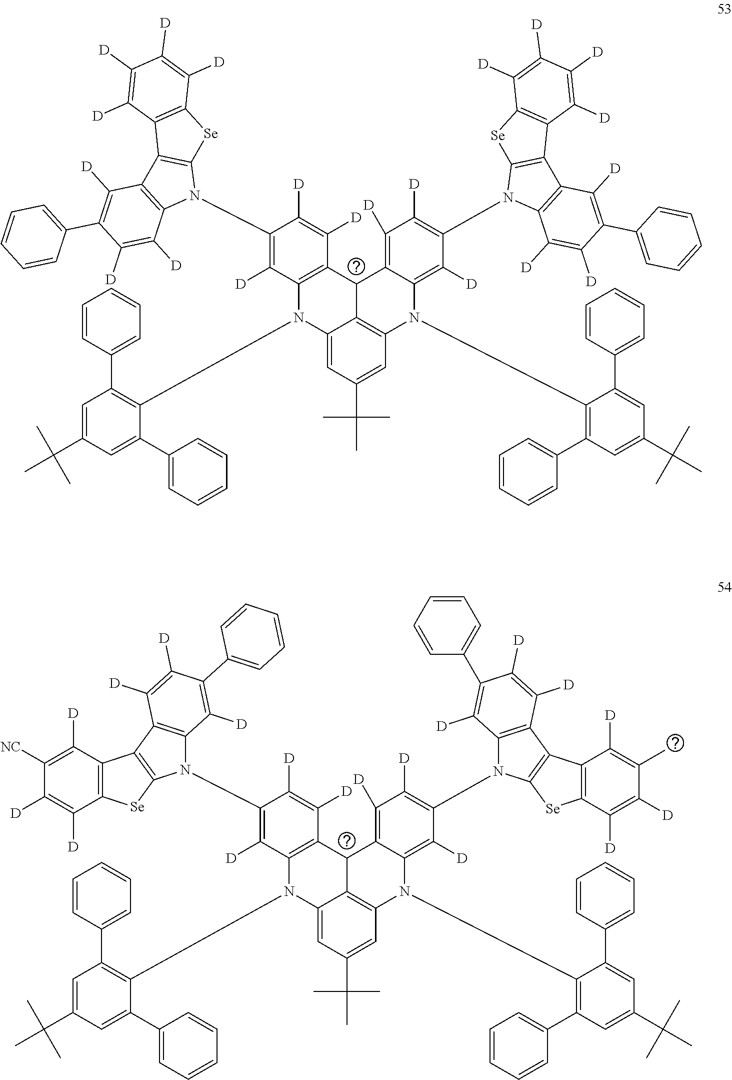

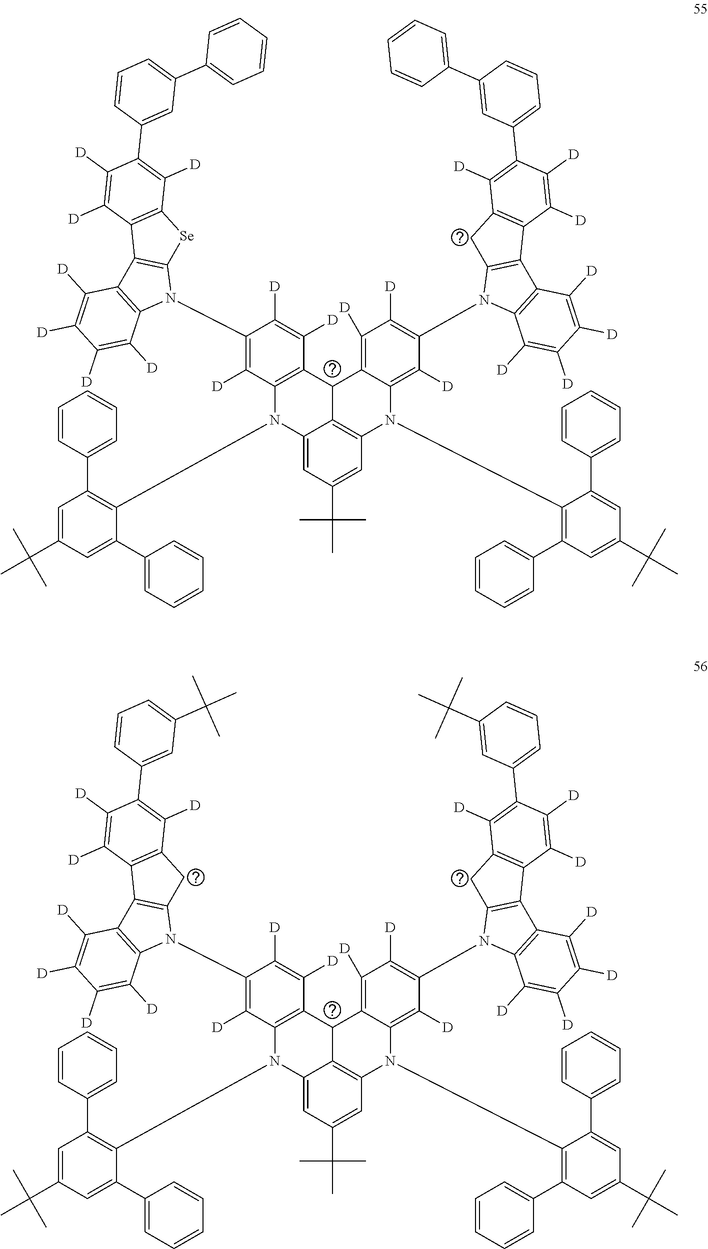

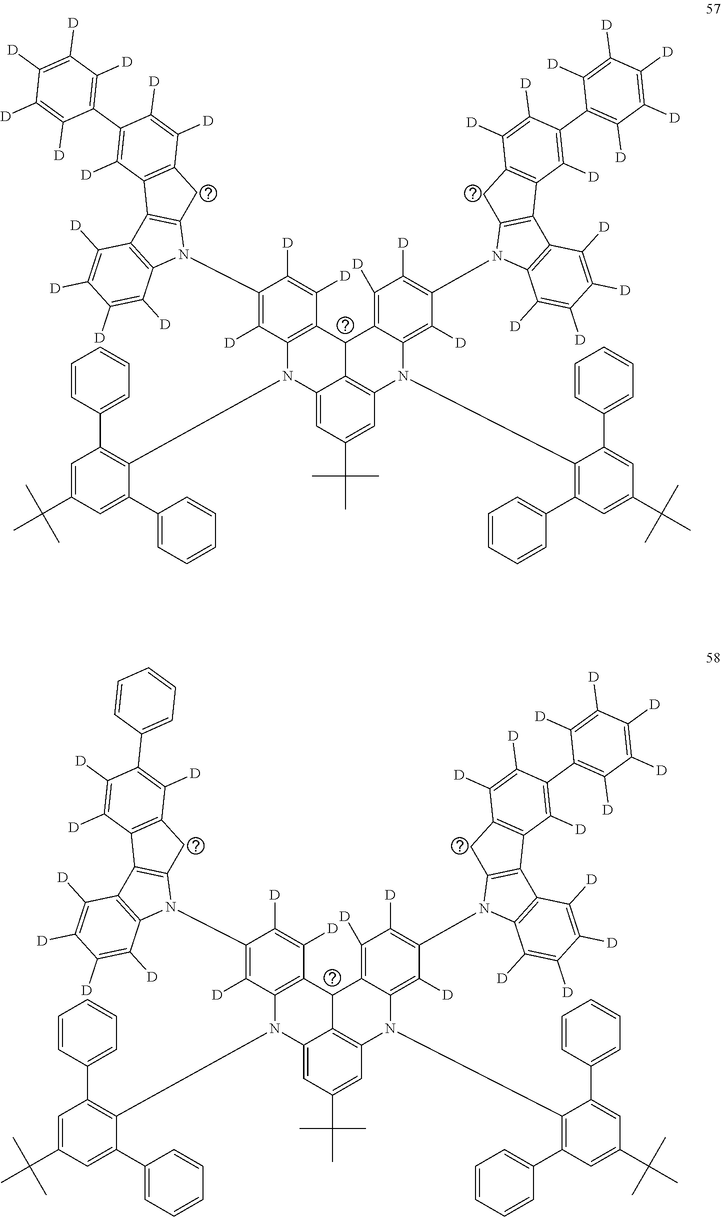

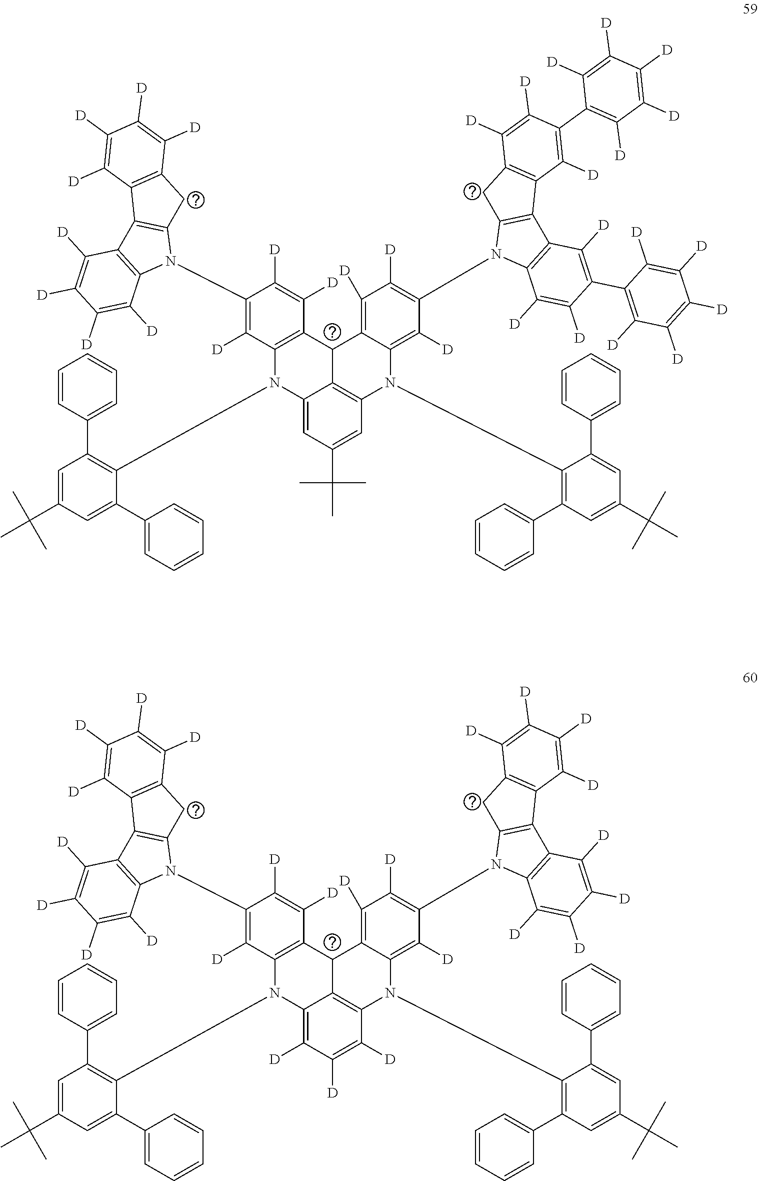

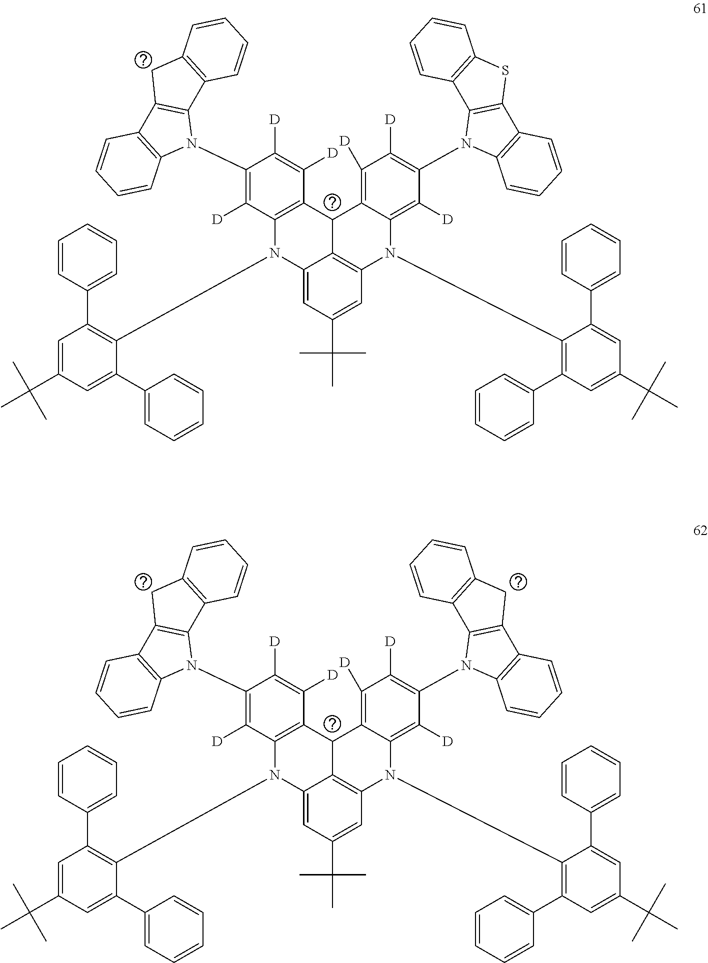

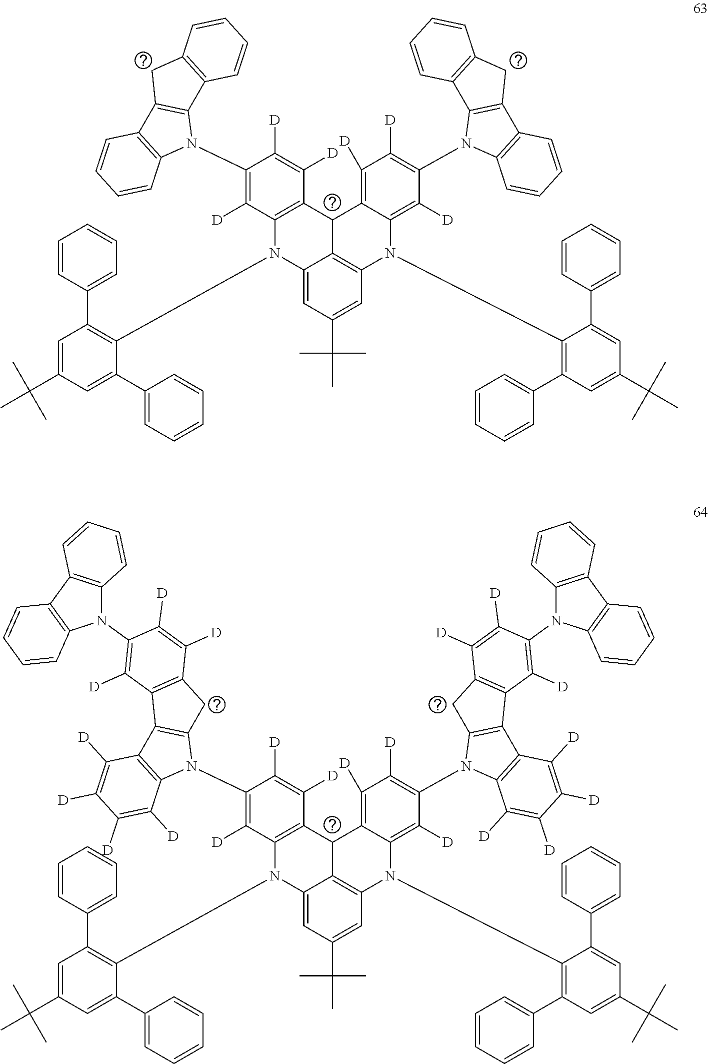

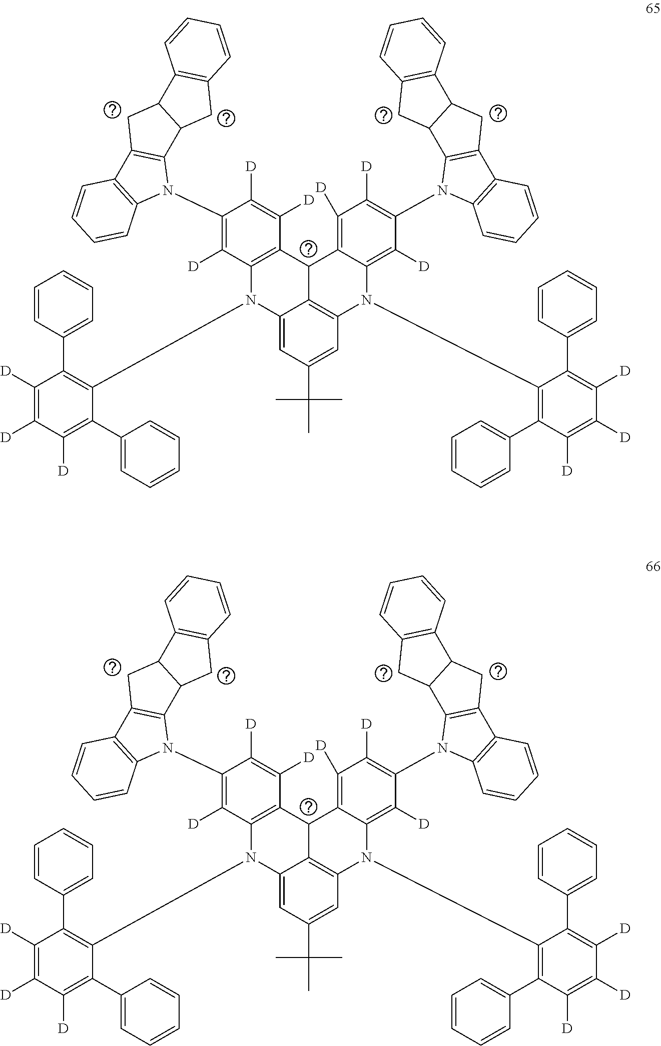 [SMILES: [2H]c1c([2H])c(-c2ccccc2)c(N2c3cc(C(C)(C)C)cc4c3C(c3c([2H])c([2H])c(-n5c6c(c7ccccc75)CC5c7ccccc7CC65)c([2H])c32)c2c([2H])c([2H])c(-n3c5c(c6ccccc63)CC3c6ccccc6CC53)c([2H])c2N4c2c(-c3ccccc3)c([2H])c([2H])c([2H])c2-c2ccccc2)c(-c2ccccc2)c1[2H] ; [2H]c1c([2H])c(-c2ccccc2)c(N2c3cc(C(C)(C)C)cc4c3C(c3c([2H])c([2H])c(-n5c6c(c7ccccc75)CC5c7ccccc7CC65)c([2H])c32)c2c([2H])c([2H])c(-n3c5c(c6ccccc63)CC3c6ccccc6CC53)c([2H])c2N4c2c(-c3ccccc3)c([2H])c([2H])c([2H])c2-c2ccccc2)c(-c2ccccc2)c1[2H]]

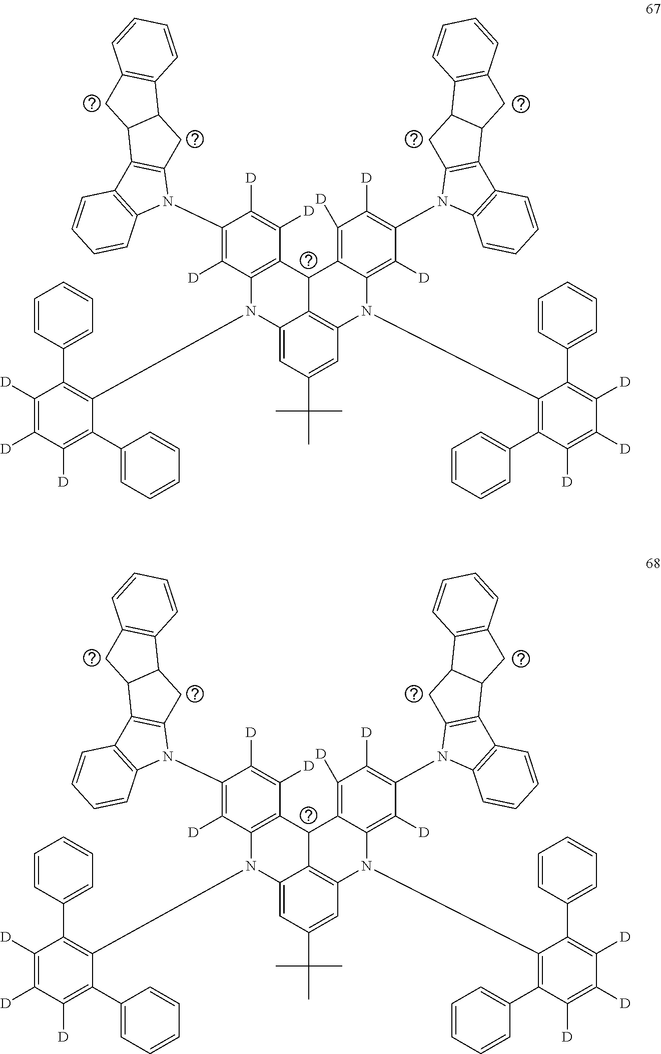 [SMILES: [2H]c1c([2H])c(-c2ccccc2)c(N2c3cc(C(C)(C)C)cc4c3C(c3c([2H])c([2H])c(-n5c6c(c7ccccc75)C5Cc7ccccc7C5C6)c([2H])c32)c2c([2H])c([2H])c(-n3c5c(c6ccccc63)C3Cc6ccccc6C3C5)c([2H])c2N4c2c(-c3ccccc3)c([2H])c([2H])c([2H])c2-c2ccccc2)c(-c2ccccc2)c1[2H] ; [2H]c1c([2H])c(-c2ccccc2)c(N2c3cc(C(C)(C)C)cc4c3C(c3c([2H])c([2H])c(-n5c6c(c7ccccc75)C5Cc7ccccc7C5C6)c([2H])c32)c2c([2H])c([2H])c(-n3c5c(c6ccccc63)C3Cc6ccccc6C3C5)c([2H])c2N4c2c(-c3ccccc3)c([2H])c([2H])c([2H])c2-c2ccccc2)c(-c2ccccc2)c1[2H]]

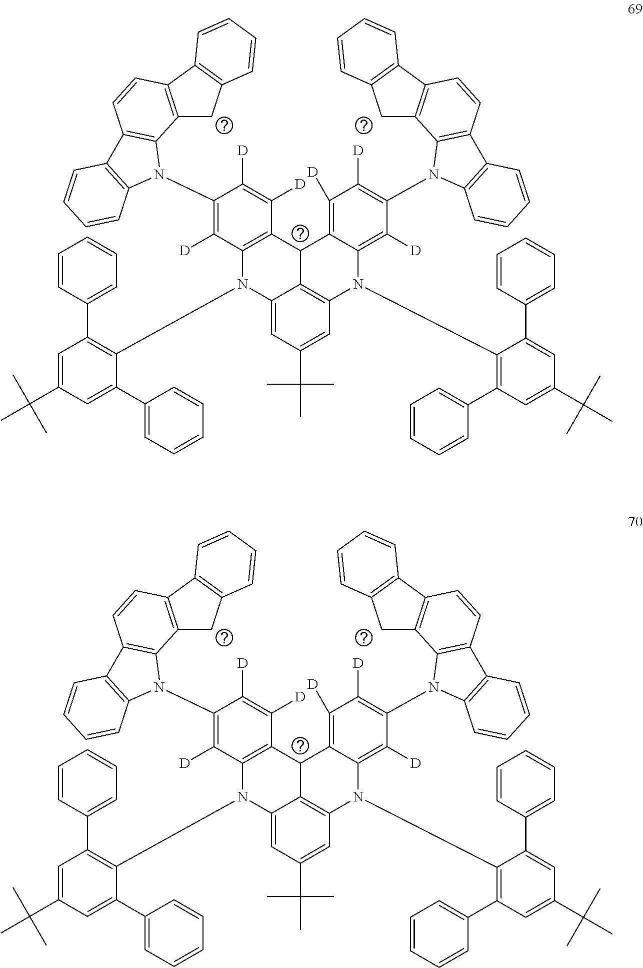

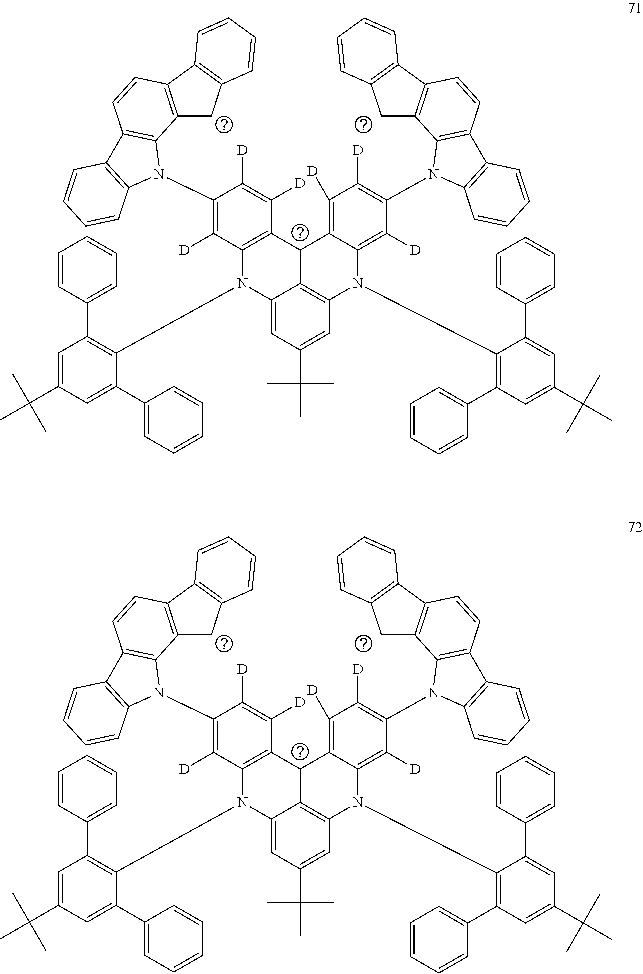

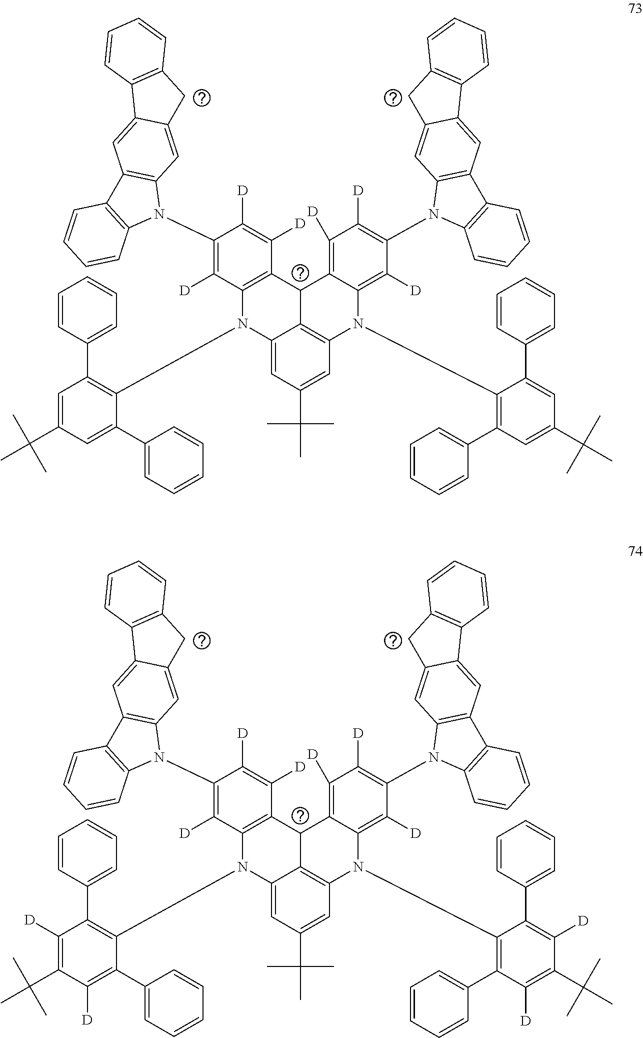

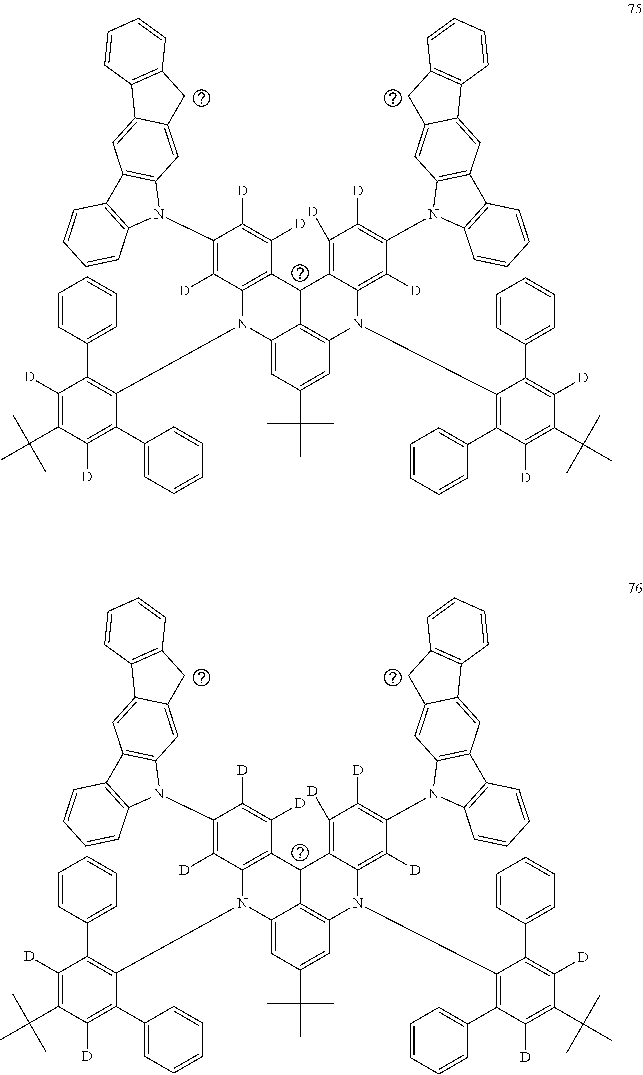

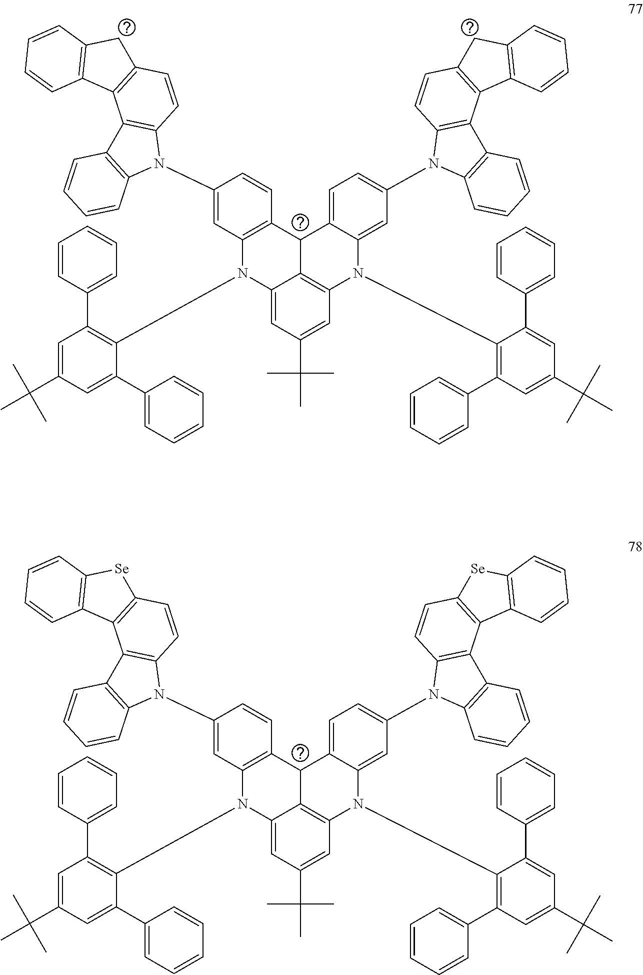

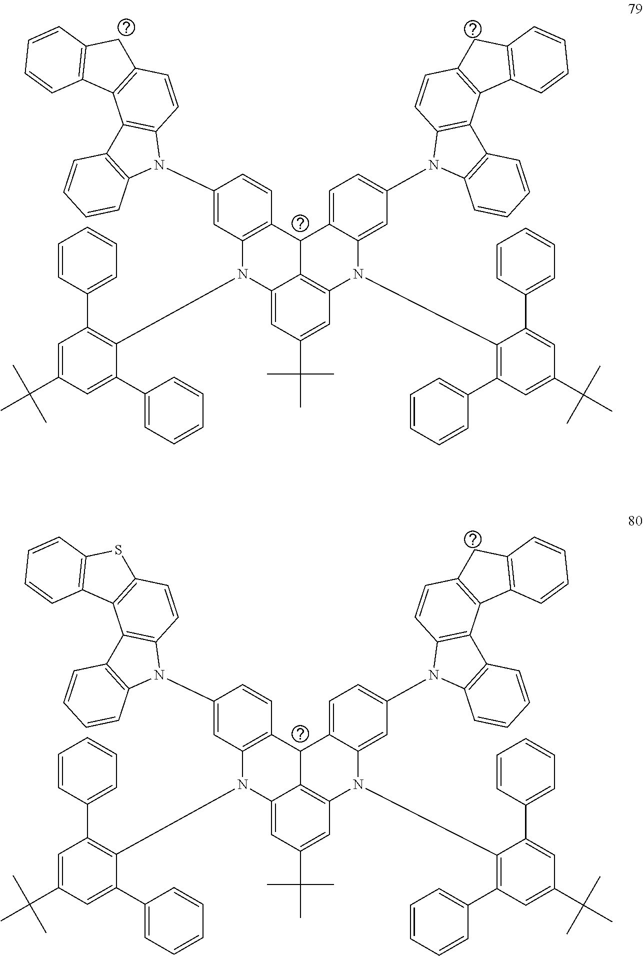

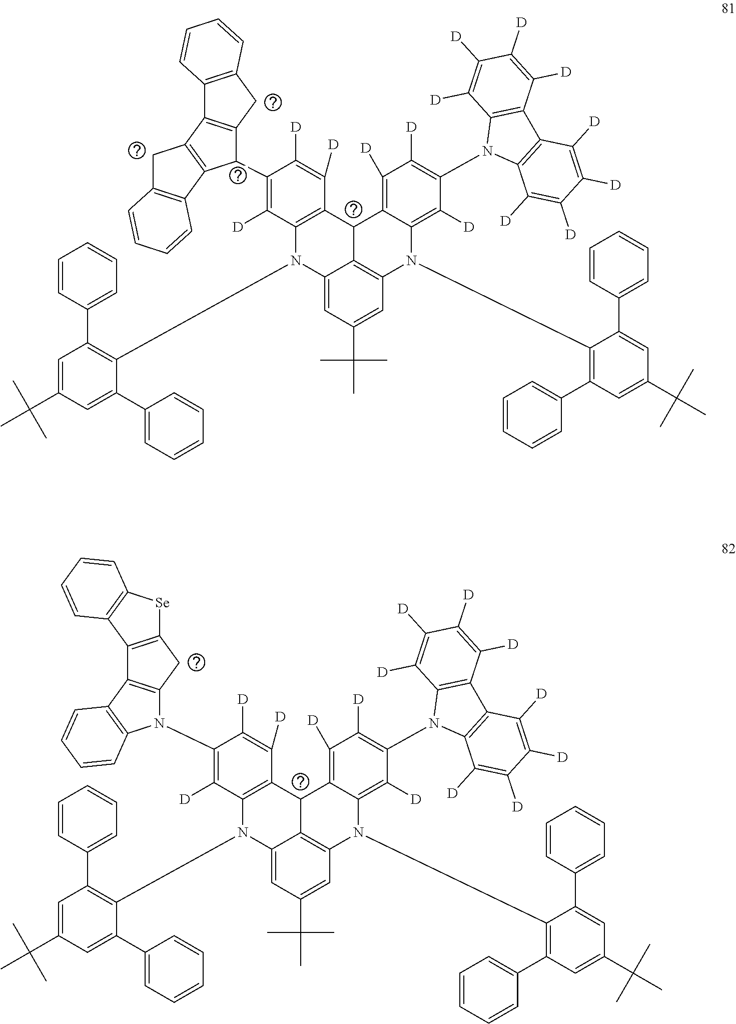

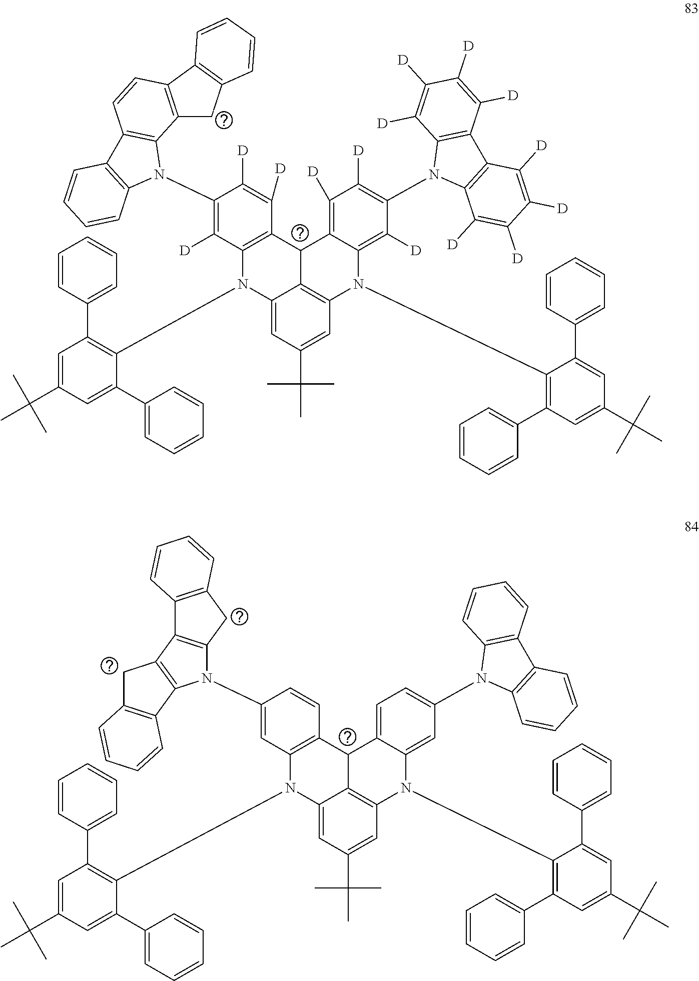

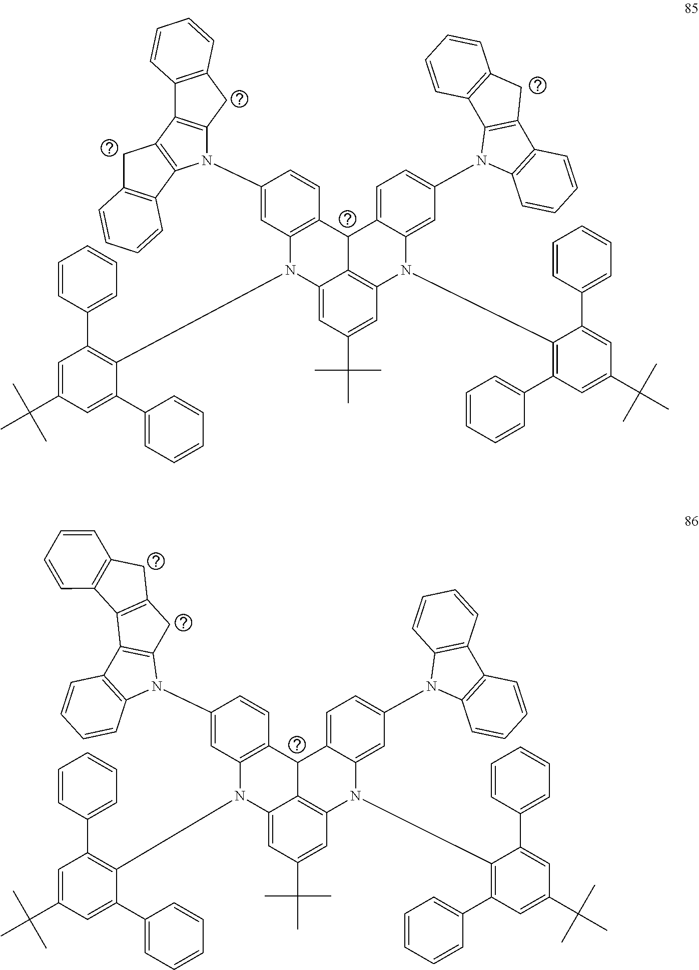

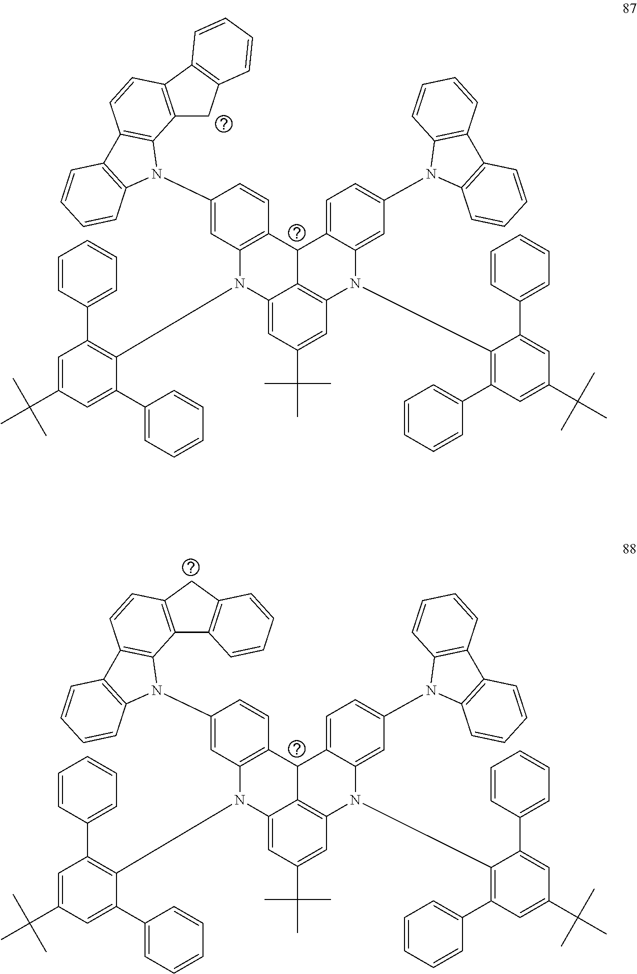

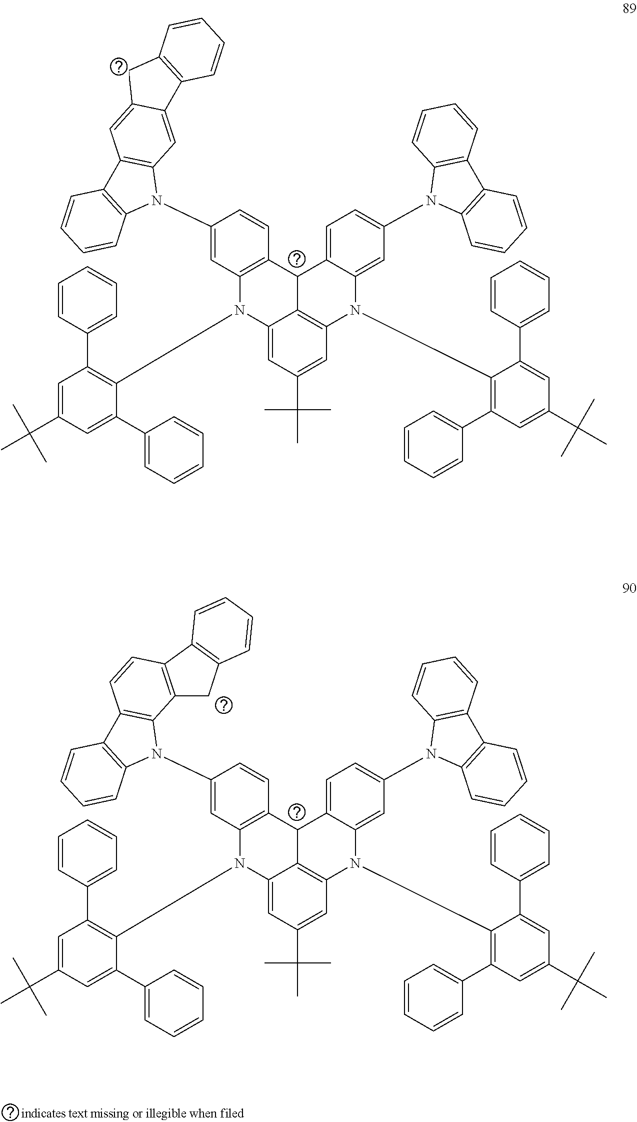

The fused polycyclic compound represented by Formula 1 has a structure in which the first substituent and the second substituent are introduced, and thus may achieve improved luminescence characteristics and a long service life.

The fused polycyclic compound represented by Formula 1 may have a structure which includes the fused ring core in which the first to third aromatic rings are fused via the boron atom, the first nitrogen atom, and the second nitrogen atom, and in which the first substituent is linked to the first or second aromatic ring and the second substituent is linked to each of the first and second nitrogen atom. The first substituent has a structure in which the first heterocycle containing the third nitrogen atom, the second heterocycle containing a heavy atom, and the benzene moiety are fused. The third nitrogen atom may be linked to the first or second aromatic ring at a para-position to the boron atom of the fused ring core. The second substituent may include a m-terphenyl moiety.

The fused polycyclic compound includes the first substituent and the second substituent, so that a steric hindrance effect of the first substituent and of the second substituent may protect the empty p-orbital of the boron atom, and the trigonal planar structure of the boron atom may be effectively maintained. Accordingly, the fused polycyclic compound of an embodiment may have improved material stability whereby material deterioration may be prevented.

The fused polycyclic compound includes the first substituent and the second substituent, and thus intermolecular interactions may be suppressed. Accordingly, the fused polycyclic compound of an embodiment may reduce phenomena such as aggregation, the formation of an excimer between molecules, or the formation of an exciplex between molecules, which are side effects of intermolecular interactions, thereby achieving effects of improving luminescence characteristics and element service life characteristics.

Since the fused polycyclic compound includes the first substituent and the second substituent, a distance between molecules is relatively increased to suppress Dexter energy transfer and to reduce quenching phenomena such as triplet-triplet annihilation (TTA) according to an increase in triplet concentration, and thus the light emitting element may have improved luminescence characteristics and element service life characteristics. The fused polycyclic compound includes the first substituent and the second substituent, and thus has high glass-transition temperature (Tg) characteristics, thereby preventing the crystallization of the fused polycyclic compound. Therefore, when the fused polycyclic compound is applied to an emission layer EML of the light emitting element ED, luminescence characteristics may be improved and the element service life may be improved.

An emission spectrum of the fused polycyclic compound represented by Formula 1 of an embodiment may have a full width at half maximum (FWHM) in a range of about 10 nm to about 50 nm. For example, the emission spectrum of the fused polycyclic compound represented by Formula 1 may have a FWHM in a range of about 20 nm to about 40 nm. The emission spectrum of the fused polycyclic compound represented by Formula 1 of an embodiment may have a FWHM in any of the above ranges, thereby improving luminous efficiency when applied to a device. When the fused polycyclic compound is used as a blue light emitting element material for the light emitting element, the element service life may be improved.

The fused polycyclic compound according to an embodiment may be included in the emission layer EML. The fused polycyclic compound may be included as a dopant material in the emission layer EML. The fused polycyclic compound may be a thermally activated delayed fluorescence material. The fused polycyclic compound may be used as a thermally activated delayed fluorescence dopant. For example, in the light emitting element ED according to an embodiment, the emission layer EML may include, as a thermally activated delayed fluorescence dopant, at least one fused polycyclic compound selected from Compound Group 1 as described above. However, embodiments are not limited thereto.

The fused polycyclic compound represented by Formula 1 may be a thermally activated delayed fluorescence emitting material. The fused polycyclic compound represented by Formula 1 may be a luminescent material having a central wavelength in a range of about 430 nm to about 490 nm. For example, the fused polycyclic compound represented by Formula 1 may be a blue thermally activated delayed fluorescence (TADF) dopant. However, embodiments are not limited thereto, and when the fused polycyclic compound is used as a luminescent material, the first compound may be used as a dopant material that emits light in various wavelength regions, such as a red emitting dopant or a green emitting dopant.

The emission layer EML in the light emitting element ED according to an embodiment may emit delayed fluorescence. For example, the emission layer EML may emit thermally activated delayed fluorescence (TADF).

The emission layer EML of the light emitting element ED may emit blue light. For example, the emission layer EML of the light emitting element ED may emit blue light having a central wavelength less than or equal to about 490 nm. However, embodiments are not limited thereto, and the emission layer EML may emit green light or red light. In an embodiment, an emission layer EML that includes the fused polycyclic compound represented by Formula 1 may emit delayed fluorescence having a central wavelength in a range of about 430 nm to about 490 nm.

The fused polycyclic compound according to an embodiment may be included in the emission layer EML. The fused polycyclic compound according to an embodiment may be included as a dopant material in the emission layer EML. The fused polycyclic compound according to an embodiment may be a thermally activated delayed fluorescence material. The fused polycyclic compound according to an embodiment may be used as a thermally activated delayed fluorescence dopant. For example, in the light emitting element ED, the emission layer EML may include, as a thermally activated delayed fluorescence dopant, at least one fused polycyclic compound selected from Compound Group 1 as described above. However, a use of the fused polycyclic compound according to an embodiment is not limited thereto.

In an embodiment, the emission layer EML may include a first compound represented by Formula 1, and may further include at least one of a second compound represented by Formula HT-1, a third compound represented by Formula ET-1, or a fourth compound represented by Formula D-1.

In an embodiment, the emission layer EML may further include a second compound represented by Formula HT-1. In an embodiment, the second compound may be used as a hole transporting host material in the emission layer EML.

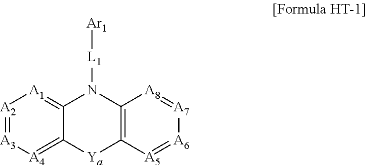

In Formula HT-1, A₁ to A₈ may each independently be N or C(R₅₁). For example, A₁ to A₈ may each independently be C(R₅₁). As another example, one of A₁ to A₈ may be N, and the remainder of A₁ to A₈ may each independently be C(R₅₁).

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, etc., but embodiments are not limited thereto.

In Formula HT-1, Yₐ may be a direct linkage, C(R₅₂)(R₅₃), or Si(R₅₄)(R₅₅). For example, the two aromatic rings that are bonded to the nitrogen atom in Formula HT-1 may directly be linked to each other via a direct linkage,

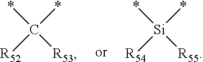

In Formula HT-1, when Yₐ is a direct linkage, the second compound represented by Formula HT-1 may include a carbazole moiety.

In Formula HT-1, Ar₁ may be a substituted or unsubstituted aryl group having 6 to 30 ring-forming carbon atoms or a substituted or unsubstituted heteroaryl group having 2 to 30 ring-forming carbon atoms. For example, An may be a substituted or unsubstituted carbazole group, a substituted or unsubstituted dibenzofuran group, a substituted or unsubstituted dibenzothiophene group, a substituted or unsubstituted biphenyl group, etc., but the embodiments are not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring. For example, R₅₁ to R₅₅ may each independently be a hydrogen atom or a deuterium atom. For example, R₅₁ to R₅₅ may each independently be an unsubstituted methyl group or an unsubstituted phenyl group.

In an embodiment, the second compound represented by Formula HT-1 may be selected from Compound Group 2. In an embodiment, in the light emitting element ED, the second compound may include at least one compound selected from Compound Group 2:

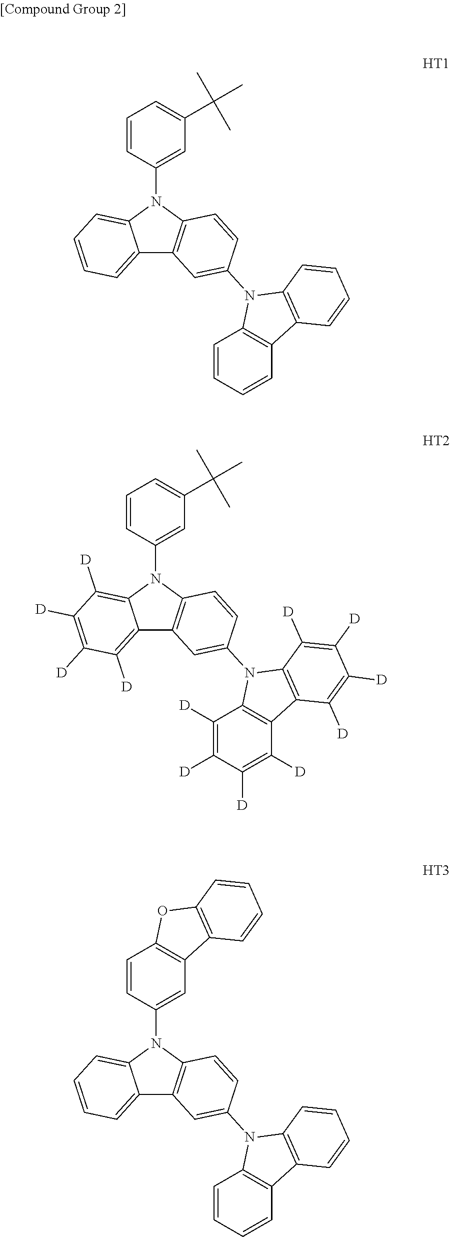 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

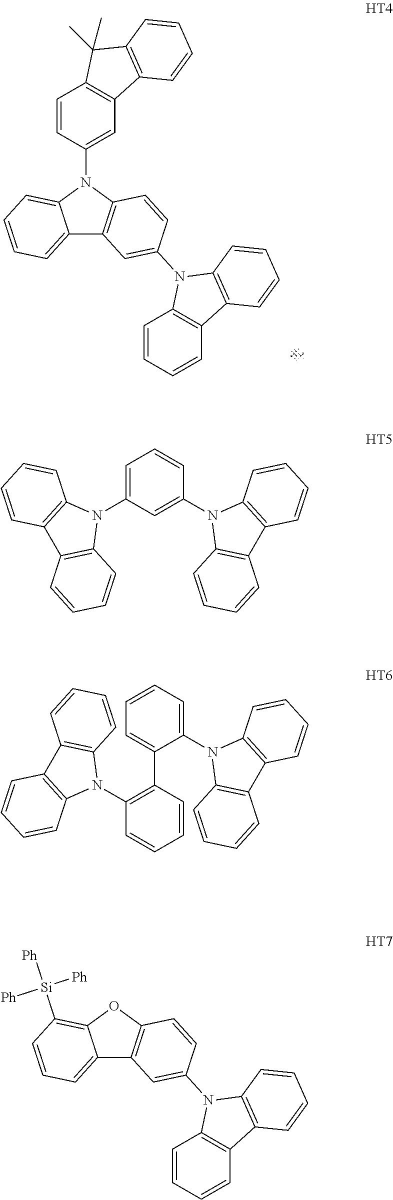 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

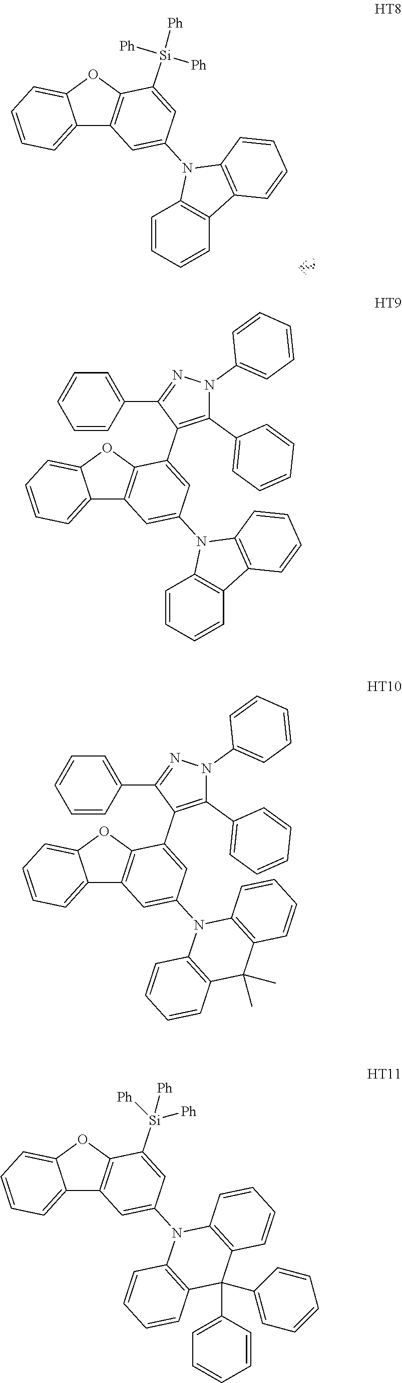 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1]

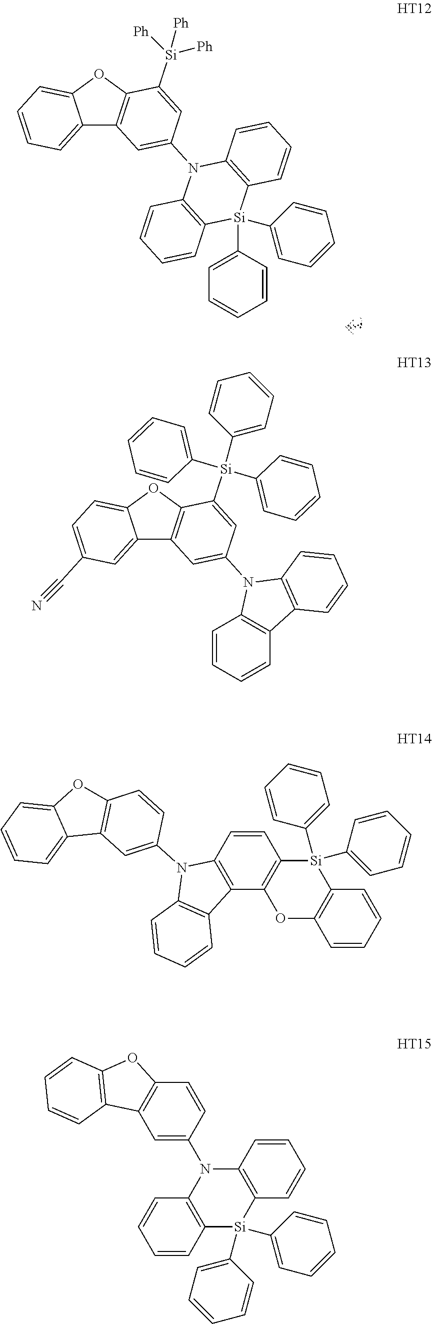 [SMILES: c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1]

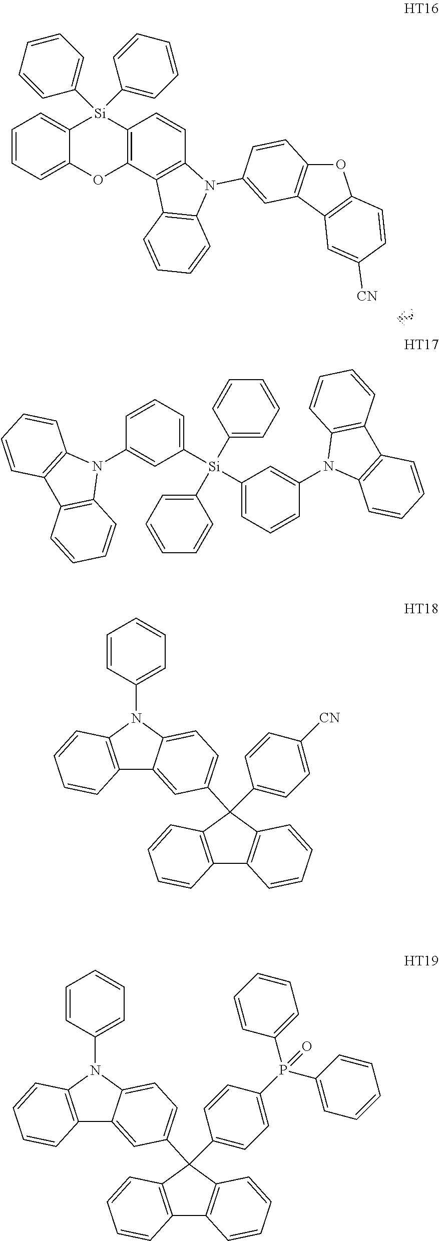 [SMILES: N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1]

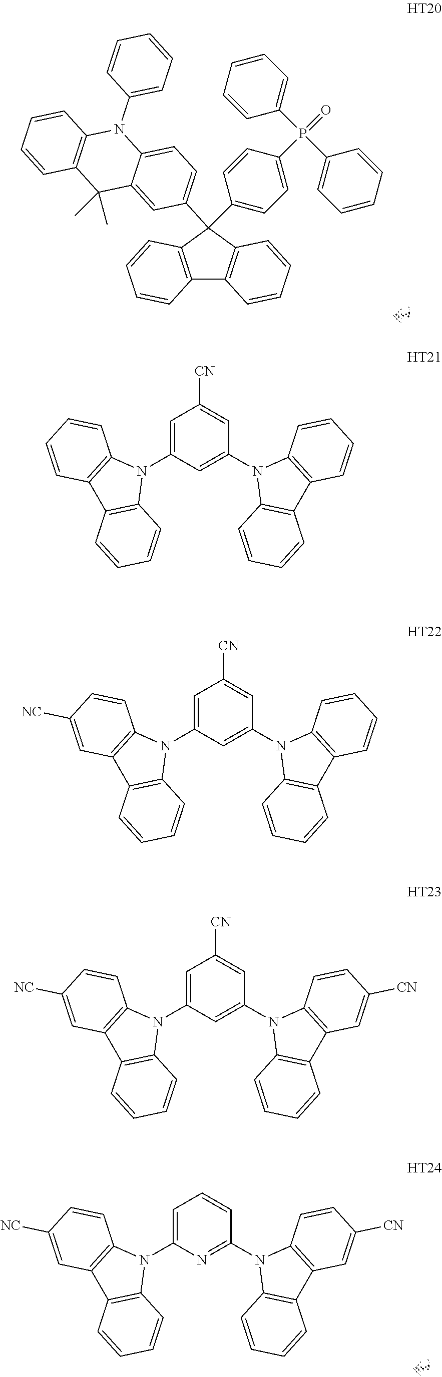 [SMILES: CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1]

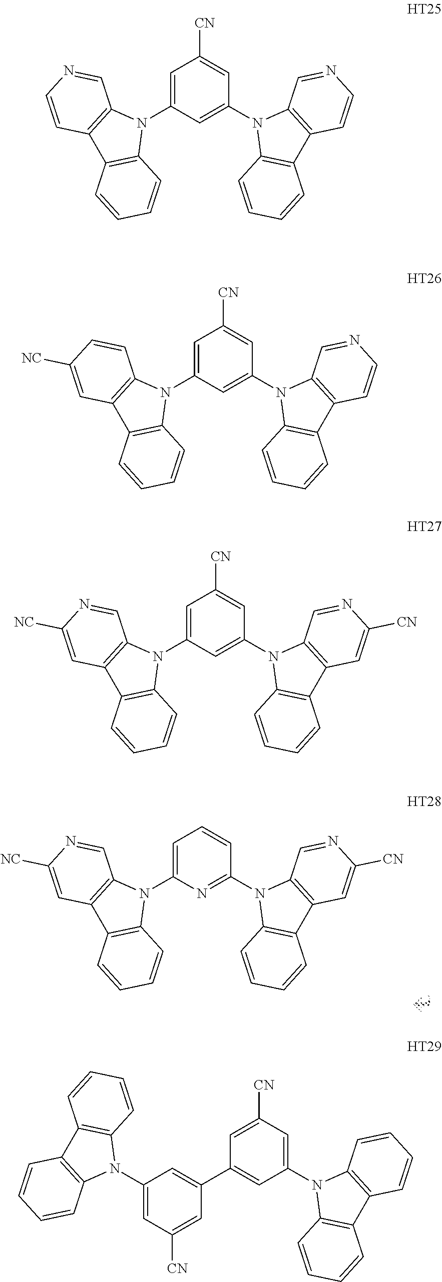 [SMILES: N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1]

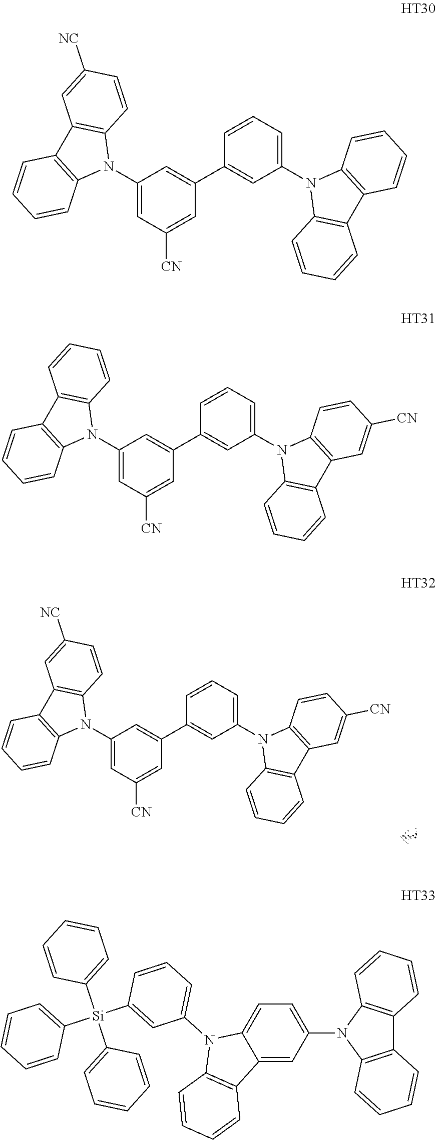 [SMILES: N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1]

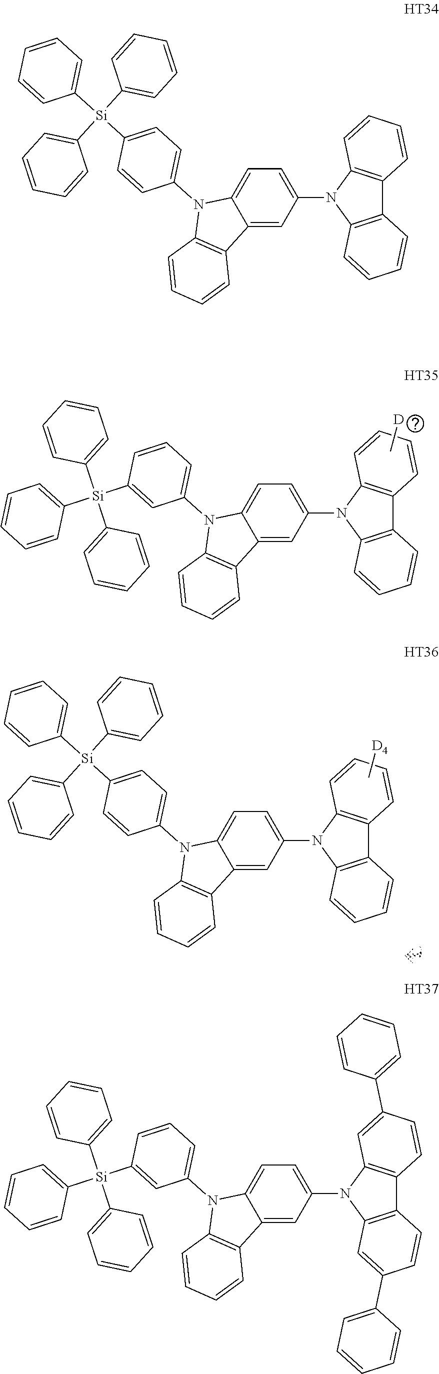

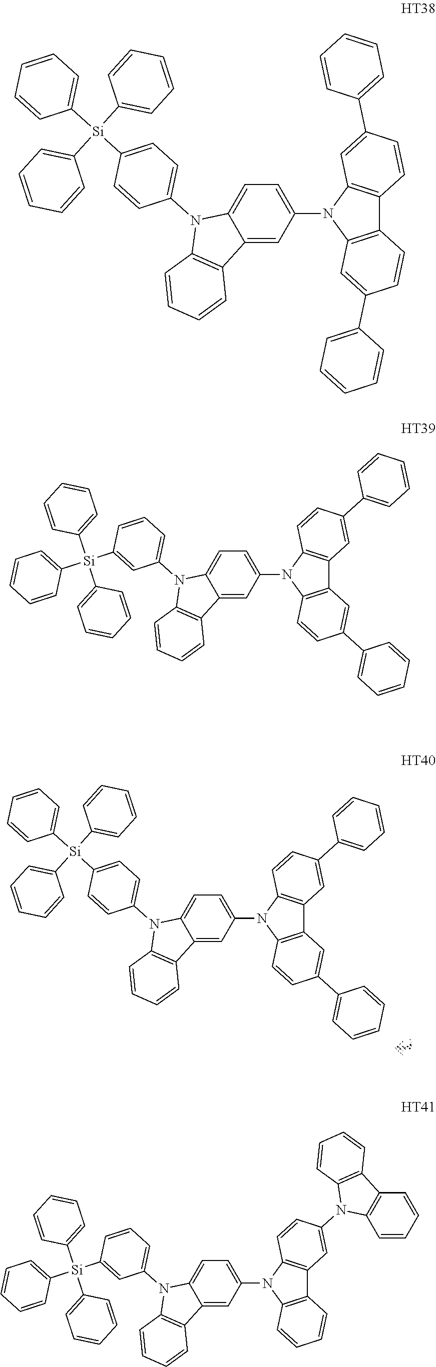 [SMILES: c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1]

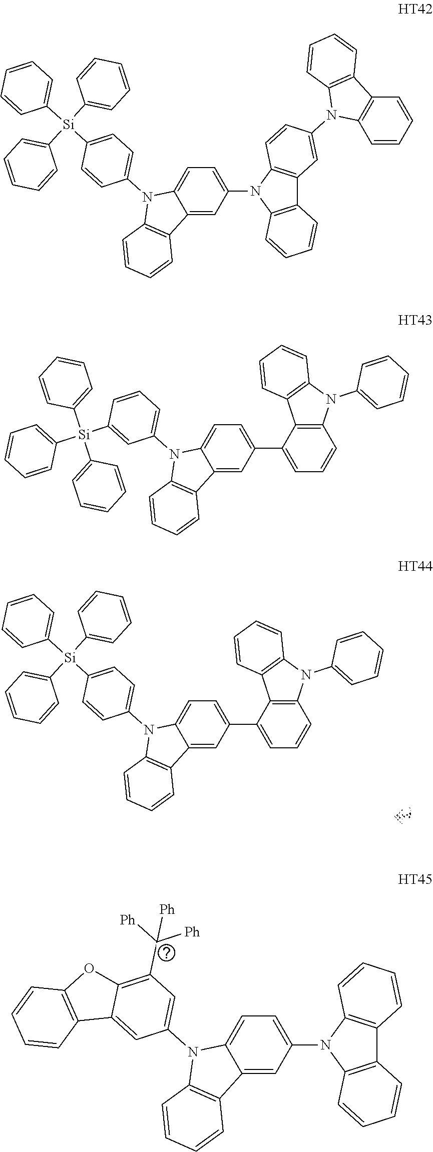 [SMILES: c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1 ; c1ccc(-n2c3ccccc3c3c(-c4ccc5c(c4)c4ccccc4n5-c4cccc([Si](c5ccccc5)(c5ccccc5)c5ccccc5)c4)cccc32)cc1 ; c1ccc(-n2c3ccccc3c3c(-c4ccc5c(c4)c4ccccc4n5-c4ccc([Si](c5ccccc5)(c5ccccc5)c5ccccc5)cc4)cccc32)cc1 ; c1ccc(C(c2ccccc2)(c2ccccc2)c2cc(-n3c4ccccc4c4cc(-n5c6ccccc6c6ccccc65)ccc43)cc3c2oc2ccccc23)cc1]

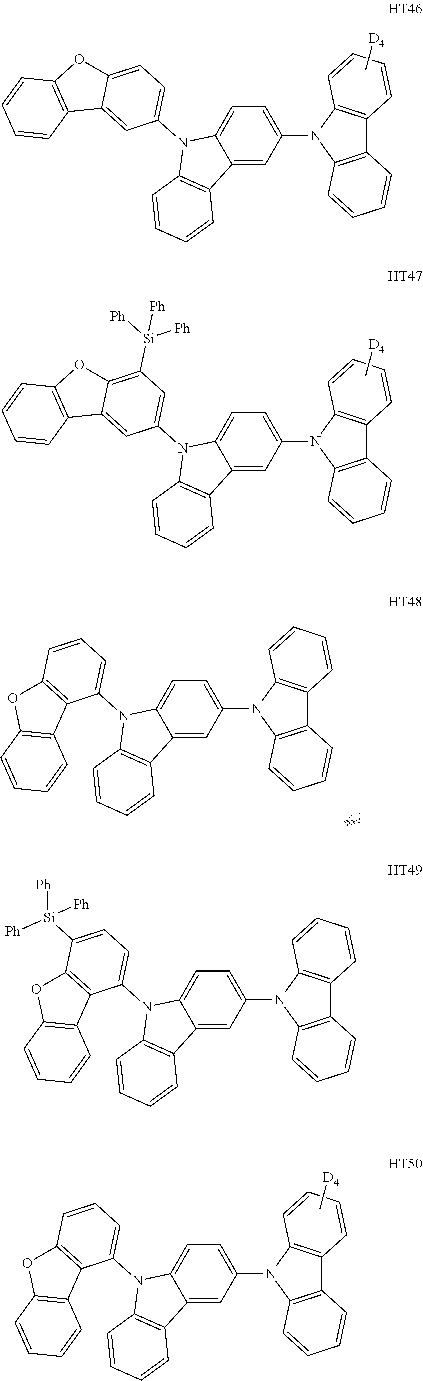

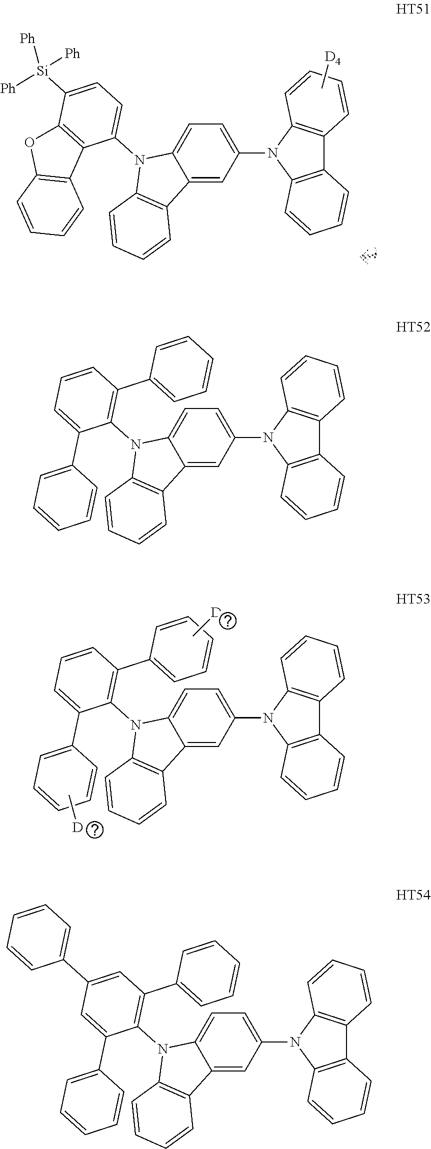

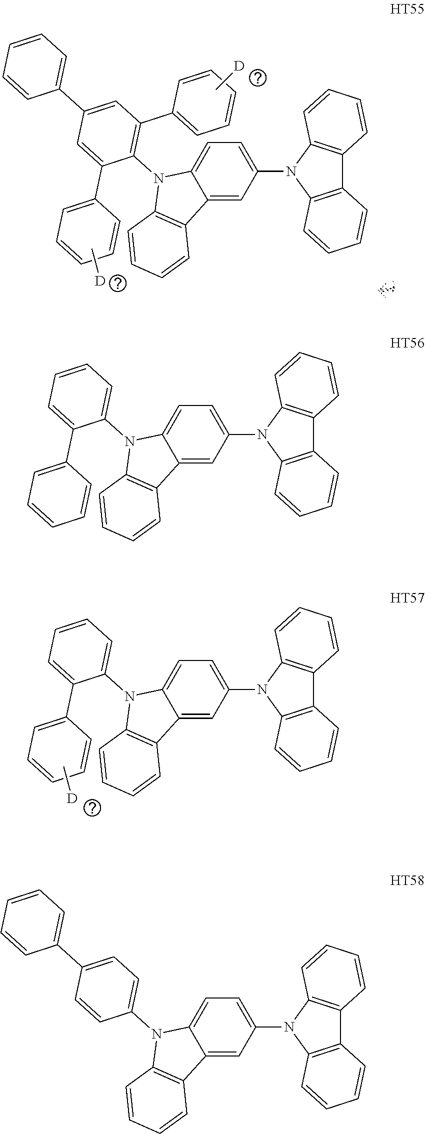

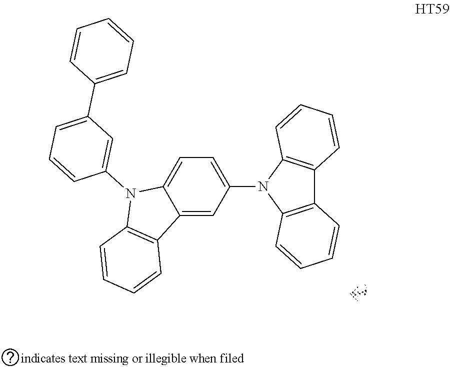 [SMILES: c1ccc(-c2cccc(-n3c4ccccc4c4cc(-n5c6ccccc6c6ccccc65)ccc43)c2)cc1]

In Compound 2, D may be a deuterium atom, and Ph may be a substituted or unsubstituted phenyl group. For example, in Compound Group 2, Ph may be an unsubstituted phenyl group.

In an embodiment, the emission layer EML may further include a third compound represented by Formula ET-1. In an embodiment, the third compound may be used as an electron transport host material for the emission layer EML.

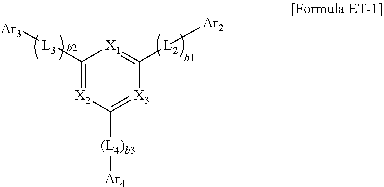

In Formula ET-1, at least one of X₁ to X₃ may each be N, and the remainder of X₁ to X₃ may each independently be C(R₅₆). For example, any one of X₁ to X₃ may be N, and the remainder of X₁ to X₃ may each independently be C(R₅₆). Accordingly, the third compound represented by Formula ET-1 may include a pyridine moiety. As another example, two of X₁ to X₃ may each be N, and the remainder of X₁ to X₃ may be C(R₅₆). Accordingly, the third compound represented by Formula ET-1 may include a pyrimidine moiety. As yet another example, X₁ to X₃ may each be N. Accordingly, the third compound represented by Formula ET-1 may include a triazine moiety.

In Formula ET-1, R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may each independently be an integer from 0 to 10.

In Formula ET-1, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₂ to Ar₄ may each independently be a substituted or unsubstituted phenyl group or a substituted or unsubstituted carbazole group.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. When b1 to b3 are each 2 or greater, L₂ to L₄ may each independently be a substituted or unsubstituted arylene group having 6 to 30 ring-forming carbon atoms or a substituted or unsubstituted heteroarylene group having 2 to 30 ring-forming carbon atoms.

In an embodiment, the third compound represented by Formula ET-1 may be selected from Compound Group 3. In an embodiment, in the light emitting element ED, the third compound may include at least one compound selected from Compound Group 3:

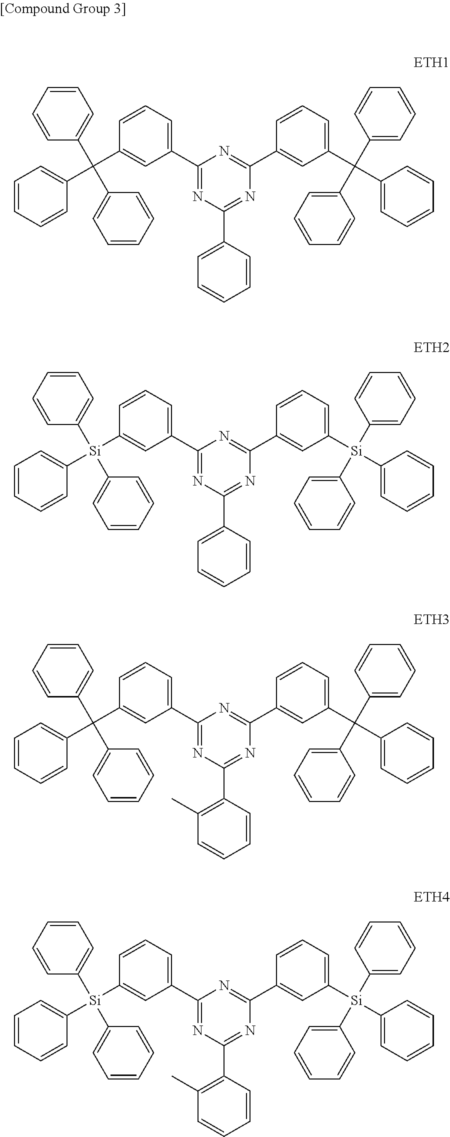 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

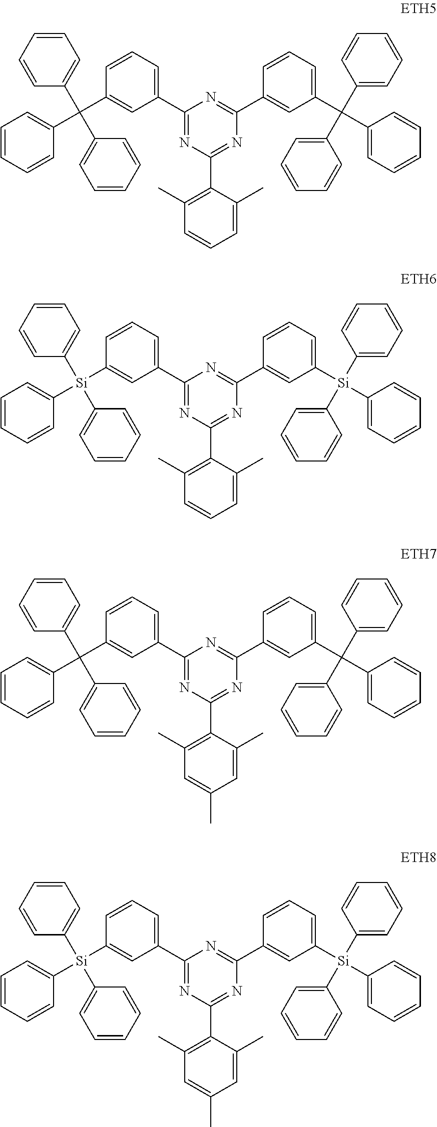 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

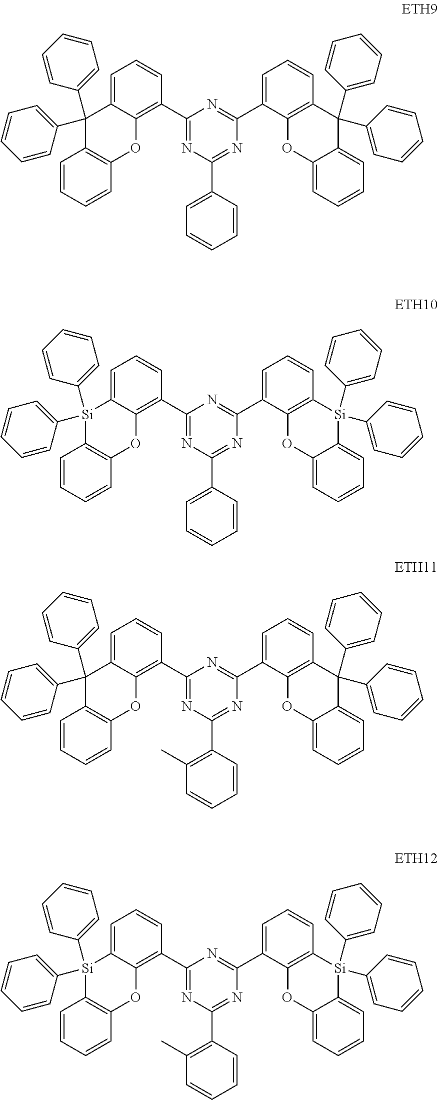

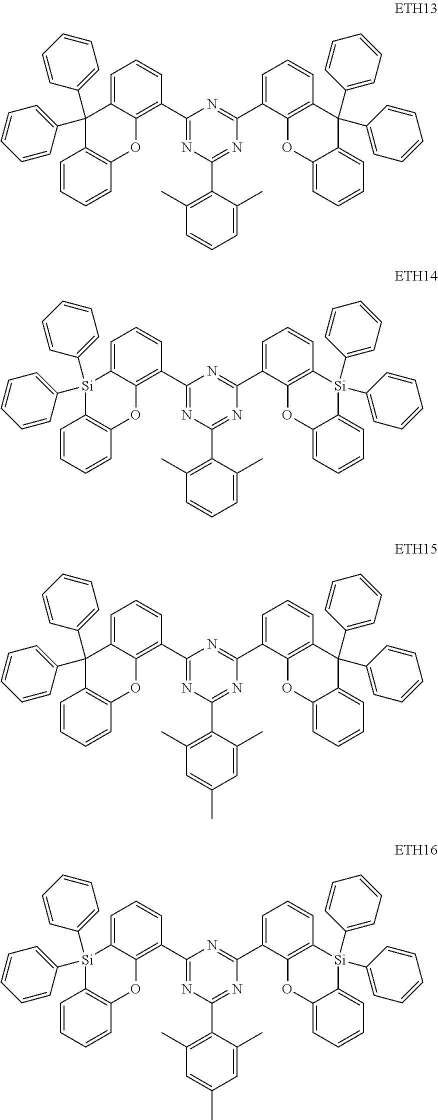 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

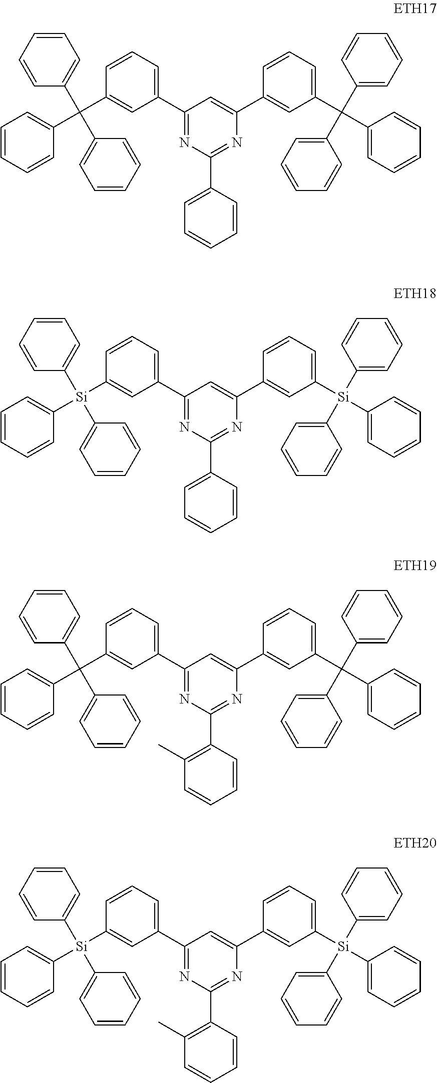 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

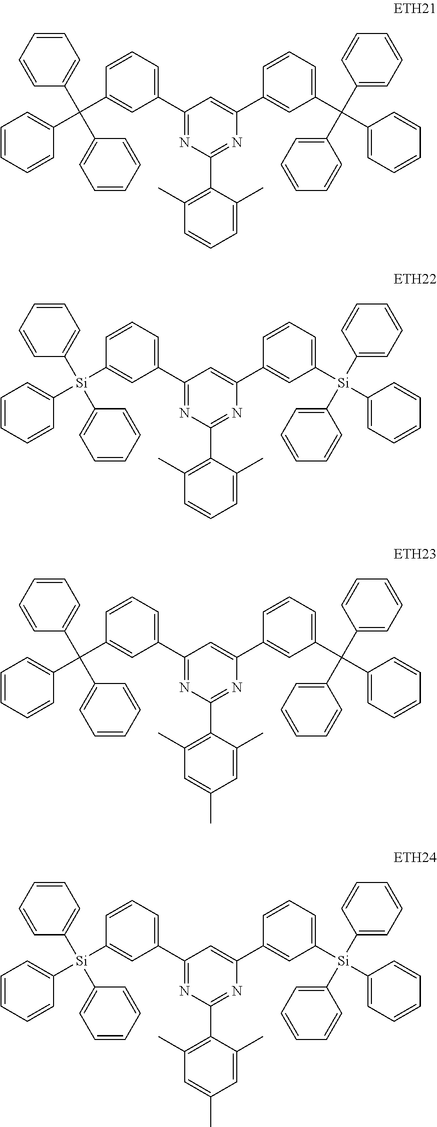 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

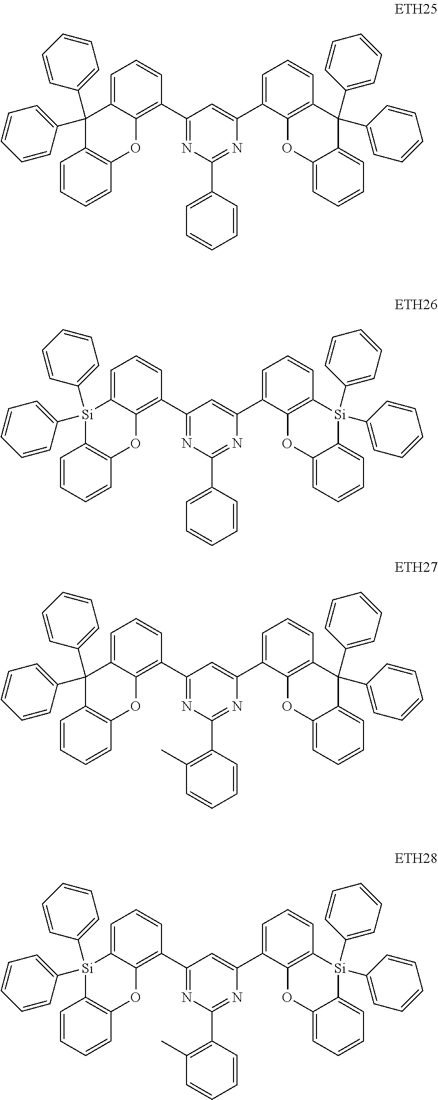

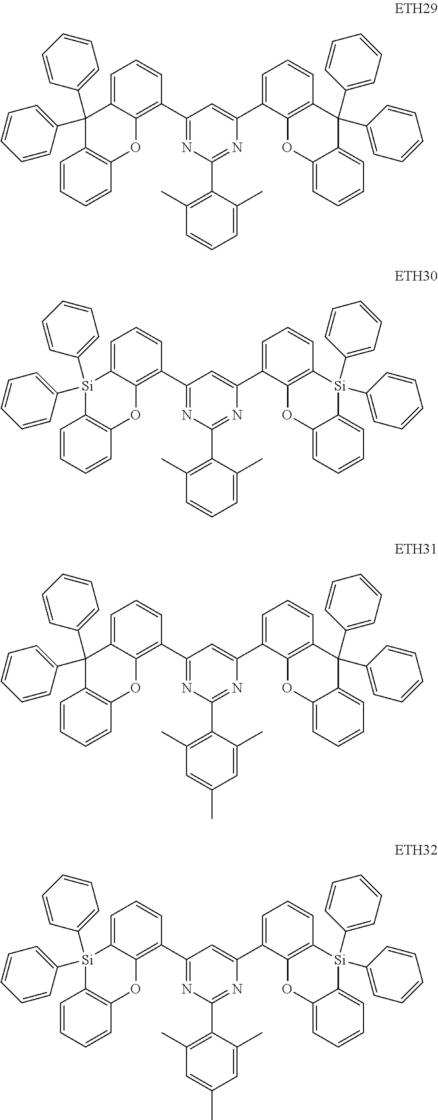 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

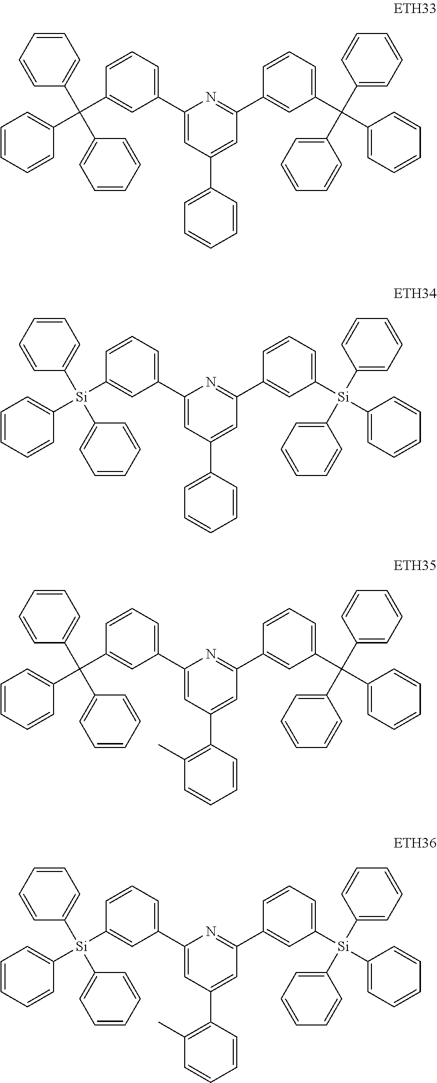 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

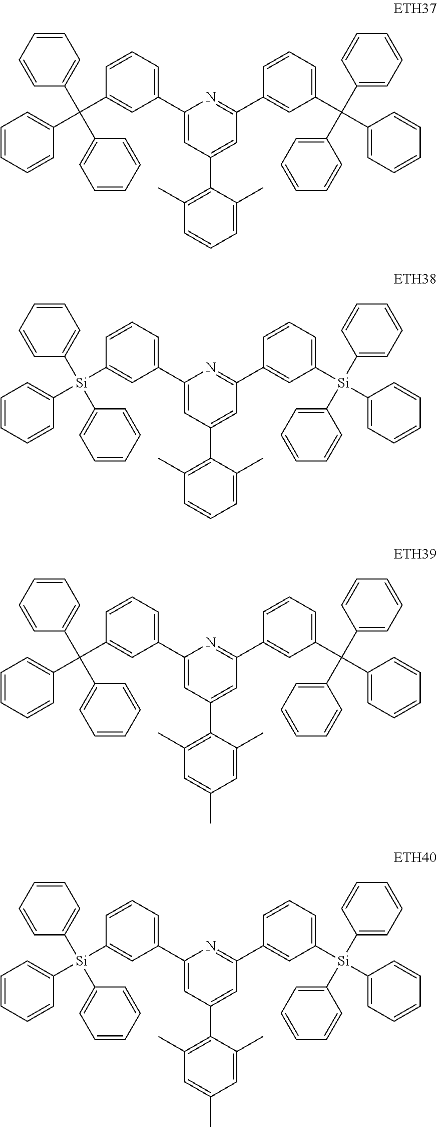 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

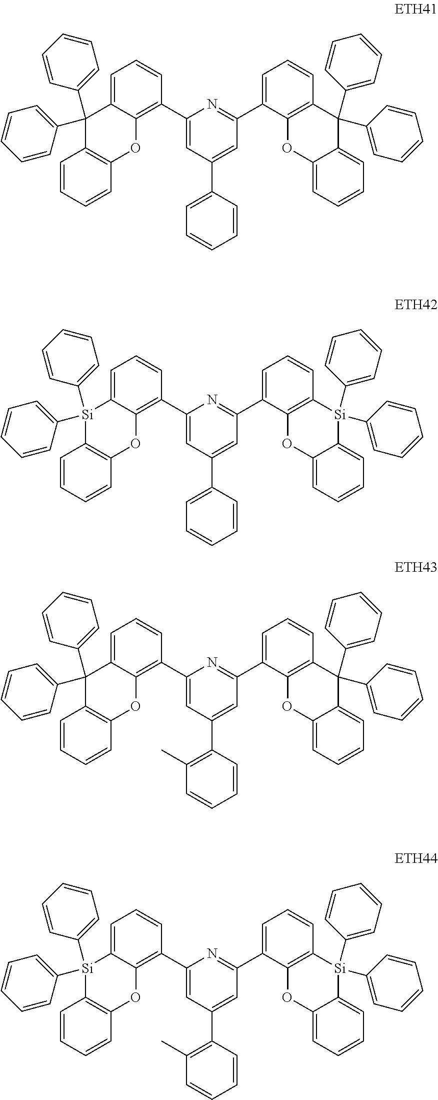

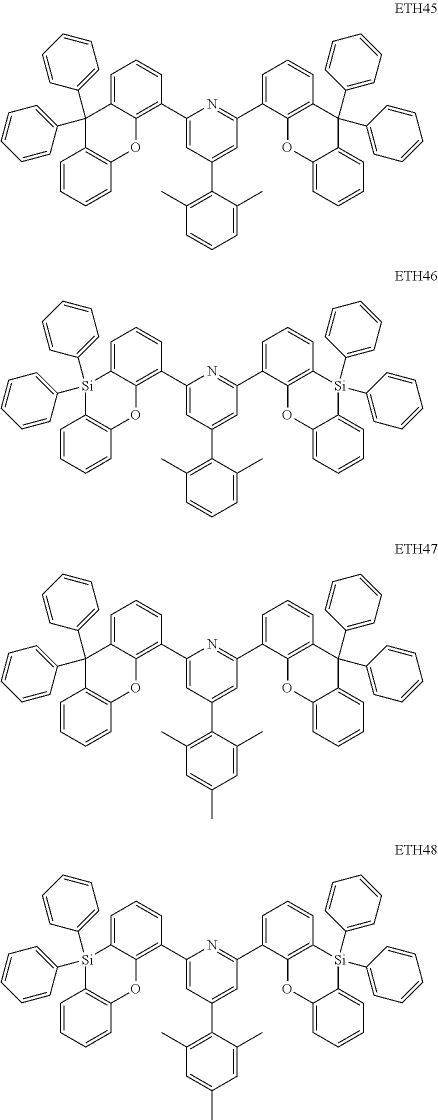 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

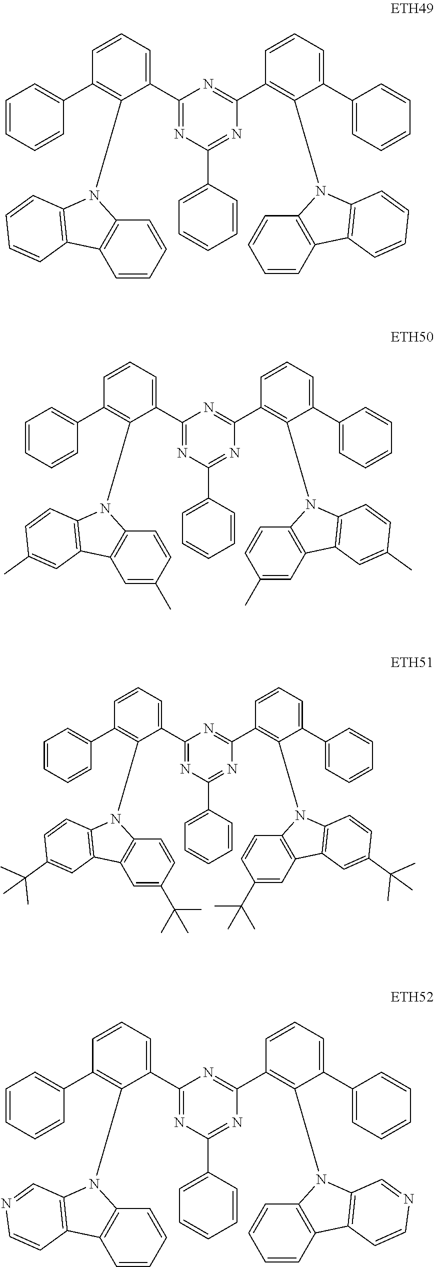

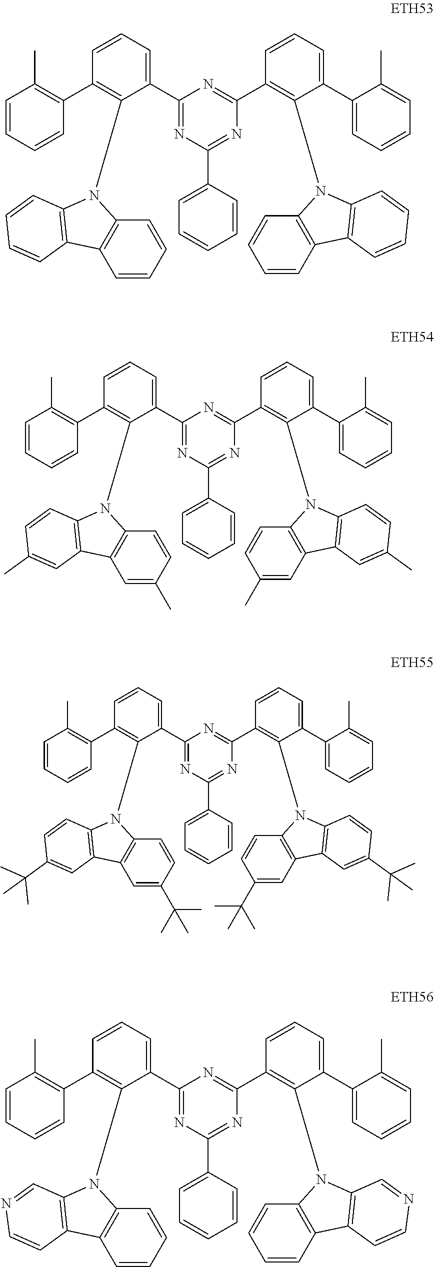

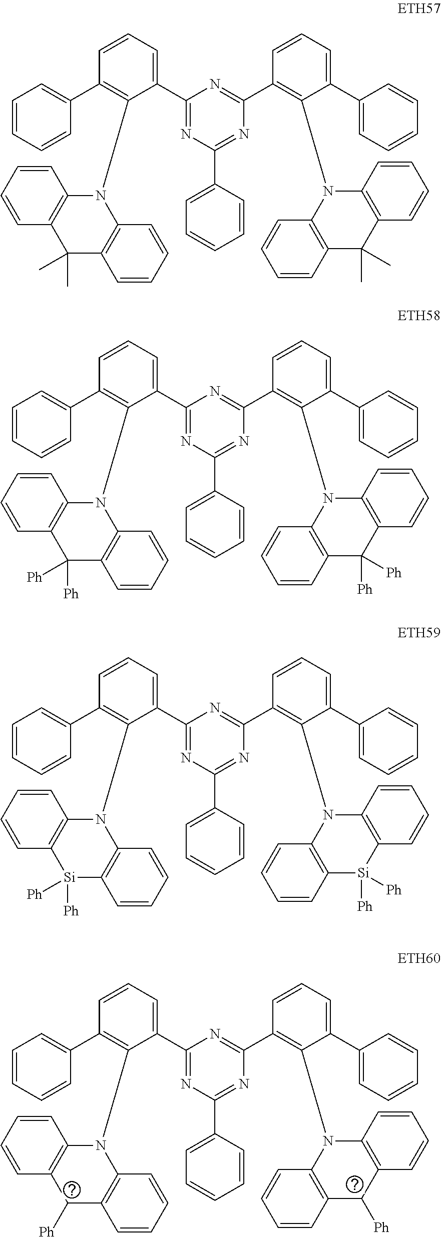

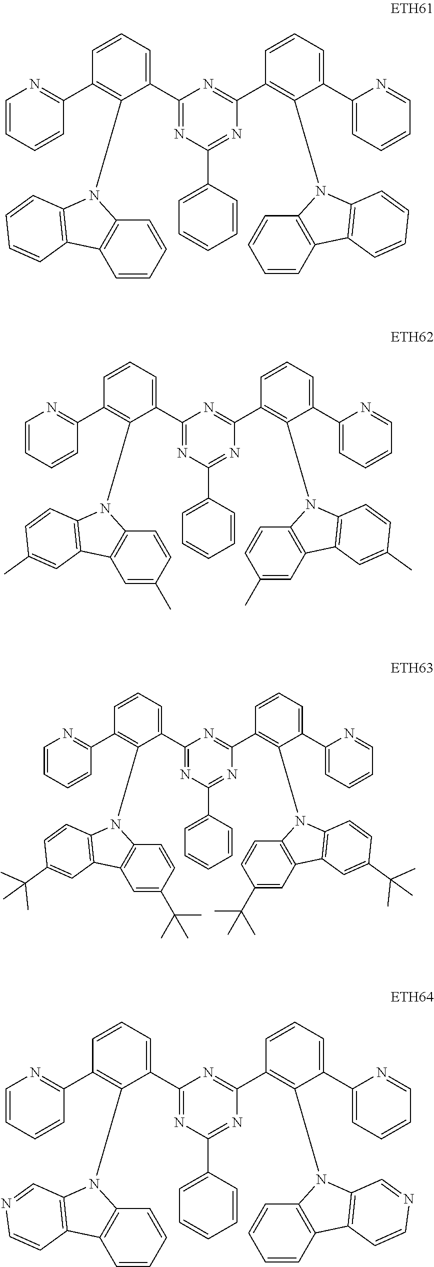

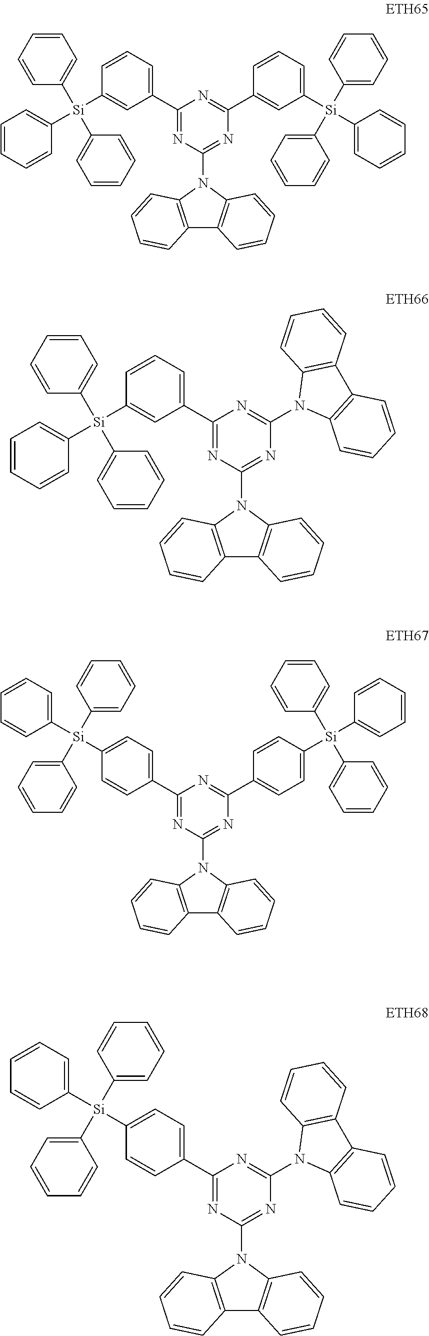 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

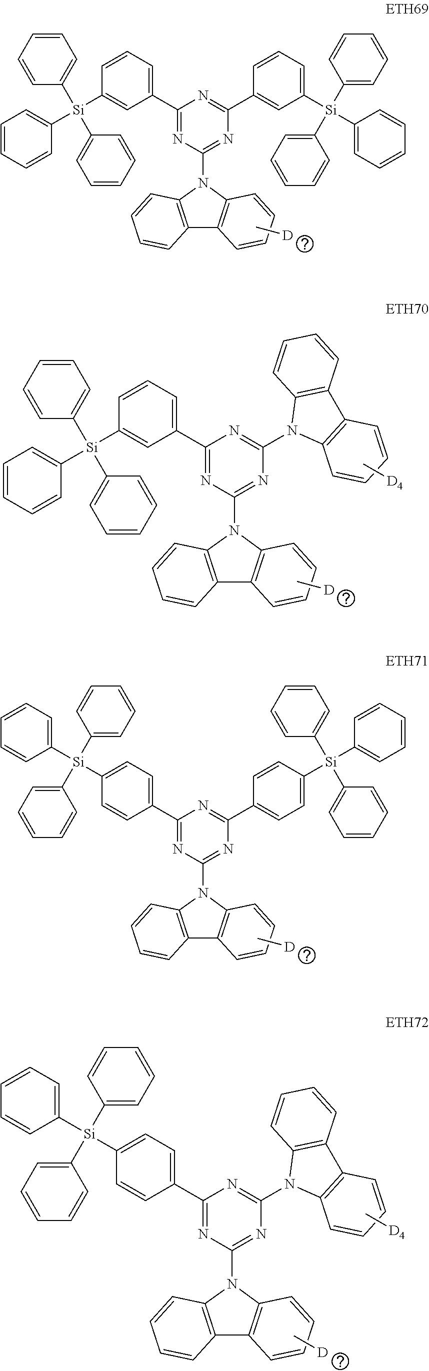

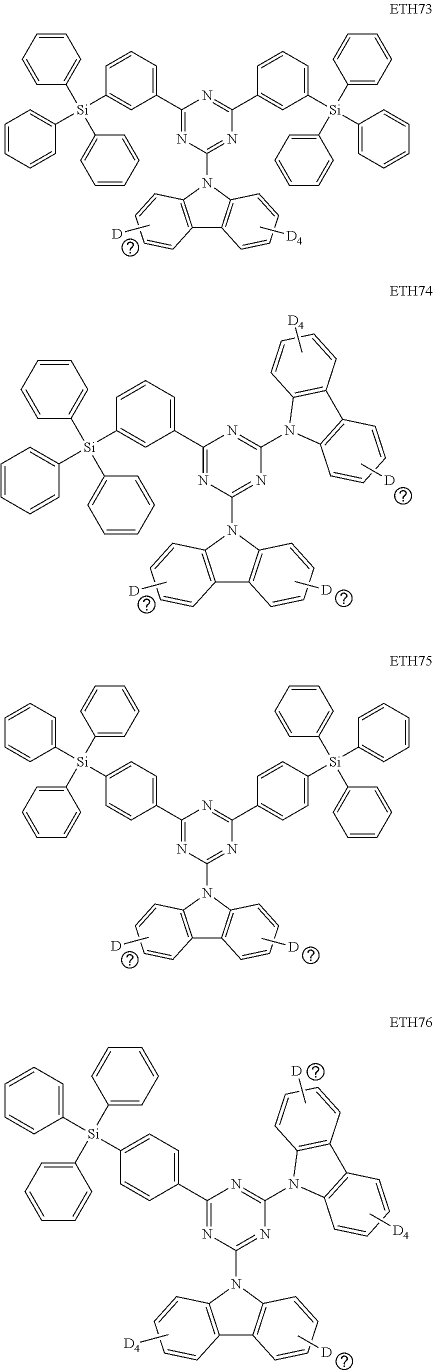

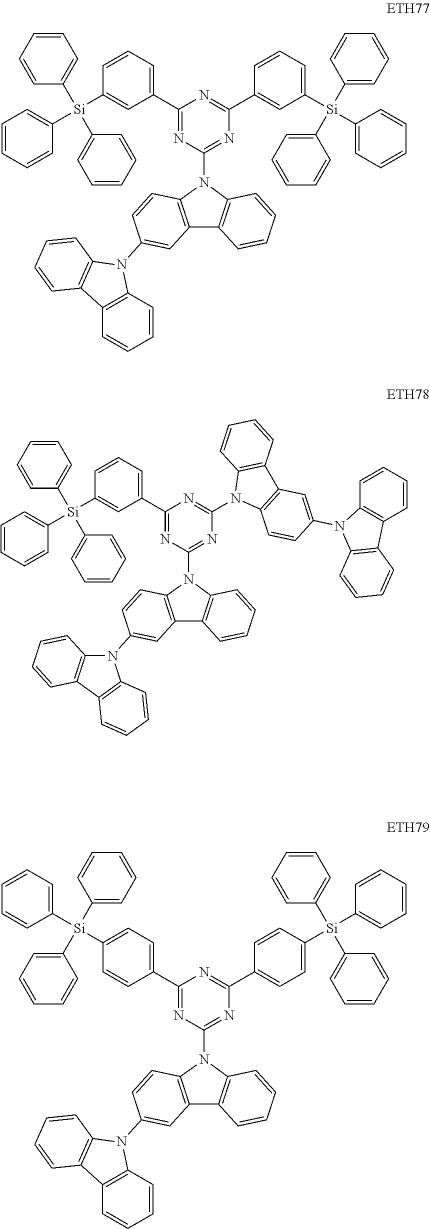 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

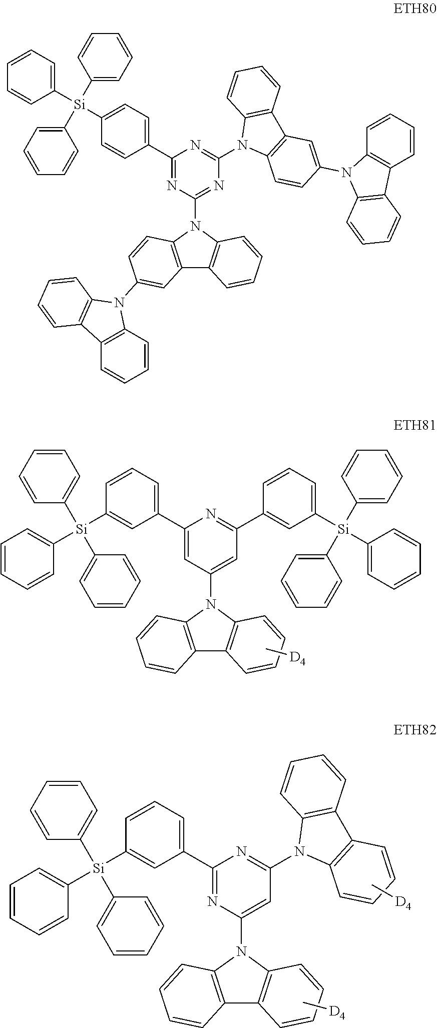

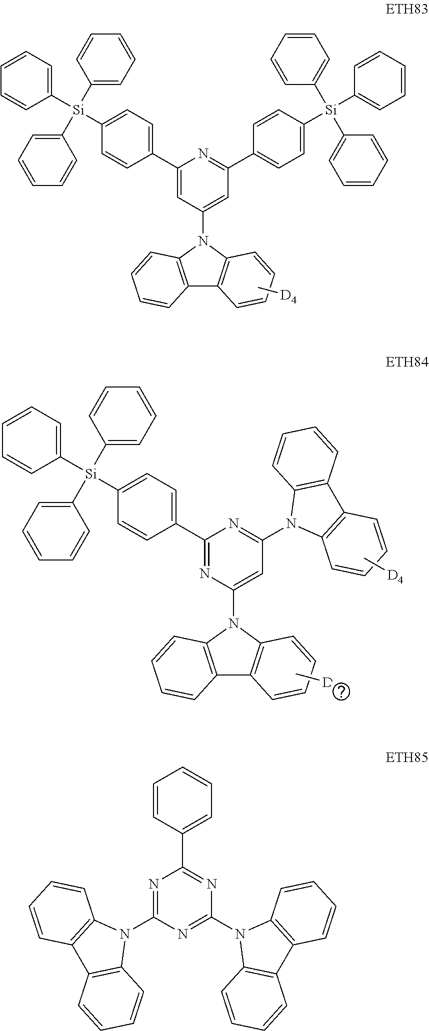

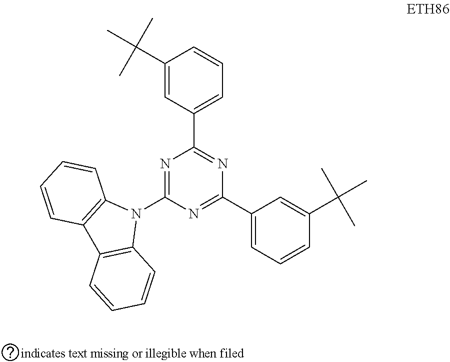 [SMILES: CC(C)(C)c1cccc(-c2nc(-c3cccc(C(C)(C)C)c3)nc(-n3c4ccccc4c4ccccc43)n2)c1]

In Compound Group 3, D may be a deuterium atom and Ph may be an unsubstituted phenyl group.

In the emission layer EML, an exciplex may be formed by the hole transport host and the electron transport host. A triplet energy level of the exciplex formed by a hole transporting host and an electron transporting host may correspond to a difference between a lowest unoccupied molecular orbital (LUMO) energy level of the electron transporting host and a highest occupied molecular orbital (HOMO) energy level of the hole transporting host.

For example, an absolute value of a triplet energy level (T1) of the exciplex formed by the hole transporting host and the electron transporting host may be in a range of about 2.4 eV to about 3.0 eV. The triplet energy level of the exciplex may have a value that is smaller than an energy gap of each host material. The exciplex may have a triplet energy level equal to or less than about 3.0 eV, which is an energy gap between the hole transporting host and the electron transporting host.

In an embodiment, the emission layer EML may include a fourth compound, in addition to the first compound, the second compound, and the third compound. The fourth compound may be used as a phosphorescent sensitizer in an emission layer EML. Energy may be transferred from the fourth compound to the first compound, thereby emitting light.

The emission layer EML may include, as a fourth compound, an organometallic complex that includes platinum (Pt) as a central metal atom and ligands linked to the central metal atom. In an embodiment, the emission layer EML may further include a fourth compound represented by Formula D-1:

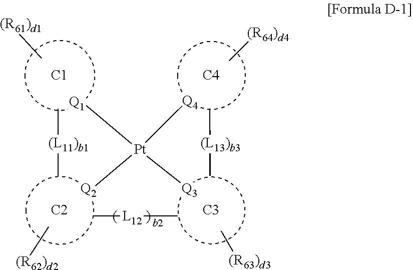

In Formula D-1, Q₁ to Q₄ may each independently be C or N.

In Formula D-1, C1 to C4 may each independently be a substituted or unsubstituted hydrocarbon ring having 5 to 30 ring-forming carbon atoms or a substituted or unsubstituted heterocycle having 2 to 30 ring-forming carbon atoms.

In Formula D-1, L₁₁ to L₁₃ may each independently be a direct linkage,

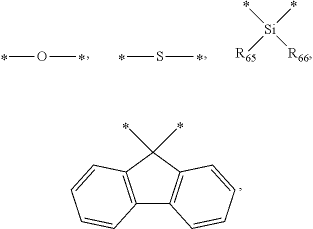

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, [symbol] represents a bond to one of C1 to C4.

In Formula D-1, b1 to b3 may each independently be 0 or 1. If b1 is 0, C1 and C2 may not be directly linked to each other. If b2 is 0, C2 and C3 may not be directly linked to each other. If b3 is 0, C3 and C4 may not be directly linked to each other.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, R₆₁ to R₆₆ may each independently be a substituted or unsubstituted methyl group or a substituted or unsubstituted t-butyl group.

In Formula D-1, d1 to d4 may each independently be an integer from 0 to 4. If d1 to d4 are each 0, the fourth compound may not be substituted with R₆₁ to R₆₄, respectively. A case where d1 to d4 are each 4 and all groups of R₆₁ to R₆₄ are hydrogen atoms may be the same as a case where d1 to d4 are each 0. When d1 to d4 are each 2 or more, multiple groups of each of R₆₁ to R₆₄ may all be the same or at least one thereof may be different from the others.

In Formula D-1, C1 to C4 may each independently be a substituted or unsubstituted hydrocarbon ring or a substituted or unsubstituted heterocycle that is represented by any one of Formula C-1 to Formula C-4:

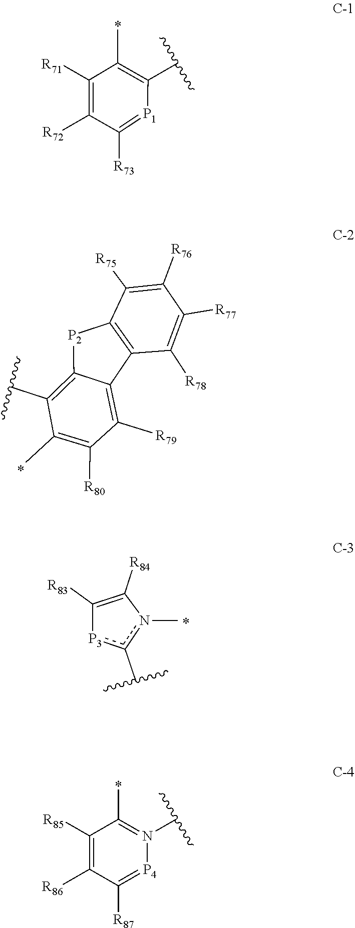

In Formula C-1 to Formula C-4, P₁ may be C—* or C(R₇₄), P₂ may be N—* or N(R₈₁), P₃ may be N—* or N(R₈₂), and P₄ may be C—* or C(R₈₈).

In Formula C-1 to Formula C-4, R₇₁ to R₈₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In Formula C-1 to Formula C-4,

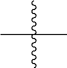

represents a bond to Pt, and [symbol] represents a bond to a neighboring cyclic group (C1 to C4) or to a linker (L₁₁ to L₁₃).

In an embodiment, the emission layer EML may include the first compound represented by Formula 1, and may further include at least one of the second compound, the third compound, and the fourth compound. In an embodiment, the emission layer EML may include the first compound, the second compound, and the third compound. In the emission layer EML, the second compound and the third compound may form an exciplex, the energy may be transferred from the exciplex to the first compound, thereby emitting light.

In another embodiment, the emission layer EML may include the first compound, the second compound, the third compound, and the fourth compound. In the emission layer EML, the second compound and the third compound may form an exciplex, and energy may be transferred from the exciplex to the fourth compound and the first compound, thereby emitting light. In an embodiment, the fourth compound may be a sensitizer. The fourth compound included in the emission layer EML in the light emitting element ED according to an embodiment may serve as a sensitizer that transfers energy from a host to the first compound, which is a light emitting dopant. For example, the fourth compound, which serves as an auxiliary dopant, may accelerate energy transfer to the first compound, which is a light emitting dopant, thereby increasing an emission ratio of the first compound. Therefore, the emission layer EML may exhibit improved luminous efficiency. When energy transfer to the first compound is increased, an exciton formed in the emission layer EML may not accumulate inside the emission layer EML may rapidly emit light, so that deterioration of the light emitting element ED may be reduced. Therefore, the service life of the light emitting element ED may increase.

The light emitting element ED may include the first compound, the second compound, the third compound, and the fourth compound, and the emission layer EML may include the combination of two host materials and two dopant materials. In the light emitting element ED, the emission layer EML may include the second compound and the third compound, which are two different hosts, the first compound which emits delayed fluorescence, and the fourth compound which includes an organometallic complex, and thus the light emitting element ED may exhibit excellent luminous efficiency characteristics.

In an embodiment, the fourth compound represented by Formula D-1 may be selected from Compound Group 4. In an embodiment, in the light emitting element ED, the fourth compound may include at least one compound selected from Compound Group 4:

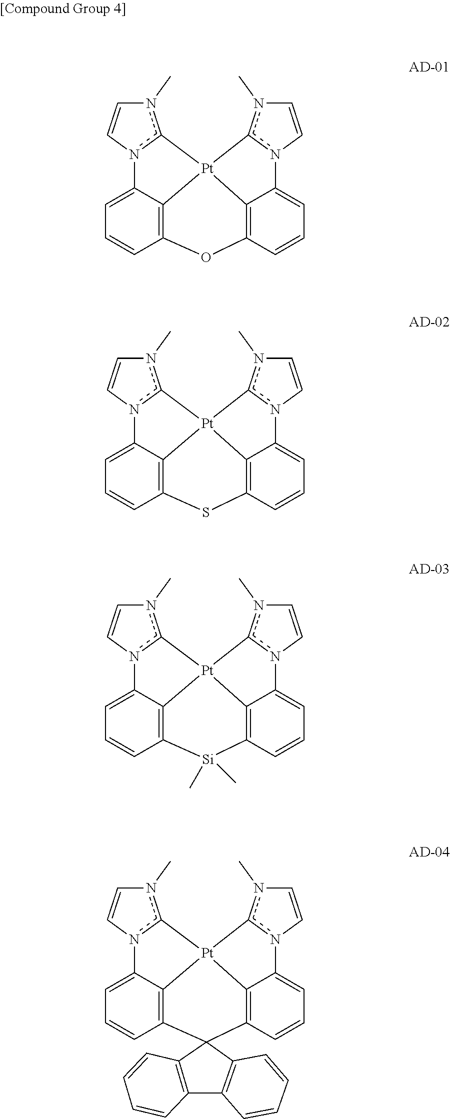

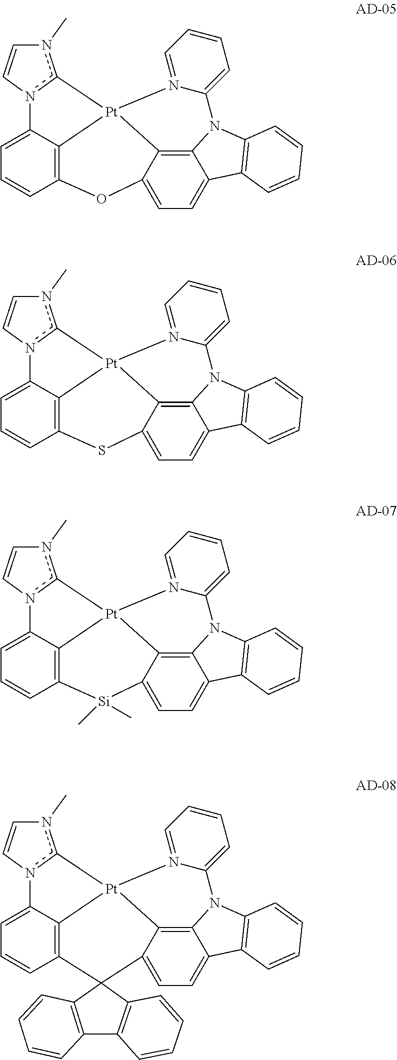

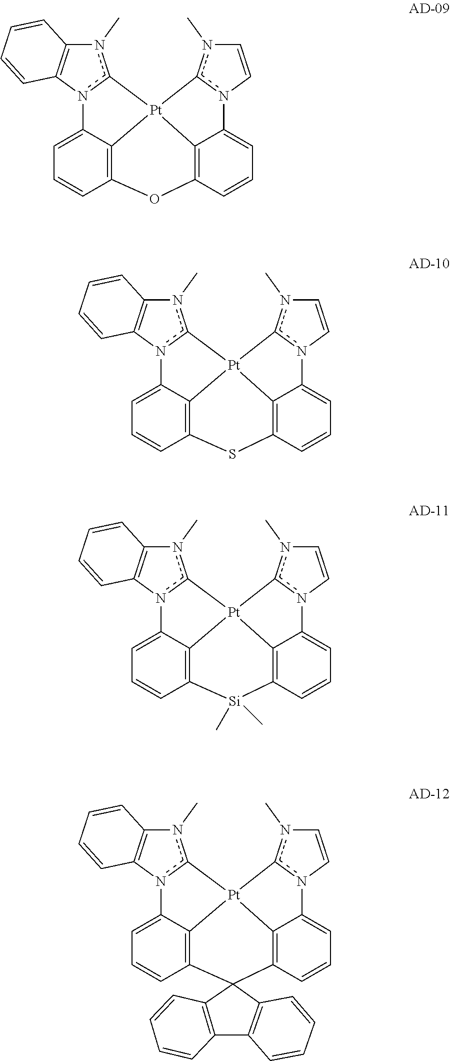

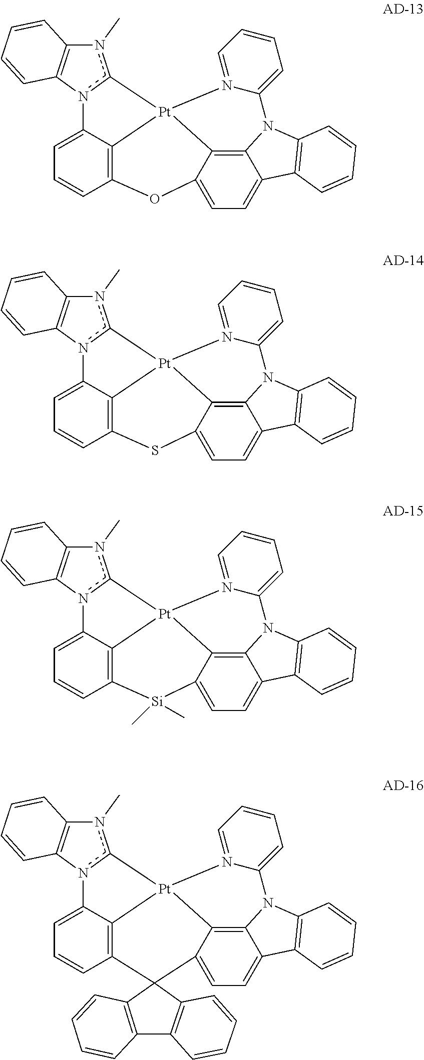

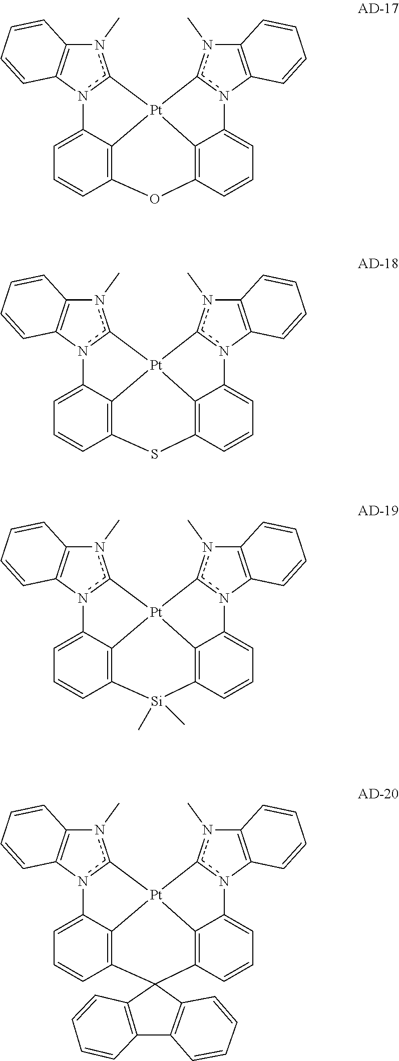

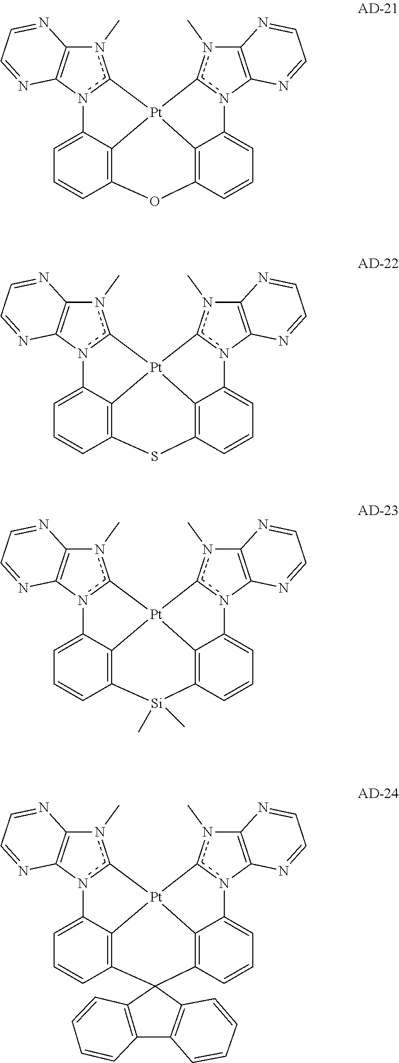

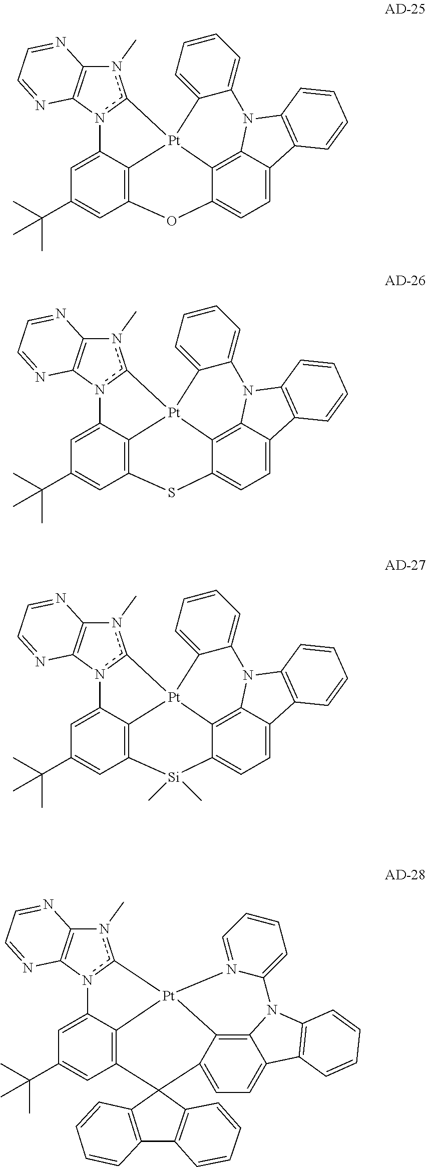

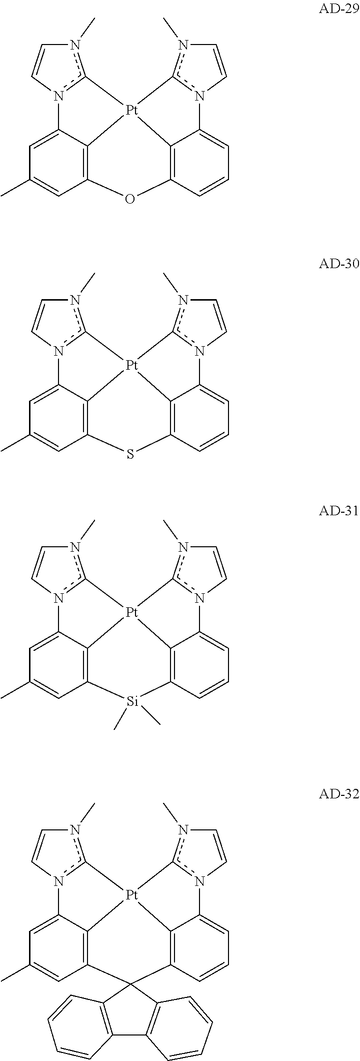

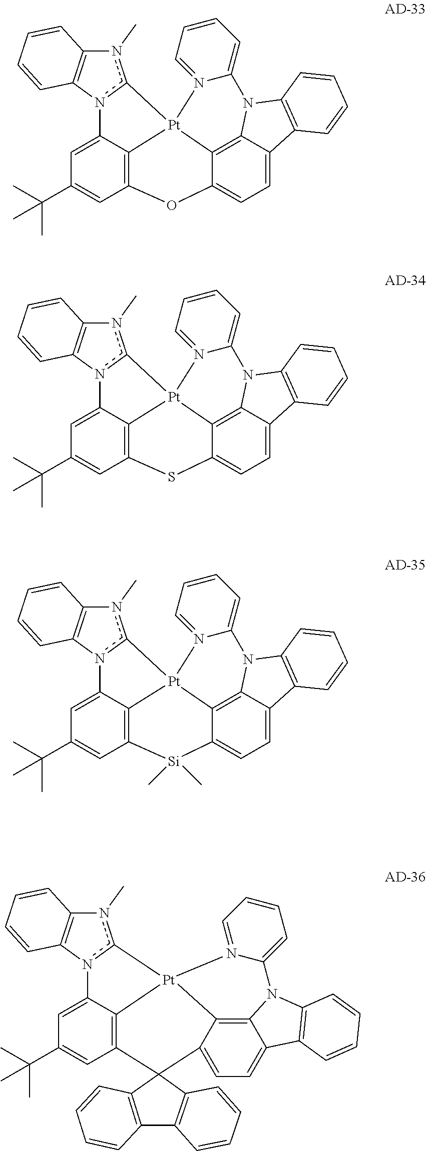

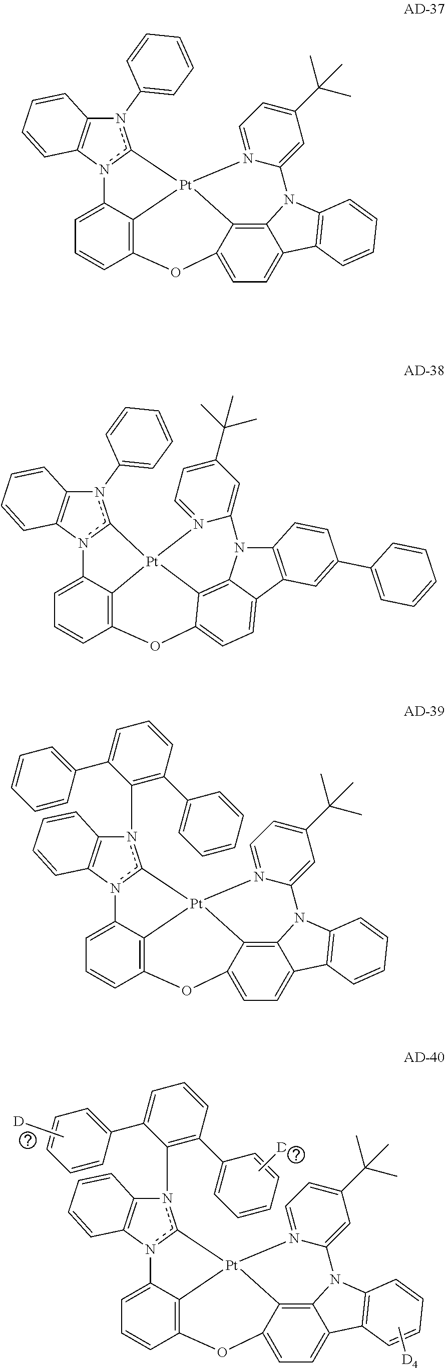

In Compound Group 4, D may be a deuterium atom.

In an embodiment, the light emitting element ED may include multiple emission layers. The multiple emission layers may be stacked and provided, so that a light emitting element ED including multiple emission layers may emit white light. The light emitting element including multiple emission layers may be a light emitting element having a tandem structure. When the light emitting element ED includes multiple emission layers, at least one emission layer EML may include the first compound represented by Formula 1. For example, when the light emitting element ED includes multiple emission layers, at least one emission layer EML may include the first compound, the second compound, the third compound, and the fourth compound, as described above.

When the emission layer EML in the light emitting element ED includes the first compound, the second compound, and the third compound, an amount of the first compound may be in a range of about 0.1 wt % to about 5 wt %, with respect to a total weight of the first compound, the second compound, and the third compound. However, embodiments are not limited thereto. When an amount of the first compound satisfies the above-described range, energy transfer from the second compound and the third compound to the first compound may increase, and thus luminous efficiency and device service life may increase.

In the emission layer EML, a total amount of the second compound and the third compound may be the remainder of the total weight of the first compound, the second compound, and the third compound, excluding the weight of the first compound. For example, a combined amount of the second compound and the third compound in the emission layer EML may be in a range of about 65 wt % to about 95 wt %, with respect to a total weight of the first compound, the second compound, and the third compound.

Within the combined amount of the second compound and the third compound in the emission layer EML, a weight ratio of the second compound to the third compound may be in a range of about 3:7 to about 7:3.

When the amounts of the second compound and the third compound satisfy the above-described ranges and ratios, charge balance characteristics in the emission layer EML may be improved, and thus luminous efficiency and device service life may increase. When the amounts of the second compound and the third compound deviate from the above-described ranges and ratios, charge balance in the emission layer EML may not be achieved, so that luminous efficiency may be reduced and the device may more readily deteriorate.

When the emission layer EML includes the fourth compound, an amount of the fourth compound in the emission layer EML may be in a range of about 10 wt % to about 30 wt %, with respect to a total weight of the first compound, the second compound, the third compound, and the fourth compound. However, embodiments are not limited thereto. When an amount of the fourth compound satisfies the above-described content range, energy transfer from a host to the first compound, which is a light emitting dopant, may increase, so that a luminous ratio may be improved, and thus luminous efficiency of the emission layer EML may be improved. When the amounts of the first compound, the second compound, the third compound, and the fourth compound included in the emission layer EML satisfy the above-described ranges and ratios, excellent luminous efficiency and long service life may be achieved.

In the light emitting element ED, the emission layer EML may include an anthracene derivative, a pyrene derivative, a fluoranthene derivative, a chrysene derivative, a dihydrobenzanthracene derivative, or a triphenylene derivative. For example, the emission layer EML may include an anthracene derivative or a pyrene derivative.

In the light emitting element ED according to embodiments as illustrated in FIGS. 3 to 6, the emission layer EML may further include a host and a dopant of the related art, besides the above-described host and dopant.

In an embodiment, the emission layer EML may include a compound represented by Formula E-1. The compound represented by Formula E-1 may be used as a fluorescent host material.

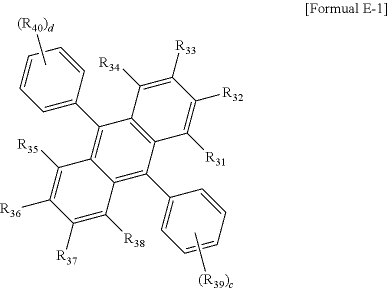

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In an embodiment, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently an integer from 0 to 5.

In an embodiment, the compound represented by Formula E-1 may be any compound selected from Compound E1 to Compound E19:

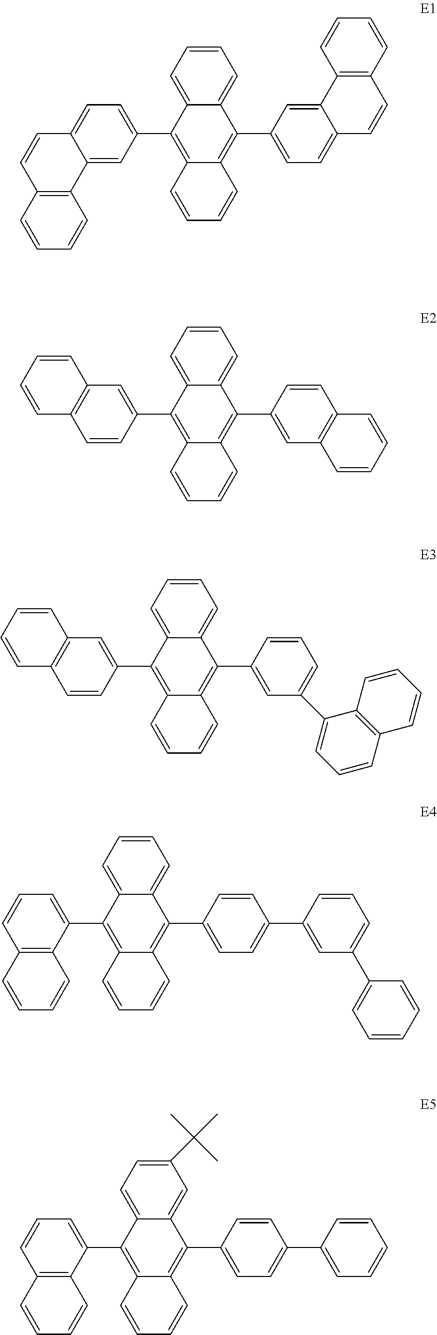

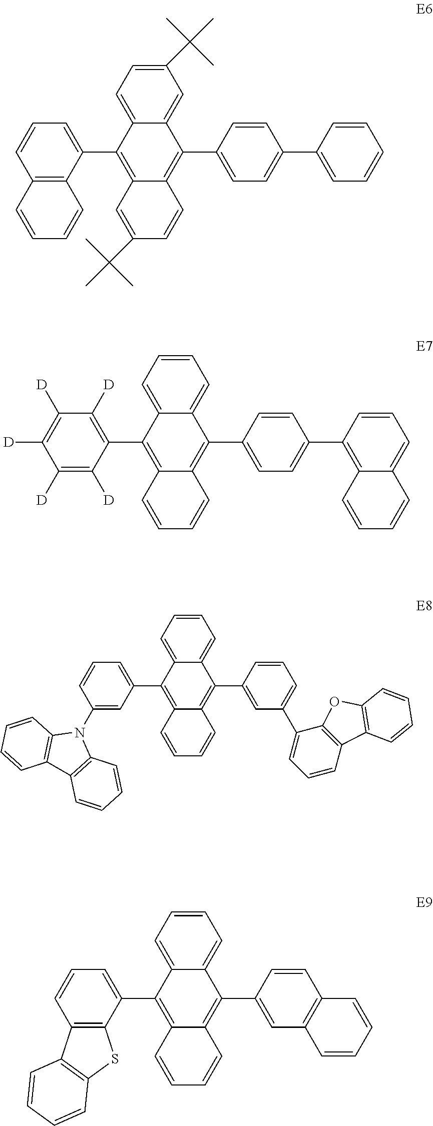

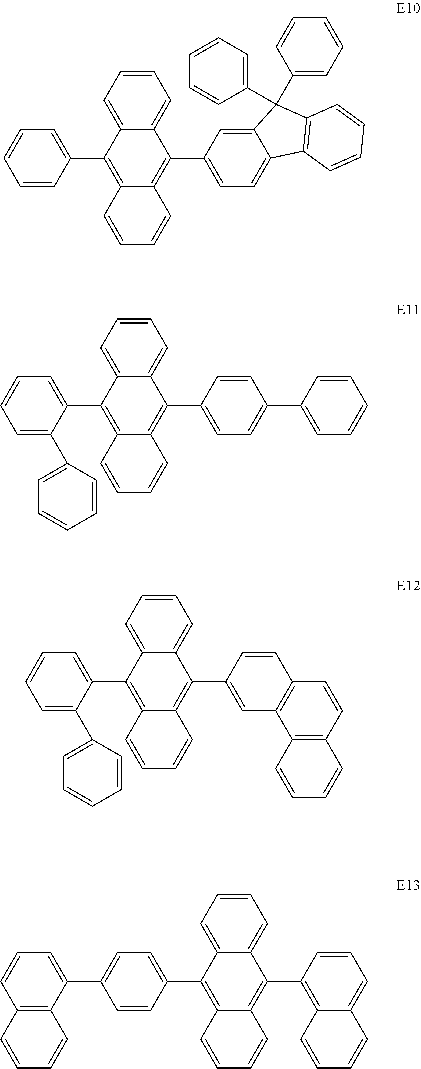

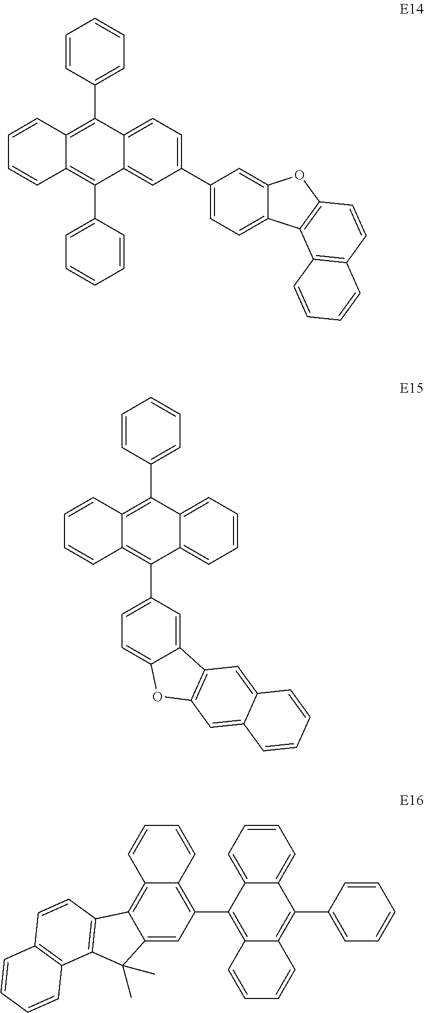

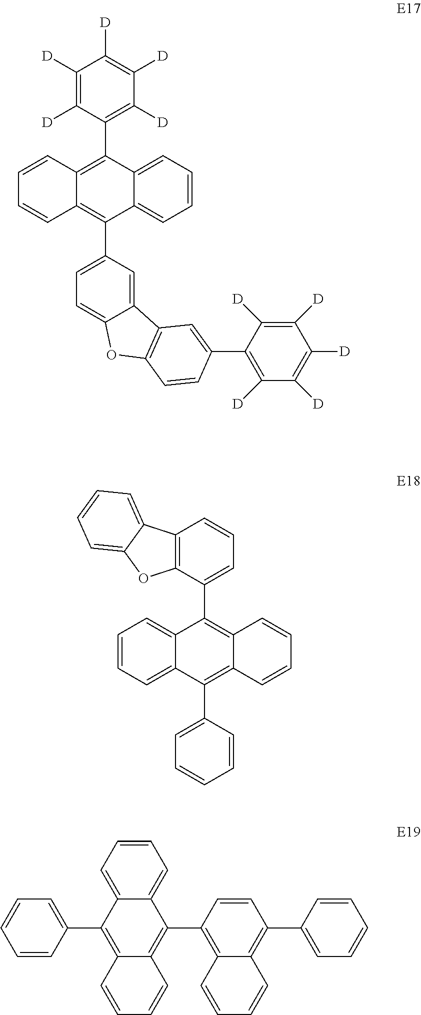

In an embodiment, the emission layer EML may include a compound represented by Formula E-2a or Formula E-2b. The compound represented by Formula E-2a or Formula E-2b may be used as a phosphorescent host material.

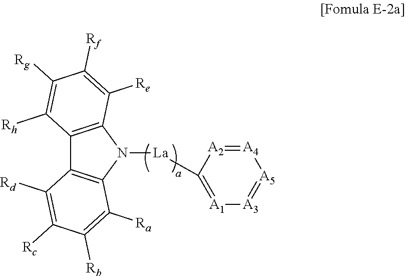

In Formula E-2a, a may be an integer from 0 to 10; and Lₐ may be a direct linkage, a substituted or unsubstituted arylene group having 6 to 30 ring-forming carbon atoms, or a substituted or unsubstituted heteroarylene group having 2 to 30 ring-forming carbon atoms. When a is 2 or greater, multiple Lₐ groups may each independently be a substituted or unsubstituted arylene group having 6 to 30 ring-forming carbon atoms or a substituted or unsubstituted heteroarylene group having 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring. For example, Rₐ to Rᵢ may be bonded to an adjacent group to form a hydrocarbon ring or a heterocycle containing N, O, S, etc., as a ring-forming atom.

In Formula E-2a, two or three of A₁ to A₅ may each be N, and the remainder of A₁ to A₅ may each independently be C(Rᵢ).

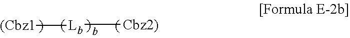

In Formula E-2b, Cbz1 and Cbz2 may each independently be an unsubstituted carbazole group or a carbazole group substituted with an aryl group having 6 to 30 ring-forming carbon atoms. In Formula E-2b, L_{b} may be a direct linkage, a substituted or unsubstituted arylene group having 6 to 30 ring-forming carbon atoms, or a substituted or unsubstituted heteroarylene group having 2 to 30 ring-forming carbon atoms. In Formula E-2b, b may be an integer from 0 to 10, and when b is 2 or more, multiple L_{b} groups may each independently be a substituted or unsubstituted arylene group having 6 to 30 ring-forming carbon atoms or a substituted or unsubstituted heteroarylene group having 2 to 30 ring-forming carbon atoms.

The compound represented by Formula E-2a or Formula E-2b may be any compound selected from Compound Group E-2. However, the compounds listed in Compound Group E-2 below are only examples, and the compound represented by Formula E-2a or Formula E-2b is not limited to Compound Group E-2.

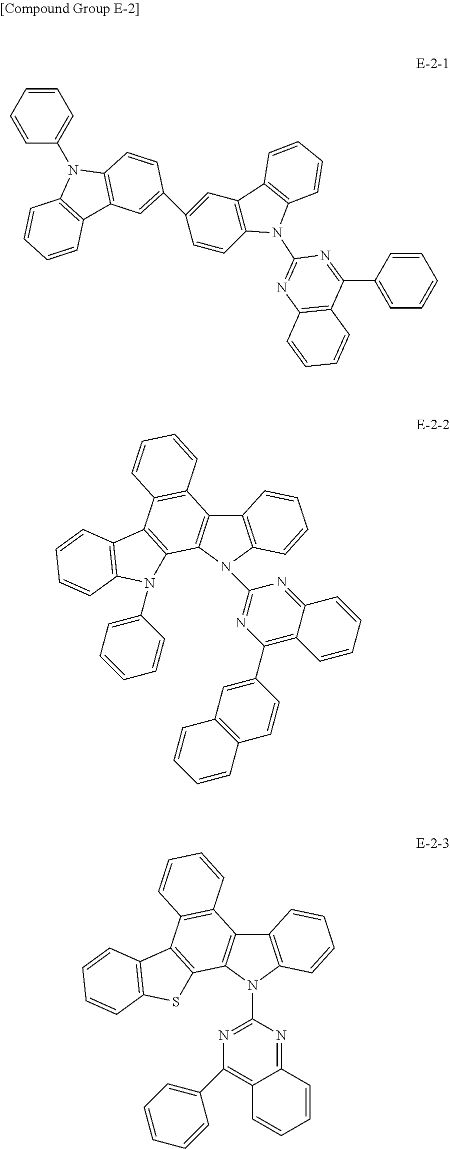 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

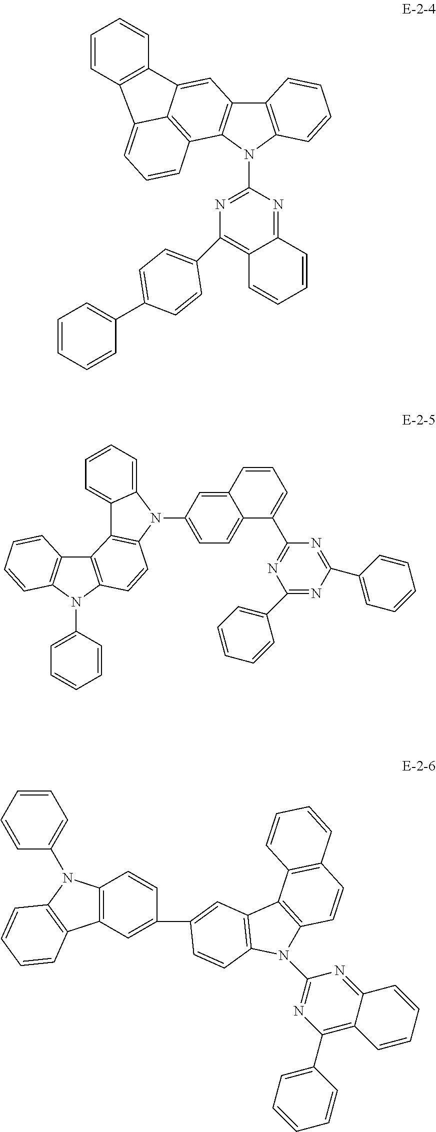 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

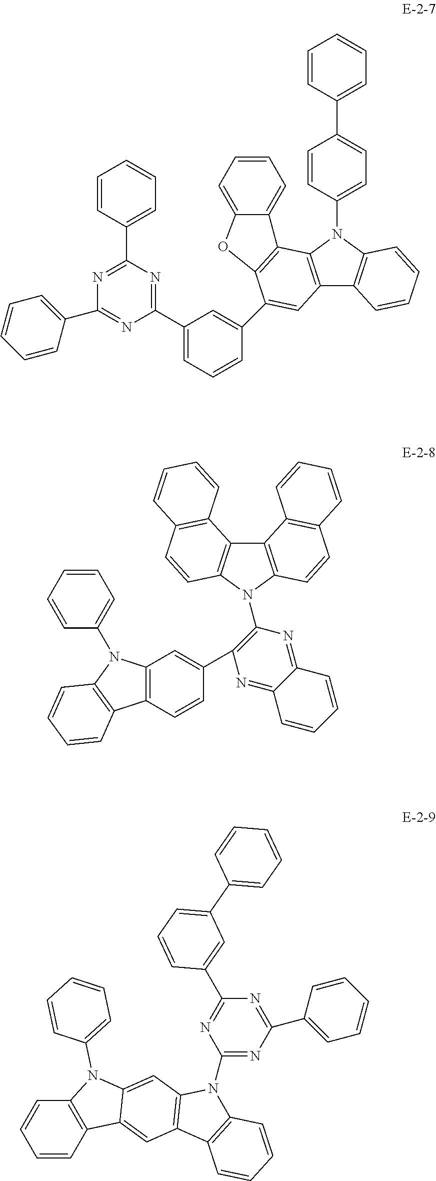 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

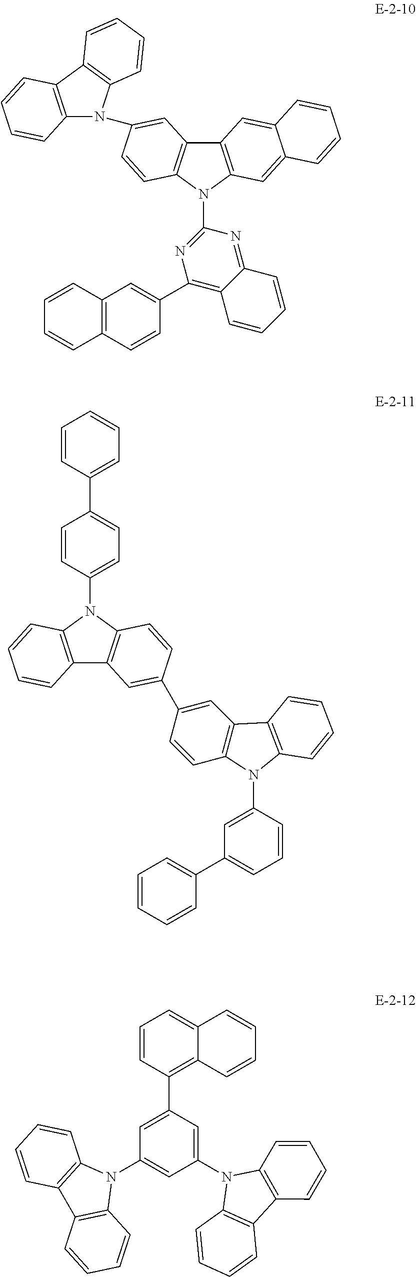 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

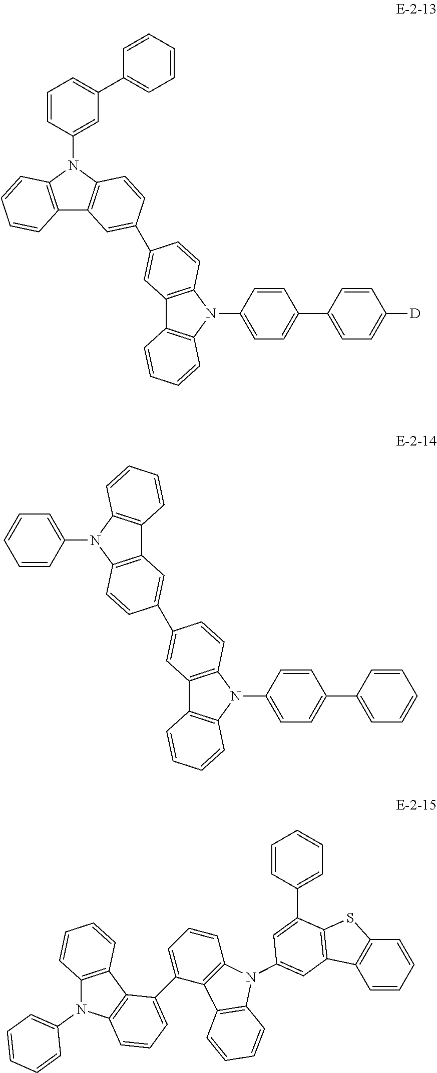 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

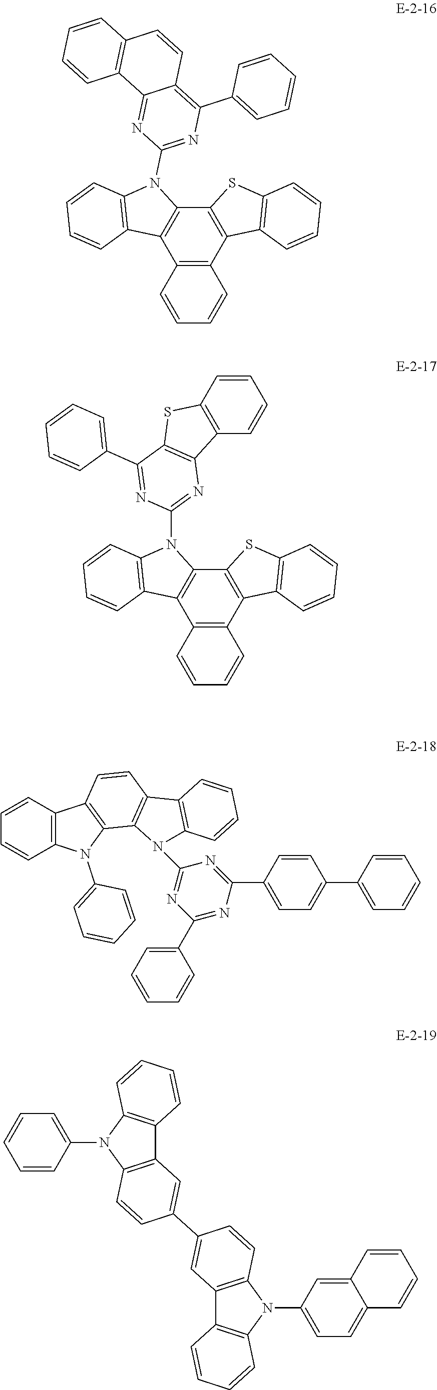 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1]

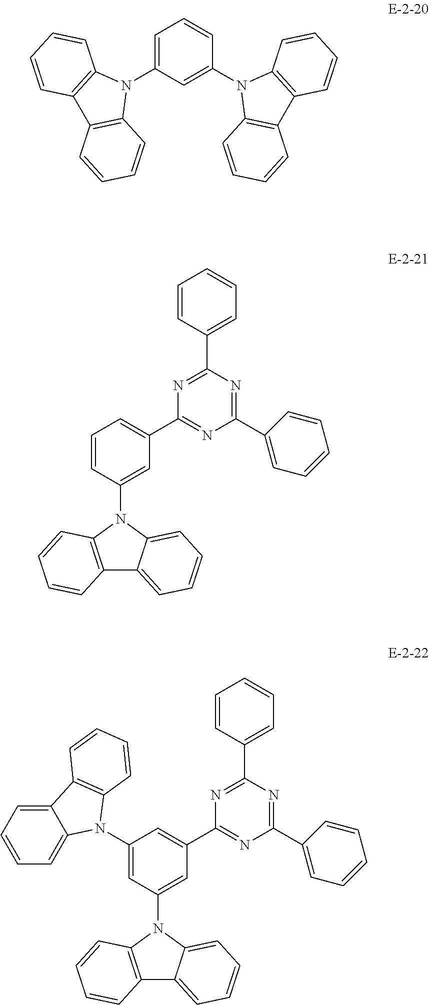 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

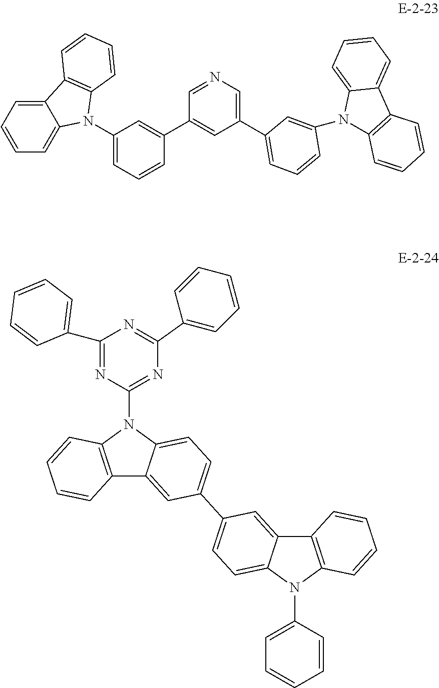 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a material of the related art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), and 1,3,5-tris(1-phenyl-1H-benzo[d]imidazole-2-yl)benzene (TPBi). However, embodiments are not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), etc. may be used as a host material.

In an embodiment, the emission layer EML may include the compound represented by Formula M-a. The compound represented by Formula M-a may be used as a phosphorescent dopant material.

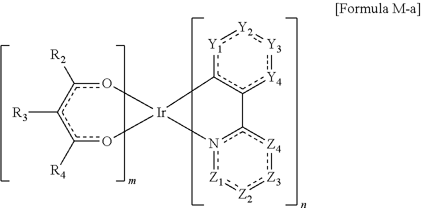

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring. In Formula M-a, m may be 0 or 1, and n may be 2 or 3. In Formula M-a, when m is 0, n may be 3, and when m is 1, n may be 2.

The compound represented by Formula M-a may be any compound selected from Compound M-al to Compound M-a25. However, Compounds M-al to M-a25 are only examples, and the compound represented by Formula M-a is not limited to Compounds M-al to M-a25:

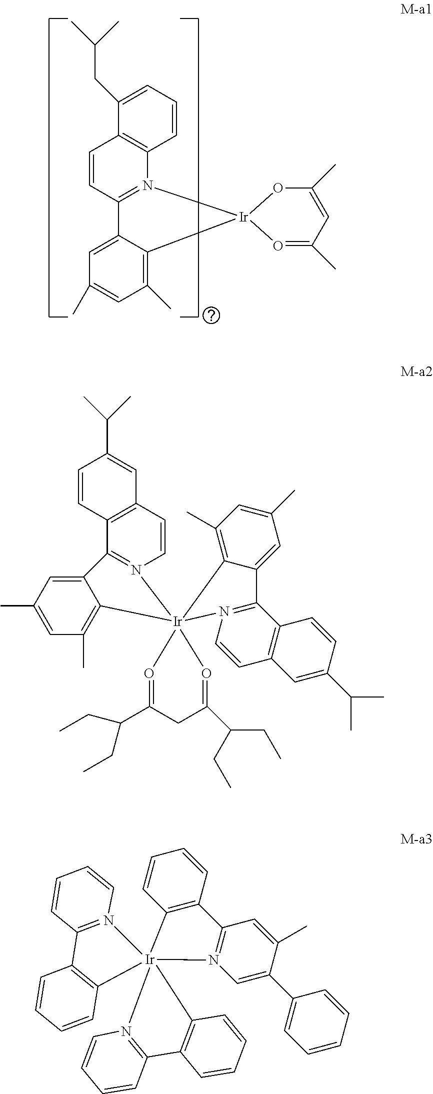

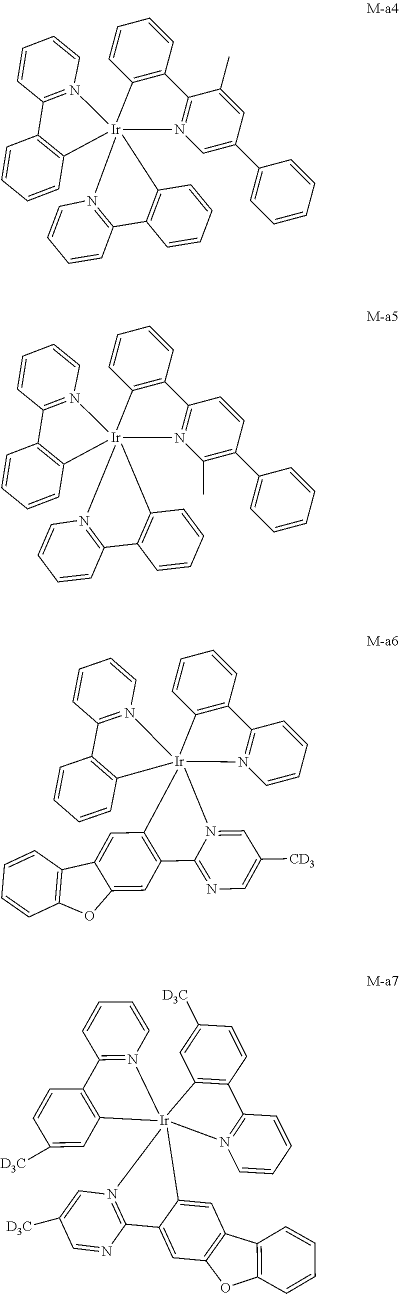

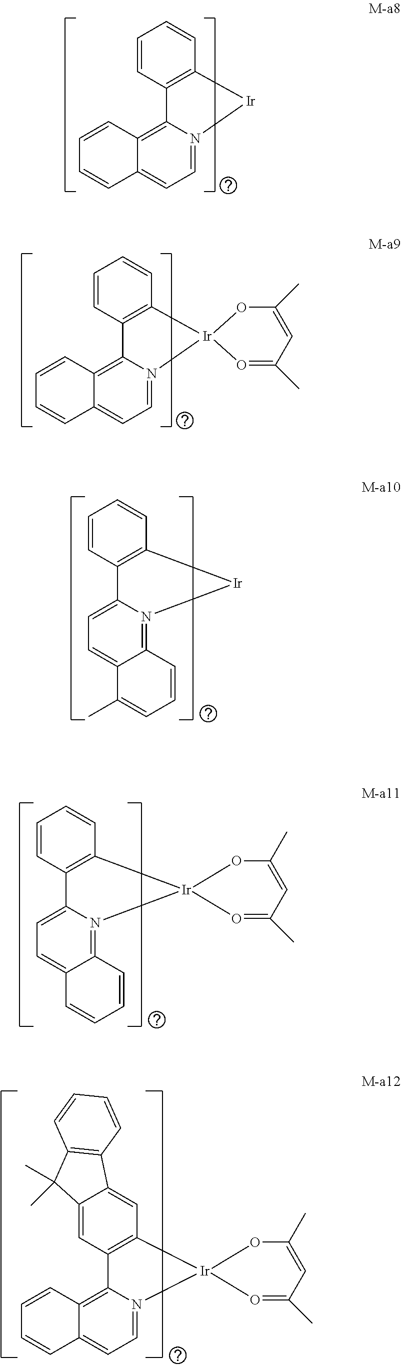

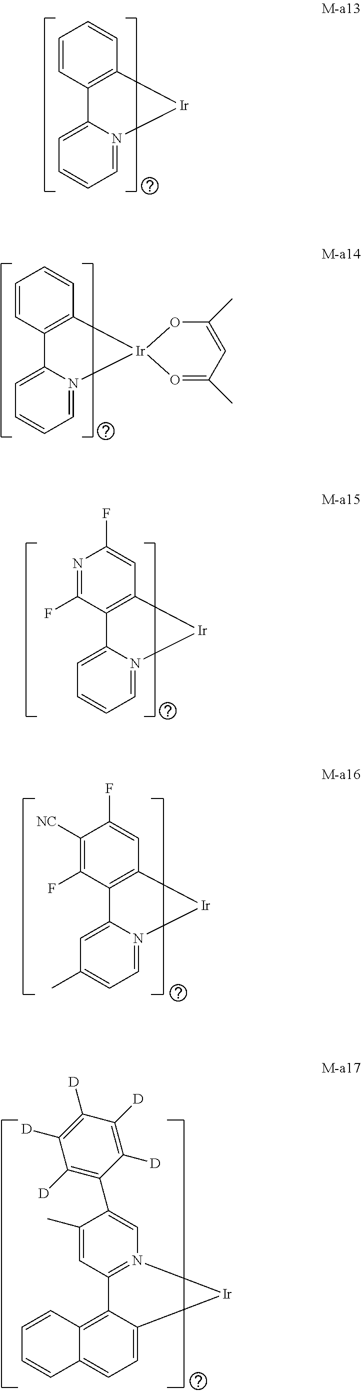

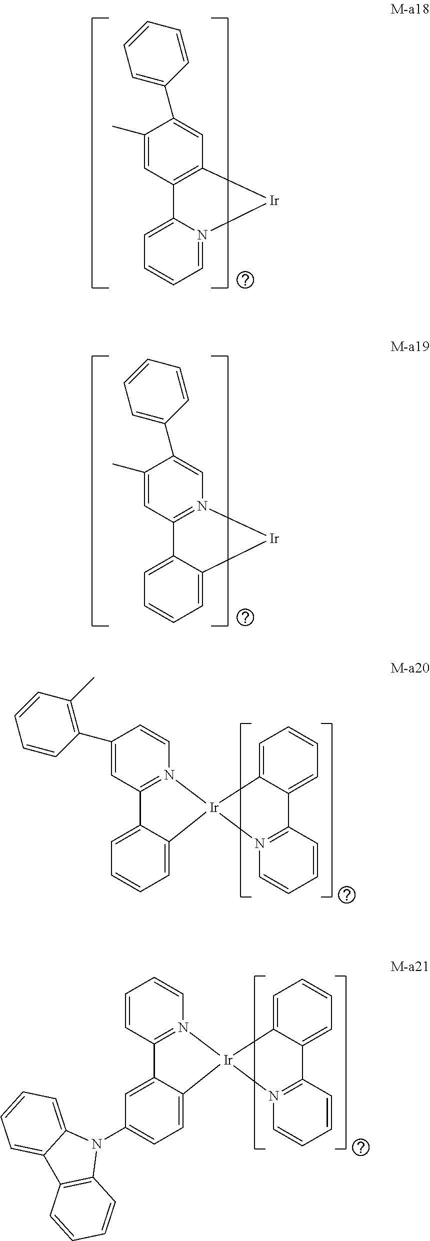

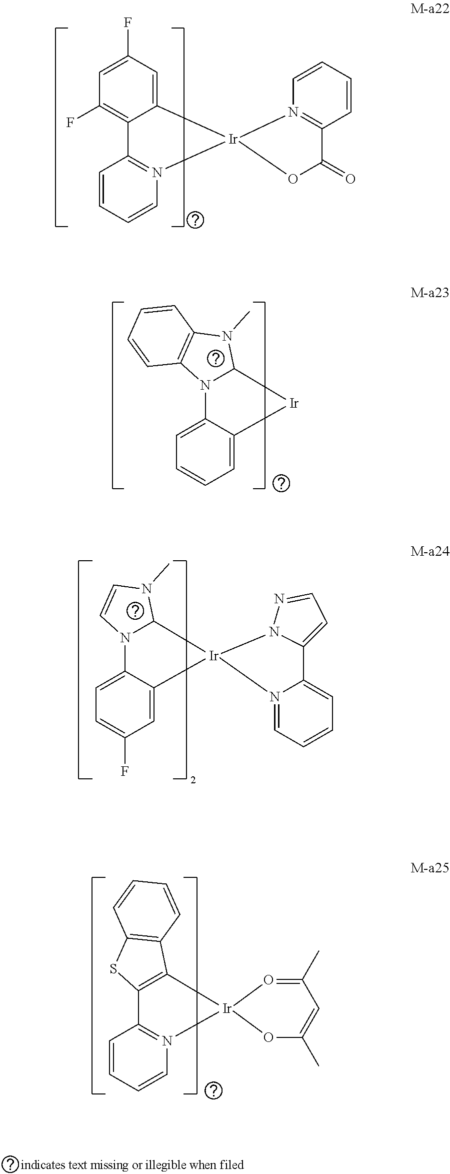

In an embodiment, the emission layer EML may include a compound represented by any one of Formula F-a to Formula F-c. The compound represented by one of Formula F-a to Formula F-c may be used as a fluorescence dopant material.

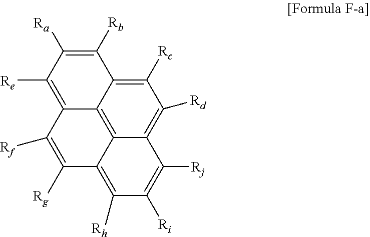

In Formula F-a, two of Rₐ to Rⱼ may each independently be substituted with a group represented by *—NAr₁Ar₂. The remainder of Rₐ to Rⱼ, which are not substituted with the group represented by *—NAr₁Ar₂, may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In the group represented by *—NAr₁Ar₂, Ar₁ and Ar₂ may be each independently a substituted or unsubstituted aryl group having 6 to 30 ring-forming carbon atoms or a substituted or unsubstituted heteroaryl group having 2 to 30 ring-forming carbon atoms. For example, at least one of Ar₁ and Ar₂ may be a heteroaryl group including O or S as a ring-forming atom.

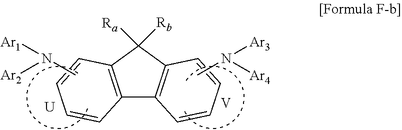

In Formula F-b, Rₐ and R_{b} may be each independently a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula F-b, Ar₁ to Ar₄ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ to Ar₄ may be a heteroaryl group containing O or S as a ring-forming atom.

In Formula F-b, U and V may each independently be a substituted or unsubstituted hydrocarbon ring having 5 to 30 ring-forming carbon atoms or a substituted or unsubstituted heterocycle having 2 to 30 ring-forming carbon atoms.

In Formula F-b, the number of rings represented by U and V may each independently be 0 or 1. When the number of U or V is 1, a fused ring may be present at a portion indicated by U or V, and when the number of U or V is 0, a fused ring may not be present at the portion indicated by U or V. When the number of U is 0 and the number of V is 1, or when the number of U is 1 and the number of V is 0, a fused ring having a fluorene core of Formula F-b may be a cyclic compound having four rings. When U and V are each 0, a fused ring having a fluorene core of Formula F-b may be a cyclic compound having three rings. When U and V are each 1, a fused ring having a fluorene core of Formula F-b may be a cyclic compound having five rings.

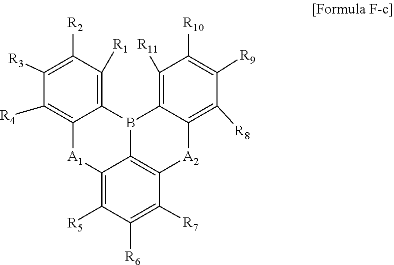

In Formula F-c, A₁ and A₂ may each independently be O, S, Se, or N(Rₘ); and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring.

In Formula F-c, A₁ and A₂ may each independently be bonded to a substituent of an adjacent ring to form a fused ring. For example, when A₁ and A₂ are each independently N(Rₘ), A₁ may be bonded to R₄ or R₅ to form a ring. For example, A₂ may be bonded to R₇ or R₈ to form a ring.

In an embodiment, the emission layer EML may further include, as a dopant material of the related art, a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene and a derivative thereof (e.g., 2,5,8,11-tetra-t-butylperylene (TBP)), pyrene and a derivative thereof (e.g., 1,1-dipyrene, 1,4-dipyrenylbenzene, 1,4-bis(N,N-diphenylamino)pyrene), etc.

The emission layer EML may further include a phosphorescence dopant material of the related art. For example, a metal complex containing iridium (Ir), platinum (Pt), osmium (Os), gold (Au), titanium (Ti), zirconium (Zr), hafnium (Hf), europium (Eu), terbium (Tb), or thulium (Tm) may be used as a phosphorescent dopant. For example, iridium(III) bis(4,6-difluorophenylpyridinato-N,C2) (FIrpic), bis(2,4-difluorophenylpyridinato)-tetrakis(1-pyrazolyl)borate iridium(III) (Fir6), or platinum octaethyl porphyrin (PtOEP) may be used as a phosphorescent dopant. However, embodiments are not limited thereto.

In an embodiment, the emission layer EML may include a quantum dot. The quantum dot may be a Group II-VI compound, a Group III-VI compound, a Group I-III-VI compound, a Group III-V compound, a Group III-II-V compound, a Group IV-VI compound, a Group IV element, a Group IV compound, or any combination thereof.

Examples of a Group II-VI compound may include: a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof; or any combination thereof.

Examples of a Group III-VI compound may include: a binary compound such as In₂S₃ or In₂Se₃; a ternary compound such as InGaS₃ or InGaSe₃; or any combination thereof.

Examples of a Group I-III-VI compound may include: a ternary compound selected from the group consisting of AgInS, AgInS₂, CuInS, CuInS₂, AgGaS₂, CuGaS₂ CuGaO₂, AgGaO₂, AgAlO₂, and a mixture thereof; a quaternary compound such as AgInGaS₂ or CuInGaS₂; or any combination thereof.

Examples of a Group III-V compound may include: a binary compound selected from the group consisting of GaN, GaP, GaAs, GaSb, AlN, AlP, AlAs, AlSb, InN, InP, InAs, InSb, and a mixture thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof; or any combination thereof. In an embodiment, a Group III-V compound may further include a Group II metal. For example, InZnP, etc., may be selected as a Group III-II-V compound.

Examples of a Group IV-VI compound may include: a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; a quaternary compound selected from the group consisting of SnPbSSe, SnPbSeTe, SnPbSTe, and a mixture thereof; or any combination thereof. Examples of a Group IV element may include Si, Ge, and any mixture thereof. Examples of a Group IV compound may include a binary compound selected from the group consisting of SiC, SiGe, and any mixture thereof.

Each element included in a polynary compound, such as a binary compound, a ternary compound, or a quaternary compound, may be present in a particle at a uniform concentration distribution or at a non-uniform concentration distribution. For example, a formula may indicate the elements included in a compound, but an elemental ratio in the compound may vary. For example, AgInGaS₂ may indicate AgInₓGa₁₋ₓS₂ (where x is a real number of 0 to 1).

In embodiments, a quantum dot may have a single structure in which the concentration of each element included in the quantum dot is uniform, or a quantum dot may have a core/shell structure. A material included in the core may be different from a material included in the shell.

The shell of the quantum dot may serve as a protection layer to prevent chemical deformation of the core to maintain semiconductor properties, and/or may serve as a charging layer to impart electrophoretic properties to the quantum dot. The shell may be a single layer or multiple layers. A quantum dot having a core/shell structure may have a concentration gradient in which the concentration of a material that is present in the shell decreases towards the core.

In embodiments, the quantum dot may have the above-described core/shell structure including a core containing nanocrystals and a shell surrounding the core. The shell of the quantum dot may serve as a protection layer to prevent chemical deformation of the core to maintain semiconductor properties, and/or may serve as a charging layer to impart electrophoresis properties to the quantum dot. The shell may be a single layer or a multilayer.

Examples of a shell of a quantum dot may include a metal oxide, a non-metal oxide, a semiconductor compound, or any combination thereof.

Examples of a metal oxide or a non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO; a ternary compound such as MgAl₂O₄, CoFe₂O₄, NiFe₂O₄, or CoMn₂O₄; or any combination thereof, but embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dot may have a full width at half maximum (FWHM) of an emission wavelength spectrum equal to or less than about 45 nm. For example, the quantum dot may have a FWHM of an emission wavelength spectrum equal to or less than about 40 nm. For example, the quantum dot may have a FWHM of an emission wavelength spectrum equal to or less than about 30 nm. Within any of the ranges above, color purity or color reproducibility may be improved. Light emitted through such quantum dot may be emitted in all directions, so that a wide viewing angle may be improved.

The form of the quantum dot is not particularly limited as long as it is a form that is used in the related art. For example, a quantum dot may have a spherical shape, a pyramidal shape, a multi-arm shape, or a cubic shape, or the quantum dot may be in the form of nanoparticles, nanotubes, nanowires, nanofibers, nanoplate particles, etc.

As the size of the quantum dot is adjusted or the elemental ratio in the quantum dot compound is adjusted, it is possible to control the energy band gap, and thus light in various wavelength ranges may be obtained from a quantum dot emission layer. Therefore, by using the quantum dot as described above (for example, using different sizes of quantum dots or different elemental ratios in the quantum dot compound), a light emitting element, which emits light in various wavelengths, may be implemented. For example, the adjustment of the size of the quantum dot or the elemental ratio in the quantum dot compound may be selected to emit red, green, and/or blue light. For example, the quantum dots may be configured to emit white light by combining various colors of light.

In the light emitting element ED according to an embodiment as illustrated in each of FIGS. 3 to 6, the electron transport region ETR may be provided on the emission layer EML. The electron transport region ETR may include at least one of a hole blocking layer HBL, an electron transport layer ETL, and an electron injection layer EIL, but embodiments are not limited thereto.

The electron transport region ETR may be a layer consisting of a single material, a layer including different materials, or a structure including multiple layers including different materials.

For example, the electron transport region ETR may have a single layer structure of an electron injection layer EIL or an electron transport layer ETL, or may have a single layer structure formed of an electron injection material and an electron transport material. In other embodiments, the electron transport region ETR may have a single layer structure formed of different materials, or may have a structure in which an electron transport layer ETL/electron injection layer EIL, or a hole blocking layer HBL/electron transport layer ETL/electron injection layer EIL are stacked in its respective stated order from the emission layer EML, but embodiments are not limited thereto. The electron transport region ETR may have a thickness, for example, in a range of about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the electron transport region ETR may include a compound represented by Formula ET-2:

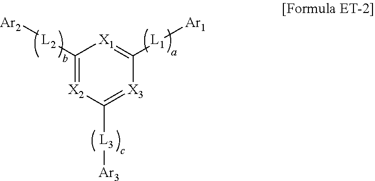

In Formula ET-2, at least one of X₁ to X₃ may each be N, and the remainder of X₁ to X₃ may each independently be C(Rₐ). In Formula ET-2, Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula ET-2, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer from 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When a to c are each independently 2 or more, L₁ to L₃ may each independently be a substituted or unsubstituted arylene group having 6 to 30 ring-forming carbon atoms or a substituted or unsubstituted heteroarylene group having 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), or any mixture thereof.

In an embodiment, the electron transport region ETR may include at least one of Compound ET1 to Compound ET36:

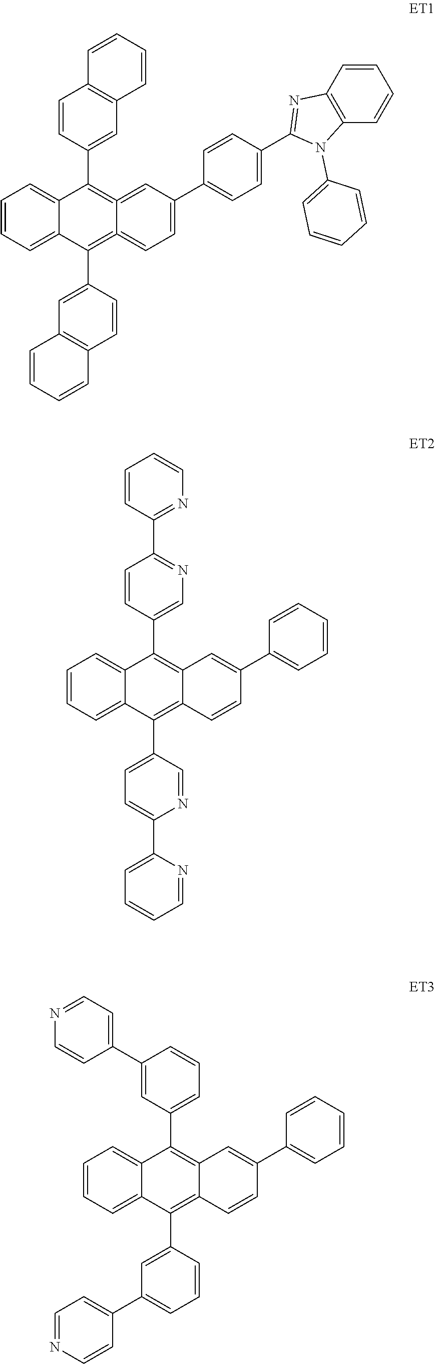

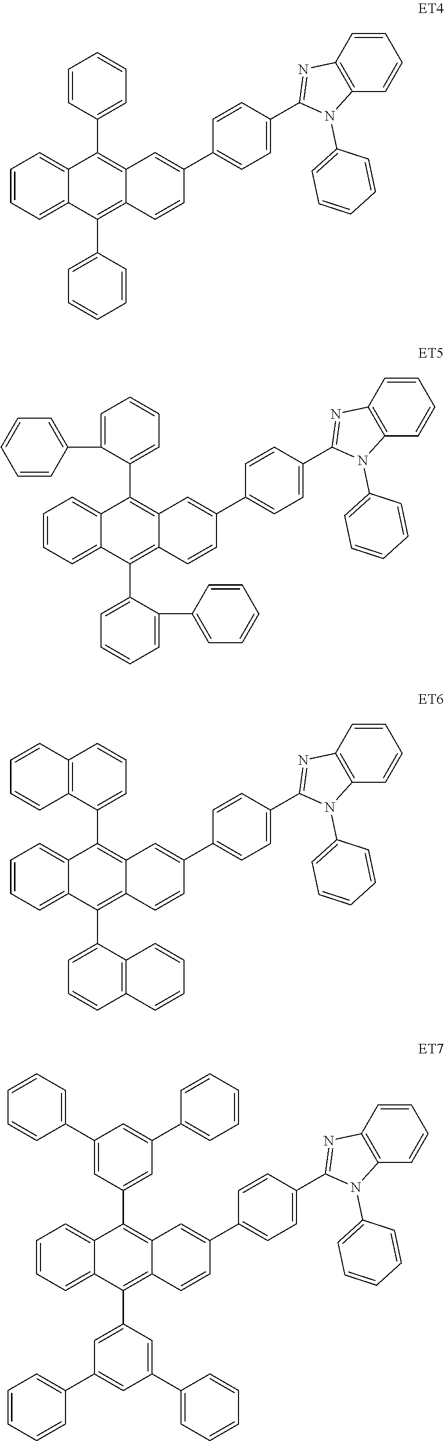 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

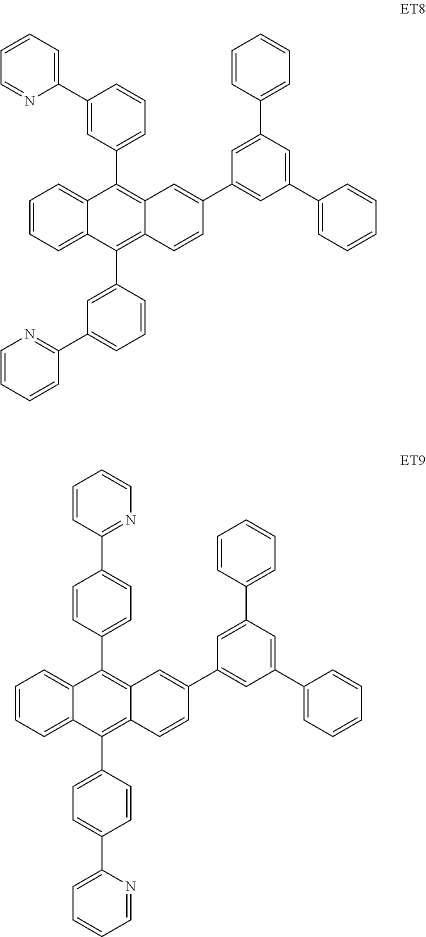 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

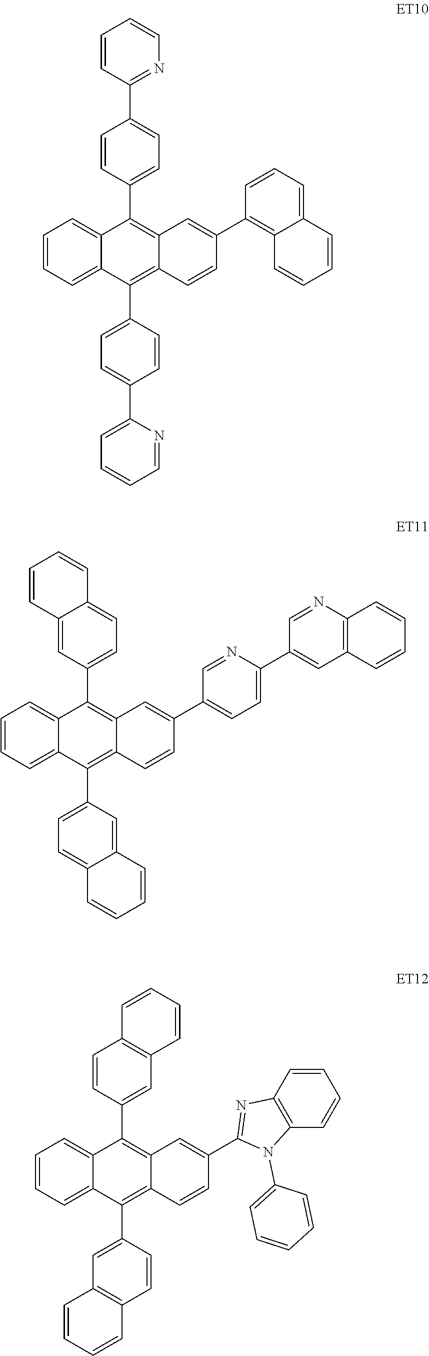 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

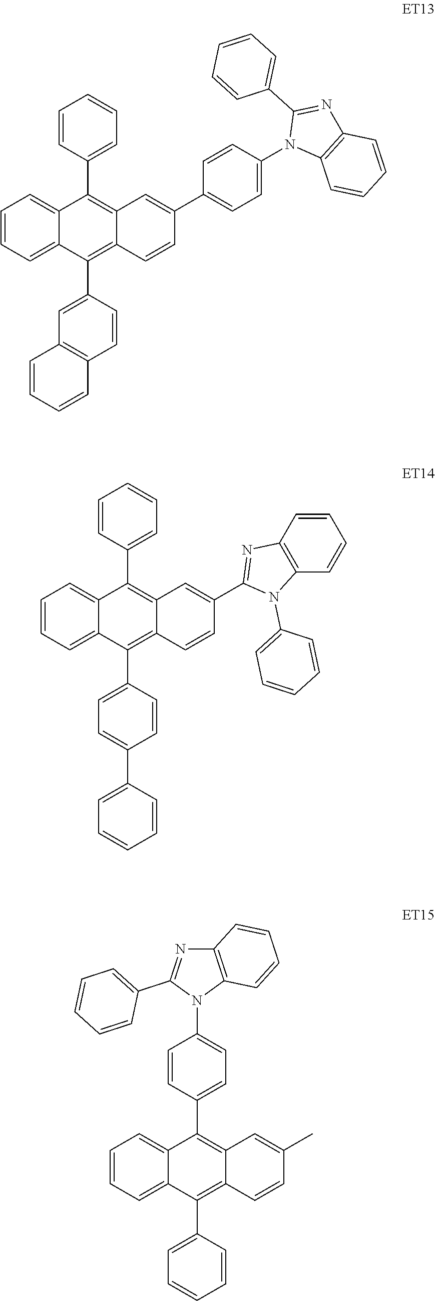 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

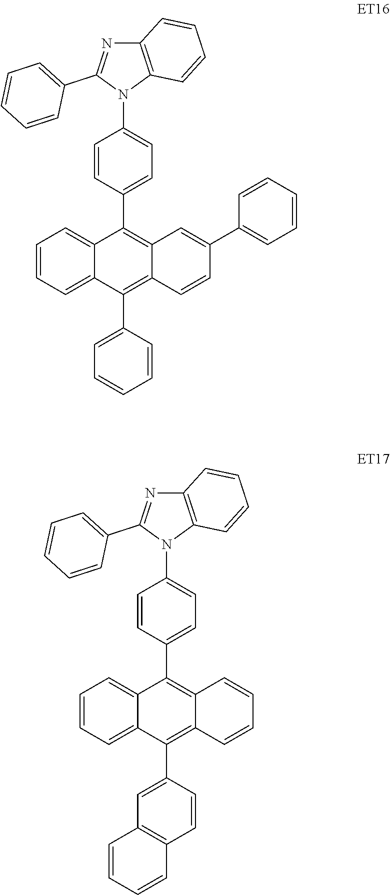 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1]

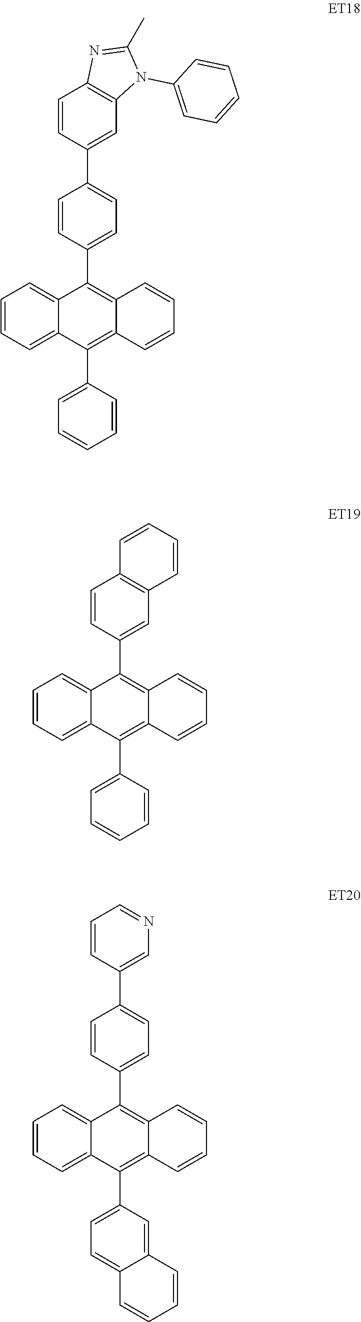

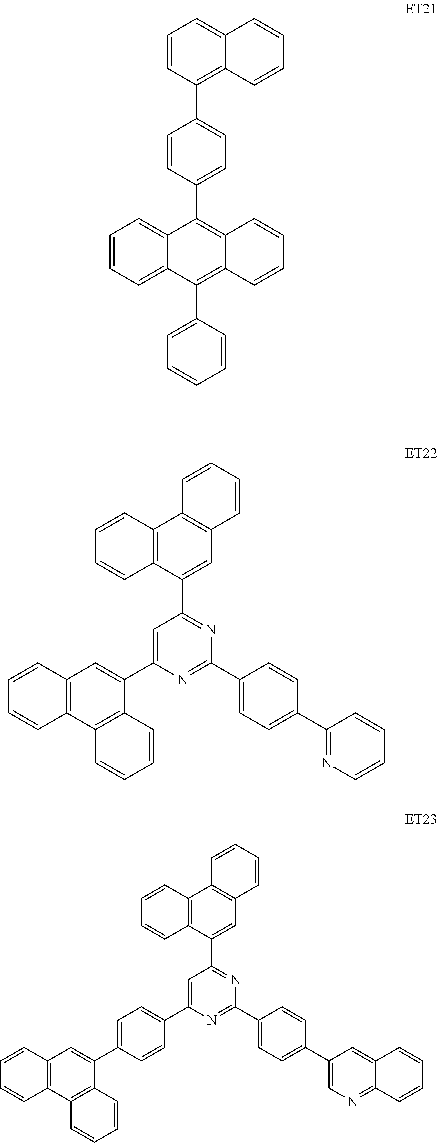

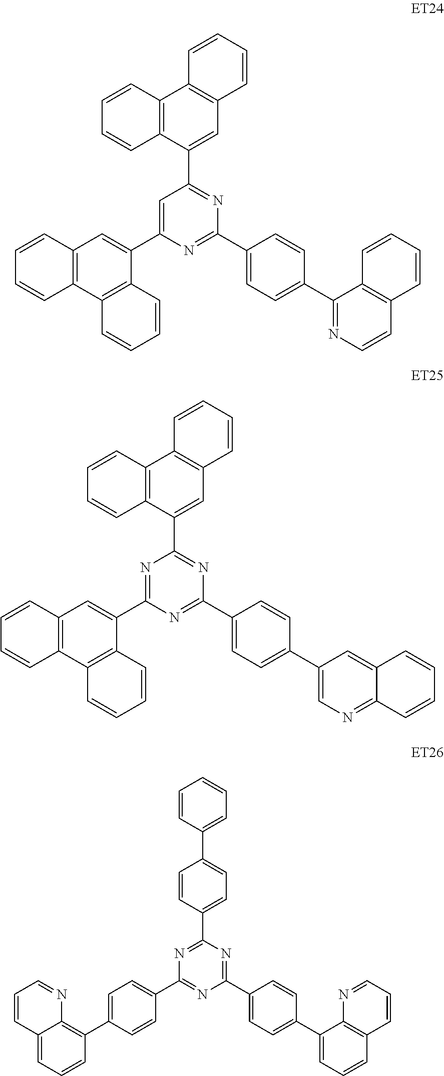 [SMILES: c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1]

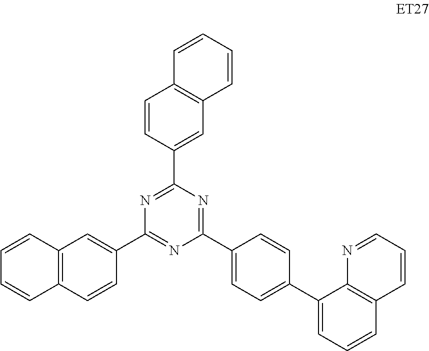 [SMILES: c1ccc2cc(-c3nc(-c4ccc(-c5cccc6cccnc56)cc4)nc(-c4ccc5ccccc5c4)n3)ccc2c1]

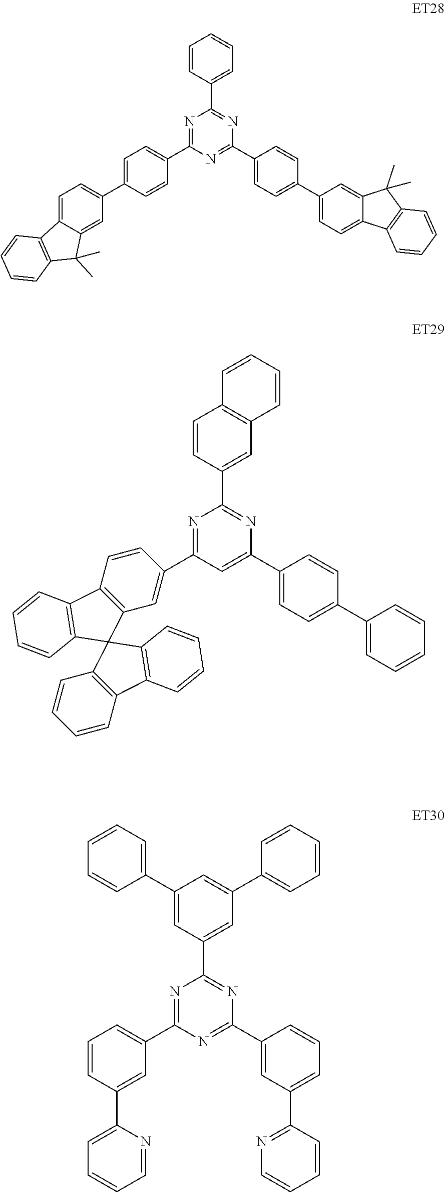 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

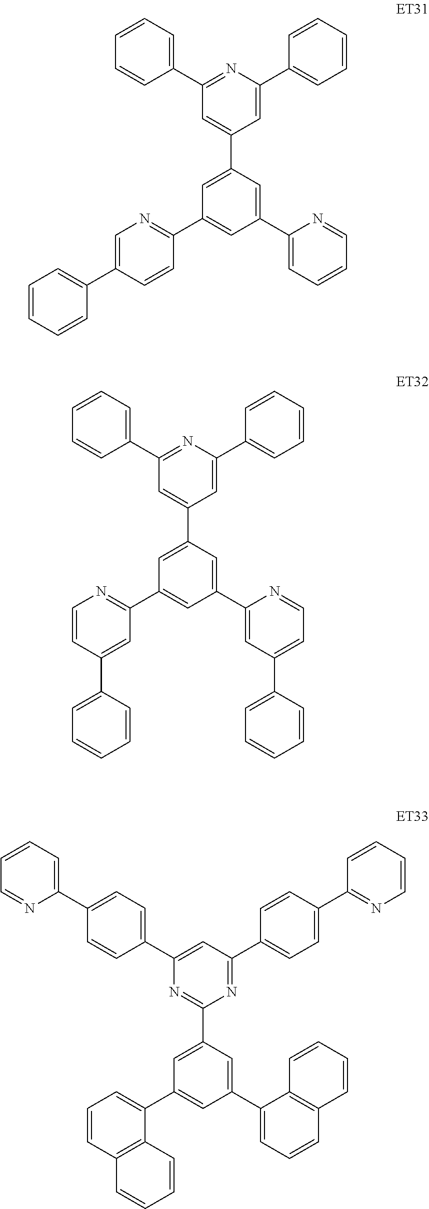 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

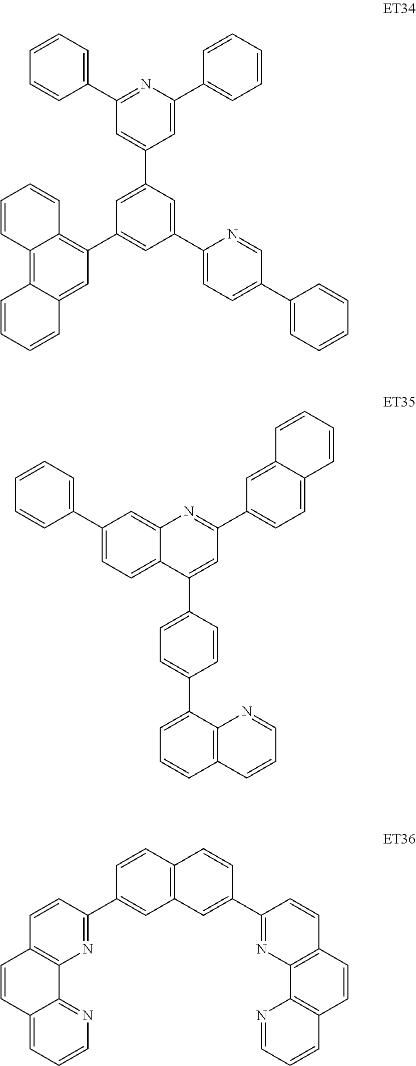 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

The electron transport region ETR may include a metal halide such as LiF, NaCl, CsF, RbCl, RbI, CuI, and KI; a lanthanide metal such as Yb; or a co-deposited material of a metal halide and a lanthanide metal. For example, the electron transport region ETR may include KI:Yb, RbI:Yb, LiF:Yb, etc., as a co-deposited material. The electron transport region ETR may include a metal oxide such as LizO or BaO, or 8-hydroxyl-lithium quinolate (Liq), etc., but embodiments are not limited thereto. The electron transport region ETR may also include a mixture material of an electron transport material and an insulating organometallic salt. The organometallic salt may be a material having an energy band gap greater than or equal to about 4 eV. For example, the organometallic salt may include a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), and 4,7-diphenyl-1,10-phenanthroline (Bphen), in addition to the above-described materials, but embodiments are not limited thereto.

The electron transport region ETR may include the above-described compounds of the hole transport region in at least one of an electron injection layer EIL, an electron transport layer ETL, and a hole blocking layer HBL.

When the electron transport region ETR includes an electron transport layer ETL, the electron transport layer ETL may have a thickness in a range of about 100 Å to about 1,000 Å. For example, the electron transport layer ETL may have a thickness in a range of about 150 Å to about 500 Å. If the thickness of the electron transport layer ETL satisfies any of the aforementioned ranges, satisfactory electron transport characteristics may be obtained without a substantial increase in driving voltage. When the electron transport region ETR includes an electron injection layer EIL, the electron injection layer EIL may have a thickness in a range of about 1 Å to about 100 Å. For example, the electron injection layer EIL may have a thickness in a range of about 3 Å to about 90 Å. If the thickness of the electron injection layer EIL satisfies any of the above-described ranges, satisfactory electron injection characteristics may be obtained without a substantial increase in driving voltage.

The second electrode EL2 may be provided on the electron transport region ETR. The second electrode EL2 may be a common electrode. The second electrode EL2 may be a cathode or an anode, but embodiments are not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is a transmissive electrode, the second electrode EL2 may include a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or mixture thereof (e.g., AgMg, AgYb, or MgYb). In an embodiment, the second electrode EL2 may have a multilayer structure including a reflective film or a transflective film formed of the above-described materials, and a transparent conductive film formed of ITO, IZO, ZnO, ITZO, etc. For example, the second electrode EL2 may include the above-described metal materials, combinations of at least two metal materials of the above-described metal materials, oxides of the above-described metal materials, or the like.

Although not shown in the drawings, the second electrode EL2 may be electrically connected to an auxiliary electrode. If the second electrode EL2 is electrically connected to an auxiliary electrode, resistance of the second electrode EL2 may be decreased.

In an embodiment, the light emitting element ED may further include a capping layer CPL disposed on the second electrode EL2. The capping layer CPL may be a multilayer or a single layer.

In an embodiment, the capping layer CPL may include an organic layer or an inorganic layer. For example, when the capping layer CPL contains an inorganic material, the inorganic material may include an alkaline metal compound (e.g., LiF), an alkaline earth metal compound (e.g., MgF₂), SiON, SiNₓ, SiO_{y}, etc.

For example, when the capping layer CPL includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), etc., an epoxy resin, or an acrylate such as methacrylate. However, embodiments are not limited thereto. In an embodiment, the capping layer CPL may include at least one of Compounds P1 to P5:

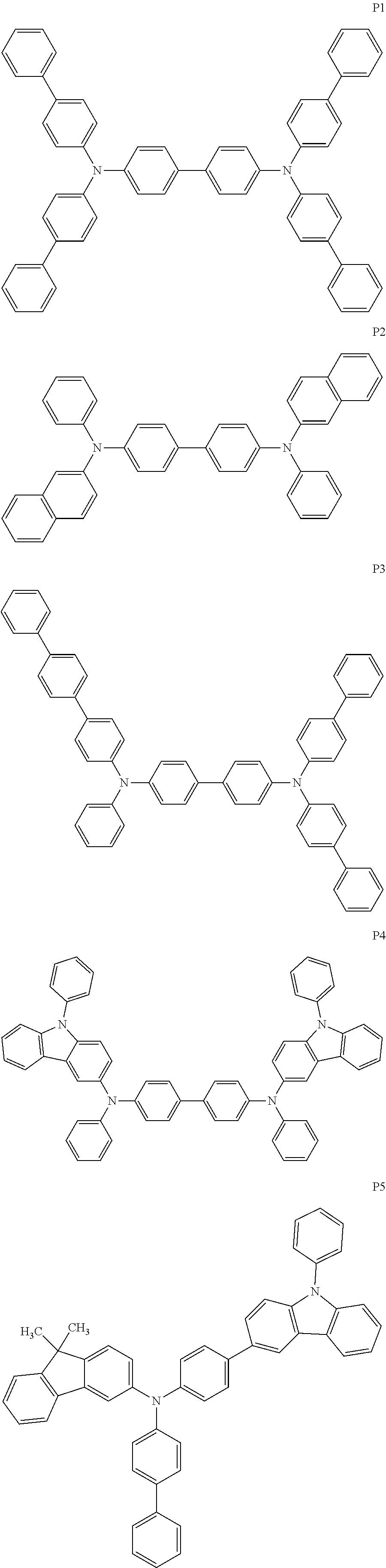 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be greater than or equal to about 1.6. For example, a refractive index of the capping layer CPL may be greater than or equal to about 1.6, with respect to light in a wavelength range of about 550 nm to about 660 nm.

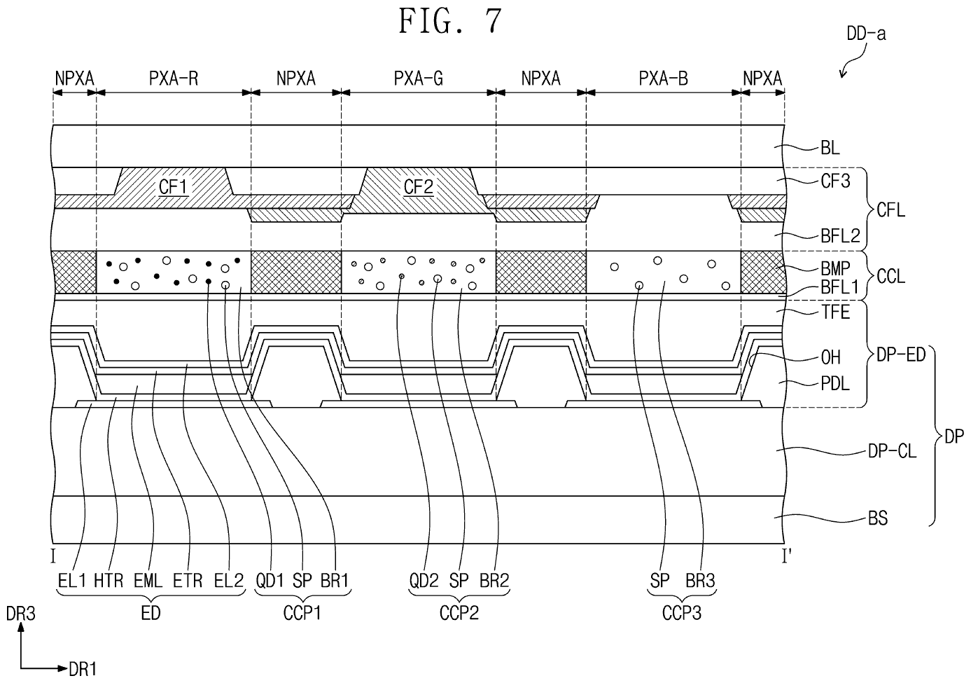

FIGS. 7 to 10 are each a schematic cross-sectional view of a display device according to an embodiment. Hereinafter, in describing the display devices according to embodiments with reference to FIGS. 7 to 10, the features which have been described above in reference to FIGS. 1 to 6 will not be described again, and the differing features will be described.

Referring to FIG. 7, the display device DD-a according to an embodiment may include a display panel DP including a display device layer DP-ED, a light control layer CCL disposed on the display panel DP, and a color filter layer CFL.

In an embodiment illustrated in FIG. 7, the display panel DP may include a base layer BS, a circuit layer DP-CL provided on the base layer BS, and a display device layer DP-ED, and the display device layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In embodiments, a structure of the light emitting element shown in FIG. 7 may be the same as a structure of a light emitting element according to one of FIGS. 3 to 6 as described herein.

The emission layer EML of the light emitting element ED included in the display device DD-a according to an embodiment may include the above-described fused polycyclic compound according to an embodiment.

Referring to FIG. 7, the emission layer EML may be disposed in an opening OH defined in a pixel defining film PDL. For example, the emission layer EML, which is separated by the pixel defining film PDL and correspondingly provided to each light emitting regions PXA-R, PXA-G, and PXA-B may emit light in a same wavelength range. In the display device DD-a, the emission layer EML may emit blue light. Although not shown in the drawings, in an embodiment, the emission layer EML may be provided as a common layer for each of the light emitting regions PXA-R, PXA-G, and PXA-B.

The light control layer CCL may be disposed on the display panel DP. The light control layer CCL may include a light conversion body. The light conversion body may be a quantum dot, a phosphor, or the like. The light conversion body may convert the wavelength of a provided light and emit the resulting light. For example, the light control layer CCL may be a layer including a quantum dot or a layer including a phosphor.

The light control layer CCL may include light control parts CCP1, CCP2, and CCP3. The light control parts CCP1, CCP2, and CCP3 may be spaced apart from each other.

Referring to FIG. 7, divided patterns BMP may be disposed between the light control parts CCP1, CCP2, and CCP3 which are spaced apart from each other, but embodiments are not limited thereto. FIG. 7 illustrates that the divided patterns BMP do not overlap the light control parts CCP1, CCP2, and CCP3, but the edges of the light control parts CCP1, CCP2 and CCP3 may overlap at least a portion of the divided patterns BMP.

The light control layer CCL may include a first light control part CCP1 containing a first quantum dot QD1 that converts first color light provided from the light emitting element ED into second color light, a second light control part CCP2 containing a second quantum dot QD2 that converts the first color light into third color light, and a third light control part CCP3 that transmits the first color light.

In an embodiment, the first light control part CCP1 may provide red light, which is the second color light, and the second light control part CCP2 may provide green light, which is the third color light. The third light control part CCP3 may provide blue light by transmitting the blue light, which is the first color light provided from the light emitting element ED. For example, the first quantum dot QD1 may be a red quantum dot, and the second quantum dot QD2 may be a green quantum dot. The quantum dots QD1 and QD2 may each be a quantum dot as described herein.

The light control layer CCL may further include a scatterer SP. The first light control part CCP1 may include the first quantum dot QD1 and a scatterer SP, the second light control part CCP2 may include the second quantum dot QD2 and a scatterer SP, and the third light control part CCP3 may not include any quantum dot but may include the scatterer SP.

The scatterer SP may be inorganic particles. For example, the scatterer SP may include at least one of TiO₂, ZnO, Al₂O₃, SiO₂, and hollow silica. The scatterer SP may include one of TiO₂, ZnO, Al₂O₃, SiO₂, and hollow silica, or the scatterer SP may be a mixture of at least two materials selected from TiO₂, ZnO, Al₂O₃, SiO₂, and hollow silica.

The first light control part CCP1, the second light control part CCP2, and the third light control part CCP3 may each include base resins BR1, BR2, and BR3 in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 may each be a medium in which the quantum dots QD1 and QD2 and the scatterer SP are dispersed, and may be formed of various resin compositions, which may be generally referred to as a binder. For example, the base resins BR1, BR2, and BR3 may be acrylic-based resins, urethane-based resins, silicone-based resins, epoxy-based resins, etc. The base resins BR1, BR2, and BR3 may be transparent resins. In an embodiment, the first base resin BR1, the second base resin BR2, and the third base resin BR3 may be the same as or different from each other.

The light control layer CCL may include a barrier layer BFL1. The barrier layer BFL1 may prevent the penetration of moisture and/or oxygen (hereinafter, referred to as ‘moisture/oxygen’). The barrier layer BFL1 may block the light control parts CCP1, CCP2, and CCP3 from exposure to moisture/oxygen. The barrier layer BFL1 may cover the light control parts CCP1, CCP2, and CCP3. A barrier layer BFL2 may be provided between the light control parts CCP1, CCP2, and CCP3 and the color filter layer CFL.

The barrier layers BFL1 and BFL2 may each include at least one inorganic layer. For example, the barrier layers BFL1 and BFL2 may each independently include an inorganic material. For example, the barrier layers BFL1 and BFL2 may each independently include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, etc. The barrier layers BFL1 and BFL2 may each independently further include an organic film. The barrier layers BFL1 and BFL2 may be formed of a single layer or formed of multiple layers.

In the display device DD-a, the color filter layer CFL may be disposed on the light control layer CCL. The color filter layer CFL may be disposed (e.g., directly disposed) on the light control layer CCL. For example, the barrier layer BFL2 may be omitted.

The color filter layer CFL may include filters CF1, CF2, and CF3. The color filter layer CFL may include a first filter CF1 that transmits the second color light, a second filter CF2 that transmits the third color light, and a third filter CF3 that transmits the first color light. For example, the first filter CF1 may be a red filter, the second filter CF2 may be a green filter, and the third filter CF3 may be a blue filter. The filters CF1, CF2, and CF3 may each include a polymeric photosensitive resin and a pigment or dye. The first filter CF1 may include a red pigment or dye, the second filter CF2 may include a green pigment or dye, and the third filter CF3 may include a blue pigment or dye.

However, embodiments are not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may not be separated but may be provided as one filter.

Although not illustrated in the drawings, the color filter layer CFL may further include a light shielding part (not shown). The light shielding part (not shown) may be a black matrix. The light shielding part (not shown) may include an organic light shielding material or an inorganic light shielding material containing a black pigment or dye. The light shielding part (not shown) may prevent light leakage, and may separate boundaries between the adjacent filters CF1, CF2, and CF3.

The first to third filters CF1, CF2, and CF3 may be disposed to respectively correspond to the red light emitting region PXA-R, the green light emitting region PXA-G, and the blue light emitting region PXA-B.

A base substrate BL may be disposed on the color filter layer CFL. The base substrate BL may provide a base surface on which the color filter layer CFL, the light control layer CCL, and the like are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

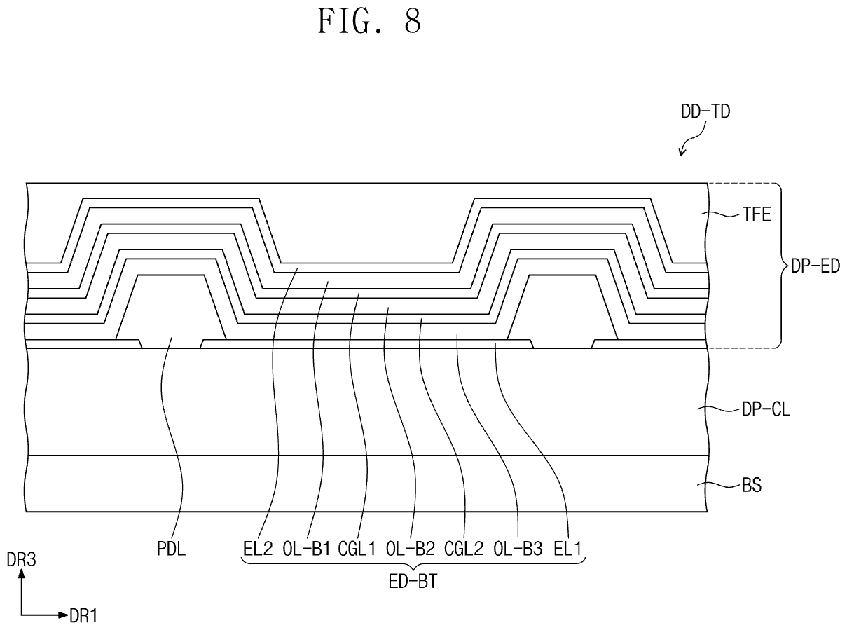

FIG. 8 is a schematic cross-sectional view of a portion of a display device according to an embodiment. In the display device DD-TD according to an embodiment, the light emitting element ED-BT may include light emitting structures OL-B1, OL-B2, and OL-B3.

The light emitting element ED-BT may include a first electrode EL1 and a second electrode EL2 which face each other, and the light emitting structures OL-B1, OL-B2, and OL-B3 stacked in a thickness direction between the first electrode EL1 and the second electrode EL2. The light emitting structures OL-B1, OL-B2, and OL-B3 may each include an emission layer EML (FIG. 7) and a hole transport region HTR and an electron transport region ETR disposed with the emission layer EML (FIG. 7) located therebetween.

For example, the light emitting element ED-BT included in the display device DD-TD may be a light emitting element having a tandem structure and including multiple emission layers.

In an embodiment illustrated in FIG. 8, light emitted from the light emitting structures OL-B1, OL-B2, and OL-B3 may each be blue light. However, embodiments are not limited thereto, and the light emitted from each of the light emitting structures OL-B1, OL-B2, and OL-B3 may have wavelength ranges that are different from each other. For example, the light emitting element ED-BT that includes the light emitting structures OL-B1, OL-B2, and OL-B3, which emit light having wavelength ranges that are different from each other, may emit white light.

Charge generation layers CGL1 and CGL2 may each be disposed between neighboring light emitting structures among the light emitting structures OL-B1, OL-B2, and OL-B3. Charge generation layers CGL1 and CGL2 may each independently include a p-type charge generation layer and/or an n-type charge generation layer.

At least one of the light emitting structures OL-B1, OL-B2, and OL-B3 included in the display device DD-TD may include the above-described fused polycyclic compound according to an embodiment. For example, at least one of the emission layers included in the light emitting element ED-BT may include the fused polycyclic compound.

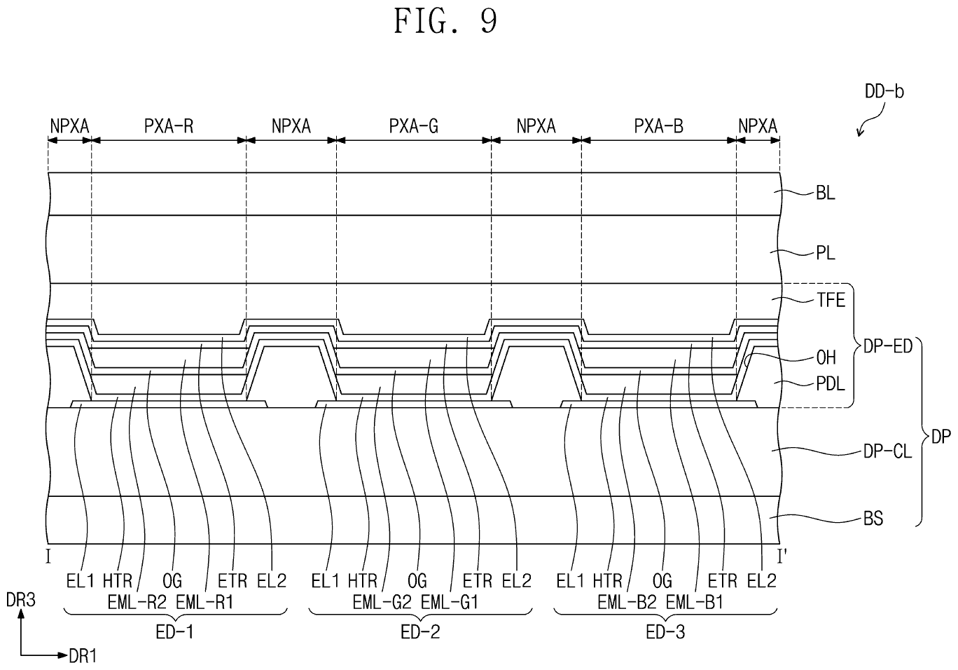

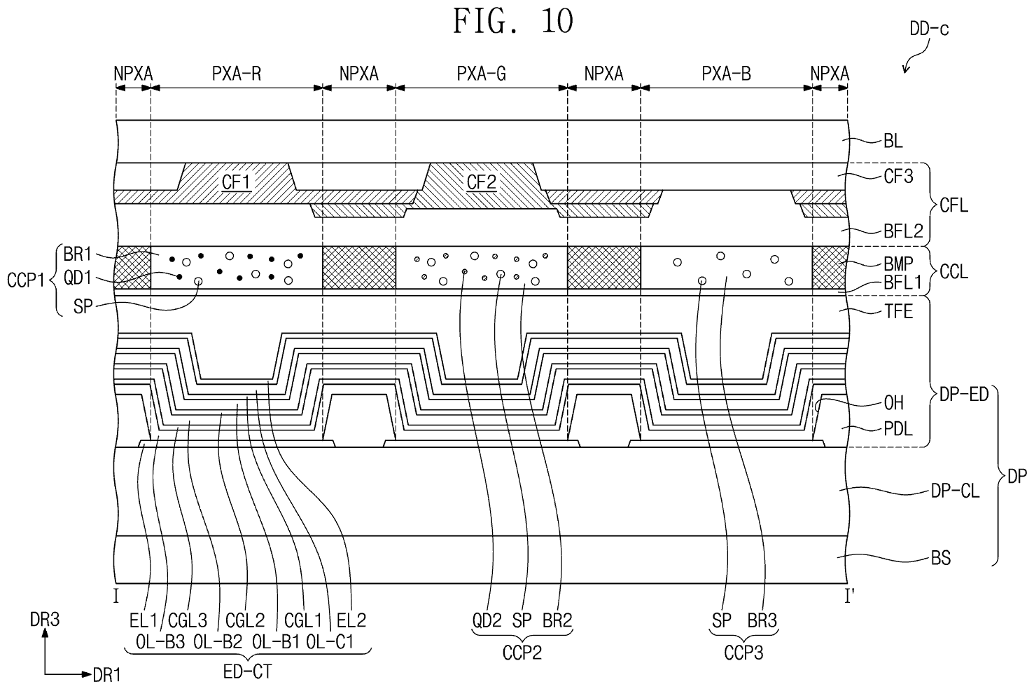

FIG. 9 is a schematic cross-sectional view of a display device DD-b according to an embodiment. The display device DD-b may include light emitting elements ED-1, ED-2, and ED-3 in which two emission layers are stacked. In comparison to the display device DD illustrated in FIG. 2, the embodiment illustrated in FIG. 9 is different at least in that the first to third light emitting elements ED-1, ED-2, and ED-3 each include two emission layers that are stacked in a thickness direction. In each of the first to third light emitting elements ED-1, ED-2, and ED-3, the two emission layers may emit light in a same wavelength region.

The first light emitting element ED-1 may include a first red emission layer EML-R1 and a second red emission layer EML-R2. The second light emitting element ED-2 may include a first green emission layer EML-G1 and a second green emission layer EML-G2. The third light emitting element ED-3 may include a first blue emission layer EML-B1 and a second blue emission layer EML-B2. An emission auxiliary part OG may be disposed between the first red emission layer EML-R₁ and the second red emission layer EML-R₂, between the first green emission layer EML-G1 and the second green emission layer EML-G2, and between the first blue emission layer EML-B1 and the second blue emission layer EML-B2.

The emission auxiliary part OG may be a single layer or a multilayer. The emission auxiliary part OG may include a charge generation layer. For example, the emission auxiliary part OG may include an electron transport region, a charge generation layer, and a hole transport region, which may be stacked in that order. The emission auxiliary part OG may be provided as a common layer for all of the first to third light emitting elements ED-1, ED-2, and ED-3. However, embodiments are not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may each be disposed between the emission auxiliary part OG and the electron transport region ETR. The second red emission layer EML-R2, the second green emission layer EML-G2, and the second blue emission layer EML-B2 may each be disposed between the hole transport region HTR and the emission auxiliary part OG.

For example, the first light emitting element ED-1 may include the first electrode EL1, the hole transport region HTR, the second red emission layer EML-R2, the emission auxiliary part OG, the first red emission layer EML-R1, the electron transport region ETR, and the second electrode EL2 that are stacked. The second light emitting element ED-2 may include the first electrode EL1, the hole transport region HTR, the second green emission layer EML-G2, the emission auxiliary part OG, the first green emission layer EML-G1, the electron transport region ETR, and the second electrode EL2 that are stacked. The third light emitting element ED-3 may include the first electrode EL1, the hole transport region HTR, the second blue emission layer EML-B2, the emission auxiliary part OG, the first blue emission layer EML-B1, the electron transport region ETR, and the second electrode EL2 that are stacked.

An optical auxiliary layer PL may be disposed on a display device layer DP-ED. The optical auxiliary layer PL may include a polarizing layer. The optical auxiliary layer PL may be disposed on the display panel DP and may control light reflected at the display panel DP from an external light. Although not shown in the drawings, in an embodiment, the optical auxiliary layer PL may be omitted from the display device DD-b.

At least one emission layer included in the display device DD-b according to an embodiment illustrated in FIG. 9 may include the above-described fused polycyclic compound. For example, in an embodiment, at least one of the first blue emission layer EML-B1 or the second blue emission layer may include the fused polycyclic compound.

In contrast to FIGS. 8 and 9, FIG. 10 illustrates a display device DD-c that is different at least in that it includes four light emitting structures OL-B1, OL-B2, OL-B3, and OL-C1. A light emitting element ED-CT may include a first electrode EL1 and a second electrode EL2 which face each other, and first to fourth light emitting structures OL-B1, OL-B2, OL-B3, and OL-C1 that are stacked in a thickness direction between the first electrode EL1 and the second electrode EL2. Charge generation layers CGL1, CGL2, and CGL3 may each be disposed between adjacent light-emitting structures among the first to fourth light emitting structures OL-B1, OL-B2, OL-B3, and OL-C1. Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light in wavelength regions that are different from each other.

Charge generation layers CGL1, CGL2, and CGL3 may each independently include a p-type charge generation layer and/or an n-type charge generation layer.

At least one of the light emitting structures OL-B1, OL-B2, OL-B3, and OL-C1 included in the display device DD-c according to an embodiment may include the above-described fused polycyclic compound. For example, in an embodiment, at least one of the first to third light emitting structures OL-B1, OL-B2, and OL-B3 may include the described-above fused polycyclic compound.

In an embodiment the light emitting element ED may include the above-described polycyclic compound represented by Formula 1 in at least one functional layer disposed between the first electrode EL1 and the second electrode EL2, thereby exhibiting excellent luminous efficiency and improved service life characteristics. For example, the polycyclic compound may be included in the emission layer EML of the light emitting element ED, and the light emitting element may exhibit a long service life characteristic.

In an embodiment, an electronic apparatus may include a display device including multiple light emitting elements, and a control part which controls the display device. The electronic apparatus according to an embodiment may be a device that is activated according to an electrical signal. The electronic apparatus may include display devices according to various embodiments. Examples of an electronic apparatus may include not only large-sized electronic apparatuses such as a television set, a monitor, or an outdoor billboard, but examples of an electronic apparatus may also include small-sized and medium-sized electronic apparatuses such as a personal computer, a laptop computer, a personal digital terminal, a display device for a vehicle, a game console, a portable electronic device, or a camera.

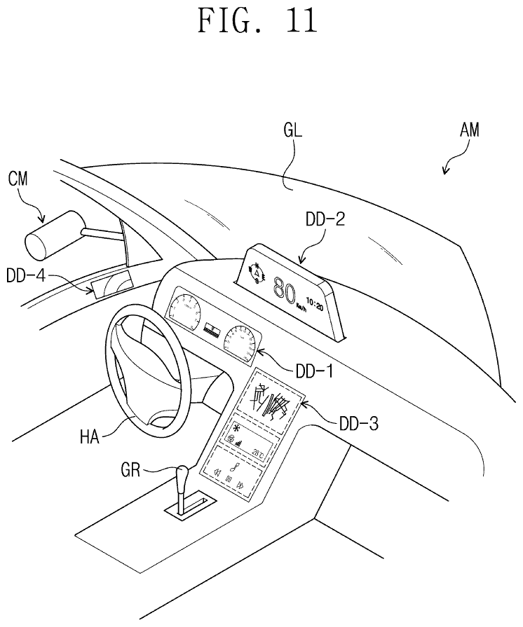

FIG. 11 is a schematic perspective view of a vehicle AM in which first to fourth display device DD-1, DD-2, DD-3, and DD-4 are disposed. At least one of the first to fourth display device DD-1, DD-2, DD-3, and DD-4 may have a structure according to one of the display device DD, DD-TD, DD-a, DD-b, and DD-c as described with reference to FIGS. 1, 2, and 7 to 10.

FIG. 11 illustrates a schematic perspective view of an interior of a vehicle AM, but this is only an example, and the first to fourth display devices DD-1, DD-2, DD-3, and DD-4 may be disposed in various transportation means such as bicycles, motorcycles, trains, ships, and airplanes. At least one of the first to fourth display devices DD-1, DD-2, DD-3, and DD-4 may have a structure according to one of the display device DD, DD-TD, DD-a, DD-b, and DD-c and, according to an embodiment, may be employed in a personal computer, a laptop computer, a personal digital terminal, a game console, a portable electronic device, a television, a monitor, an outdoor billboard, or the like. However, these are merely provided as examples, and thus may be included in other electronic apparatuses.

At least one of the first to fourth display devices DD-1, DD-2, DD-3, and DD-4 may include the light emitting element ED according to an embodiment as described with reference to FIGS. 3 to 6. The light emitting element ED according to an embodiment may include a fused polycyclic compound according to an embodiment. At least one of the first to fourth display devices DD-1, DD-2, DD-3, and DD-4 may include the light emitting element ED which includes a fused polycyclic compound according to an embodiment, thereby improving a display service life.

Referring to FIG. 11, the vehicle AM may include a steering wheel HA and a gearshift GR for driving the vehicle AM. The vehicle AM may include a front window GL disposed so as to face the driver.

The first display device DD-1 may be disposed in a first region overlapping the steering wheel HA. For example, the first display device DD-1 may be a digital cluster which displays first information of the vehicle AM. The first information may include a first scale which indicates a driving speed of the vehicle AM, a second scale which indicates an engine speed (for example, as revolutions per minute (RPM)), an image which indicates a fuel gauge, etc. The first scale and the second scale may each be indicated as a digital image.

A second display device DD-2 may be disposed in a second region facing the driver's seat and overlapping the front window GL. The driver's seat may be a seat in which the steering wheel HA is disposed. For example, the second display device DD-2 may be a head up display (HUD) which displays second information of the vehicle AM. The second display device DD-2 may be optically transparent. The second information may include digital numbers which indicate a driving speed, and may further include information such as the current time. Although not shown in the drawings, according to an embodiment, the second information of the second display device DD-2 may be projected to the front window GL to be displayed.

A third display device DD-3 may be disposed in a third region adjacent to the gearshift GR. For example, the third display device DD-3 may be disposed between the driver's seat and the passenger seat and may be a center information display (CID) for a vehicle for displaying third information. The passenger seat may be a seat that is spaced apart from the driver's seat with the gearshift GR disposed therebetween. The third information may include information about traffic (e.g., navigation information), playing music or radio or a video (or an image), temperatures inside the vehicle AM, etc.

A fourth display device DD-4 may be spaced apart from the steering wheel HA and the gearshift GR, and may be disposed in a fourth region adjacent to the side of the vehicle AM. For example, the fourth display device DD-4 may be a digital side-view mirror which displays a fourth information. The fourth display device DD-4 may display an image outside the vehicle AM taken by a camera module CM disposed outside the vehicle AM. The fourth information may include an image outside the vehicle AM.

The first to fourth information as described herein are examples, and the first to fourth display devices DD-1, DD-2, DD-3, and DD-4 may further display information about the interior and the exterior of the vehicle AM. The first to fourth information may include information that is different from each other. However, embodiments are not limited thereto, and a part of the first to fourth information may include the same information as one another.

Hereinafter, a fused polycyclic compound according to an embodiment and a light emitting element according to an embodiment will be described with reference to the Examples and the Comparative Examples. The Examples described below are only provided as illustrations to assist in understanding the disclosure and the scope thereof is not limited thereto.

### Examples and Comparative Examples

### 1. Synthesis of Fused Polycyclic Compound

A synthesis method of the fused polycyclic compound according to an embodiment will be described by illustrating synthesis methods for Compounds 7, 9, 10, 38, 61, 65, 69, 73, 81, 82 and 83. The synthesis methods of the fused polycyclic compounds as described below are only examples, and the synthesis methods of the fused polycyclic compound according to embodiments are not limited to the following examples.

### (1) Synthesis of Compound 7

### Synthesis of Intermediate 7-a

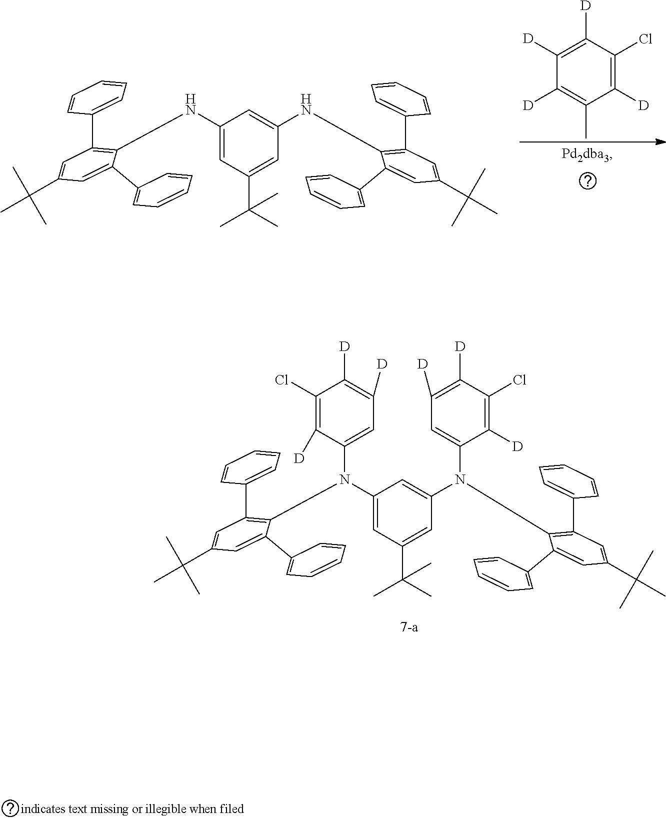

In an argon atmosphere, to a 2-L flask, 5-(tert-butyl)-N1,N3-bis(5′-(tert-butyl)-[1,1′:3′,1″-terphenyl]-2′-yl)benzene-1,3-diamine (10 g, 13.5 mmol), 1-chloro-3-iodobenzene-2,4,5,6-d4 (6.6 g, 27 mmol), pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and the reaction solution was stirred at about 140° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as an eluent to obtain Intermediate 7-a (white solid, 10 g, yield: 77%). ESI-LCMS: [M]+: C66H56D6Cl2N2. 958.4711.

### Synthesis of Intermediate 7-b

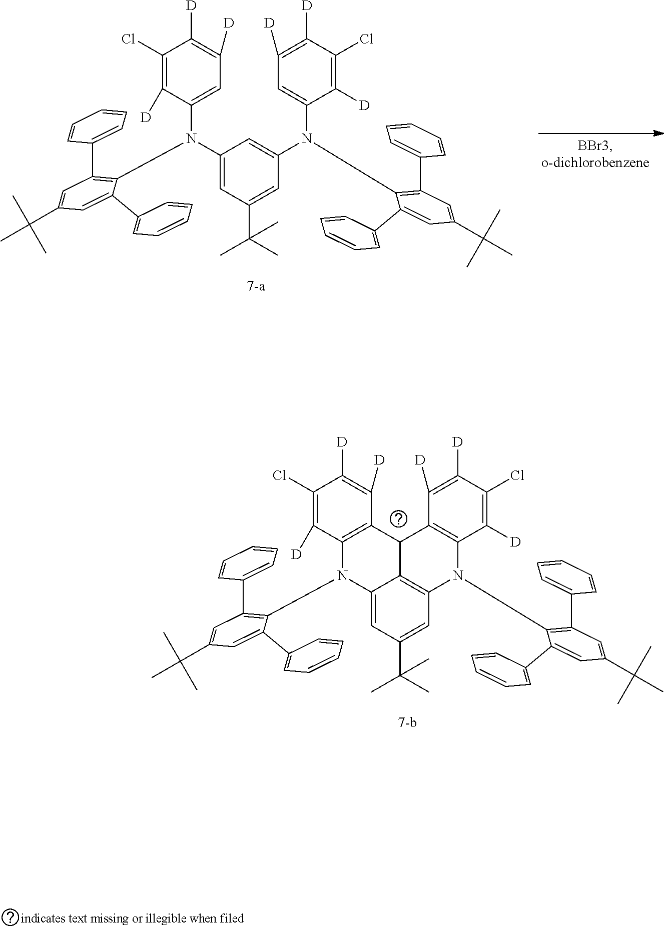

In an argon atmosphere, to a 1-L flask, Intermediate 7-a (10 g, 10 mmol) was added and dissolved in 100 mL of o-dichlorobenzene, and BBr₃ (1.5 equiv.) was added thereto. The reaction solution was stirred at about 140° C. for about 12 hours. After the reaction solution was cooled, the reaction was terminated by adding triethylamine, and the solvent was removed under reduced pressure to obtain a solid. The solid thus obtained was purified and separated by silica gel column chromatography using CH₂Cl₂ and hexane as an eluent to Intermediate 7-b (yellow solid, 2.4 g, yield: 24%). ESI-LCMS: [M]+: C66H53D6BCl2N2. 966.4532

### Synthesis of Compound 7

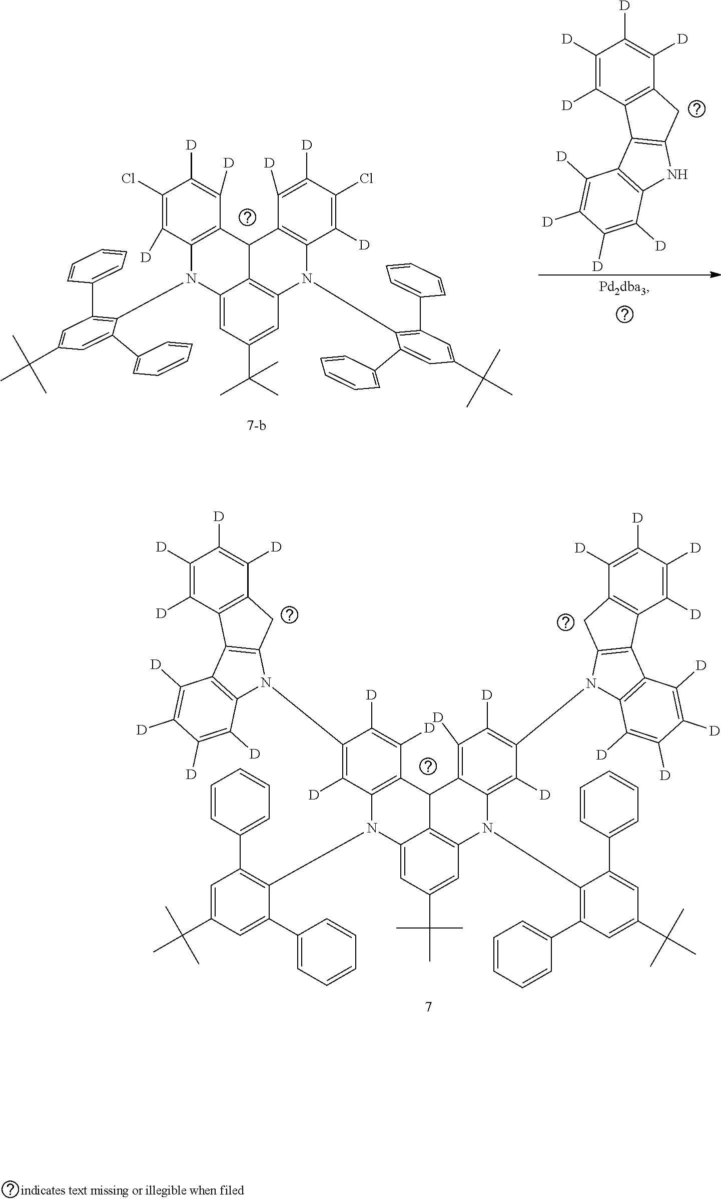

In an argon atmosphere, to a 1-L flask, Intermediate 7-b (2.4 g, 2.5 mmol), 6H-benzo[4,5]thieno[2,3-b]indole-1,2,3,4,7,8,9,10-d8 (1.15 g, 5 mmol), pd₂dba₃ (0.06 g, 0.12 mmol), tris-tert-butyl phosphine (0.06 mL, 0.24 mmol), and sodium tert-butoxide (0.5 g, 5.1 mmol) were added and dissolved in 100 mL of xylene, and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as an eluent to obtain Compound 7 (yellow solid, 2.5 g, yield: 75%). ESI-LCMS: [M]+: C94H53D22BN4S2. 1356.6969.

### (2) Synthesis of Compound 9

### Synthesis of Compound 9

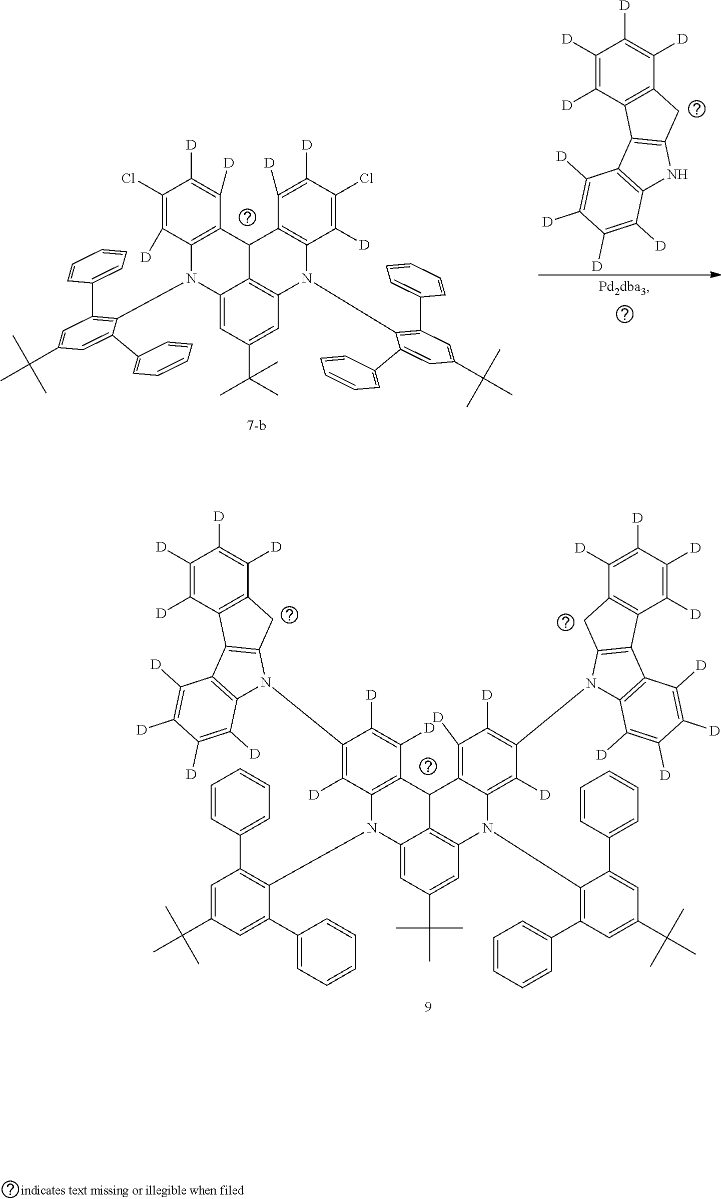

In an argon atmosphere, to a 1-L flask, Intermediate 7-b (2.4 g, 2.5 mmol), 6H-benzo[4,5]selenopheno[2,3-b]indole-1,2,3,4,7,8,9,10-d8 (1.4 g, 5 mmol), pd₂dba₃ (0.06 g, 0.12 mmol), tris-tert-butyl phosphine (0.06 mL, 0.24 mmol), and sodium tert-butoxide (0.5 g, 5.1 mmol) were added and dissolved in 100 mL of xylene, and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as an eluent to obtain Compound 9 (yellow solid, 2.6 g, yield: 71%). ESI-LCMS: [M]+: C94H53D22BN4Se2. 1452.0058.

### (3) Synthesis of Compound 10

### Synthesis of Compound 10

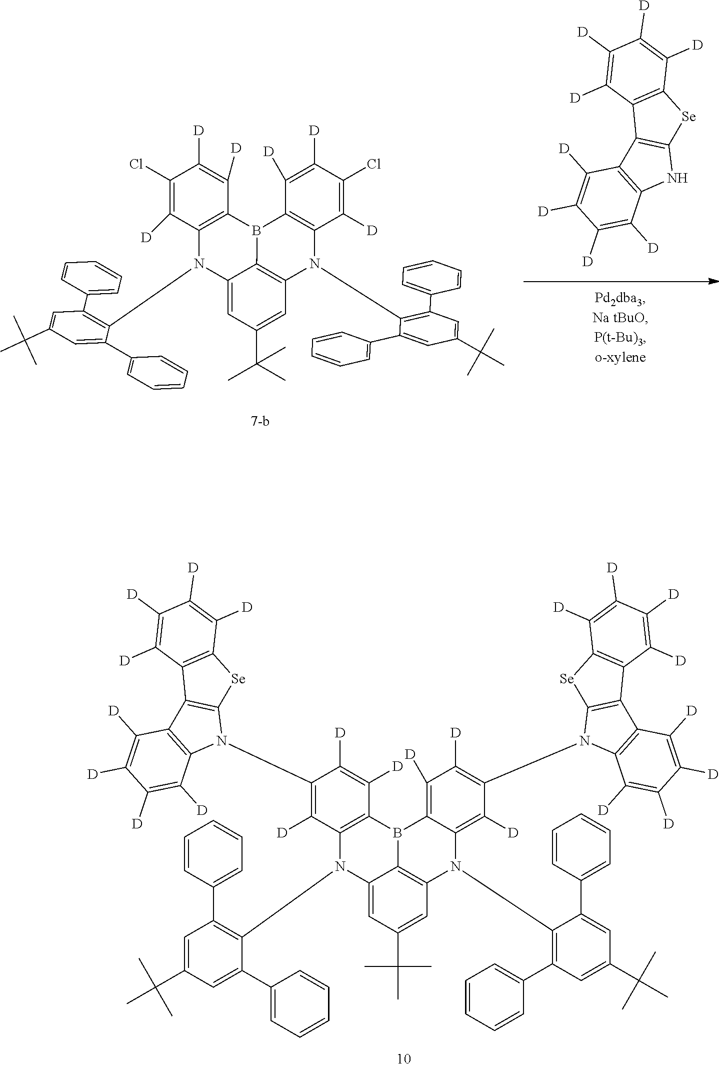

In an argon atmosphere, to a 1-L flask, Intermediate 7-b (2.4 g, 2.5 mmol), 6H-benzo[4,5]telluropheno[2,3-b]indole-1,2,3,4,7,8,9,10-d8 (1.6 g, 5 mmol), pd₂dba₃ (0.06 g, 0.12 mmol), tris-tert-butyl phosphine (0.06 mL, 0.24 mmol), and sodium tert-butoxide (0.5 g, 5.1 mmol) were added and dissolved in 100 mL of xylene, and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as an eluent to obtain Compound 10 (yellow solid, 2.93 g, yield: 74%). ESI-LCMS: [M]+: C94H53D22BN4Te2. 1552.5612.

### (4) Synthesis of Compound 38

### Synthesis of Intermediate 38-a

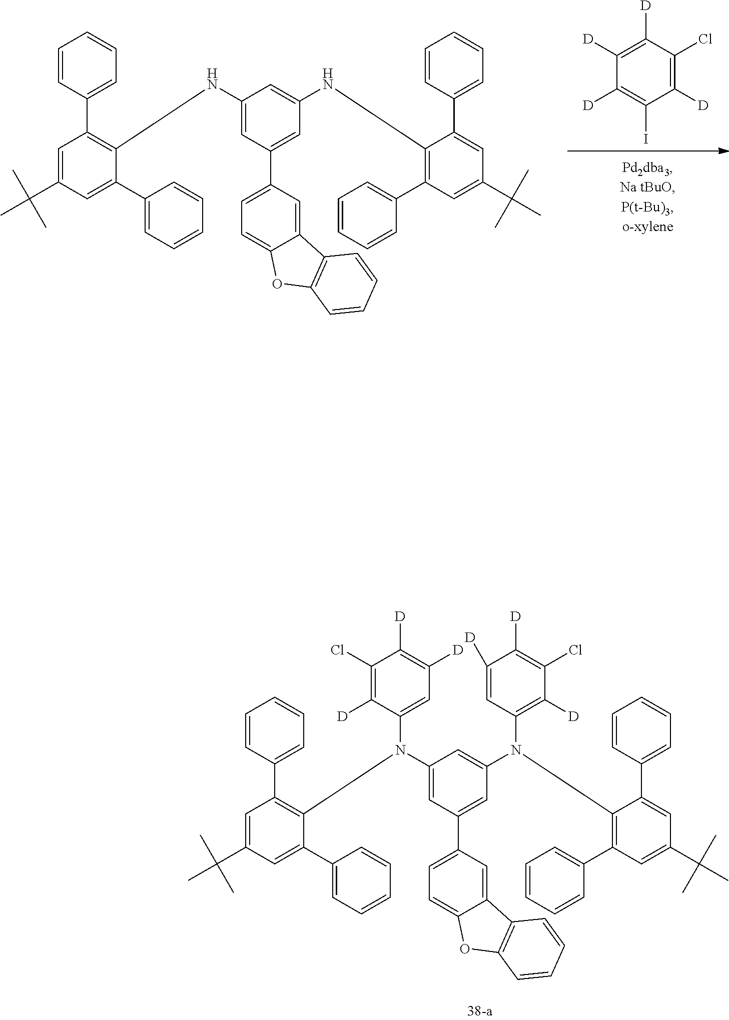

In an argon atmosphere, to a 2-L flask, N1,N3-bis(5′-(tert-butyl)-[1,1′:3′,1″-terphenyl]-2′-yl)-5-(dibenzo[b,d]furan-2-yl)benzene-1,3-diamine (10 g, 12 mmol), 1-chloro-3-iodobenzene-2,4,5,6-d4 (5.6 g, 24 mmol), pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and the reaction solution was stirred at about 140° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as an eluent to obtain Intermediate 38-a (white solid, 8.8 g, yield: 69%). ESI-LCMS: [M]+: C74H54D6Cl2N20. 1068.4513.

### Synthesis of Intermediate 38-b

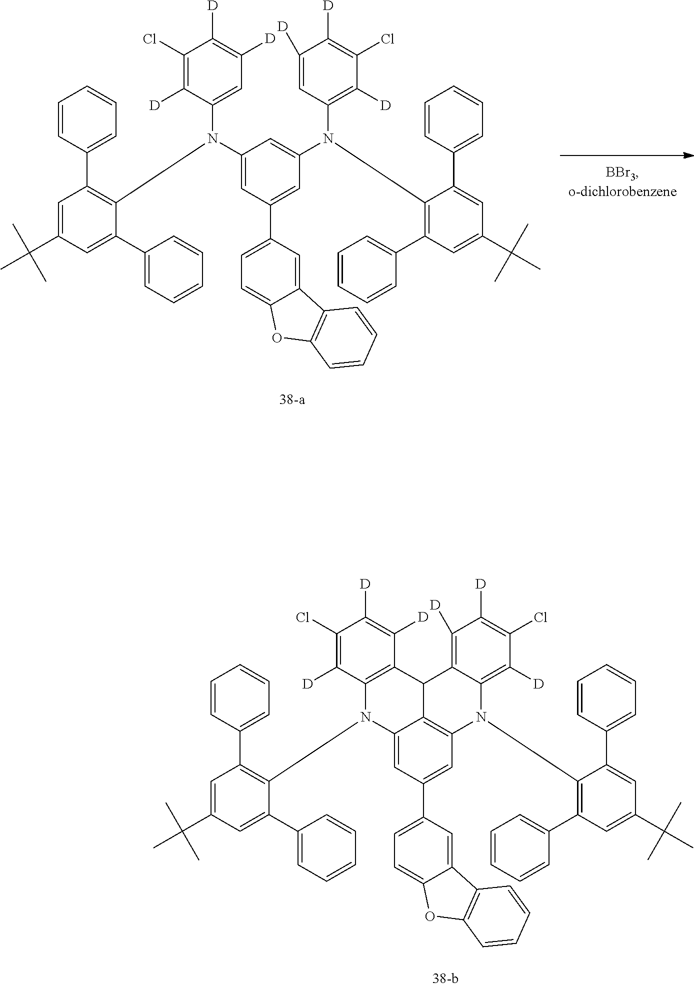

In an argon atmosphere, to a 1-L flask, Intermediate 38-a (8.8 g, 8 mmol) was added and dissolved in 100 mL of o-dichlorobenzene, and BBr₃ (1.5 equiv.) was added thereto. The reaction solution was stirred at about 140° C. for about 12 hours. After the reaction solution was cooled, the reaction was terminated by adding triethylamine, and the solvent was removed under reduced pressure to obtain a solid. The solid thus obtained was purified and separated by silica gel column chromatography using CH₂Cl₂ and hexane as an eluent to obtain Intermediate 38-b (yellow solid, 2.8 g, yield: 32%). ESI-LCMS: [M]+: C74H51D6BCl2N2O. 1076.1243.

### Synthesis of Compound 38

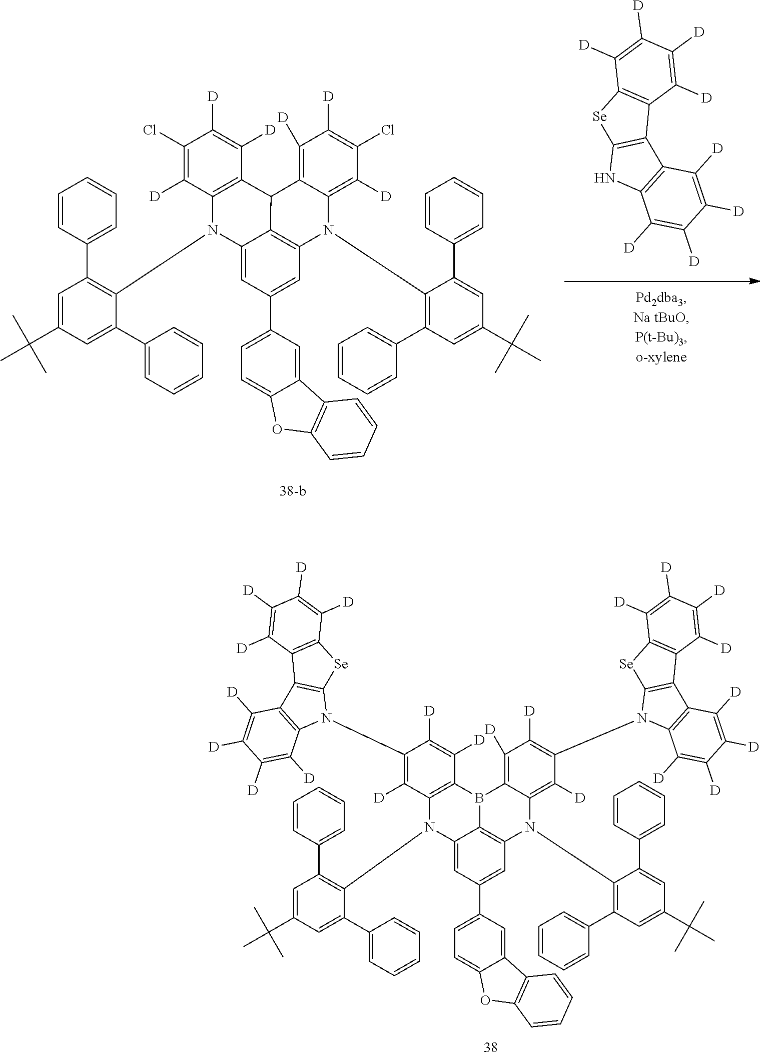

In an argon atmosphere, to a 1-L flask, Intermediate 38-b (2.8 g, 2.6 mmol), 6H-benzo[4,5]selenopheno[2,3-b]indole-1,2,3,4,7,8,9,10-d8 (1.45 g, 5.2 mmol), pd₂dba₃ (0.06 g, 0.12 mmol), tris-tert-butyl phosphine (0.06 mL, 0.24 mmol), and sodium tert-butoxide (0.5 g, 5.1 mmol) were added and dissolved in 100 mL of xylene, and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as an eluent to obtain Compound 38 (yellow solid, 3.1 g, yield: 77%). ESI-LCMS: [M]+: C102H51D22BN4OSe2. 1562.5636.

### (5) Synthesis of Compound 61

### Synthesis of Compound 61

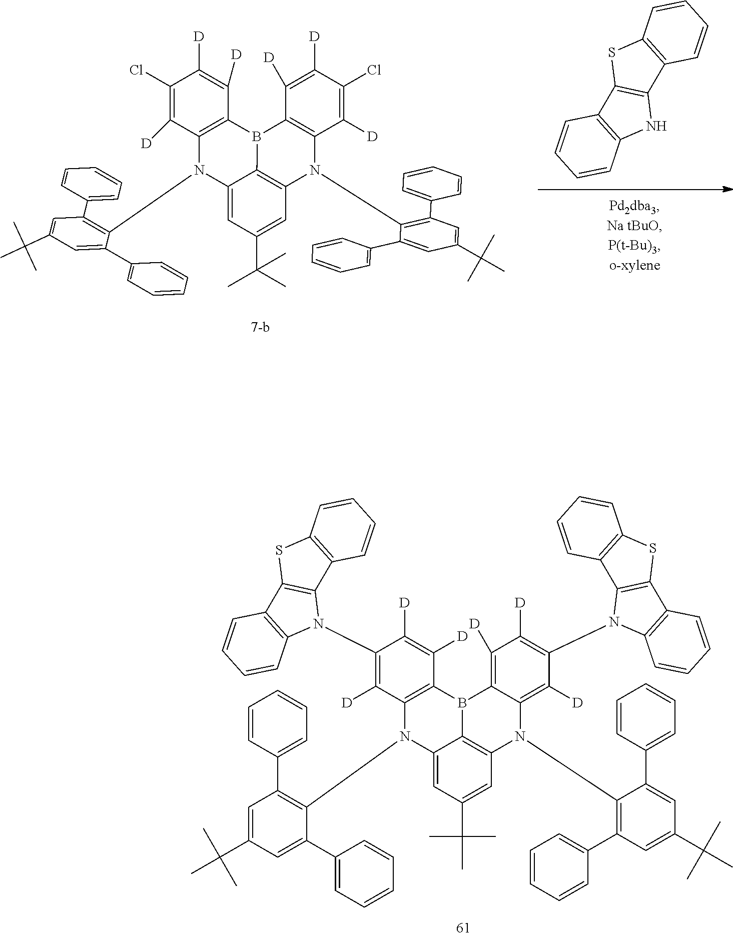

In an argon atmosphere, to a 1-L flask, Intermediate 7-b (2.4 g, 2.5 mmol), 10H-benzo[4,5]thieno[3,2-b]indole (1.1 g, 5 mmol), pd₂dba₃ (0.06 g, 0.12 mmol), tris-tert-butyl phosphine (0.06 mL, 0.24 mmol), and sodium tert-butoxide (0.5 g, 5.1 mmol) were added and dissolved in 100 mL of xylene, and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as an eluent to obtain Compound 61 (yellow solid, 2.5 g, yield: 77%). ESI-LCMS: [M]+: C94H69D6BN4S2. 1340.4059.

### (6) Synthesis of Compound 65

### Synthesis of Intermediate 65-a

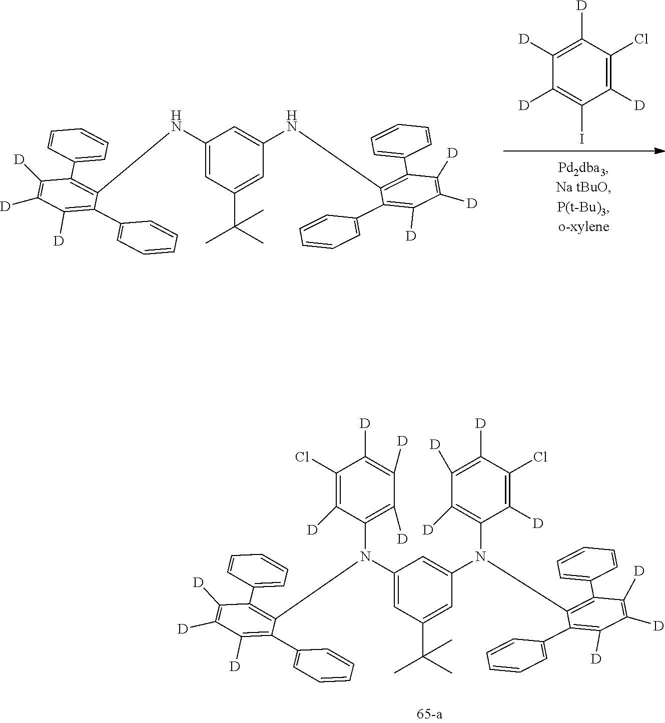 [SMILES: [2H]c1c([2H])c(-c2ccccc2)c(Nc2cc(Nc3c(-c4ccccc4)c([2H])c([2H])c([2H])c3-c3ccccc3)cc(C(C)(C)C)c2)c(-c2ccccc2)c1[2H] ; [2H]c1c([2H])c(Cl)c([2H])c(I)c1[2H] ; [2H]c1c([2H])c(-c2ccccc2)c(N(c2cc(N(c3c([2H])c([2H])c([2H])c(Cl)c3[2H])c3c(-c4ccccc4)c([2H])c([2H])c([2H])c3-c3ccccc3)cc(C(C)(C)C)c2)c2c([2H])c([2H])c([2H])c(Cl)c2[2H])c(-c2ccccc2)c1[2H]]

In an argon atmosphere, to a 2-L flask, N1,N3-bis([1,1′:3′,1″-terphenyl]-2′-yl-4′,5′,6′-d3)-5-(tert-butyl)benzene-1,3-diamine (10 g, 16 mmol), 1-chloro-3-iodobenzene-2,4,5,6-d4 (6.6 g, 32 mmol), pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and the reaction solution was stirred at about 140° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as an eluent to obtain Intermediate 65-a (white solid, 10 g, yield: 74%). ESI-LCMS: [M]+: C58H32D14Cl2N2. 854.3932.

### Synthesis of Intermediate 65-b

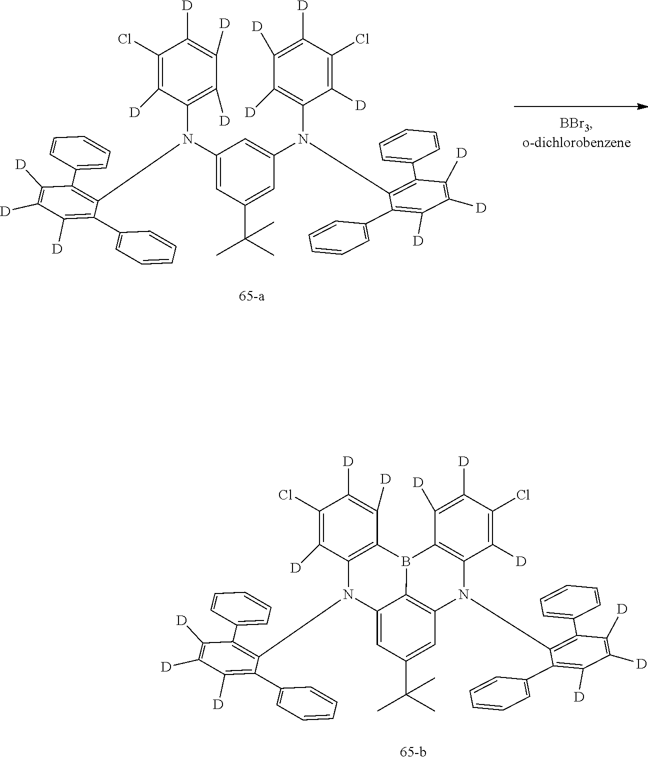 [SMILES: [2H]c1c([2H])c(-c2ccccc2)c(N(c2cc(N(c3c([2H])c([2H])c([2H])c(Cl)c3[2H])c3c(-c4ccccc4)c([2H])c([2H])c([2H])c3-c3ccccc3)cc(C(C)(C)C)c2)c2c([2H])c([2H])c([2H])c(Cl)c2[2H])c(-c2ccccc2)c1[2H] ; [2H]c1c([2H])c(-c2ccccc2)c(N2c3cc(C(C)(C)C)cc4c3B(c3c([2H])c([2H])c(Cl)c([2H])c32)c2c([2H])c([2H])c(Cl)c([2H])c2N4c2c(-c3ccccc3)c([2H])c([2H])c([2H])c2-c2ccccc2)c(-c2ccccc2)c1[2H]]

In an argon atmosphere, to a 1-L flask, Intermediate 65-a (10 g, 12 mmol) was added and dissolved in 100 mL of o-dichlorobenzene, and BBr₃ (1.5 equiv.) was added thereto. The reaction solution was stirred at about 140° C. for about 12 hours. After the reaction solution was cooled, the reaction was terminated by adding triethylamine, and the solvent was removed under reduced pressure to obtain a solid. The solid thus obtained was purified and separated by silica gel column chromatography using CH₂Cl₂ and hexane as an eluent to obtain Intermediate 65-b (yellow solid, 2.4 g, yield: 24%). ESI-LCMS: [M]+: C58H31D12BCl2N2. 860.3637.

### Synthesis of Compound 65

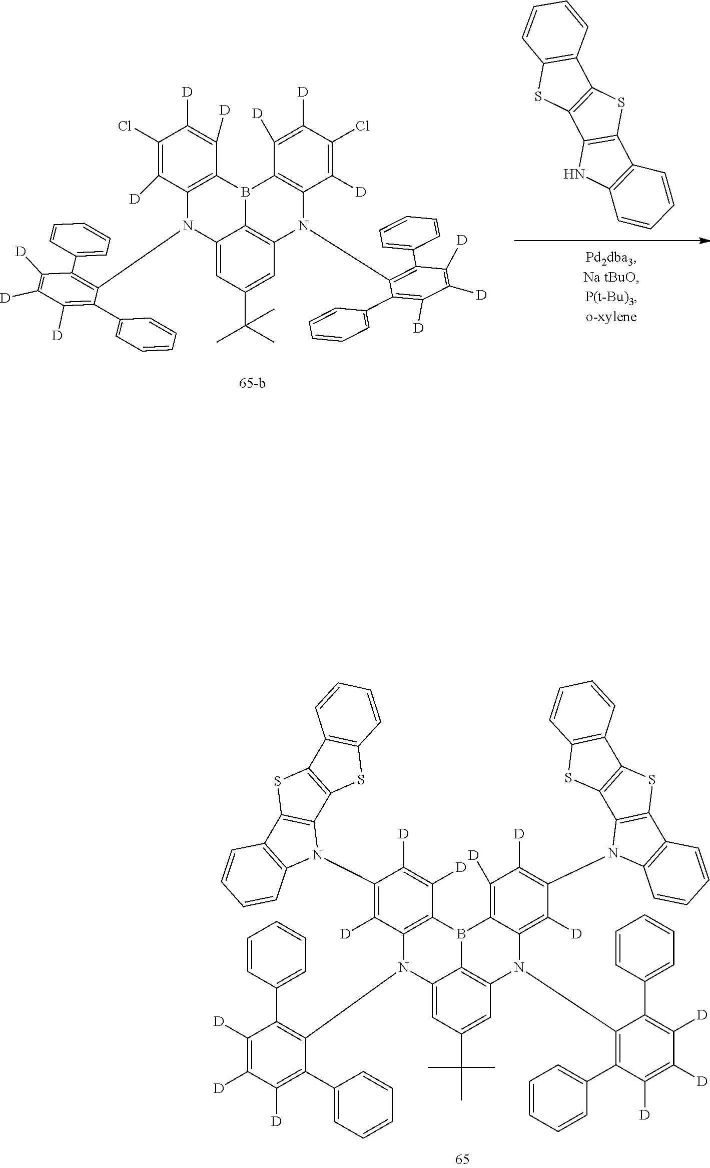 [SMILES: [2H]c1c([2H])c(-c2ccccc2)c(N2c3cc(C(C)(C)C)cc4c3B(c3c([2H])c([2H])c(Cl)c([2H])c32)c2c([2H])c([2H])c(Cl)c([2H])c2N4c2c(-c3ccccc3)c([2H])c([2H])c([2H])c2-c2ccccc2)c(-c2ccccc2)c1[2H] ; c1ccc2c(c1)[nH]c1c2sc2c3ccccc3sc12 ; [2H]c1c([2H])c(-c2ccccc2)c(N2c3cc(C(C)(C)C)cc4c3B(c3c([2H])c([2H])c(-n5c6ccccc6c6sc7c8ccccc8sc7c65)c([2H])c32)c2c([2H])c([2H])c(-n3c5ccccc5c5sc6c7ccccc7sc6c53)c([2H])c2N4c2c(-c3ccccc3)c([2H])c([2H])c([2H])c2-c2ccccc2)c(-c2ccccc2)c1[2H]]

In an argon atmosphere, to a 1-L flask, Intermediate 65-b (2.4 g, 2.8 mmol), 10H-benzo[4′,5′][2′,3′: 4,5]thieno[3,2-b]indole (1.6 g, 5.6 mmol), pd₂dba₃ (0.06 g, 0.12 mmol), tris-tert-butyl phosphine (0.06 mL, 0.24 mmol), and sodium tert-butoxide (0.5 g, 5.1 mmol) were added and dissolved in 100 mL of xylene, and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as an eluent to obtain Compound 65 (yellow solid, 2.8 g, yield: 74%). ESI-LCMS: [M]+: C90H47D12BN4S4. 1346.4512.

### (7) Synthesis of Compound 69

### Synthesis of Compound 69

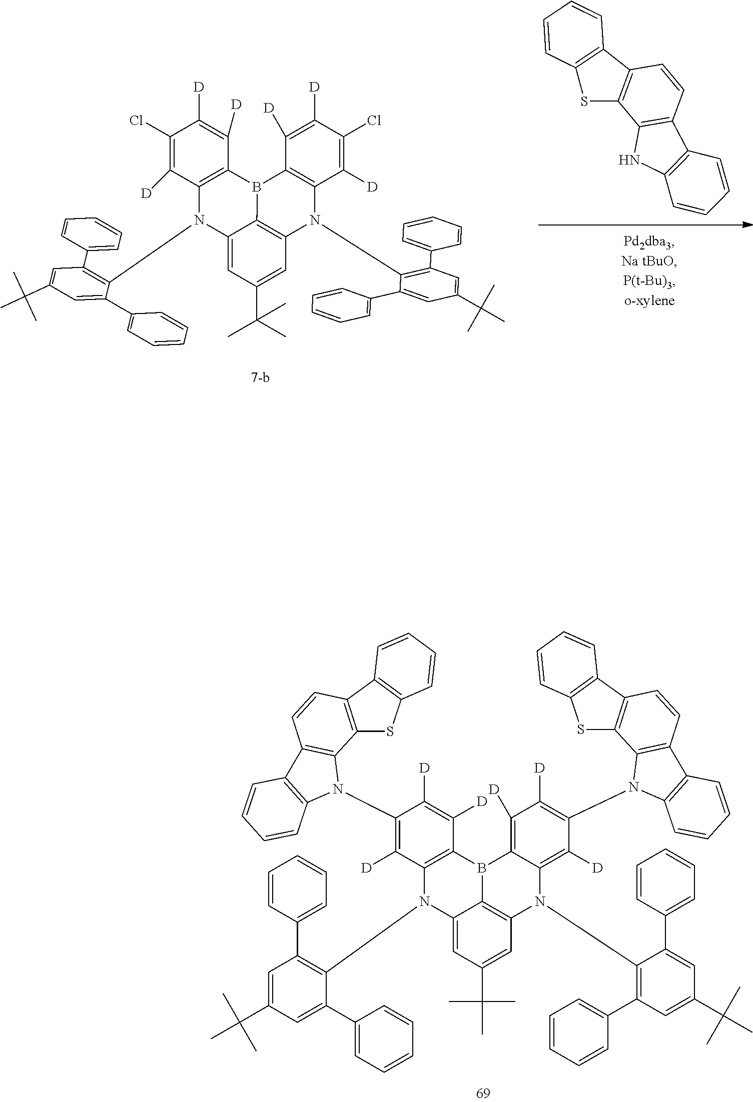

In an argon atmosphere, to a 1-L flask, Intermediate 7-b (2.4 g, 2.5 mmol), 12H-benzo[4,5]thieno[2,3-a]carbazole (1.36 g, 5 mmol), pd₂dba₃ (0.06 g, 0.12 mmol), tris-tert-butyl phosphine (0.06 mL, 0.24 mmol), and sodium tert-butoxide (0.5 g, 5.1 mmol) were added and dissolved in 100 mL of xylene, and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as an eluent to obtain Compound 69 (yellow solid, 2.55 g, yield: 70%). ESI-LCMS: [M]+: C102H73D6BN4S2. 1440.6002.

### (8) Synthesis of Compound 73

### Synthesis of Compound 73

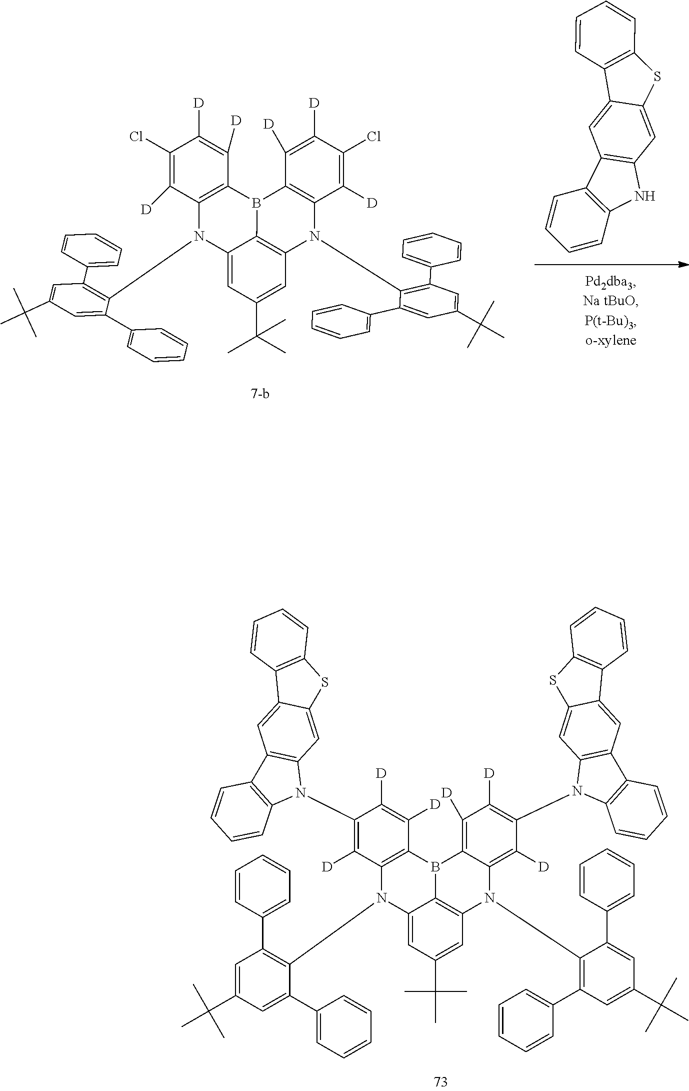

In an argon atmosphere, to a 1-L flask, Intermediate 7-b (2.4 g, 2.5 mmol), 10-(9H-carbazol-3-yl)-10H-phenoxazine (1.74 g, 5 mmol), pd₂dba₃ (0.06 g, 0.12 mmol), tris-tert-butyl phosphine (0.06 mL, 0.24 mmol), and sodium tert-butoxide (0.5 g, 5.1 mmol) were added and dissolved in 100 mL of xylene, and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as an eluent to obtain Compound 49 (yellow solid, 3.1 g, yield: 78%). ESI-LCMS: [M]+: C114H83D6BN602. 1590.5175.

### (9) Synthesis of Compound 81

### Synthesis of Intermediate 81-a

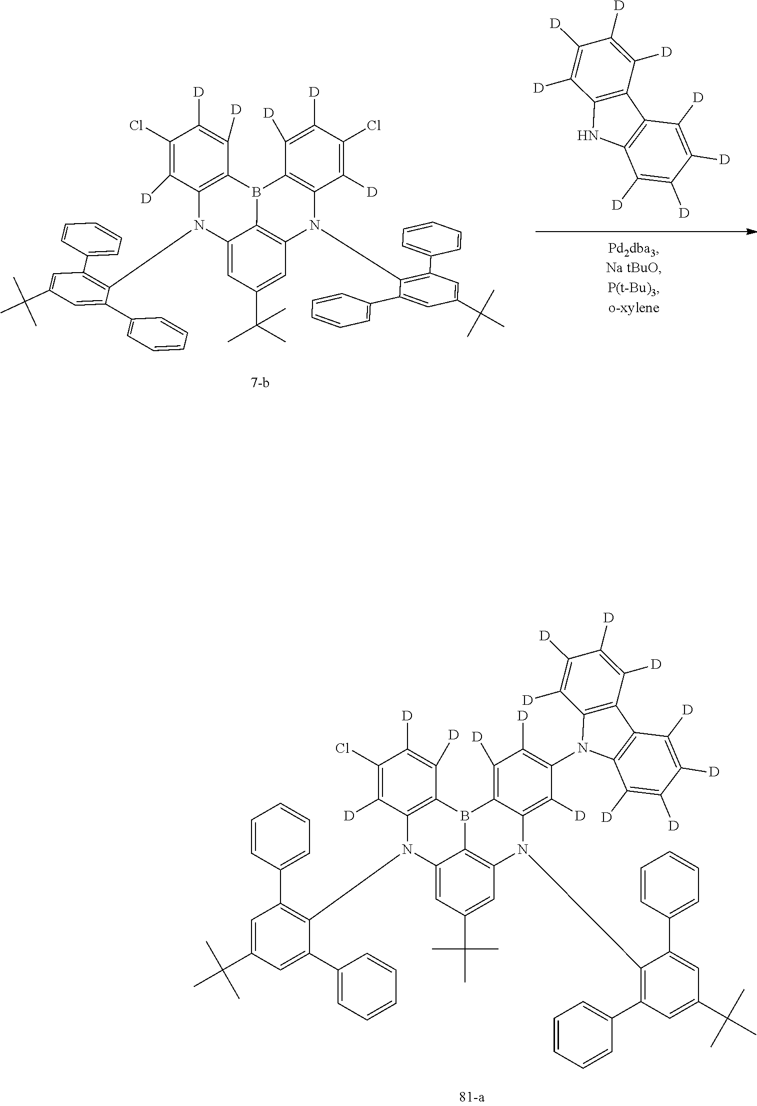

In an argon atmosphere, to a 1-L flask, Intermediate 7-b (2.4 g, 2.5 mmol), 9H-carbazole-1,2,3,4,5,6,7,8-d8 (0.43 g, 2.5 mmol), pd₂dba₃ (0.06 g, 0.12 mmol), tris-tert-butyl phosphine (0.06 mL, 0.24 mmol), and sodium tert-butoxide (0.5 g, 5.1 mmol) were added and dissolved in 100 mL of xylene, and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as an eluent to obtain Intermediate 81-a (yellow solid, 2 g, yield: 73%). ESI-LCMS: [M]+: C78H53D14BClN3. 1105.0550.

### Synthesis of Compound 81

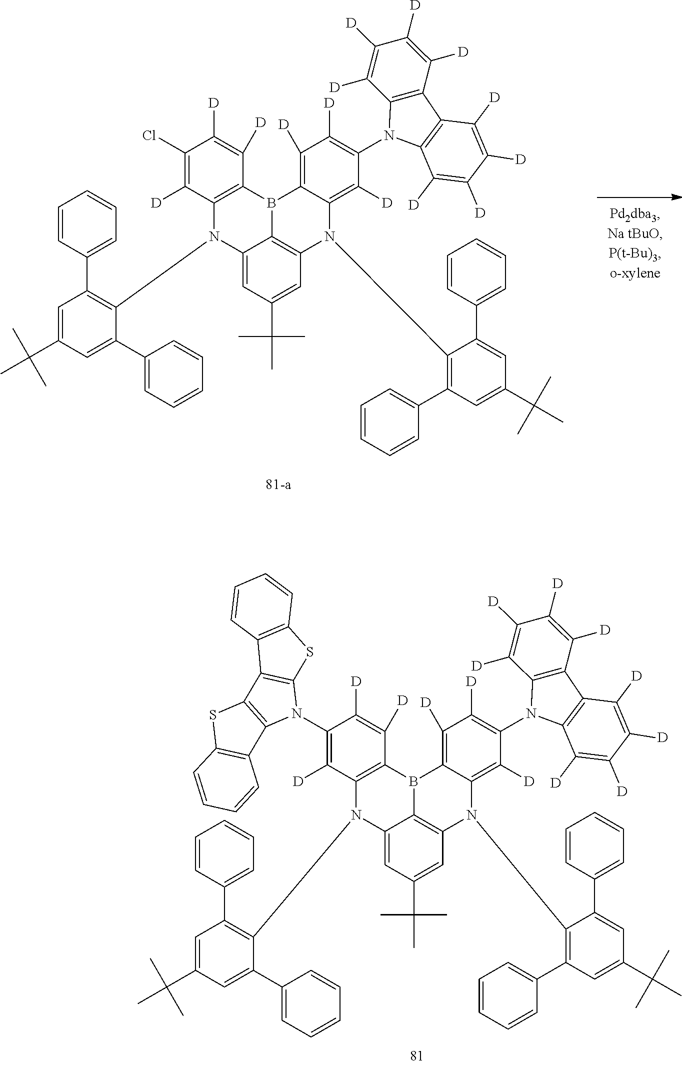

In an argon atmosphere, to a 1-L flask, Intermediate 81-a (2 g, 1.8 mmol), 6H-benzo[4,5]thieno[2,3-b]benzo[4,5]thieno[2,3-d]pyrrole (0.5 g, 1.8 mmol), pd₂dba₃ (0.06 g, 0.12 mmol), tris-tert-butyl phosphine (0.06 mL, 0.24 mmol), and sodium tert-butoxide (0.5 g, 5.1 mmol) were added and dissolved in 100 mL of xylene, and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as an eluent to obtain Compound 81 (yellow solid, 1.8 g, yield: 76%). ESI-LCMS: [M]+: C94H61D14BN4S2. 1348.9964.

### (10) Synthesis of Compound 82

### Synthesis of Compound 82

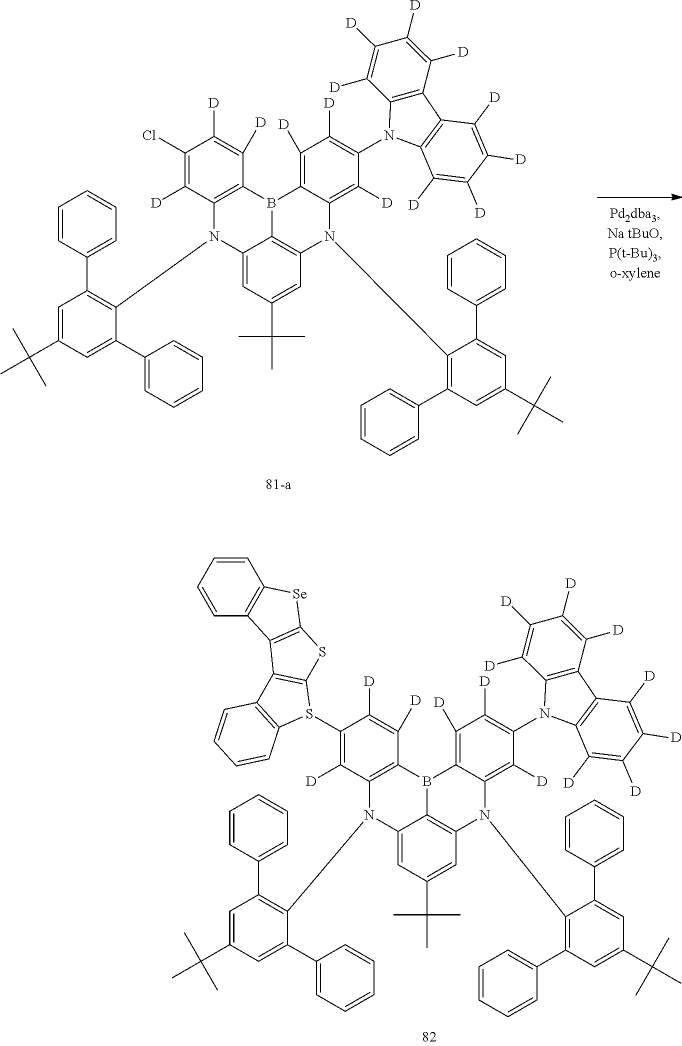

In an argon atmosphere, to a 1-L flask, Intermediate 81-a (2 g, 1.8 mmol), 7H-benzo[4′,5′]selenopheno[3′,2′:4,5]thieno[2,3-b]indole (0.6 g, 1.8 mmol), pd₂dba₃ (0.06 g, 0.12 mmol), tris-tert-butyl phosphine (0.06 mL, 0.24 mmol), and sodium tert-butoxide (0.5 g, 5.1 mmol) were added and dissolved in 100 mL of xylene, and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as an eluent to obtain Compound 82 (yellow solid, 1.8 g, yield: 73%). ESI-LCMS: [M]+: C94H61D14BN4SSe. 1396.5558.

### (11) Synthesis of Compound 83

### Synthesis of Compound 83

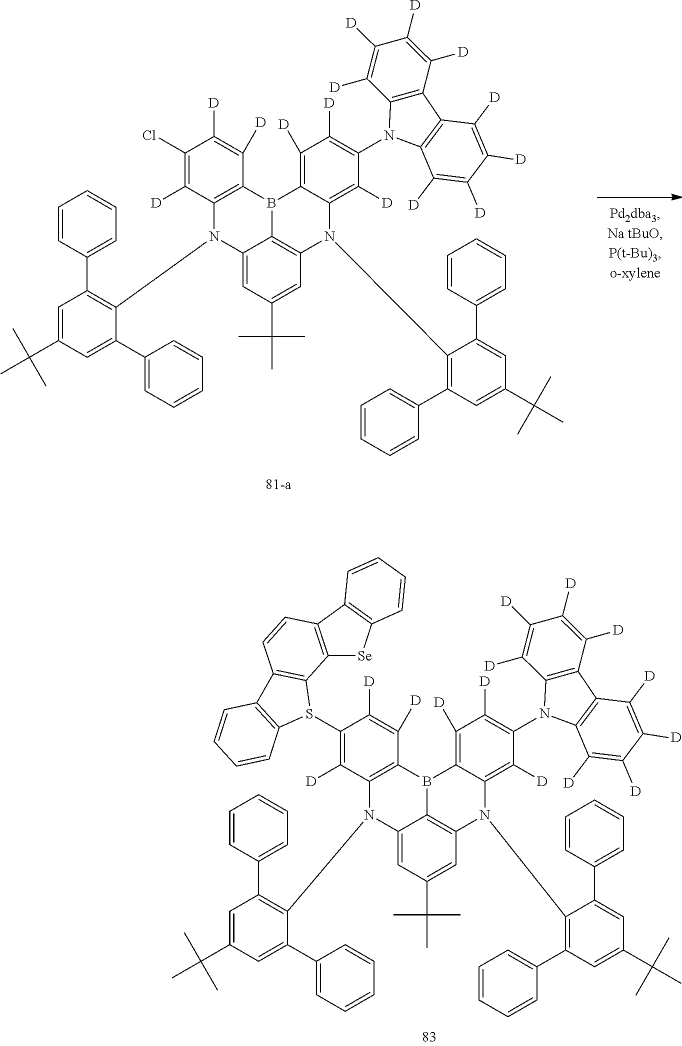

In an argon atmosphere, to a 1-L flask, Intermediate 81-a (2 g, 1.8 mmol), 12H-benzo[4,5]selenopheno[2,3-a]carbazole (0.57 g, 1.8 mmol), pd₂dba₃ (0.06 g, 0.12 mmol), tris-tert-butyl phosphine (0.06 mL, 0.24 mmol), and sodium tert-butoxide (0.5 g, 5.1 mmol) were added and dissolved in 100 mL of xylene, and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as an eluent to obtain Compound 83 (yellow solid, 1.8 g, yield: 73%). ESI-LCMS: [M]+: C96H63D14BN4Se. 1390.6313.

¹H NMR of synthesized compounds of Synthesis Examples (1) to (11) above are shown in Table 1. The synthesis methods of other compounds may be readily recognized by those skilled in the art with reference to the above synthesis paths and raw materials.

TABLE 1

| Compound | |
|---|---|
| number | 1H NMR chemical shift (CDCl₃) |
| 7 | 7.45 (s, 4H), 7.18 (m, 12H), 7.01 (m, 8H), 6.88 (s, 2H), 1.39 (s, 18H), 1.15 (s, 9H) |
| 9 | 7.40 (s, 4H), 7.15 (m, 12H), 7.00 (m, 8H), 6.85 (s, 2H), 1.33 (s, 18H), 1.12 (s, 9H) |
| 10 | 7.38 (s, 4H), 7.13 (m, 12H), 6.97 (m, 8H), 6.83 (s, 2H), 1.31 (s, 18H), 1.11 (s, 9H) |
| 38 | 8.00 (d, 1H), 7.88 (m, 3H), 7.55 (d, 2H), 7.44 (s, 4H), 7.41 (m, 12H), 7.35 (t, 1H), |
| | 7.12 (m, 8H), 6.93 (s, 2H) |
| 61 | 8.43 (d, 2H), 8.05 (d, 2H), 7.94 (d, 2H), 7.50 (m, 4H), 7.43 (s, 4H), 7.28 (t, 2H), |
| | 7.15 (m, 12H), 7.03 (m, 8H), 6.87 (s, 2H), 1.35 (s, 18H), 1.15 (s, 9H) |
| 65 | 8.43 (d, 2H), 8.085 (d, 2H), 7.94 (d, 4H), 7.52 (m, 8H), 7.45 (m, 14H), 7.39 (m, 4H), |
| | 7.33 (t, 2H), 7.22 (t, 2H), 7.03 (s, 2H), 1.29 (s, 9H) |
| 69 | 8.55 (d, 2H), 8.45 (d, 2H), 8.05 (d, 2H), 7.93 (d, 2H), 7.63 (d, 2H), 7.56 (d, 2H), |
| | 7.49 (d, 2H), 7.24 (m, 12H), 7.17 (2H), 7.08 (m, 8H), 6.93 (s, 2H), 1.36 (s, 18H), |
| | 1.21 (s, 9H) |
| 73 | 8.55 (d, 2H), 7.94 (d, 2H), 7.54 (d, 2H), 7.45 (s, 4H), 7.35 (m, 6H), 7.20 (t, 2H), |
| | 7.11 (m, 4H), 7.05 (m, 8H), 6.96 (d, 4H), 7.14 (m, 8H), 6.90 (s, 2H), 1.36 (s, 18H), |
| | 1.21 (s, 9H) |
| 81 | 8.45 (d, 1H), 8.11 (d, 1H), 7.95 (d, 2H), 7.66 (t, 1H), 7.51 (t, 1H), 7.47 (s, 4H), |
| | 7.40 (m, 12H), 7.12 (m, 8H), 1.32 (s, 9H) |
| 82 | 8.56 (d, 1H), 7.99 (d, 1H), 7.77 (d, 1H), 7.52 (m, 2H), 7.44 (m, 13H), 7.40 (s, 4H), |
| | 7.33 (t, 1H), 7.20 (t, 1H), 7.08 (m, 8H), 6.96 (s, 2H) |
| 83 | 8.51 (d, 1H), 8.31 (d, 1H), 7.95 (m, 2H), 7.69 (d, 1H), 7.50 (m, 2H), 7.48 (m, 13H), |
| | 7.41 (s, 4H), 7.22 (t, 1H), 7.05 (m, 8H), 7.00 (s, 2H) |

### 1. Manufacture and Evaluation of Light Emitting Elements

### (1) Manufacture of Light Emitting Elements

The light emitting element of an Example including the fused polycyclic compound of an Example in an emission layer was manufactured as follows. Compounds 7, 9, 10, 38, 61, 65, 69, 73, 81, 82, and 83, which are Example Compounds as described above, were used as dopant materials for the emission layers to manufacture the light emitting elements of Examples 1 to 11, respectively. Comparative Examples 1 to 4 correspond to the light emitting elements manufactured by using Comparative Example Compounds C1 to C4 as dopant materials for the emission layers, respectively.

### Example Compounds

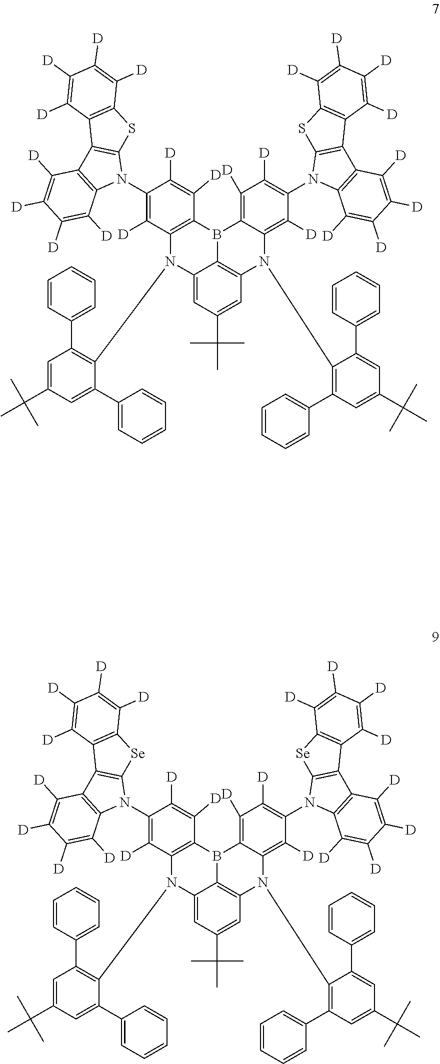

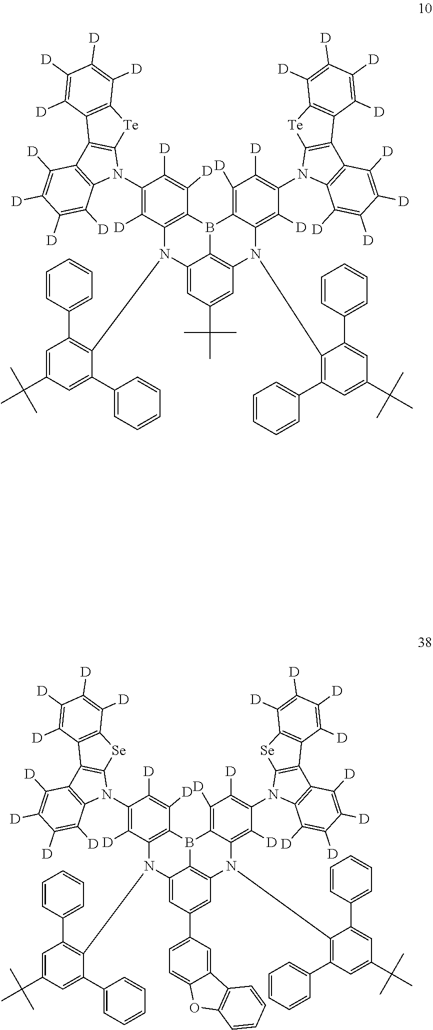

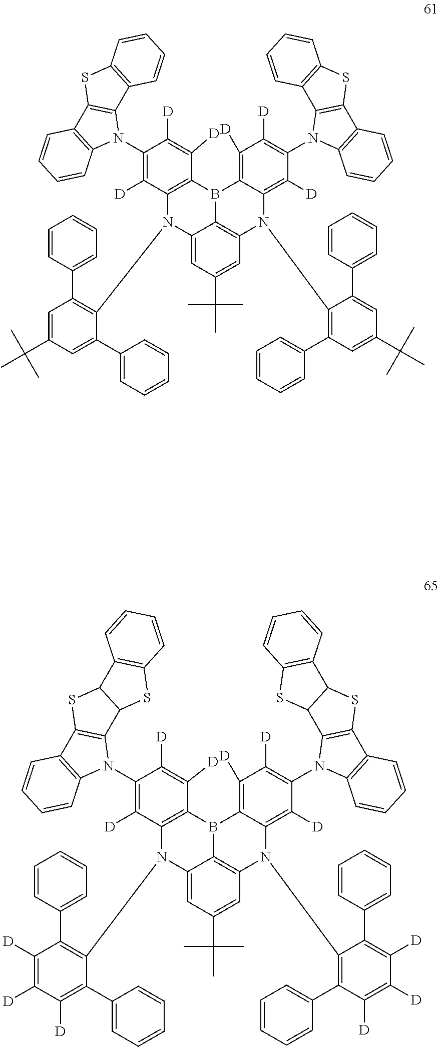 [SMILES: [2H]c1c([2H])c(-n2c3ccccc3c3sc4ccccc4c32)c([2H])c2c1B1c3c(cc(C(C)(C)C)cc3N(c3c(-c4ccccc4)cc(C(C)(C)C)cc3-c3ccccc3)c3c([2H])c(-n4c5ccccc5c5sc6ccccc6c54)c([2H])c([2H])c31)N2c1c(-c2ccccc2)cc(C(C)(C)C)cc1-c1ccccc1 ; [2H]c1c([2H])c(-c2ccccc2)c(N2c3cc(C(C)(C)C)cc4c3B(c3c([2H])c([2H])c(-n5c6c(c7ccccc75)SC5c7ccccc7SC65)c([2H])c32)c2c([2H])c([2H])c(-n3c5c(c6ccccc63)SC3c6ccccc6SC53)c([2H])c2N4c2c(-c3ccccc3)c([2H])c([2H])c([2H])c2-c2ccccc2)c(-c2ccccc2)c1[2H]]

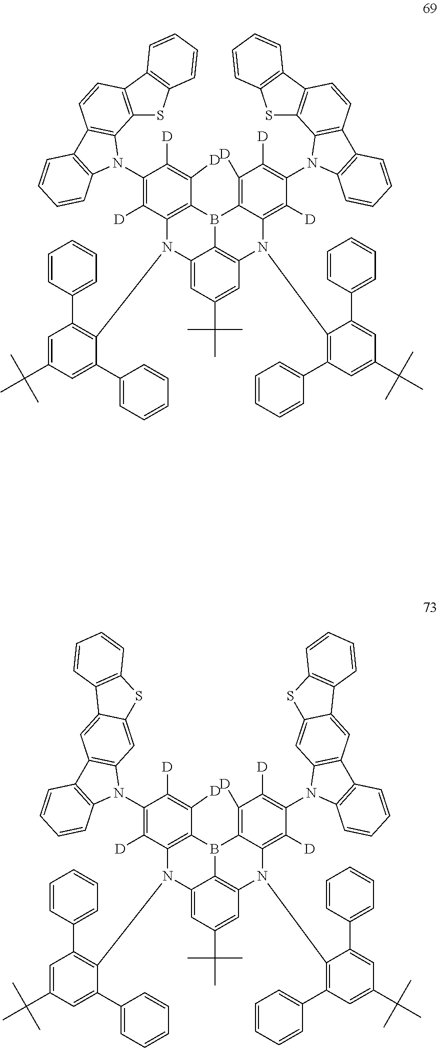

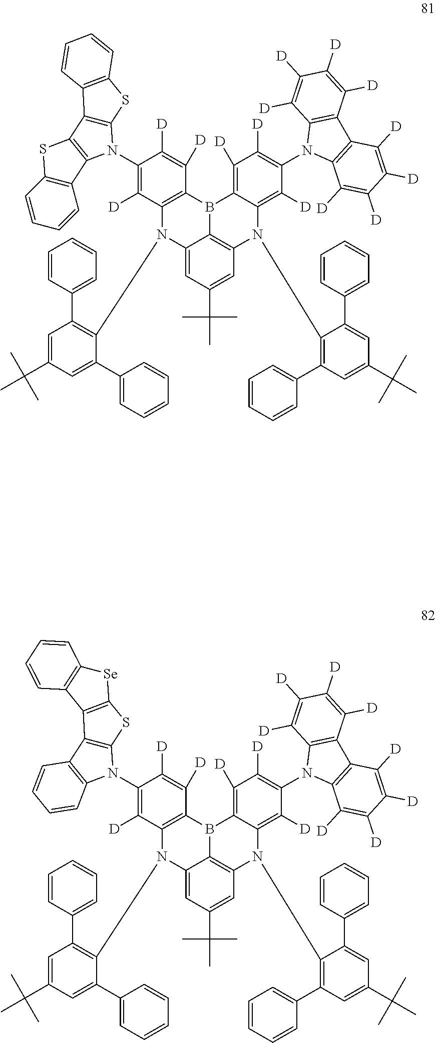

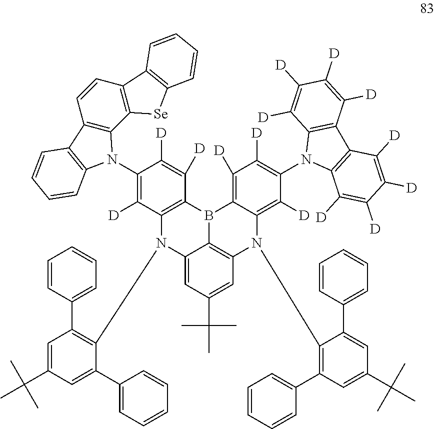 [SMILES: [2H]c1c([2H])c(-n2c3c([2H])c([2H])c([2H])c([2H])c3c3c([2H])c([2H])c([2H])c([2H])c32)c([2H])c2c1B1c3c(cc(C(C)(C)C)cc3N(c3c(-c4ccccc4)cc(C(C)(C)C)cc3-c3ccccc3)c3c([2H])c(-n4c5ccccc5c5ccc6c7ccccc7[se]c6c54)c([2H])c([2H])c31)N2c1c(-c2ccccc2)cc(C(C)(C)C)cc1-c1ccccc1]

### Comparative Example Compounds

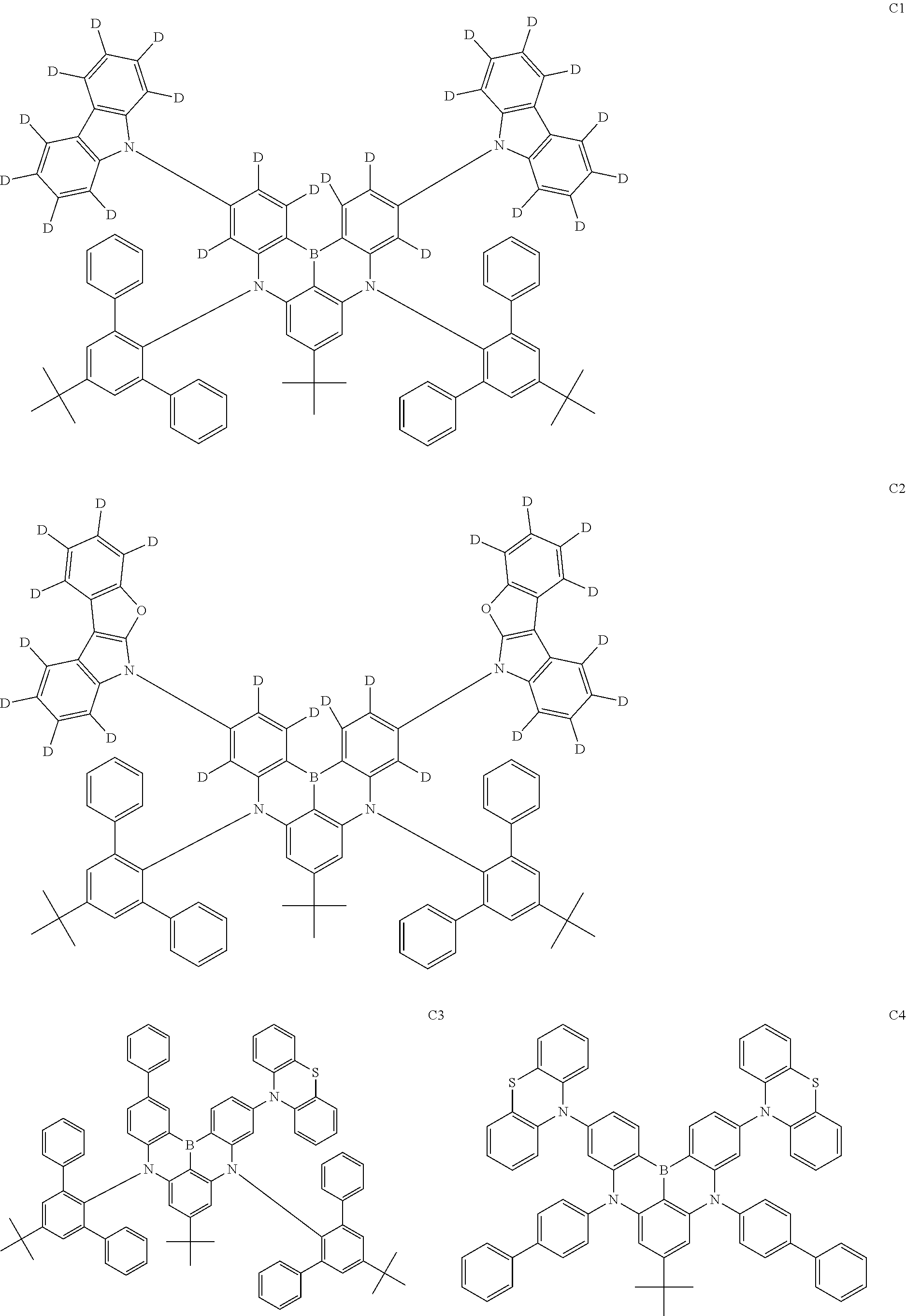

### Manufacture of Light Emitting Elements

In the light emitting elements of Examples and Comparative Examples, a glass substrate (made by Corning Co.), on which an ITO electrode of about 15 Ω/cm² (about 1200 Å) had been formed as an anode, was cut to a size of about 50 mm×50 mm×0.7 mm, cleansed by ultrasonic waves using isopropyl alcohol and pure water for about five minutes each, and irradiated with ultraviolet rays for about 30 minutes and exposed to ozone and cleansed. The glass substrate was installed on a vacuum deposition apparatus.

NPD was deposited on the upper portion of the anode to form a 300 Å-thick hole injection layer, H-1-19 was deposited on the upper portion of the hole injection layer to form a 200 Å-thick hole transport layer, and CzSi was deposited on the upper portion of the hole transport layer to form a 100 Å-thick emission-auxiliary layer.

The host in which the second compound (HT33) as a hole transporting host and the third compound (ETH66) as an electron transporting host were mixed in a ratio of about 1:1, the fourth compound (AD-39) as a sensitizer, and an Example Compound or a Comparative Example Compound were co-deposited in a weight ratio of about 85:14:1 to form a 200 Å-thick emission layer, and on the upper portion of the emission layer, TSPO1 was deposited to form a 200 Å-thick hole blocking layer. On the upper portion of the hole blocking layer, TPBI was deposited to form a 300 Å-thick electron transport layer, and on the upper portion of the electron transport layer, LiF was deposited to form a 10 Å-thick electron injection layer. On the electron injection layer, Al was deposited to form a 3,000 Å-thick cathode. Compound P4 was deposited on the upper portion of the cathode to form a 700 Å-thick capping layer, thereby manufacturing a light emitting element. Each layer was formed by a vacuum deposition method.

Compounds used for manufacturing the light emitting elements of Examples and Comparative Examples are disclosed below. The materials below were used to manufacture the devices by subjecting commercial products to sublimation purification.

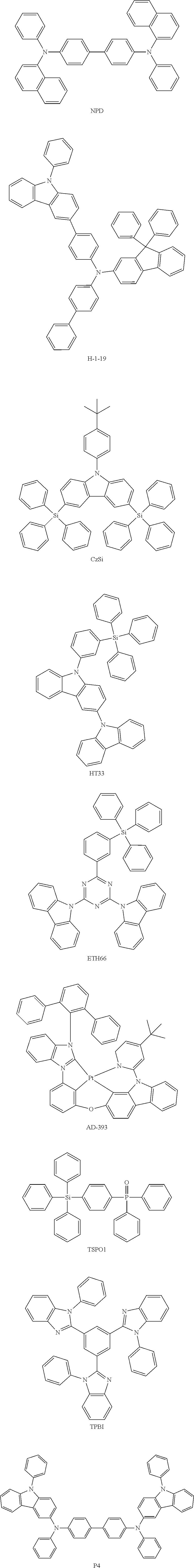

### (2) Evaluation of Compound and Light Emitting Element Characteristics

### Evaluation of Compound Characteristics

With respect to Example Compounds 7, 9, 10, 38, 61, 65, 69, 73, 81, 82, and 83 and Comparative Example Compounds C1 to C4 as described above, the lowest excited singlet energy level (S1), the lowest excited triplet energy level (T1), and the maximum emission wavelength (λₘₐₓ) were measured using FluorEssence software while xenon light source and monochromator were installed in fluoromax+ spectrometer equipment manufactured by HORIBA Co., Ltd., and ΔE_{ST}, which is a difference between the lowest excited singlet energy level (S1) and the lowest excited triplet energy level (T1), was calculated. A rate constant (k_{RISC}) of the reverse intersystem crossing was calculated from the equation, k_{RISC}=Φ_{d}/(k_{ISC}*τₚ*τ_{d}*Φₚ), wherein each factor in the equation was measured by depositing a single film on a glass substrate to a thickness of about 40 nm by vacuum deposition, and using the following method. Φ_{d} and Φₚ were measured with Quantaurus-QY measurement system (C11347-11, Hamamatsu Photonics) equipment, and τ_{d} and τₚ were measured using Quantaurus-Tau fluorescence lifetime measurement system (C11367-03, Hamamatsu Photonics). The spin-orbit coupling matrix element (SOC) calculated the structure of the second stable triplet excited state through the calculation of unrestricted density functional theory (UDFT) and calculated the energy corresponding to the calculated structure. The UDFT calculation was performed using Gaussian09, which is a commercial program, and a 6-311G(d,p) basis function and a B3LYP exchange-correlation function were used. The maximum absorption wavelength (λ_{abs}) was measured by using Labsolution UV-Vis software while Deuterium/Tungsten-Halogen light source and silicon photodiode were installed in UV-1800 UV/Visible Scanning Spectrophotometer (SHIMADZU, Co.) equipment, and stokes-shift, which is a difference between the maximum absorption wavelength (λ_{abs}) and the maximum emission wavelength (λₘₐₓ), was calculated. The results from the measurement and calculation are listed in Table 2.

TABLE 2

| | | | | | | Maximum | Maximum | |
|---|---|---|---|---|---|---|---|---|
| | | | | | | absorption | emission | Stokes- |
| | S1 | T1 | ΔE_{ST} | k_{rISC} | SOC | wavelength | wavelength | shift |
| Compound | (eV) | (eV) | (eV) | (s⁻¹) | (cm⁻¹) | (λ_{abs}, nm) | (λₘₐₓ, nm) | (nm) |
| Compound 7 | 2.71 | 2.59 | 0.12 | 3.4*10⁻⁷ | 0.064 | 452 | 463 | 11 |
| Compound 9 | 2.70 | 2.60 | 0.10 | 0.9*10⁻¹¹ | 1.114 | 453 | 463 | 10 |
| Compound 10 | 2.70 | 2.60 | 0.10 | 1.1*10⁻¹³ | 1.847 | 453 | 465 | 12 |
| Compound 38 | 2.69 | 2.55 | 0.14 | 1.4*10⁻¹¹ | 1.321 | 455 | 465 | 10 |
| Compound 61 | 2.71 | 2.58 | 0.13 | 8.9*10⁻¹⁰ | 1.091 | 451 | 464 | 13 |
| Compound 65 | 2.68 | 2.57 | 0.11 | 1.1*10⁻¹¹ | 1.209 | 454 | 466 | 12 |
| Compound 69 | 2.71 | 2.59 | 0.12 | 9.4*10⁻⁹ | 0.843 | 448 | 459 | 11 |
| Compound 73 | 2.71 | 2.59 | 0.12 | 8.5*10⁻⁹ | 0.719 | 449 | 459 | 10 |
| Compound 81 | 2.70 | 2.58 | 0.12 | 2.7*10⁻⁷ | 0.091 | 450 | 459 | 9 |
| Compound 82 | 2.71 | 2.59 | 0.12 | 1.2*10⁻¹¹ | 1.009 | 451 | 461 | 10 |
| Compound 83 | 2.71 | 2.61 | 0.10 | 0.7*10⁻¹¹ | 0.994 | 450 | 459 | 9 |
| Comparative | 2.71 | 2.58 | 0.13 | 1.2*10⁻⁵ | 0.021 | 446 | 458 | 12 |
| Example | | | | | | | | |
| Compound C1 | | | | | | | | |
| Comparative | 2.70 | 2.58 | 0.12 | 1.7*10⁻⁵ | 0.018 | 450 | 462 | 12 |
| Example | | | | | | | | |
| Compound C2 | | | | | | | | |
| Comparative | 2.65 | 2.48 | 0.17 | 1.4*10⁻⁴ | 0.015 | 455 | 473 | 18 |
| Example | | | | | | | | |
| Compound C3 | | | | | | | | |
| Comparative | 2.62 | 2.42 | 0.20 | 1.2*10⁻⁴ | 0.012 | 462 | 485 | 23 |
| Example | | | | | | | | |
| Compound C4 | | | | | | | | |

### Evaluation of Light Emitting Element Characteristics

Element efficiencies and element service lives of the light emitting elements manufactured with Example Compounds 7, 9, 10, 38, 61, 65, 69, 73, 81, 82, and 83 and Comparative Example Compounds C1 to C4 as described above were evaluated. Evaluation results of the light emitting elements of Examples 1 to 11 and Comparative Examples 1 to 4 are listed in Table 3. To evaluate the characteristics of the light emitting elements manufactured in Examples 1 to 7 and Comparative Examples 1 to 4 above, each of driving voltages (V), top luminous efficiencies (Cd/A/y), and emission colors at a current density of 10 mA/cm² was measured by using Keithley MU 236 and a luminance meter PR650, and the time taken to reach 95% brightness relative to an initial brightness was measured as a service life (T95), and a relative service life was calculated on the basis of the element of Comparative Example 1, and the results are listed in Table 3.

TABLE 3

| | | | | | Top | | Relative | |
|---|---|---|---|---|---|---|---|---|
| | Host (second | | | Driving | luminous | Luminous | service | Color |
| | compound:third | Fourth | First | voltage | efficiency | wavelength | life | purity |
| | compound = 5:5) | compound | compound | (V) | (cd/A/y) | (nm) | (T95) | (CIEy) |
| Example 1 | HT33/ETH66 | AD-39 | Compound 7 | 4.1 | 543.4 | 462 | 4.3 | 0.051 |
| Example 2 | HT33/ETH66 | AD-39 | Compound 9 | 4.0 | 588.9 | 462 | 7.5 | 0.051 |
| Example 3 | HT33/ETH66 | AD-39 | Compound 10 | 4.1 | 600.3 | 463 | 5.4 | 0.054 |
| Example 4 | HT33/ETH66 | AD-39 | Compound 38 | 4.0 | 611.0 | 465 | 4.9 | 0.059 |
| Example 5 | HT33/ETH66 | AD-39 | Compound 61 | 4.1 | 555.4 | 463 | 4.8 | 0.055 |
| Example 6 | HT33/ETH66 | AD-39 | Compound 65 | 4.0 | 561.5 | 465 | 5.1 | 0.058 |
| Example 7 | HT33/ETH66 | AD-39 | Compound 69 | 4.0 | 547.4 | 463 | 6.5 | 0.053 |
| Example 8 | HT33/ETH66 | AD-39 | Compound 73 | 4.0 | 555.1 | 463 | 6.2 | 0.054 |
| Example 9 | HT33/ETH66 | AD-39 | Compound 81 | 4.1 | 548.1 | 462 | 4.1 | 0.053 |
| Example 10 | HT33/ETH66 | AD-39 | Compound 82 | 4.1 | 573.0 | 462 | 6.6 | 0.051 |
| Example 11 | HT33/ETH66 | AD-39 | Compound 83 | 4.0 | 566.5 | 462 | 6.9 | 0.052 |
| Comparative | HT33/ETH66 | AD-39 | Comparative | 4.1 | 500.1 | 462 | 1 | 0.051 |
| Example 1 | | | Example | | | | | |
| | | | Compound C1 | | | | | |
| Comparative | HT33/ETH66 | AD-39 | Comparative | 4.2 | 505.5 | 463 | 1.1 | 0.053 |
| Example 2 | | | Example | | | | | |
| | | | Compound C2 | | | | | |
| Comparative | HT33/ETH66 | AD-39 | Comparative | 4.3 | 485.1 | 478 | 0.4 | 0.071 |
| Example 3 | | | Example | | | | | |
| | | | Compound C3 | | | | | |
| Comparative | HT33/ETH66 | AD-39 | Comparative | 4.1 | 470.3 | 490 | 0.2 | 0.085 |
| Example 4 | | | Example | | | | | |
| | | | Compound C4 | | | | | |

Referring to the results of Table 3, it may be confirmed that the light emitting elements of Examples in which the fused polycyclic compounds according to embodiments are used as a luminescent material have relatively high luminous efficiency compared to the light emitting elements of Comparative Examples, and driving voltage, service life characteristics, and color purity characteristics are generally improved. Example Compounds include the fused ring core in which multiple aromatic rings are fused via a boron atom and nitrogen atoms and have a structure in which the first substituent and the second substituent are linked to the fused ring core, and thus may achieve high luminous efficiency and a long service life. Example Compounds include the fused ring core in which the first to third aromatic rings are fused about the boron atom, the first nitrogen atom, and the second nitrogen atom, and the first substituent is linked to the first or second aromatic ring and the second substituent is linked to each of the first and second nitrogen atoms. The first substituent has a structure in which the first heterocycle including the third nitrogen atom, the second heterocycle including a heavy atom, and the benzene moiety are fused, and the third nitrogen atom of the first substituent and the boron atom of the fused ring core may be bonded at the para-position with respect to the first or second aromatic ring. The second substituent may include a m-terphenyl moiety. By using Example Compounds including the first substituent and second substituent as a dopant for the thermally activated delayed fluorescence (TADF) light emitting element, it is possible to achieve high element efficiency of increasing luminous efficiency and long service life in a short wavelength region, for example, a blue light wavelength region.

Referring to the results of Table 2 and Table 3, Comparative Example Compounds C1, C2, and C3 include a planar skeleton structure having one boron atom, and two nitrogen atoms in the center, and a second substituent linked to the first and second nitrogen atoms, but the planar skeleton does not include the first substituent as described above, and thus it is understood that the ΔE_{ST} and SOC values are generally low and the reverse intersystem crossing speed is relatively slow. Accordingly, it may be confirmed that Comparative Example 1, Comparative Example 2, and Comparative Example 3 including Comparative Example Compound C1, Comparative Example Compound C2, and Comparative Example Compound C3, respectively, have a relatively high driving voltage value compared to Example Compounds, and the luminous efficiency and element service life are deteriorated. Comparative Example Compound C1 includes a carbazole moiety without a heavy atom rather than the first substituent, Comparative Example Compound C2 includes a fused structure including an oxygen atom (O) rather than the first substituent, and Comparative Example Compound C3 includes a hetero hexagonal ring including a nitrogen atom and a heavy atom in a single ring rather than the first substituent, and thus the light emitting elements of Comparative Example 1, Comparative Example 2, and Comparative Example 3 including Comparative Example Compound C1, Comparative Example Compound C2, and Comparative Example Compound C3, respectively, are considered to have the deterioration in the luminous efficiency and element service life.

Comparative Example Compound C4 includes a planar skeleton structure having one boron atom and two nitrogen atoms in the center, but the planar skeleton does not include the first and second substituents as described above, and thus it is understood that the ΔE_{ST} and SOC values are generally low, the reverse intersystem crossing speed is relatively slow, and the stokes-shift is increased. Accordingly, it may be confirmed that the light emitting element of Comparative Example 4 includes Comparative Example Compound C4 has a relatively high driving voltage value compared to the elements including Example Compounds, has the deterioration in the luminous efficiency and element service life, and has low blue purity, thereby emitting blue light close to green. Comparative Example Compound C4 includes a hetero hexagonal ring including a nitrogen atom and a heavy atom in a single ring rather than the first substituent, and a biphenyl group rather than the second substituent, and thus is considered to have the deterioration in the characteristics of the element of Comparative Example 4 including Comparative Example Compound C4.

The light emitting element according to an embodiment may exhibit improved element characteristics with high efficiency and a long service life.

The fused polycyclic compound according to an embodiment may be included in the emission layer of the light emitting element to contribute to high efficiency and a long service life of the light emitting element.

Embodiments have been disclosed herein, and although terms are employed, they are used and are to be interpreted in a generic and descriptive sense only and not for purposes of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting element comprising:
a first electrode;
a second electrode disposed on the first electrode; and
at least one functional layer disposed between the first electrode and the second electrode and comprising a first compound represented by Formula 1: 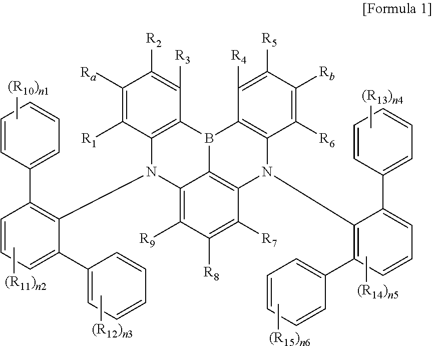
wherein in Formula 1,
R₁ to R₁₅ are each independently a hydrogen atom, a deuterium atom, a halogen atom, a cyano group, a hydroxy group, a substituted or unsubstituted oxy group, a substituted or unsubstituted thio group, a substituted or unsubstituted boron group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
Rₐ and R_{b} are each independently a substituted or unsubstituted heteroaryl group having 2 to 30 ring-forming carbon atoms and a nitrogen atom (N) as a ring-forming atom, or a group represented by Formula 2,
at least one of Rₐ and R_{b} is a group represented by Formula 2,
n1, n3, n4, and n6 are each independently an integer from 0 to 5, and
n2 and n5 are each independently an integer from 0 to 3: 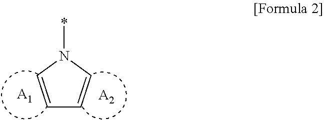
wherein in Formula 2,
A₁ and A₂ are each independently a substituted or unsubstituted hydrocarbon ring having 6 to 30 ring-forming carbon atoms, or a substituted or unsubstituted heterocycle having 2 to 30 ring-forming carbon atoms,
at least one of A₁ and A₂ is a heterocycle including, as a ring-forming atom, at least one of a sulfur atom (S), a selenium atom (Se), and a tellurium atom (Te), and [symbol]
is a position linked to Formula 1.

2. The light emitting element of claim 1, wherein
the at least one functional layer comprises:
an emission layer;
a hole transport region disposed between the first electrode and the emission layer; and
an electron transport region disposed between the emission layer and the second electrode, and
the emission layer comprises the first compound.

3. The light emitting element of claim 2, wherein the emission layer emits delayed fluorescence having a central wavelength in a range of about 430 nm to about 490 nm.

4. The light emitting element of claim 1, wherein
R₁ to R₇ and R₉ are each independently a hydrogen atom or a deuterium atom, and
R₈ is a substituted or unsubstituted alkyl group having 1 to 4 carbon atoms, a substituted or unsubstituted aryl group having 6 to 30 ring-forming carbon atoms, or a substituted or unsubstituted heteroaryl group having 2 to 30 ring-forming carbon atoms.

5. The light emitting element of claim 1, wherein R₁₀ to R₁₅ are each independently a hydrogen atom, a deuterium atom, a halogen atom, a cyano group, a substituted or unsubstituted alkyl group having 1 to 4 carbon atoms, or a substituted or unsubstituted aryl group having 6 to 12 ring-forming carbon atoms.

6. The light emitting element of claim 1, wherein the first compound is represented by Formula 1-1: 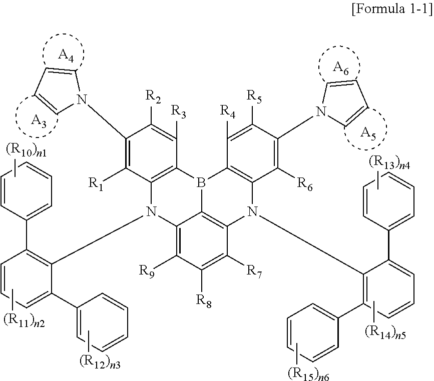
wherein in Formula 1-1,
A₃, A₄, A₅, and A₆ are each independently a substituted or unsubstituted hydrocarbon ring having 6 to 30 ring-forming carbon atoms or a substituted or unsubstituted heterocycle having 2 to 30 ring-forming carbon atoms,
at least one of A₃, A₄, A₅, and A₆ is a heterocycle including, as a ring-forming atom, at least one of a sulfur atom (S), a selenium atom (Se), and a tellurium atom (Te), and
R₁ to R₁₅ and n1 to n6 are the same as defined in Formula 1.

7. The light emitting element of claim 1, wherein the group represented by Formula 2 is a group represented by one of Formula 2-1 to Formula 2-4: 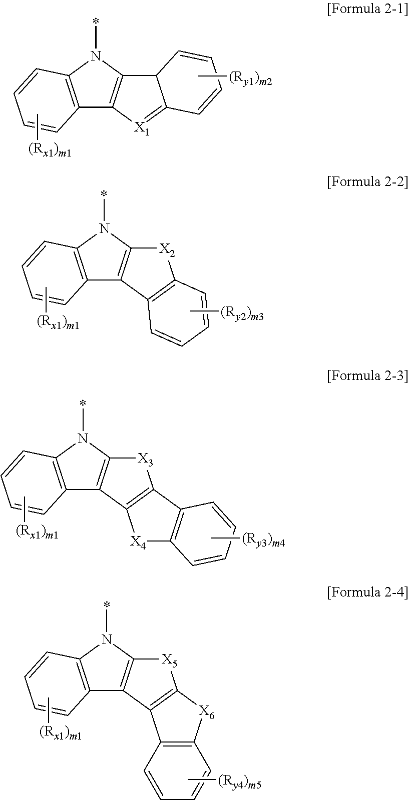
wherein in Formula 2-1 to Formula 2-4,
Rₓ₁ and R_{y1} to R_{y4} are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
λ₁ to λ₆ are each independently a sulfur atom (S), a selenium atom (Se), or a tellurium atom (Te),
m1 to m5 are each independently an integer from 0 to 4, and [symbol]
is a position linked to Formula 1.

8. The light emitting element of claim 7, wherein Rₓ₁ and R_{y1} to R_{y4} are each independently a hydrogen atom, a deuterium atom, a halogen atom, a cyano group, a substituted or unsubstituted alkyl group having 1 to 4 carbon atoms, or a substituted or unsubstituted aryl group having 6 to 12 ring-forming carbon atoms.

9. The light emitting element of claim 1, wherein the group represented by Formula 2 is a group represented by Formula 3: 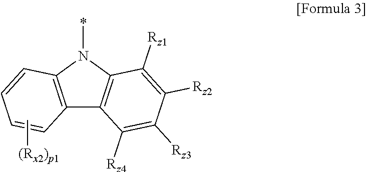
wherein in Formula 3,
Rₓ₂ is a hydrogen atom, a deuterium atom, a halogen atom, a cyano group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
R_{z1} to R_{z4} are each independently a hydrogen atom, a deuterium atom, a thio group, a selenyl group, a tellanyl group, a substituted or unsubstituted aryl group having 6 to 30 ring-forming carbon atoms, or a substituted or unsubstituted heteroaryl group having 2 to 30 ring-forming carbon atoms,
one of R_{z1} to R_{z4} is a thio group, a selenyl group, or a tellanyl group, and is bonded to an adjacent group among the remainder of R_{z1} to R_{z4} to form a ring,
p1 is an integer from 0 to 4, and [symbol]
is a position linked to Formula 1.

10. The light emitting element of claim 9, wherein the group represented by Formula 3 is a group represented by one of Formula 3-1 to Formula 3-6: 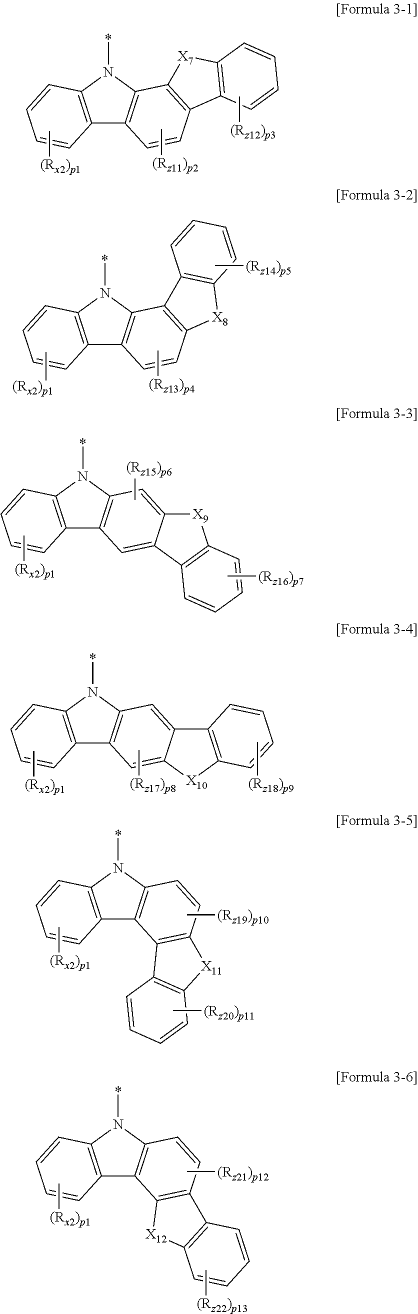
wherein in Formula 3-1 to Formula 3-6,
R_{z11} to R_{z22} are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
λ₇ to λ₁₂ are each independently a sulfur atom (S), a selenium atom (Se), or a tellurium atom (Te),
p2, p4, p6, p8, p10, and p12 are each independently an integer from 0 to 2,
p3, p5, p7, p9, p11, and p13 are each independently an integer from 0 to 4, and
Rₓ₂, p1, and [symbol] are the same as defined in Formula 3.

11. The light emitting element of claim 10, wherein R_{z11} to R_{z22} are each independently a hydrogen atom, a deuterium atom, a halogen atom, a cyano group, a substituted or unsubstituted alkyl group having 1 to 4 carbon atoms, or a substituted or unsubstituted aryl group having 6 to 12 ring-forming carbon atoms.

12. The light emitting element of claim 1, wherein the first compound comprises at least one compound selected from Compound Group 1: 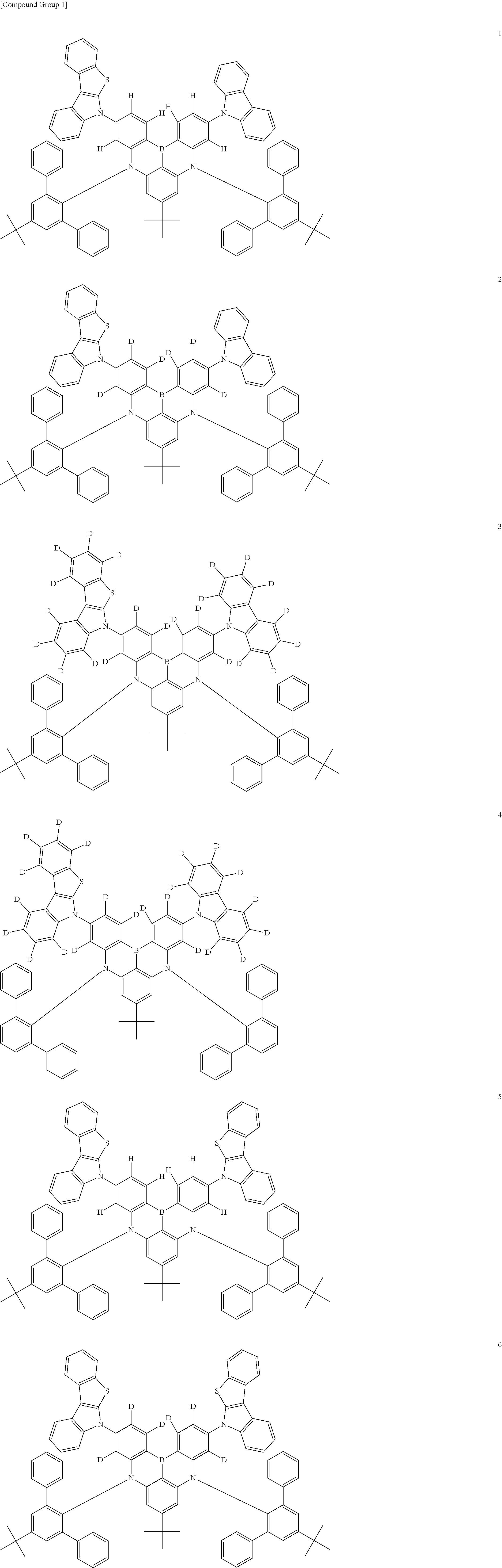 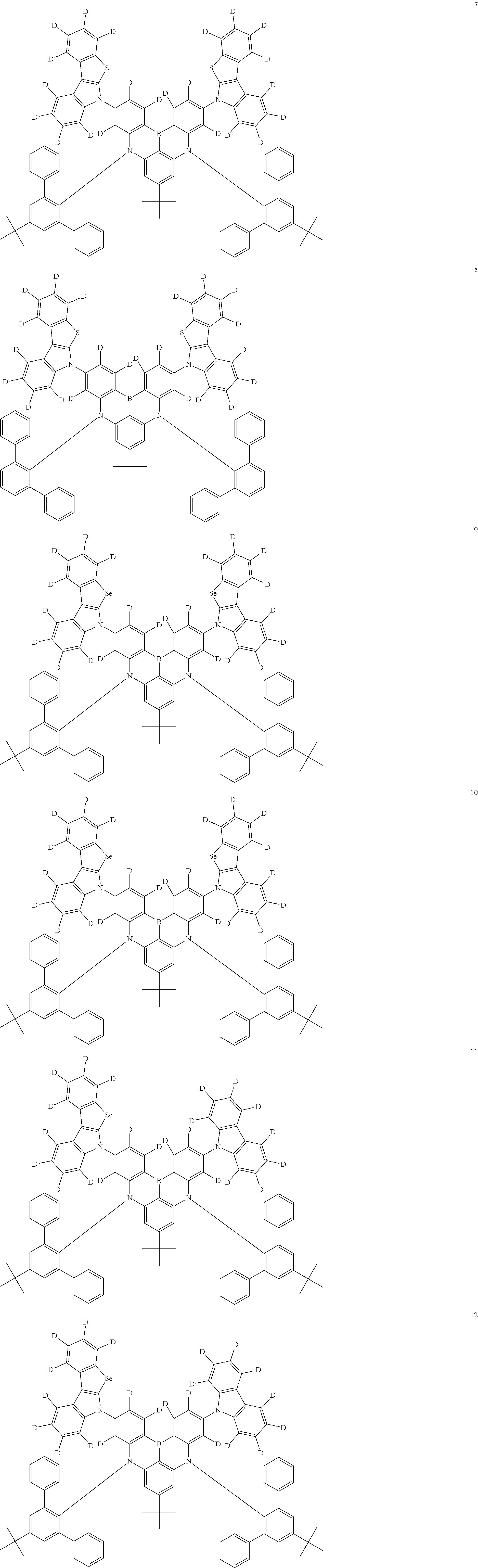 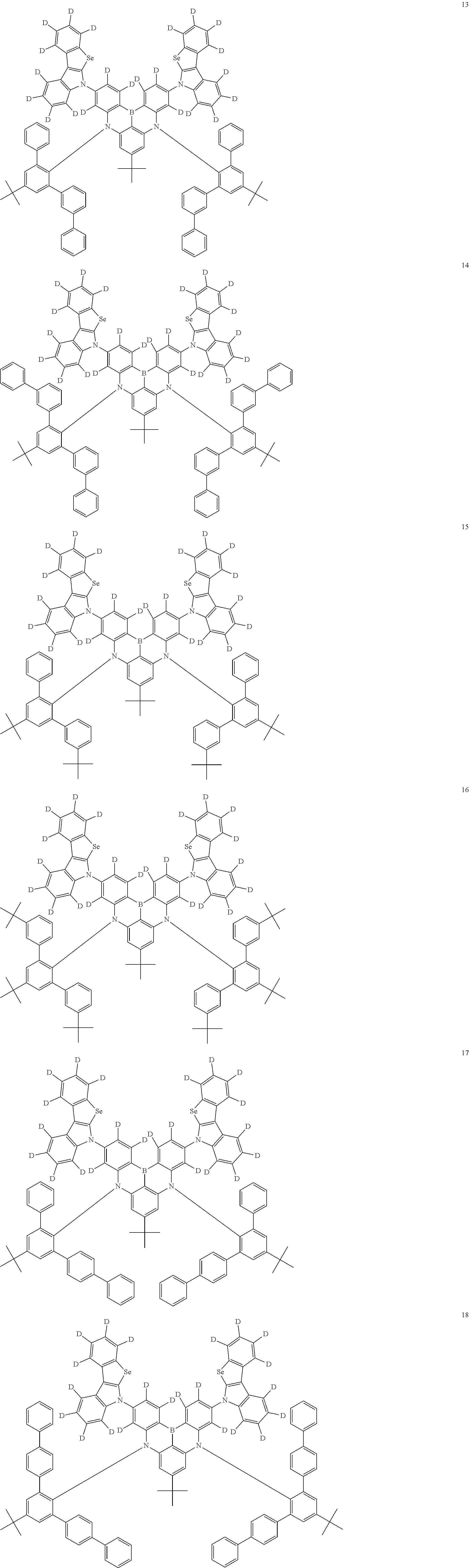 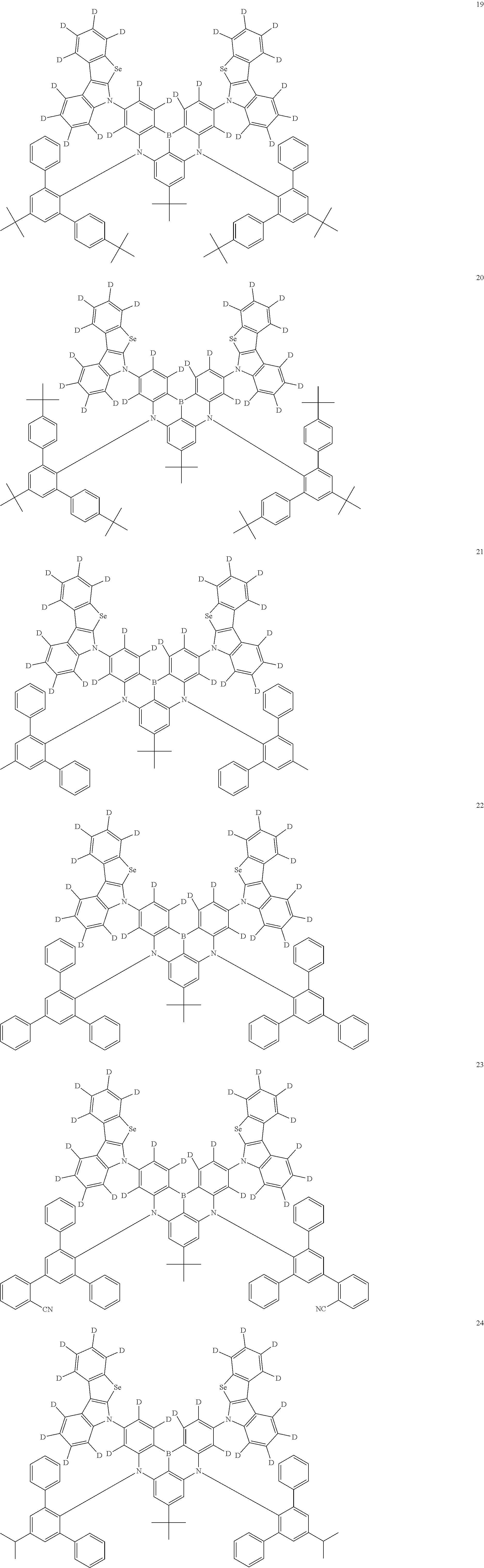 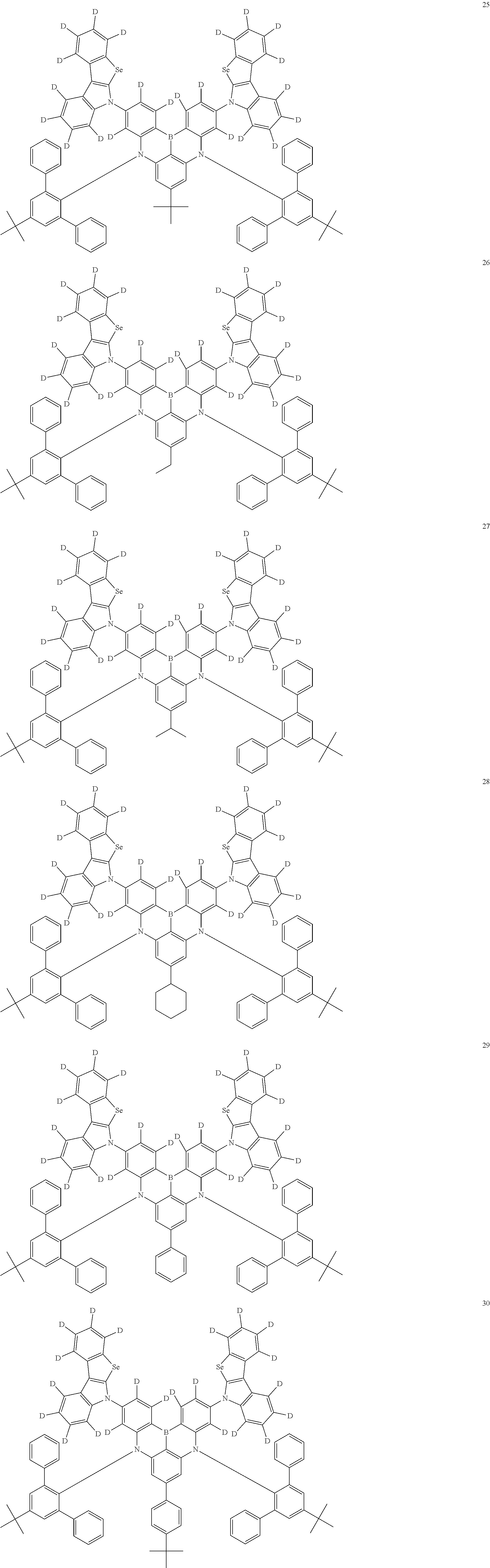 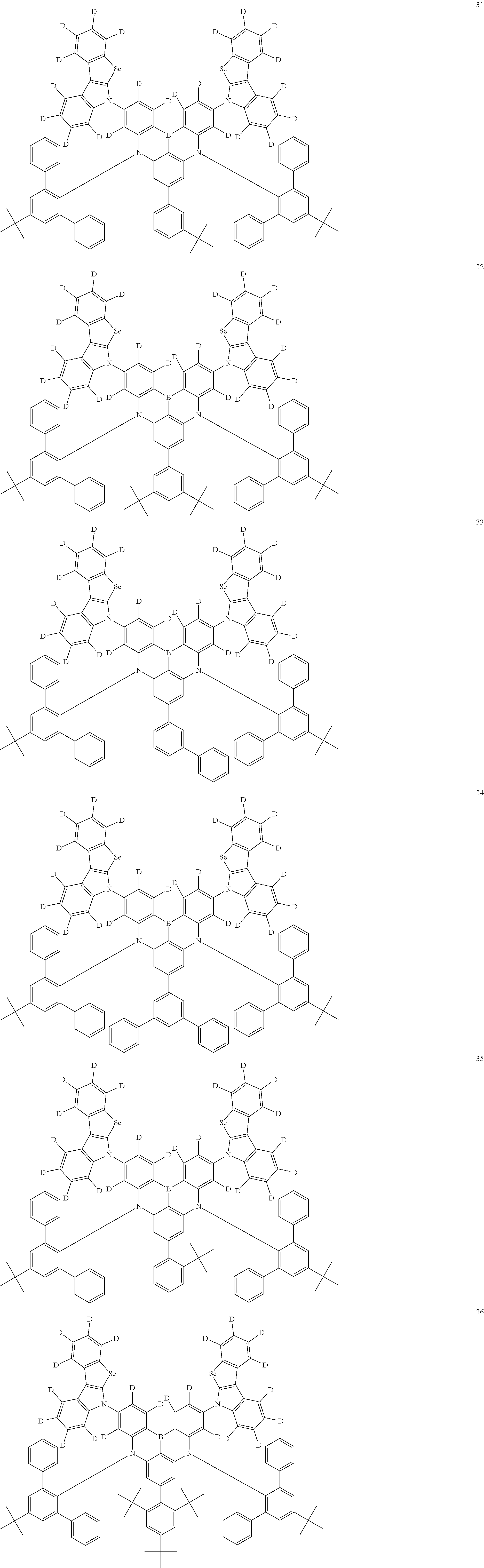 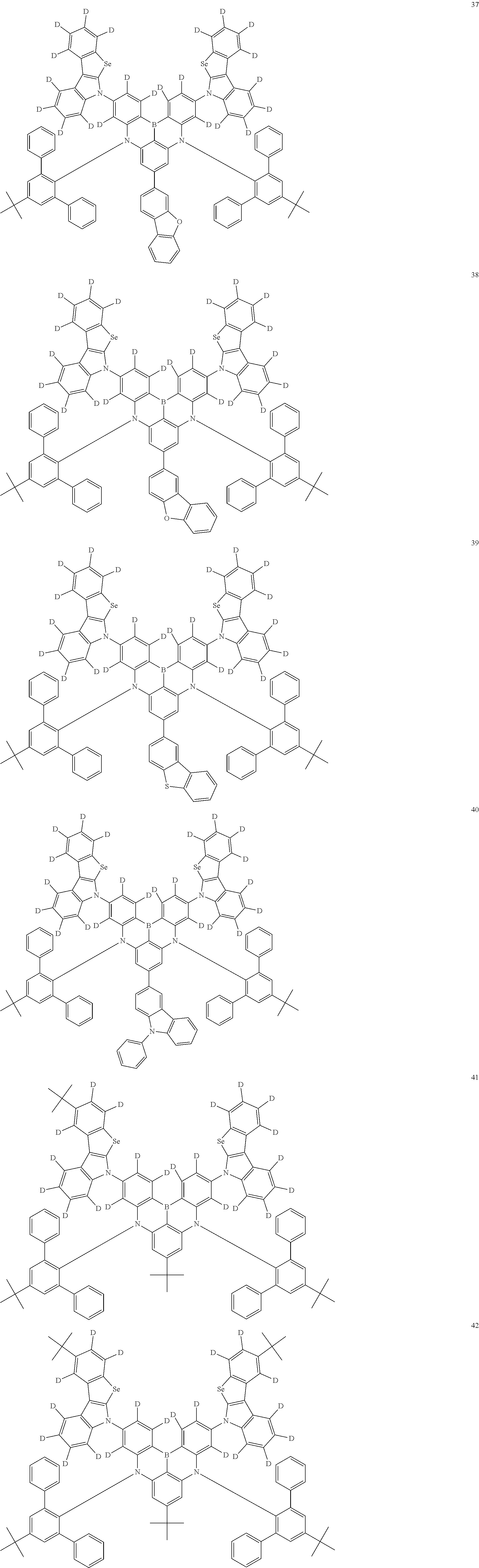 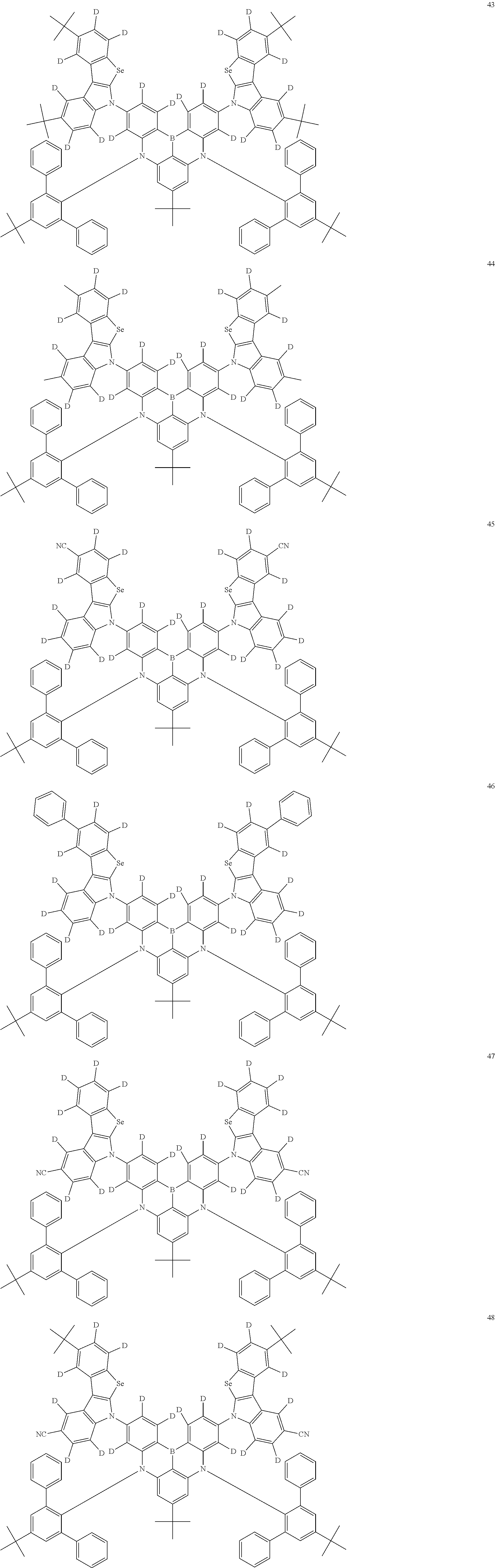 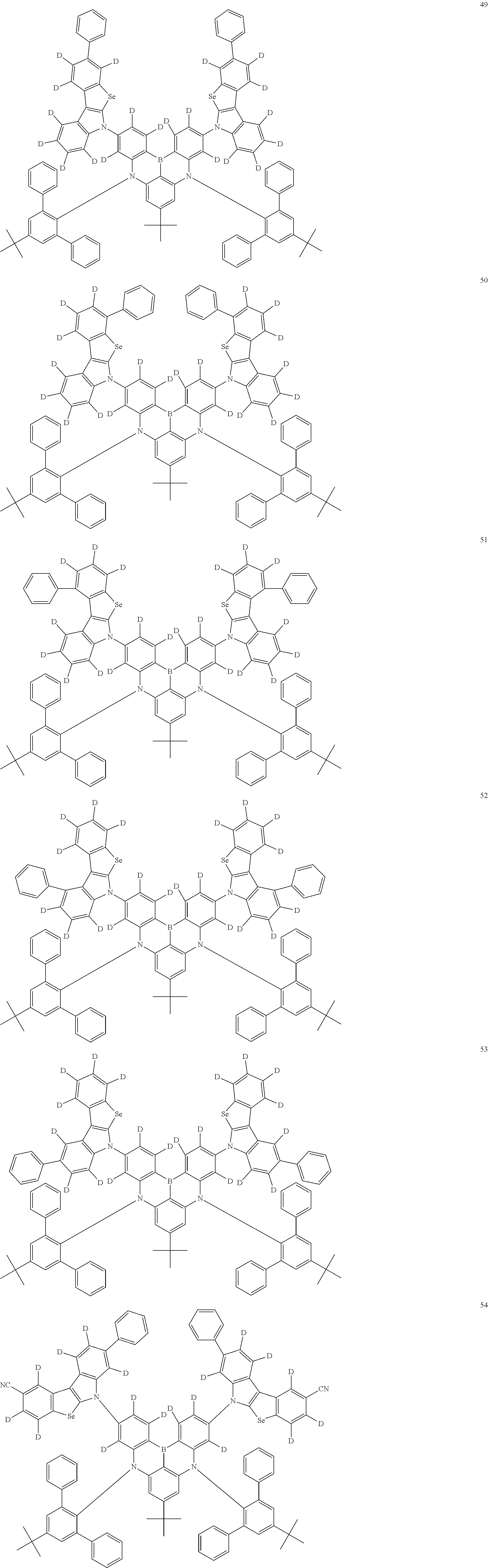 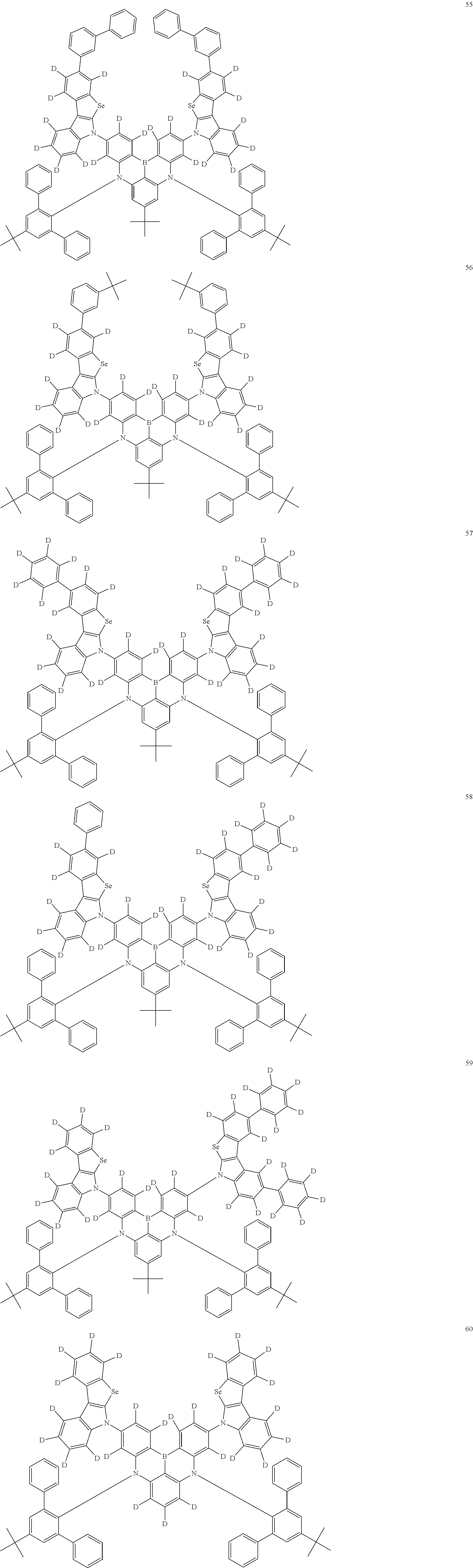 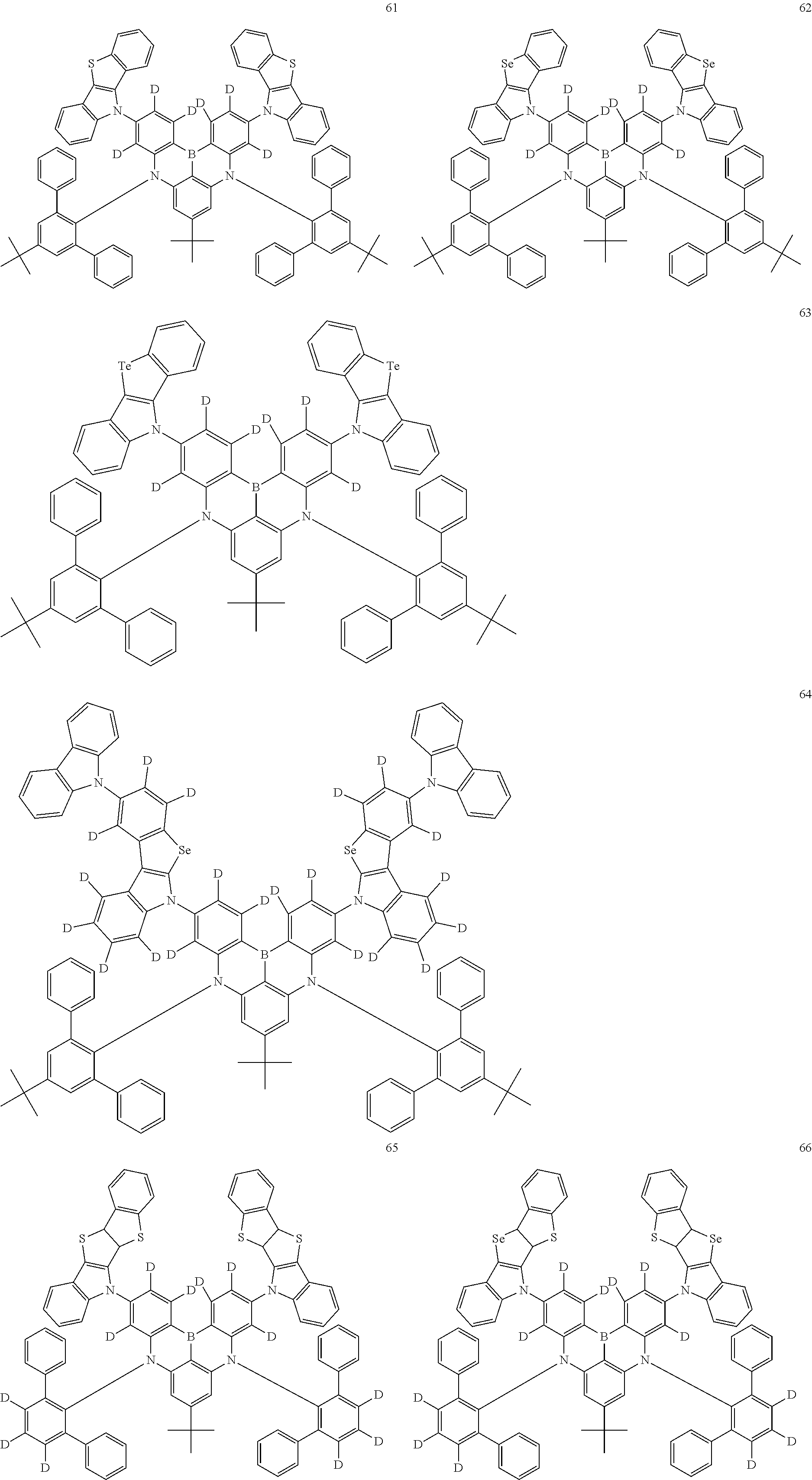 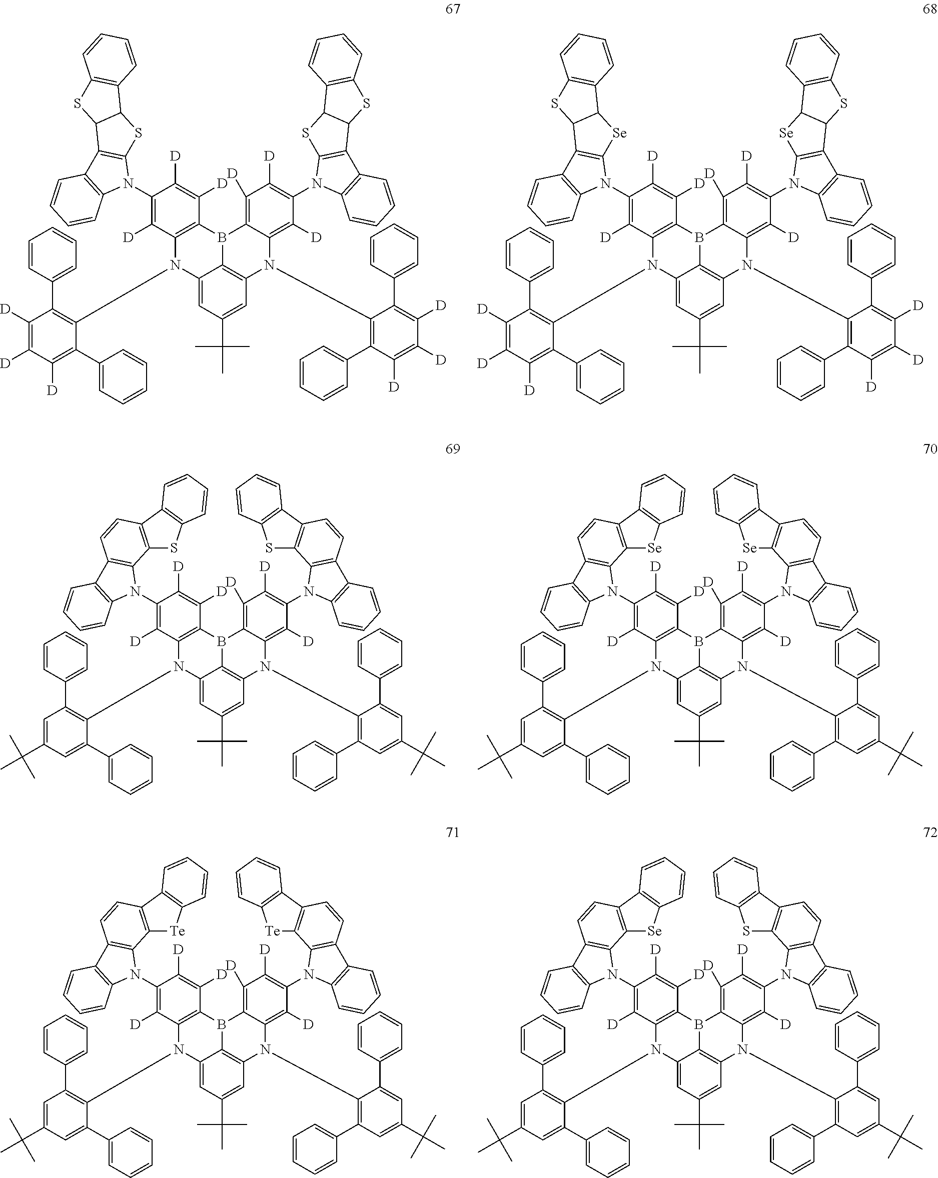 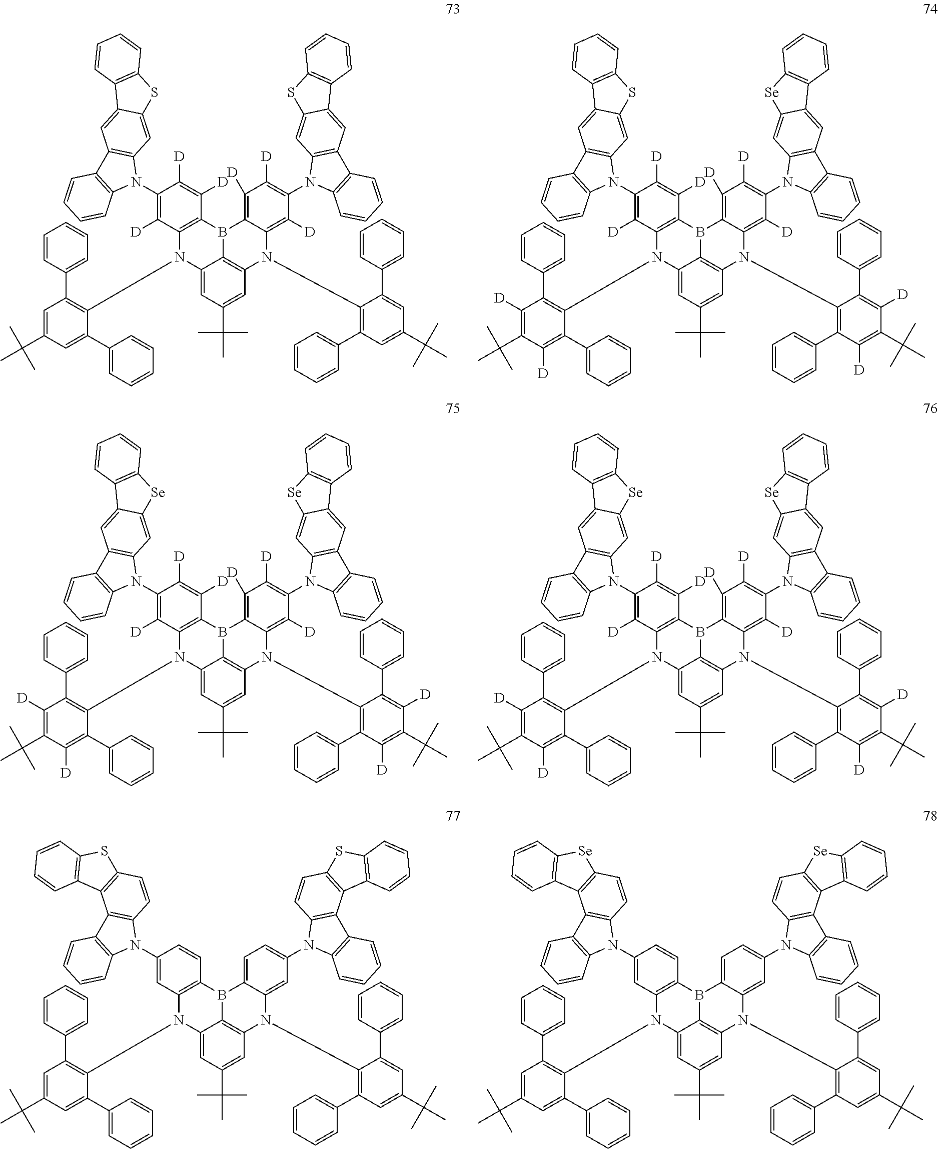 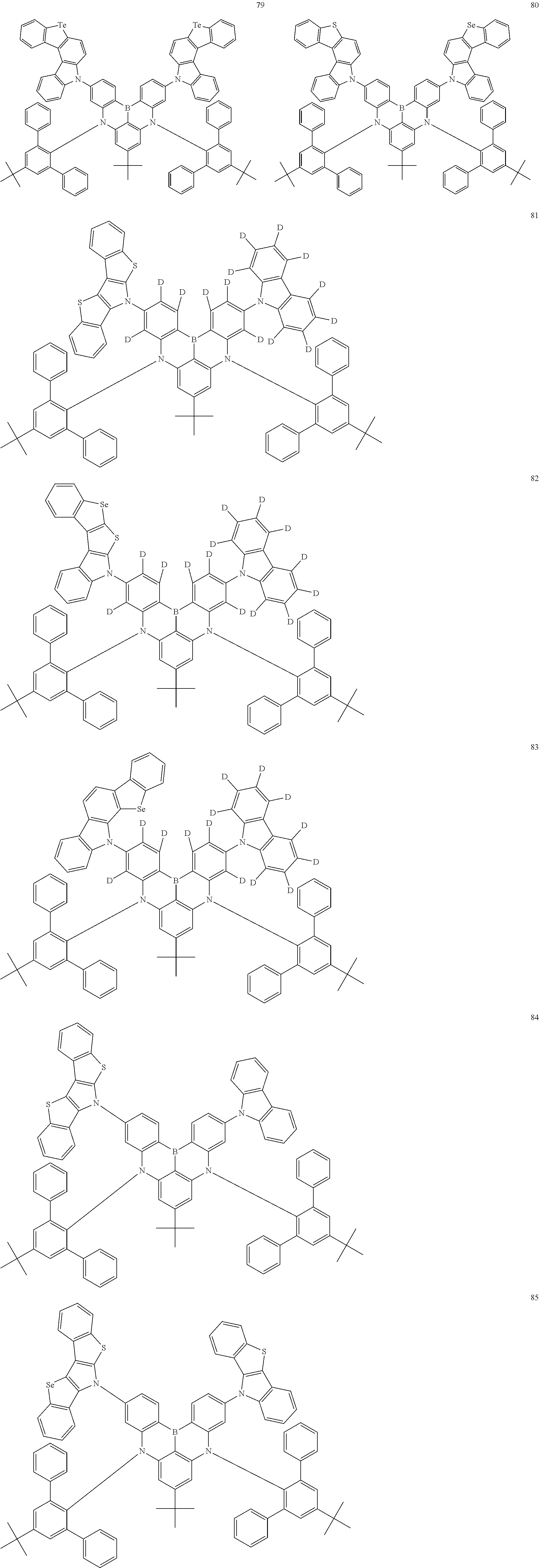 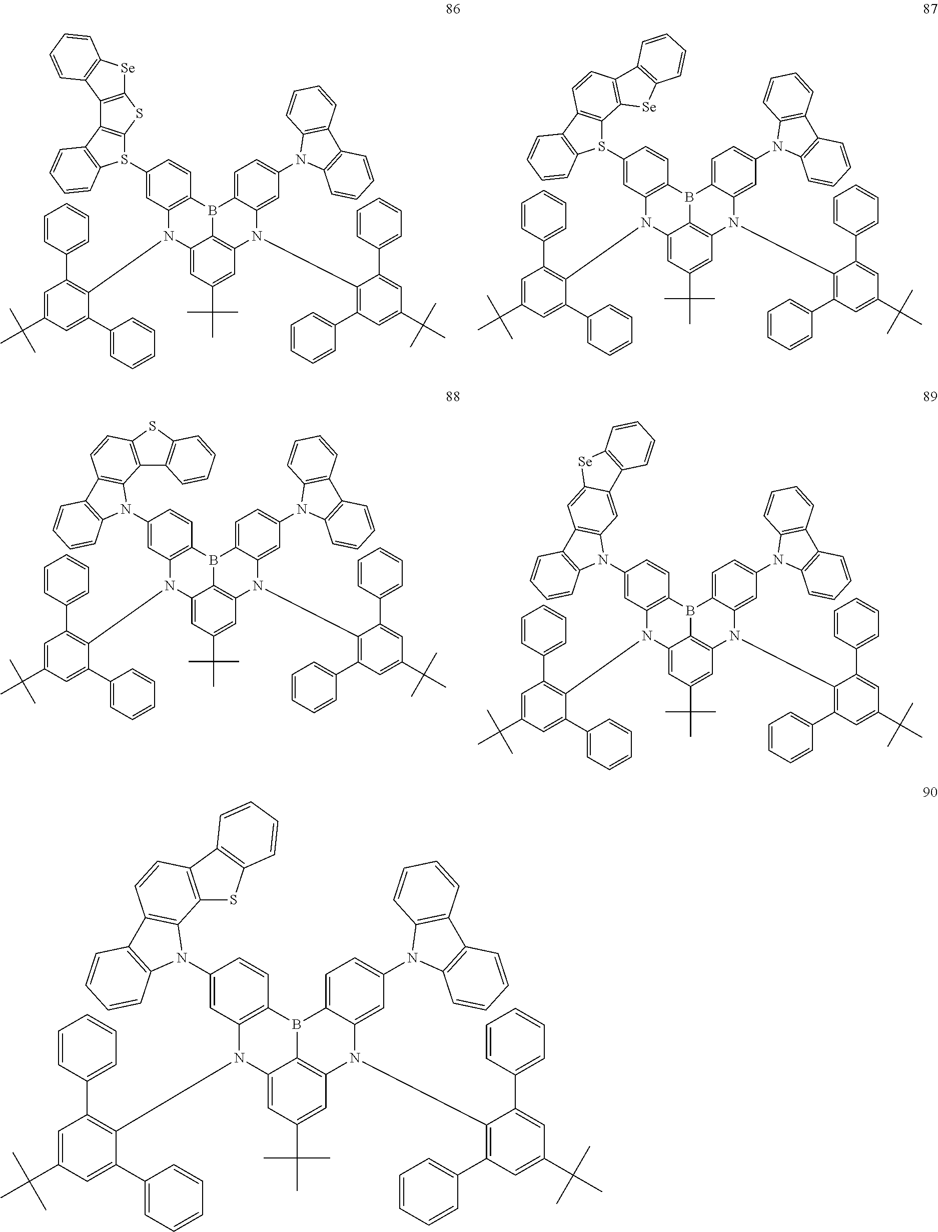
wherein in Compound Group 1,
D is a deuterium atom, and
H is a hydrogen atom.

13. A fused polycyclic compound represented by Formula 1: 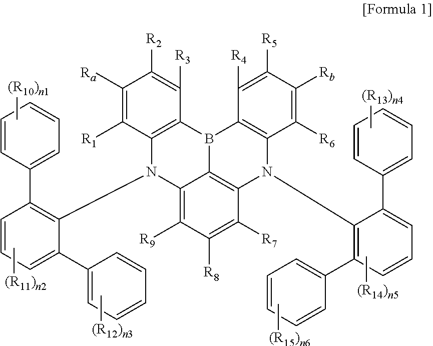
wherein in Formula 1,
R₁ to R₁₅ are each independently a hydrogen atom, a deuterium atom, a halogen atom, a cyano group, a hydroxy group, a substituted or unsubstituted oxy group, a substituted or unsubstituted thio group, a substituted or unsubstituted boron group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
Rₐ and R_{b} are each independently a substituted or unsubstituted heteroaryl group having 2 to 30 ring-forming carbon atoms and a nitrogen atom (N) as a ring-forming atom, or a group represented by Formula 2,
at least one of Rₐ and R_{b} is a group represented by Formula 2,
n1, n3, n4, and n6 are each independently an integer from 0 to 5, and
n2 and n5 are each independently an integer from 0 to 3: 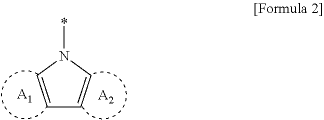
wherein in Formula 2,
A₁ and A₂ are each independently a substituted or unsubstituted hydrocarbon ring having 6 to 30 ring-forming carbon atoms or a substituted or unsubstituted heterocycle having 2 to 30 ring-forming carbon atoms,
at least one of A₁ and A₂ is a heterocycle including, as a ring-forming atom, at least one of a sulfur atom (S), a selenium atom (Se), and a tellurium atom (Te), and [symbol]
is a position linked to Formula 1.

14. The fused polycyclic compound of claim 13, wherein
R₁ to R₇ and R₉ are each independently a hydrogen atom or a deuterium atom, and
R₈ is a substituted or unsubstituted alkyl group having 1 to 4 carbon atoms, a substituted or unsubstituted aryl group having 6 to 30 ring-forming carbon atoms, or a substituted or unsubstituted heteroaryl group having 2 to 30 ring-forming carbon atoms.

15. The fused polycyclic compound of claim 13, wherein R₁₀ to R₁₅ are each independently a hydrogen atom, a deuterium atom, a halogen atom, a cyano group, a substituted or unsubstituted alkyl group having 1 to 4 carbon atoms, or a substituted or unsubstituted aryl group having 6 to 12 ring-forming carbon atoms.

16. The fused polycyclic compound of claim 13, wherein the fused polycyclic compound represented by Formula 1 is represented by Formula 1-1: 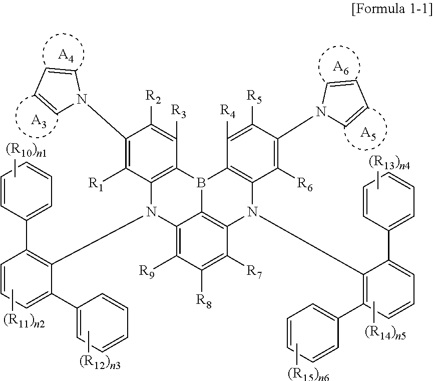
wherein in Formula 1-1,
A₃, A₄, A₅, and A₆ are each independently a substituted or unsubstituted hydrocarbon ring having 6 to 30 ring-forming carbon atoms or a substituted or unsubstituted heterocycle having 2 to 30 ring-forming carbon atoms,
at least one of A₃, A₄, A₅, and A₆ is a heterocycle including, as a ring-forming atom, at least one of a sulfur atom (S), a selenium atom (Se), and a tellurium atom (Te), and
R₁ to R₁₅ and n1 to n6 are the same as defined in Formula 1.

17. The fused polycyclic compound of claim 13, wherein the group represented by Formula 2 is a group represented by one of Formula 2-1 to Formula 2-4: 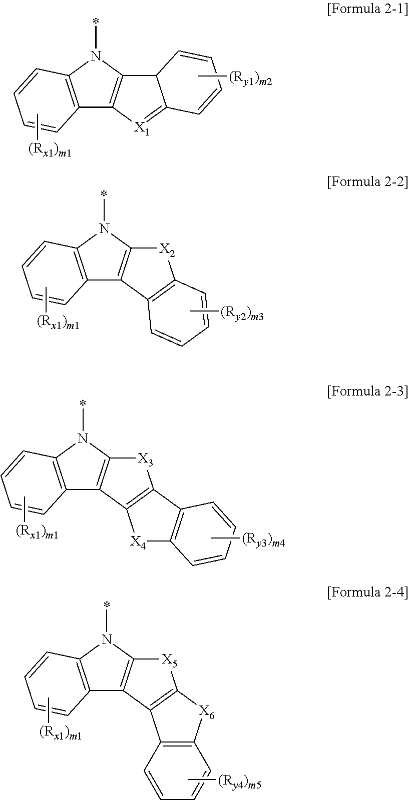
wherein in Formula 2-1 to Formula 2-4,
Rₓ₁ and R_{y1} to R_{y4} are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
λ₁ to λ₆ are each independently a sulfur atom (S), a selenium atom (Se), or a tellurium atom (Te),
m1 to m5 are each independently an integer from 0 to 4, and [symbol]
is a position linked to Formula 1.

18. The fused polycyclic compound of claim 13, wherein the group represented by Formula 2 is a group represented by one of Formula 3-1 to Formula 3-6: 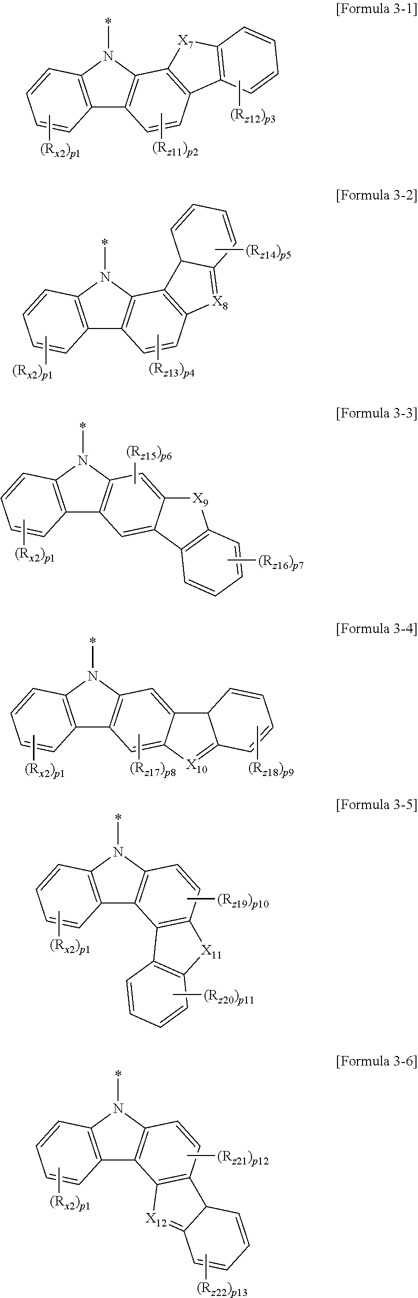
wherein in Formula 3-1 to Formula 3-6,
Rₓ₂ and R_{z11} to R_{z22} are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
λ₇ to λ₁₂ are each independently a sulfur atom (S), a selenium atom (Se), or a tellurium atom (Te),
p2, p4, p6, p8, p10, and p12 are each independently an integer from 0 to 2,
p1, p3, p5, p7, p9, p11, and p13 are each independently an integer from 0 to 4, and [symbol]
is a position linked to Formula 1.

19. The fused polycyclic compound of claim 13, wherein the fused polycyclic compound represented by Formula 1 is selected from Compound Group 1: 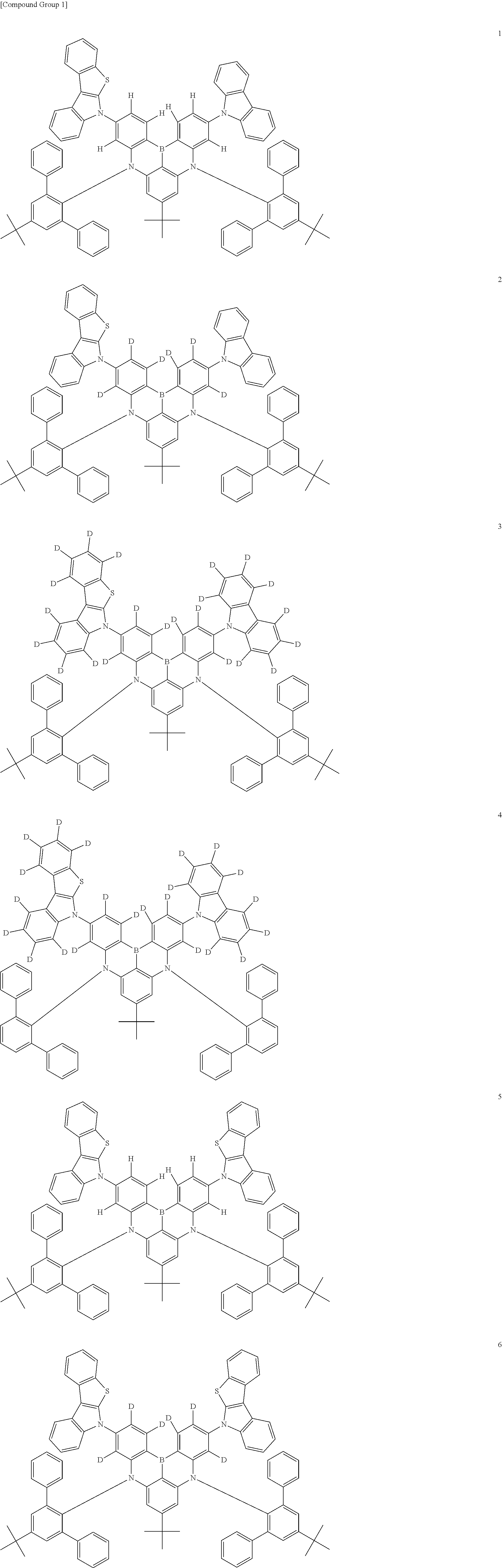 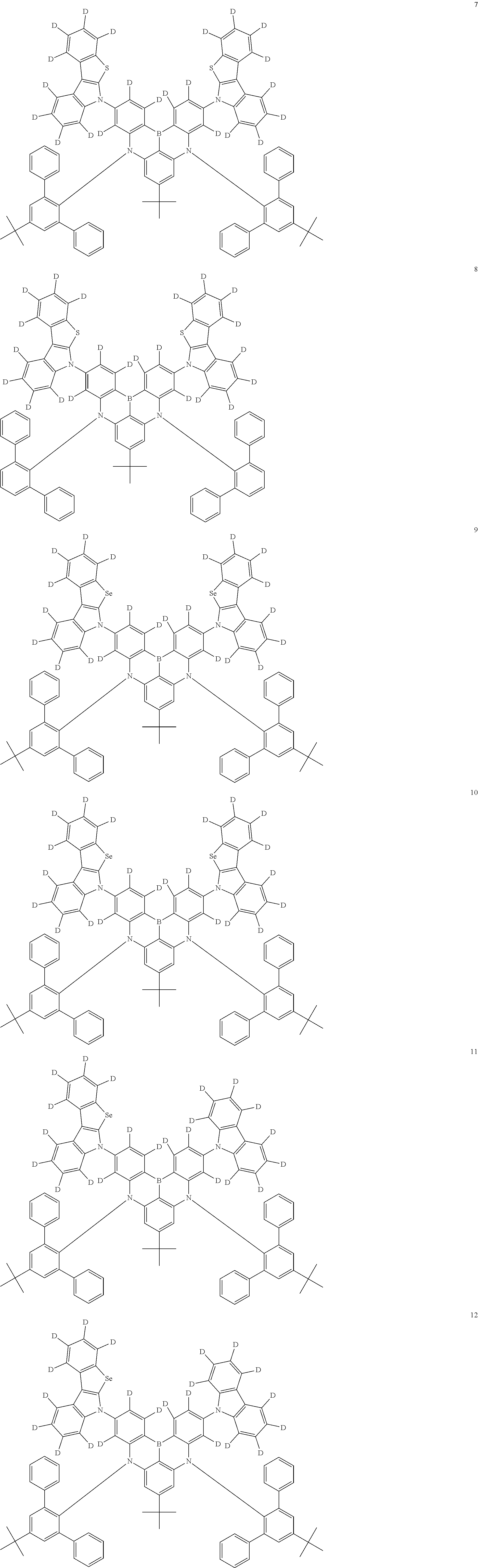 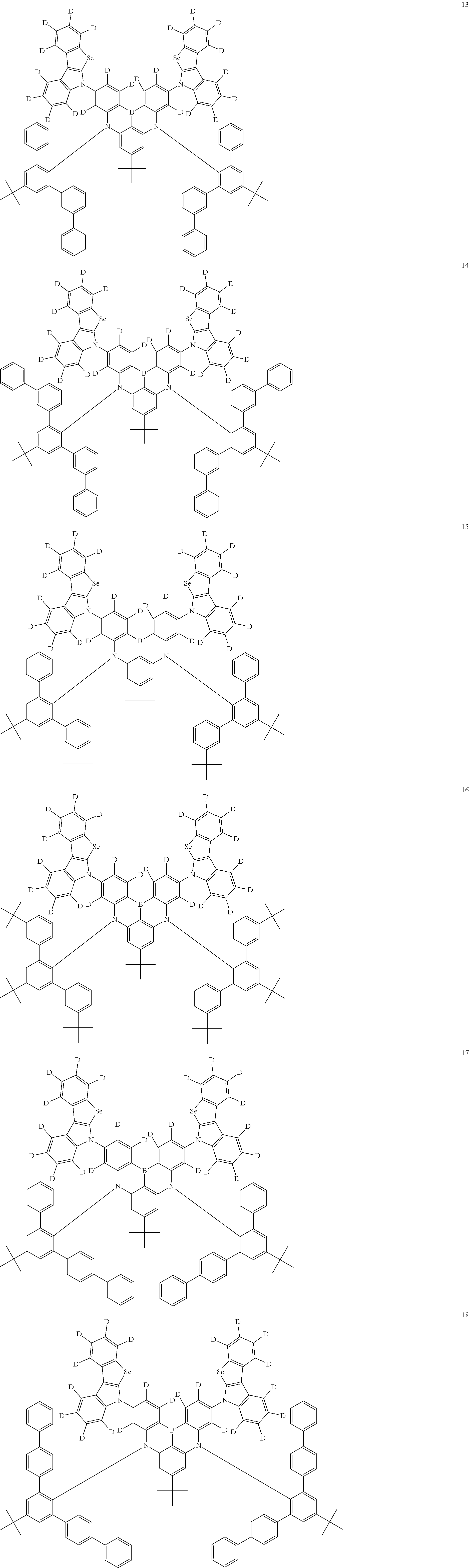 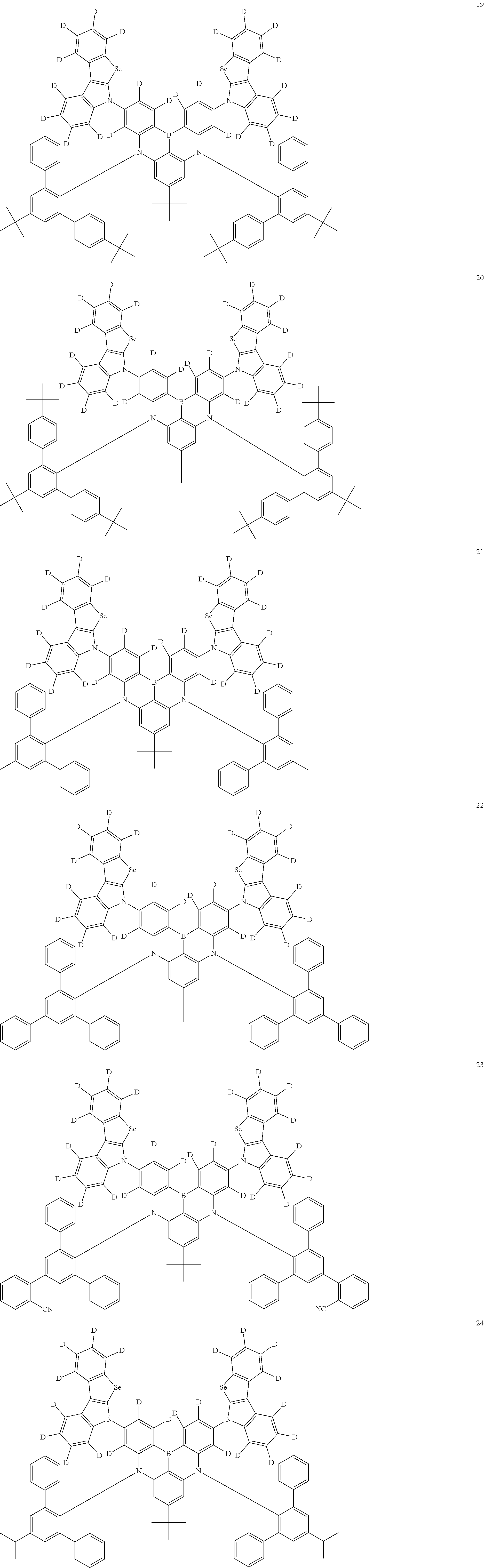 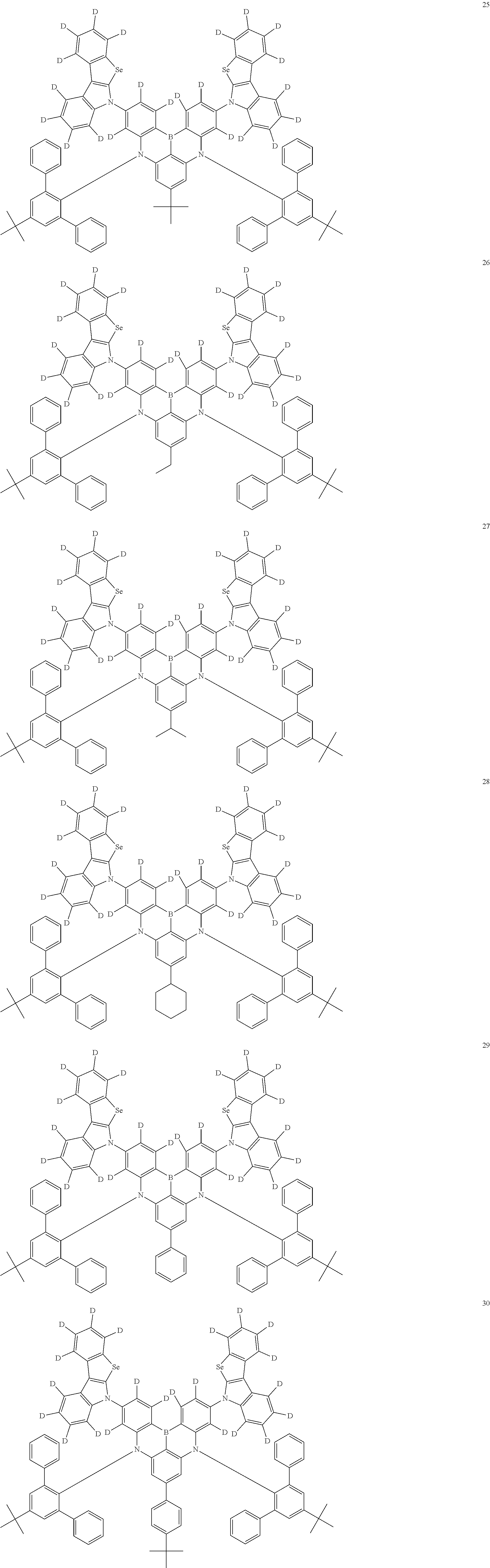 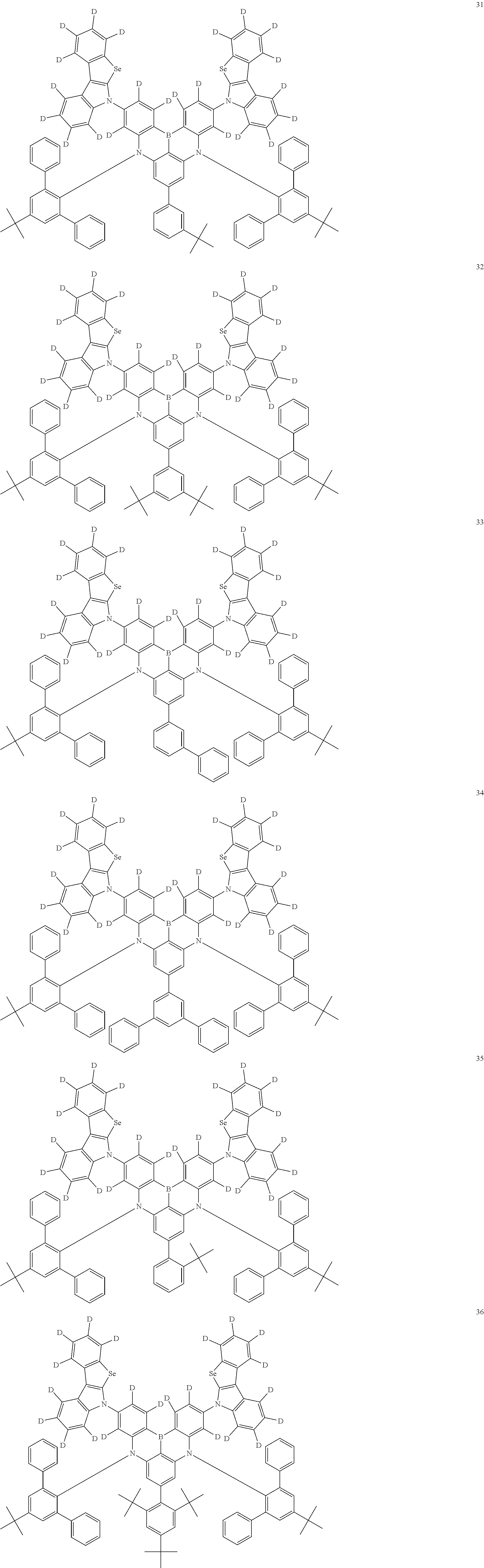 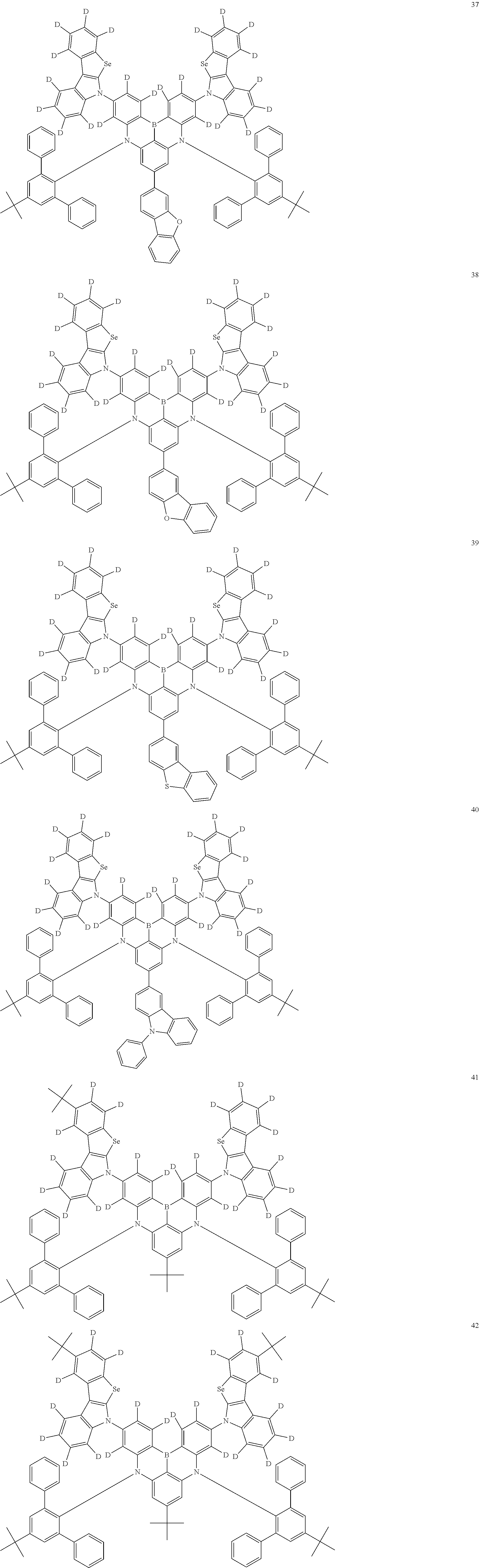 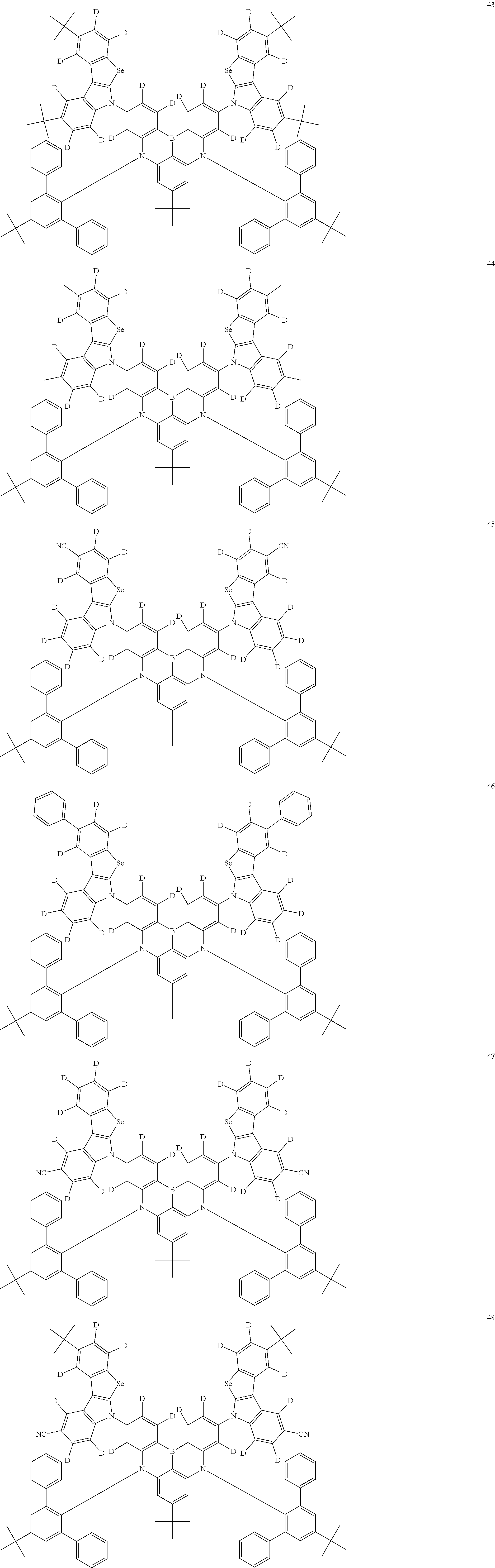 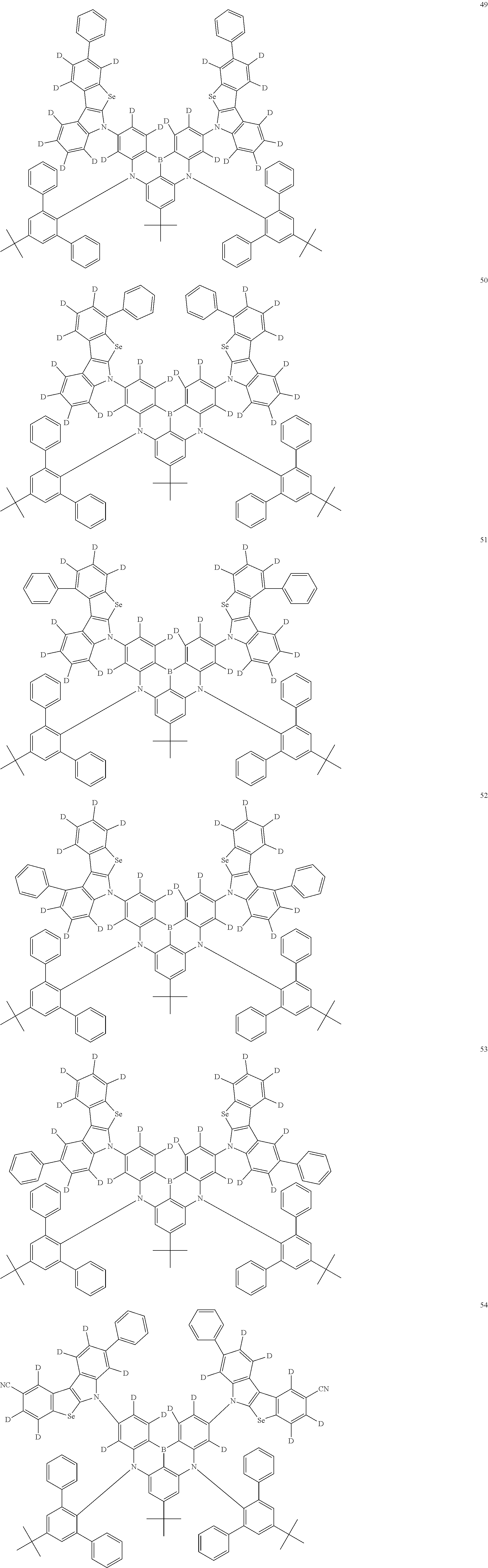 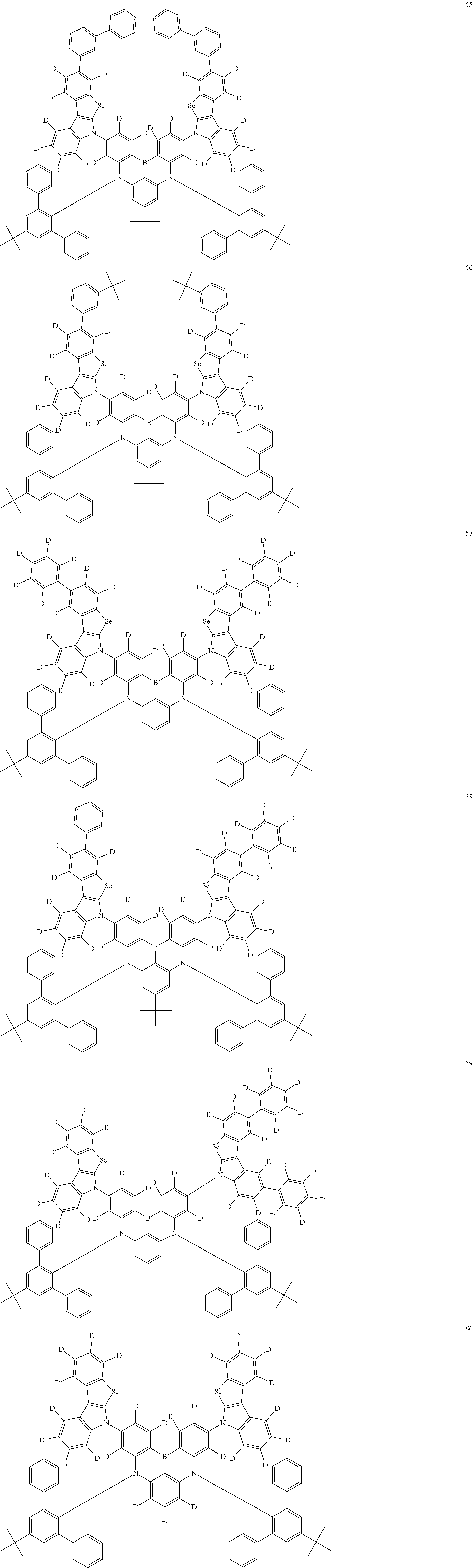 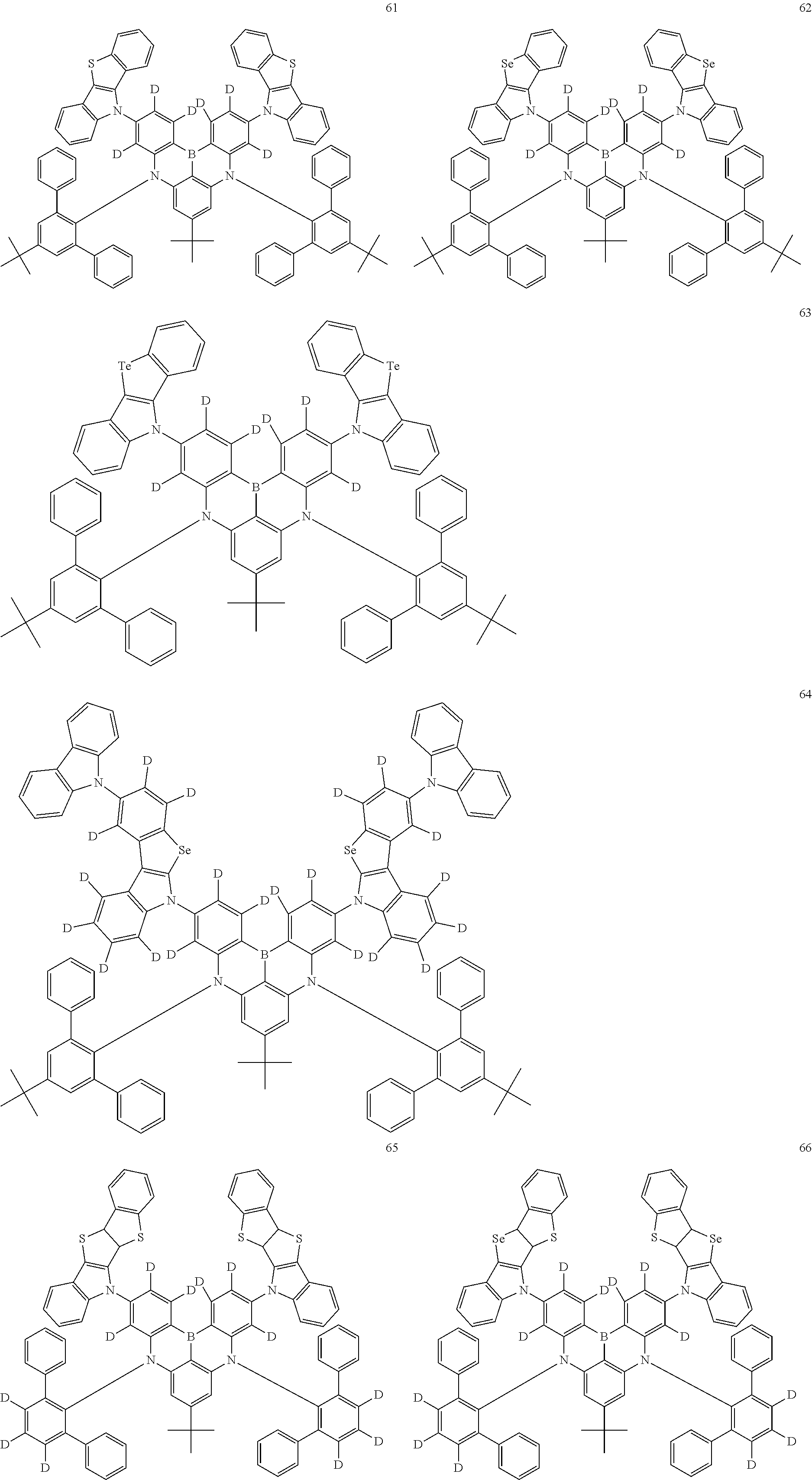 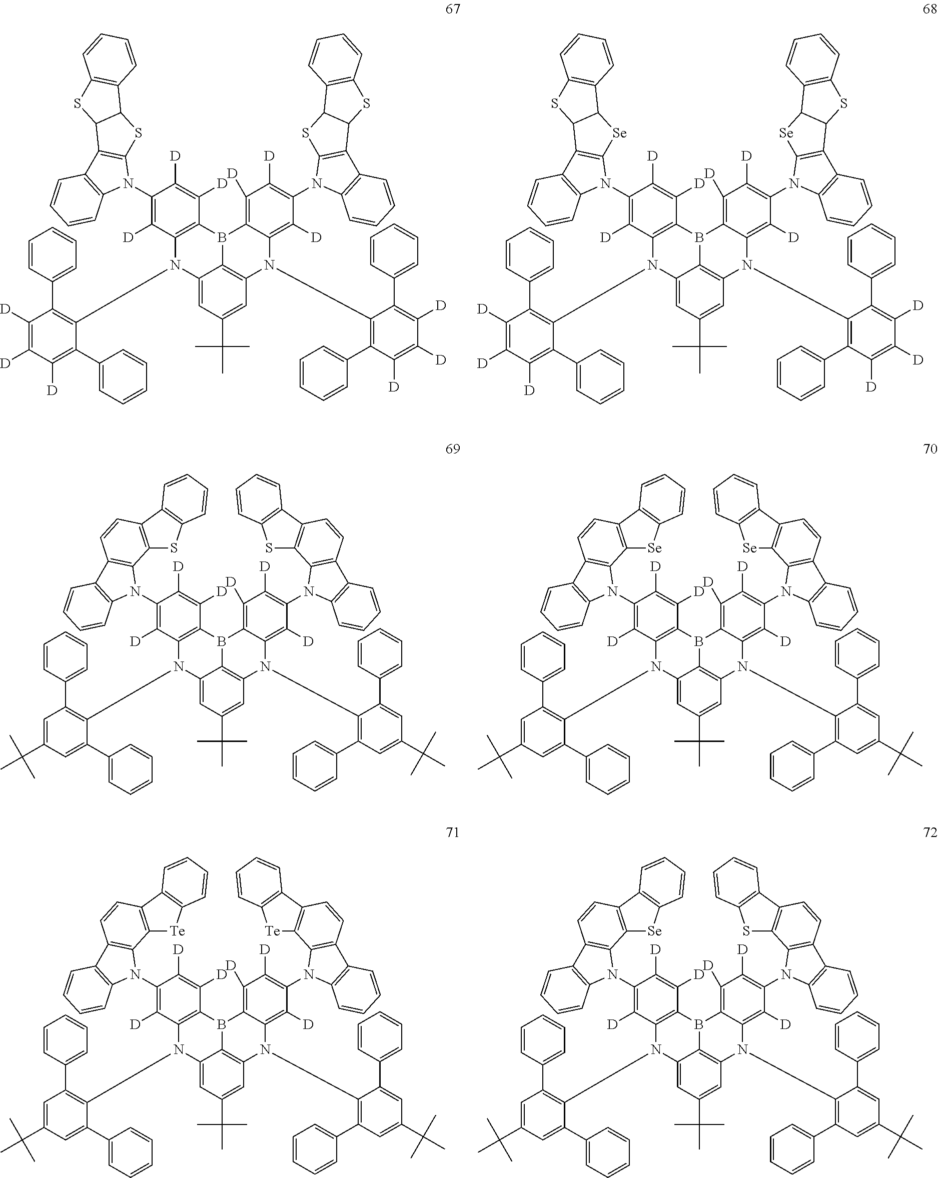 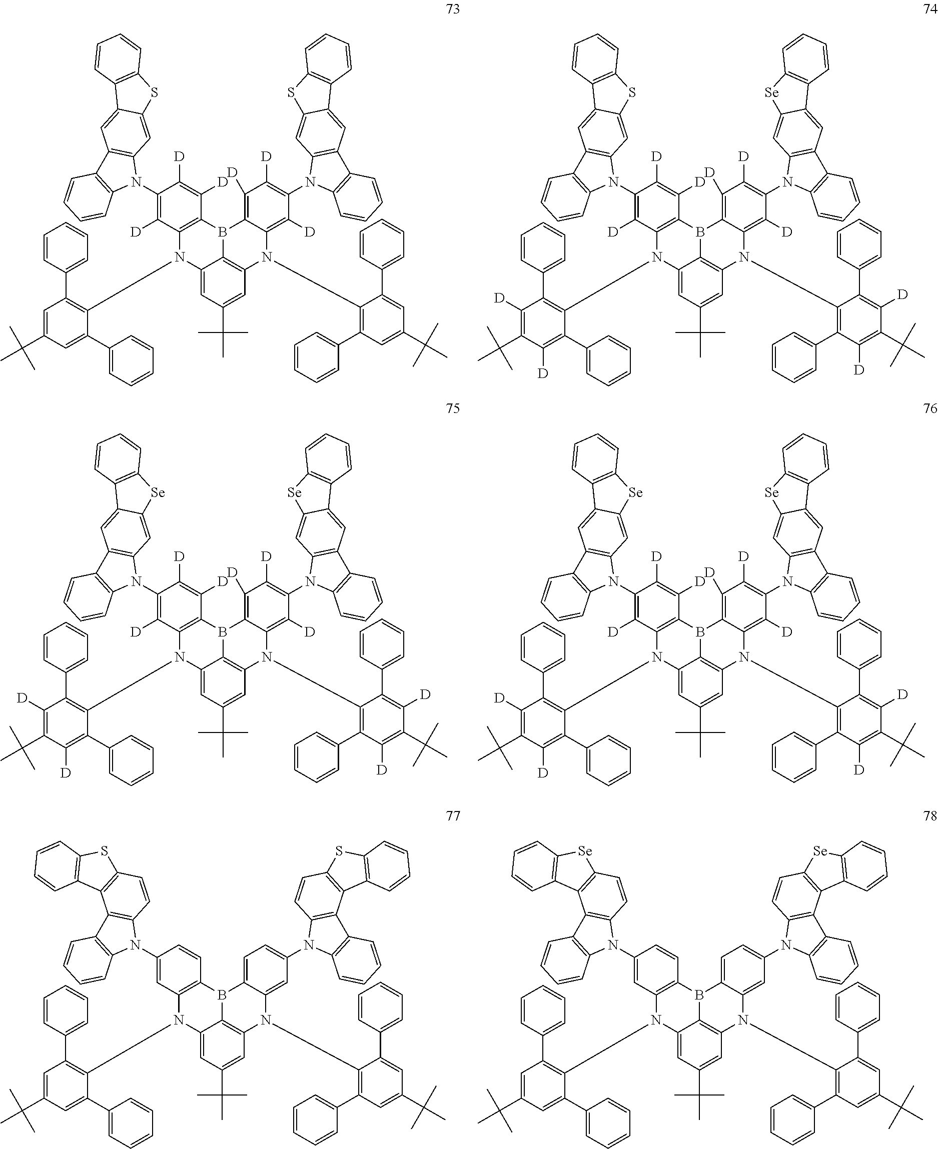 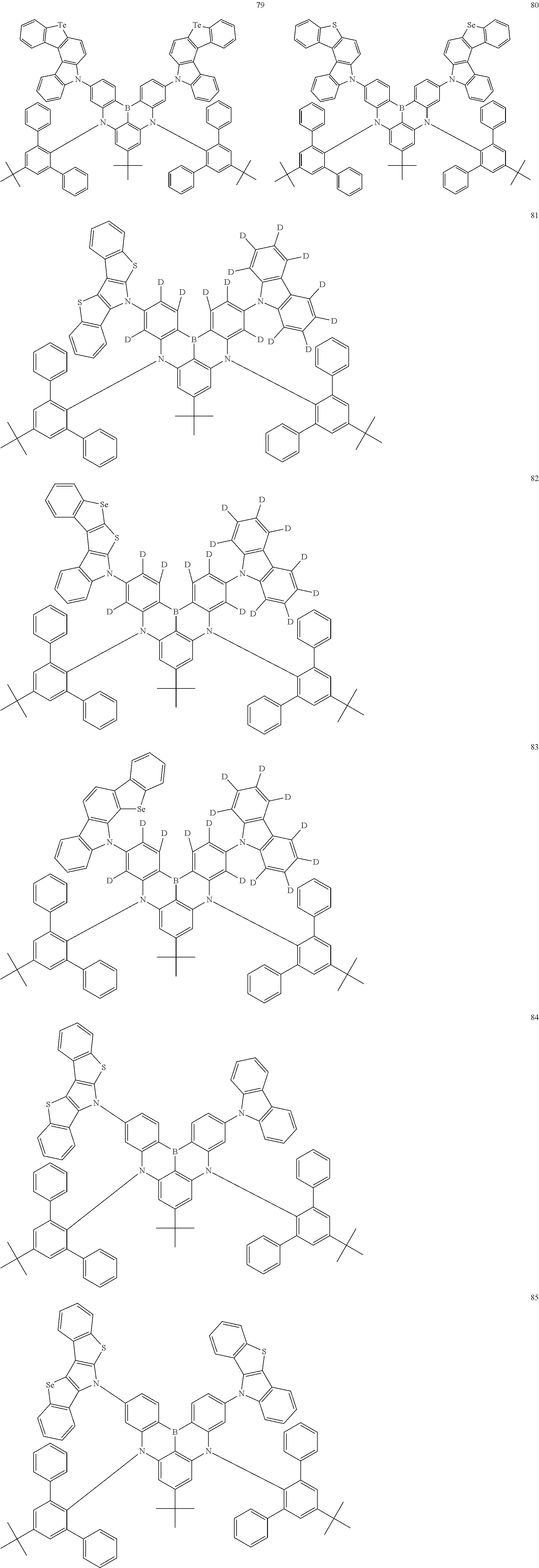 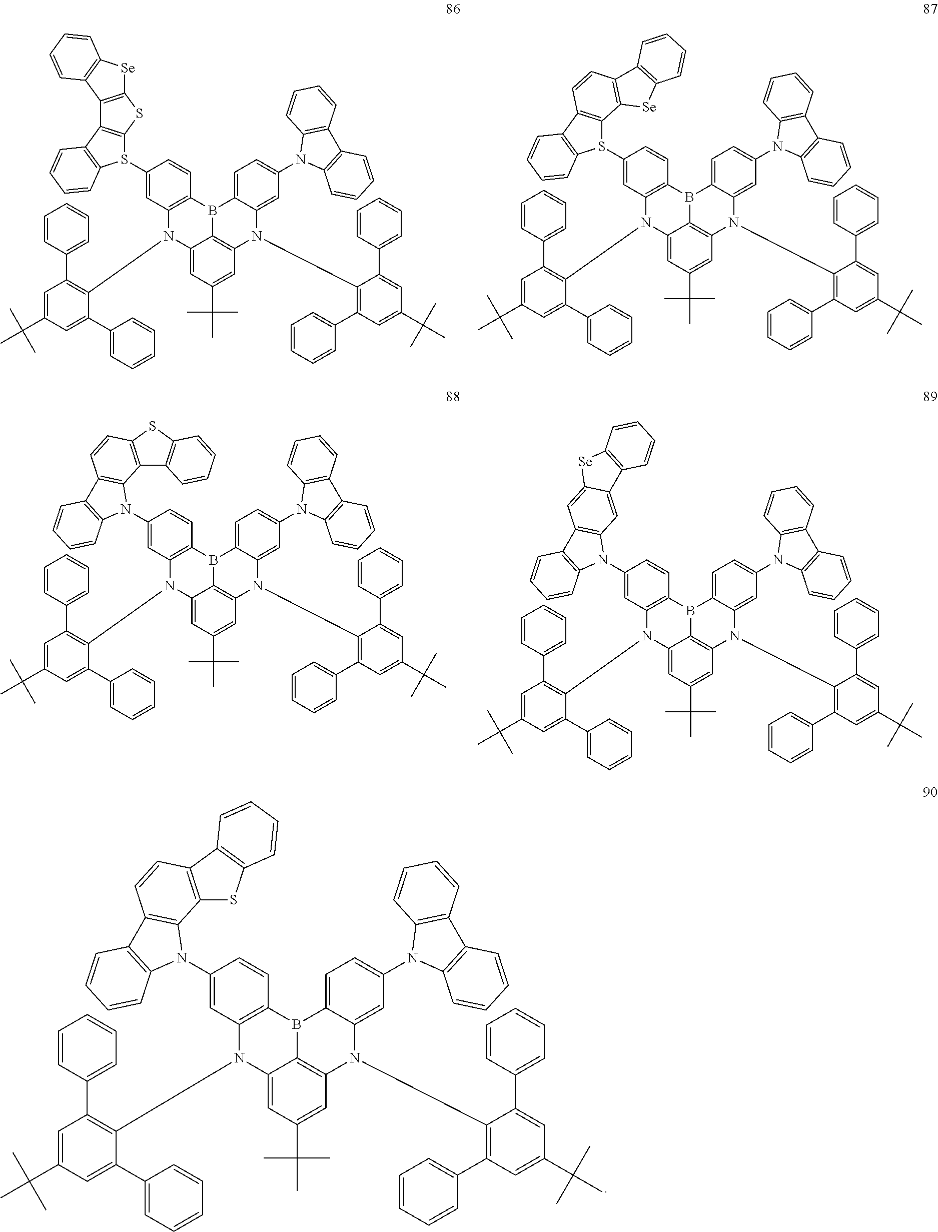
wherein in Compound Group 1,
D is a deuterium atom, and
H is a hydrogen atom.

20. A display device comprising:
a circuit layer disposed on a base layer; and
a display element layer disposed on the circuit layer and comprising a light emitting element, wherein
the light emitting element comprises:
a first electrode;
a second electrode disposed on the first electrode; and
an emission layer disposed between the first electrode and the second electrode and comprising a first compound represented by Formula 1: 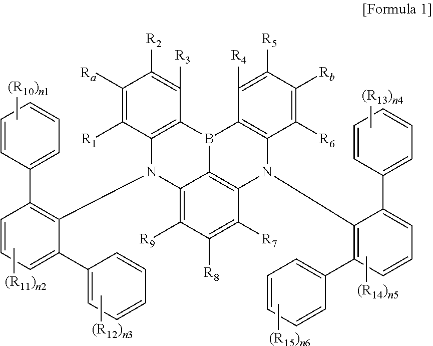
wherein in Formula 1,
R₁ to R₁₅ are each independently a hydrogen atom, a deuterium atom, a halogen atom, a cyano group, a hydroxy group, a substituted or unsubstituted oxy group, a substituted or unsubstituted thio group, a substituted or unsubstituted boron group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
Rₐ and R_{b} are each independently a substituted or unsubstituted heteroaryl group having 2 to 30 ring-forming carbon atoms and a nitrogen atom (N) as a ring-forming atom, or a group represented by Formula 2,
at least one of Rₐ and R_{b} is a group represented by Formula 2,
n1, n3, n4, and n6 are each independently an integer from 0 to 5, and
n2 and n5 are each independently an integer from 0 to 3: 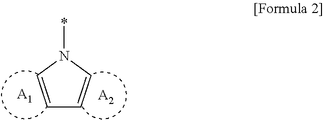
wherein in Formula 2,
A₁ and A₂ are each independently a substituted or unsubstituted hydrocarbon ring having 6 to 30 ring-forming carbon atoms or a substituted or unsubstituted heterocycle having 2 to 30 ring-forming carbon atoms,
at least one of A₁ and A₂ is a heterocycle including, as a ring-forming atom, at least one of a sulfur atom (S), a selenium atom (Se), and a tellurium atom (Te), and [symbol]
is a position linked to Formula 1.
